(19) United States
(12) Patent Application Publication
(10) Pub. No.: US 2025/0306462 A1
(43) Pub. Date: Oct. 2, 2025

(54) PATTERNING PROCESS AND RESIST MATERIAL

(71) Applicant: SHIN-ETSU CHEMICAL CO., LTD., Tokyo (JP)

(72) Inventors: Jun HATAKEYAMA, Joetsu-shi (JP); Yutaro OTOMO, Joetsu-shi (JP)

(73) Assignee: SHIN-ETSU CHEMICAL CO., LTD., Tokyo (JP)

(21) Appl. No.: 19/086,964

(22) Filed: Mar. 21, 2025

(30) Foreign Application Priority Data
Mar. 27, 2024 (JP) 2024-052470

(51) Int. Cl. G03F 7/039; C08F 212/14; C08F 220/14; C08F 220/20; C08F 220/28; C08F 230/08; G03F 7/004

(52) U.S. Cl. CPC G03F 7/039; C08F 212/24; C08F 220/14; C08F 220/20; C08F 220/281; C08F 220/282; C08F 230/085; G03F 7/0045

(57) ABSTRACT

The present invention is a patterning process including: providing a resist material containing a polymer having a silicon-containing acid-labile group; forming a resist film by using the resist material; and subjecting the resist film to exposure and baking, and then to development by dry etching to form a pattern. This can provide a patterning process according to which a fine pattern can be formed with a high aspect ratio and without pattern collapse occurring.

### TECHNICAL FIELD

The present invention relates to: a patterning process; and a resist material.

### BACKGROUND ART

As LSIs advance toward higher integration and higher processing speed, miniaturization of pattern rule is progressing rapidly. This is because the spread of high-speed communication of 5 G and artificial intelligence (AI) has progressed, and high-performance devices for processing these are needed. As a cutting-edge technology for miniaturization, 5-nm node and 3-nm node devices have been mass-produced by extreme ultraviolet ray (EUV) lithography at a wavelength of 13.5 nm. Furthermore, studies are also in progress on employing EUV lithography in next-generation 2-nm node and the following-generation 14-Å node devices. IMEC in Belgium has announced the development of devices of 2 Å.

As the miniaturization progresses, image blurs due to acid diffusion become a problem. To ensure resolution for fine patterns with dimensional sizes of 45 nm and smaller, there is a proposal that it is important to not only improve dissolution contrast as previously reported, but also control acid diffusion (Non Patent Document 1). Nevertheless, since chemically-amplified resist materials enhance the sensitivity and contrast through acid diffusion, an attempt to minimize acid diffusion by reducing the temperature and/or time of post-exposure baking (PEB) results in significant reductions of sensitivity and contrast.

A triangular tradeoff relationship among sensitivity, resolution, and edge roughness (LWR) has been pointed out. Specifically, resolution improvement requires suppression of acid diffusion, whereas shortening acid diffusion distance results in the reduction of sensitivity.

The addition of an acid generator capable of generating a bulky acid is effective in suppressing acid diffusion. Hence, it has been proposed to incorporate in a polymer a repeating unit derived from an onium salt having a polymerizable unsaturated bond. In this case, the polymer also functions as an acid generator (polymer-bound acid generator). Patent Document 1 proposes a sulfonium and iodonium salt having a polymerizable unsaturated bond that generates a particular sulfonic acid. Patent Document 2 proposes a sulfonium salt having a sulfonic acid moiety directly bonded to the main chain.

It is reported that pattern collapse determines the resolution limit of a resist (Non Patent Document 1) Patterns collapse due to the stress applied to the pattern during spin-drying after rinsing in aqueous alkaline development. To reduce the stress during spin-drying, it is effective to reduce the surface tension of the rinsing liquid, and rinsing liquids containing a surfactant is used for this purpose, but this is not sufficient for line patterns having dimensions with a pattern pitch of 20 nm or less. The use of rinsing with carbon dioxide in a supercritical state, where the surface tension is 0, has been considered, but a special chamber is necessary for creating a high-pressure supercritical state, and this is not practical from the viewpoint of improving throughput. There has been proposed a method of filling spaces between patterns with a water-soluble silicon-containing rinsing liquid and performing dry etching with oxygen gas, but there is a problem that image reversal occurs.

As an alternative method, there has been proposed a patterning process in which exposed portions are opened by performing dry etching on a resist pattern in which the exposed portions have shrunk due to deprotection of acid-labile groups by exposure and PEB (Patent Document 3). However, even in this method, if the shrinkage amount of an exposed portion is large, there are problems that a two-dimensional pattern having an L-shape or the like becomes deformed or that the cross-sectional shape of a line becomes triangular.

There has been proposed a dry development process in which a resist containing a blend of a trimethylsilyl group-containing polyphthalaldehyde and an acid generator is exposed and the polyphthalaldehyde is decomposed and evaporated by PEB after the exposure to form a positive pattern, and then the pattern is transferred to an underlying substrate by etching with oxygen gas (Non Patent Document 2). In this process, a pattern is formed by exposing a resist film and performing heat development while baking, and therefore, to achieve favorable patterning, it is necessary to set the PEB conditions in such a manner as to achieve appropriate decomposition of the polyphthalaldehyde. Therefore, process conditions are limited, and it is difficult to improve sensitivity and resolution.

For a long time, there has been considered surface layer imaging, where a resist surface that has become hydrophilic by the deprotection of acid-labile groups caused by exposure and PEB is treated with a gas or solution of a silicon compound to silylate the resist surface and the resist surface is dry-etched to form a pattern (Patent Document 4). In surface imaging, pattern collapse does not occur, but there is a problem that edge roughness (LWR) is poor.

In addition, there are proposals of bilayer resists containing a polymer substituted with a silicon-containing acid-labile group (Non Patent Document 3 and Patent Documents 5 to 7).

### CITATION LIST

### Patent Literature

Patent Document 1: JP 2006-045311 A
Patent Document 2: JP 2006-178317 A
Patent Document 3: JP 2023-157346 A
Patent Document 4: JP H7-22304 A
Patent Document 5: JP 2001-278918 A
Patent Document 6: JP 2001-158808 A
Patent Document 7: JP 2002-105130 A

### Non Patent Literature

Non Patent Document 1: SPIE Vol. 6153 p 61531C-1 (2006)
Non Patent Document 2: J. Electrochem. Soc. 136, p 245, (1989)
Non Patent Document 3: SPIE Vol. 3678 p 241 (1999)

### SUMMARY OF INVENTION

### Technical Problem

The present invention has been made in view of the above circumstances. An object of the present invention is to provide a patterning process according to which a fine pattern can be formed with a high aspect ratio and without pattern collapse occurring.

### Solution to Problem

To achieve the object, the present invention provides a patterning process comprising:
providing a resist material containing a polymer having a silicon-containing acid-labile group;
forming a resist film by using the resist material; and
subjecting the resist film to exposure and baking, and then to development by dry etching to form a pattern.

According to the inventive patterning process, a fine pattern can be formed with a high aspect ratio without pattern collapse occurring.

In the present invention, the polymer having the silicon-containing acid-labile group preferably has any one or more of repeating units represented by the following general formulae (a1) to (a3),

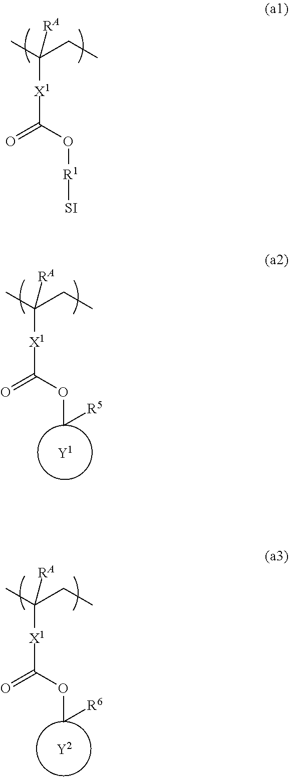

wherein each R^{A} independently represents a hydrogen atom or a methyl group; R¹ represents a linear, branched, or cyclic divalent hydrocarbon group having 1 to 12 carbon atoms and optionally having a trimethylsilyl group or a trimethylsilyloxy group; SI is represented by R²R³R⁴Si and is an organosilicon group containing 1 to 4 silicon atoms; R², R³, and R⁴ each independently represent a trimethylsilyl group, a trimethylsilyloxy group, or a linear, branched, or cyclic monovalent aliphatic hydrocarbon group having 1 to 14 carbon atoms, optionally having a double bond or a triple bond, and optionally having a trimethylsilyl group or a trimethylsilyloxy group; R⁵ represents a linear, branched, or cyclic alkyl group having 1 to 6 carbon atoms and optionally having a silicon atom; R⁶ represents a linear, branched, or cyclic hydrocarbon group having 1 to 6 carbon atoms and having a silicon atom; X¹ represents a single bond, a phenylene group, a naphthylene group, or —C(═O)—R⁷—; R⁷ represents a phenylene group, a naphthylene group, or a linear, branched, or cyclic alkylene group having 1 to 10 carbon atoms and optionally having an oxygen atom, a sulfur atom, or a nitrogen atom; ring Y¹ represents a cyclic organosilicon group having one or more silicon atoms; and ring Y² represents a cyclic organic group not having a silicon atom.

According to the method using a polymer having a silicon-containing acid-labile group having such a repeating unit, a fine pattern can be formed more favorably with a high aspect ratio without pattern collapse occurring.

In this case, a resist material containing a polymer having a repeating unit-b having an acid-generating moiety in addition to the one or more of the repeating units is preferably used.

By using a polymer incorporating an acid-generating moiety (polymer-bound acid generator) as described, a suitable acid-generating function in the resist material can be achieved.

Here, the repeating unit-b having the acid-generating moiety is preferably any one or more of repeating units selected from repeating units represented by the following formulae (b1) to (b5),

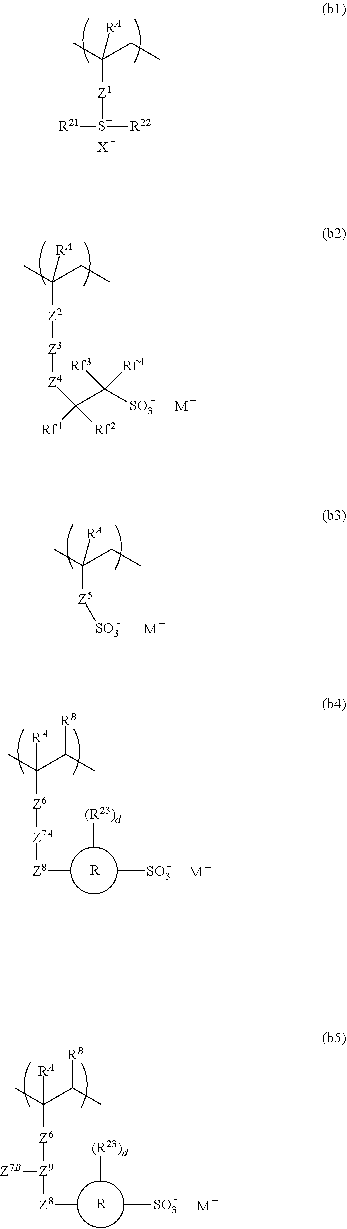

wherein each R^{A} independently represents a hydrogen atom or a methyl group; each R^{B} independently represents a hydrogen atom or is optionally bonded to Z⁶ to form a ring; Z¹ represents a single bond, an aliphatic hydrocarbylene group having 1 to 6 carbon atoms, a phenylene group, a naphthylene group, a group having 7 to 18 carbon atoms derived from a combination of these groups, —O—Z¹¹—, —C(═O)—O—Z¹¹—, or —C(═O)—NH—Z¹¹—; Z¹¹ represents an aliphatic hydrocarbylene group having 1 to 6 carbon atoms, a phenylene group, a naphthylene group, or a group having 7 to 18 carbon atoms derived from a combination of these groups, Z¹¹ optionally containing a carbonyl group, an ester bond, an ether bond, or a hydroxy group; Z² represents a single bond or an ester bond; Z³ represents a single bond, —Z³¹—C(═O)—O—, or —Z³¹—O—; Z³¹ represents a hydrocarbylene group having 1 to 12 carbon atoms, a phenylene group, or a group having 7 to 18 carbon atoms derived from a combination of these groups, Z³¹ optionally containing a carbonyl group, a nitro group, a cyano group, an ester bond, an ether bond, a urethane bond, a fluorine atom, an iodine atom, or a bromine atom; Z⁴ represents a single bond, a methylene group, or an ethylene group; Z⁵ represents a single bond, a methylene group, an ethylene group, a phenylene group, a methylphenylene group, a dimethylphenylene group, a fluorinated phenylene group, a phenylene group substituted with a trifluoromethyl group, —O—Z⁵¹—, —C(═O)—O—Z⁵¹—, or —C(═O)—NH—Z⁵¹—; Z⁵¹ represents an aliphatic hydrocarbylene group having 1 to 6 carbon atoms, a phenylene group, a methylphenylene group, a dimethylphenylene group, a fluorinated phenylene group, or a phenylene group substituted with a trifluoromethyl group, Z⁵¹ optionally containing a carbonyl group, an ester bond, an ether bond, a hydroxy group, or a halogen atom; Z⁶ represents a single bond, a phenylene group, a naphthylene ring, an ester bond, or an amide bond; Z^{7A} represents a single bond or a divalent organic group having 1 to 24 carbon atoms, Z^{7A} optionally having at least one selected from a halogen atom, an oxygen atom, a nitrogen atom, and a sulfur atom; Z^{7B} represents a monovalent organic group having 1 to 10 carbon atoms, Z^{7B} optionally having at least one selected from a halogen atom, an oxygen atom, a nitrogen atom, and a sulfur atom; Z⁸ represents a single bond, an ether bond, an ester bond, a thioether bond, or an alkanediyl group having 1 to 6 carbon atoms; Z⁹ represents a trivalent organic group having 1 to 12 carbon atoms, Z⁹ optionally having at least one selected from an oxygen atom, a nitrogen atom, and a sulfur atom; Rf¹ to Rf⁴ each independently represent a hydrogen atom, a fluorine atom, or a trifluoromethyl group, provided that at least one of Rf¹ to Rf⁴ is a fluorine atom or a trifluoromethyl group, Rf¹ and Rf² optionally being combined to form a carbonyl group together with the carbon atom bonded to Rf¹ and Rf²; R²¹ and R²² each independently represent a halogen atom or a hydrocarbyl group having 1 to 20 carbon atoms and optionally containing a heteroatom; R²³ represents a saturated hydrocarbyl group having 1 to 10 carbon atoms, an aryl group having 6 to 10 carbon atoms, a fluorine atom, an iodine atom, a trifluoromethoxy group, a difluoromethoxy group, a cyano group, or a nitro group; ring R represents a (d+2)-valent aromatic hydrocarbon group having 6 to 10 carbon atoms; “d” represents an integer of 0 to 5; X⁻ represents a non-nucleophilic counter ion; and M⁺ represents a sulfonium cation or an iodonium cation.

In the present invention, by using a polymer incorporating a repeating unit-b having such an acid-generating moiety, a fine pattern with a high aspect ratio can be formed more favorably without pattern collapse.

In this case, the repeating unit-b having the acid-generating moiety can be any one or more repeating units selected from the repeating units represented by the formulae (b2) to (b5) in which the Z³, the Z^{7A}, the Z^{7B}, or the M⁺ contains one or more iodine atoms.

By using such a repeating unit containing an iodine atom, more suitable pattern formation is possible.

In the present invention, the exposure can be performed with an extreme ultraviolet ray having a wavelength of 3 to 15 nm or an electron beam with an acceleration voltage of 1 to 150 kV.

In the present invention, a fine pattern with a high aspect ratio can be formed more favorably without pattern collapse by using such high-energy beams.

The present invention also provides a resist material for patterning by dry etching, the resist material comprising a polymer having any one or more of repeating units represented by the following general formulae (a1) to (a3),

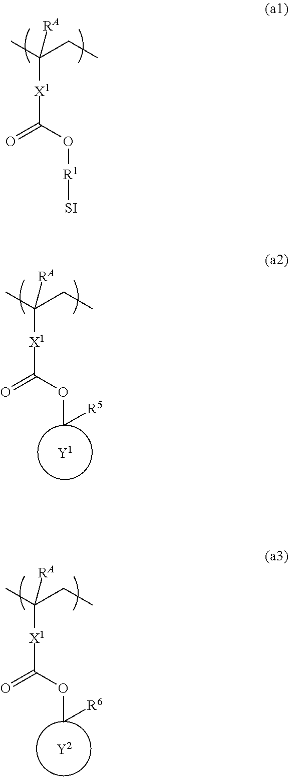

wherein each R^{A} independently represents a hydrogen atom or a methyl group; R¹ represents a linear, branched, or cyclic divalent hydrocarbon group having 1 to 12 carbon atoms and optionally having a trimethylsilyl group or a trimethylsilyloxy group; SI is represented by R²R³R⁴Si and is an organosilicon group containing 1 to 4 silicon atoms; R², R³, and R⁴ each independently represent a trimethylsilyl group, a trimethylsilyloxy group, or a linear, branched, or cyclic monovalent aliphatic hydrocarbon group having 1 to 14 carbon atoms, optionally having a double bond or a triple bond, and optionally having a trimethylsilyl group or a trimethylsilyloxy group; R⁵ represents a linear, branched, or cyclic alkyl group having 1 to 6 carbon atoms and optionally having a silicon atom; R⁶ represents a linear, branched, or cyclic hydrocarbon group having 1 to 6 carbon atoms and having a silicon atom; X¹ represents a single bond, a phenylene group, a naphthylene group, or —C(═O)—R⁷—; R⁷ represents a phenylene group, a naphthylene group, or a linear, branched, or cyclic alkylene group having 1 to 10 carbon atoms and optionally having an oxygen atom, a sulfur atom, or a nitrogen atom; ring Y¹ represents a cyclic organosilicon group having one or more silicon atoms; and ring Y² represents a cyclic organic group not having a silicon atom.

Such a resist material can be used suitably in the inventive patterning process.

In the present invention, the polymer preferably further has a repeating unit-b having an acid-generating moiety containing one or more iodine atoms.

Such a resist material makes it possible to form a fine pattern with a high aspect ratio more suitably while suppressing pattern collapse in a patterning process in which the resist material is used.

In the present invention, it is also preferable that the polymer is a copolymer further having any one or more of repeating units selected from repeating units represented by the following formulae (b1) to (b5),

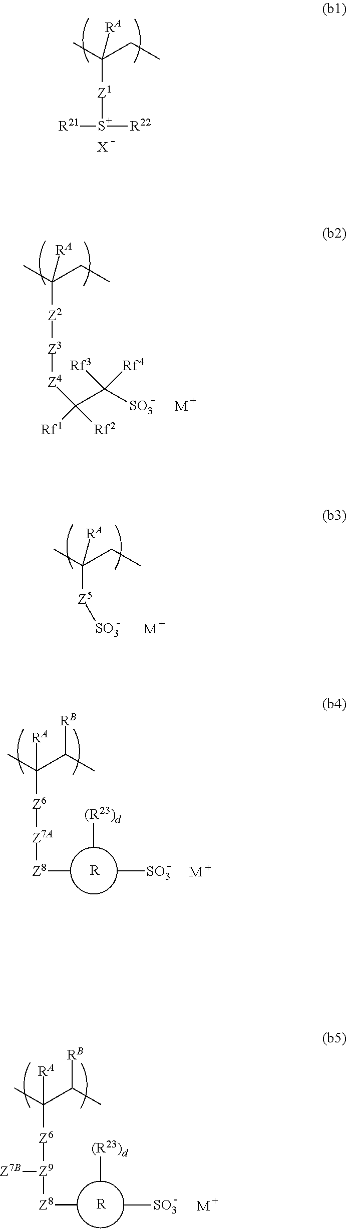

wherein each R^{A} independently represents a hydrogen atom or a methyl group; each R^{B} independently represents a hydrogen atom or is optionally bonded to Z⁶ to form a ring; Z¹ represents a single bond, an aliphatic hydrocarbylene group having 1 to 6 carbon atoms, a phenylene group, a naphthylene group, a group having 7 to 18 carbon atoms derived from a combination of these groups, —O—Z¹¹—, —C(═O)—O—Z¹¹—, or —C(═O)—NH—Z¹¹—; Z¹¹ represents an aliphatic hydrocarbylene group having 1 to 6 carbon atoms, a phenylene group, a naphthylene group, or a group having 7 to 18 carbon atoms derived from a combination of these groups, Z¹¹ optionally containing a carbonyl group, an ester bond, an ether bond, or a hydroxy group; Z² represents a single bond or an ester bond; Z³ represents a single bond, —Z³¹—C(═O)—O—, or —Z³¹—O—; Z³¹ represents a hydrocarbylene group having 1 to 12 carbon atoms, a phenylene group, or a group having 7 to 18 carbon atoms derived from a combination of these groups, Z³¹ optionally containing a carbonyl group, a nitro group, a cyano group, an ester bond, an ether bond, a urethane bond, a fluorine atom, an iodine atom, or a bromine atom; Z⁴ represents a single bond, a methylene group, or an ethylene group; Z⁵ represents a single bond, a methylene group, an ethylene group, a phenylene group, a methylphenylene group, a dimethylphenylene group, a fluorinated phenylene group, a phenylene group substituted with a trifluoromethyl group, —O—Z⁵¹—, —C(═O)—O—Z⁵¹—, or —C(═O)—NH—Z⁵¹—; Z⁵¹ represents an aliphatic hydrocarbylene group having 1 to 6 carbon atoms, a phenylene group, a methylphenylene group, a dimethylphenylene group, a fluorinated phenylene group, or a phenylene group substituted with a trifluoromethyl group, Z⁵¹ optionally containing a carbonyl group, an ester bond, an ether bond, a hydroxy group, or a halogen atom; Z⁶ represents a single bond, a phenylene group, a naphthylene ring, an ester bond, or an amide bond; Z^{7A} represents a single bond or a divalent organic group having 1 to 24 carbon atoms, Z^{7A} optionally having at least one selected from a halogen atom, an oxygen atom, a nitrogen atom, and a sulfur atom; Z^{7B} represents a monovalent organic group having 1 to 10 carbon atoms, Z^{7B} optionally having at least one selected from a halogen atom, an oxygen atom, a nitrogen atom, and a sulfur atom; Z⁸ represents a single bond, an ether bond, an ester bond, a thioether bond, or an alkanediyl group having 1 to 6 carbon atoms; Z⁹ represents a trivalent organic group having 1 to 12 carbon atoms, Z⁹ optionally having at least one selected from an oxygen atom, a nitrogen atom, and a sulfur atom; Rf¹ to Rf⁴ each independently represent a hydrogen atom, a fluorine atom, or a trifluoromethyl group, provided that at least one of Rf¹ to Rf⁴ is a fluorine atom or a trifluoromethyl group, Rf¹ and Rf² optionally being combined to form a carbonyl group together with the carbon atom bonded to Rf¹ and Rf²; R²¹ and R²² each independently represent a halogen atom or a hydrocarbyl group having 1 to 20 carbon atoms and optionally containing a heteroatom; R²³ represents a saturated hydrocarbyl group having 1 to 10 carbon atoms, an aryl group having 6 to 10 carbon atoms, a fluorine atom, an iodine atom, a trifluoromethoxy group, a difluoromethoxy group, a cyano group, or a nitro group; ring R represents a (d+2)-valent aromatic hydrocarbon group having 6 to 10 carbon atoms; “d” represents an integer of 0 to 5; X⁻ represents a non-nucleophilic counter ion; and M⁺ represents a sulfonium cation or an iodonium cation.

Such a resist material can be used further suitably in the inventive patterning process.

### Advantageous Effects of Invention

In the inventive patterning process, an acid is generated in a resist film by exposure, the acid-labile group containing silicon in the polymer undergoes deprotection and the silicon content is reduced, and exposed portions are opened by dry etching to form a positive pattern. Etching with a gas containing oxygen causes the etching rate to decrease in unexposed portions due to silicon-containing groups forming silicon dioxide, and causes the etching rate to increase in exposed portions due to the reduced silicon content. Positive patterns are formed by the difference in etching rate between exposed portions and unexposed portions being large. Development by dry etching makes it possible to form a fine pattern with a high aspect ratio, since pattern collapse due to capillary force does not occur.

### DESCRIPTION OF EMBODIMENTS

As stated above, as LSIs advance toward higher integration and higher processing speed, miniaturization of pattern rule is progressing, and in this situation, there have been demands for a patterning process in which pattern collapse and pattern deformation do not occur.

To achieve the object, the present inventors have earnestly studied, and found out that, by using a resist material containing, as a base, a polymer having a repeating unit substituted with an acid-labile group having a silicon atom, unexposed portions have silicon-containing groups and the contained amount of silicon is reduced in exposed portions by deprotection, and when this is dry-etched, the etching rate in the unexposed portions is decreased and the etching rate in the exposed portions is increased, thus increasing the selectivity of the etching rate between the exposed portions and the unexposed portions and making it possible to form a fine pattern with a high aspect ratio. Thus, the present invention has been completed.

That is, the present invention is a patterning process comprising:
providing a resist material containing a polymer (base polymer) having a silicon-containing acid-labile group;
forming a resist film by using the resist material; and
subjecting the resist film to exposure and baking, and then to development by dry etching to form a pattern. Incidentally, in the following, a base polymer may also be referred to as a base resin.

Hereinafter, the present invention will be described in detail, but the present invention is not limited thereto. In the present description, the recitations of numerical ranges by endpoints include all numbers subsumed within that range. An organic group, unless otherwise specified, refers to a hydrocarbon group which may contain a heteroatom such as an oxygen atom, a sulfur atom, a nitrogen atom or a halogen atom, and which may be saturated or unsaturated, and may be linear, branched or cyclic, and an organic group which further contains a silicon atom refers to an organosilicon group.

### [Patterning Process]

The inventive patterning process includes the following steps (i) to (iv):
(i) providing a resist material containing a polymer having a repeating unit substituted with an acid-labile group containing silicon;
(ii) forming a resist film by using the resist material and exposing the resist film;
(iii) baking the resist film after exposure; and
(iv) subjecting the baked resist film to development by dry etching to form a pattern.
   [Step (i)]

Step (i) is a step of providing a resist material containing a repeating unit substituted with a silicon-containing acid-labile group. Details of the resist material will be described later.

[Step (ii)]

Step (ii) is a step of forming a resist film by using the resist material and exposing the resist film. The resist film can be formed, for example, by applying the resist material containing the base resin onto a substrate and performing a heat treatment.

Specifically, for example, the resist material is applied onto a substrate for manufacturing an integrated circuit or a layer to be processed on the substrate (Si, SiO₂, SiN, SiON, TiN, WSi, BPSG, SOG, organic antireflective film, etc.), or a substrate for manufacturing a mask circuit or a layer to be processed on the substrate (Cr, CrO, CrON, MoSi₂, SiO₂, Ru, Ta, TaB, TaBN, TaBO, etc.) by an appropriate coating process, such as spin coating, roll coating, flow coating, dip coating, spray coating, or doctor coating, so that the coating film has a thickness of 0.1 to 2.0 μm. The resultant is prebaked on a hot plate at 60 to 150° C. for 10 seconds to 30 minutes, preferably at 80 to 120° C. for 30 seconds to 20 minutes to form a resist film.

Then, the resist film is exposed to be the target pattern via a predetermined mask or directly with a high-energy beam, such as ultraviolet ray, deep ultraviolet ray, electron beam (EB) with an acceleration voltage of 1 to 150 kV, extreme ultraviolet ray (EUV) having a wavelength of 3 to 15 nm, X-ray, soft X-ray, excimer laser, γ-ray, or synchrotron radiation. The exposure dose is preferably about 1 to 300 mJ/cm², particularly 10 to 200 mJ/cm², or about 1 to 500 μC/cm², particularly 5 to 400 μC/cm².

In the inventive patterning process, it is particularly preferable to perform the exposure with an extreme ultraviolet ray having a wavelength of 3 to 15 nm or with an electron beam with an acceleration voltage of 1 to 150 kV.

[Step (iii)]

Step (iii) is a step of baking (PEB) the resist film at 30 to 170° C. after the exposure. The PEB temperature is preferably 40 to 160° C., more preferably 50 to 150° C., and the treatment time is preferably 10 seconds to 30 minutes, more preferably 10 seconds to 20 minutes.

In the inventive patterning process, the heating in the PEB after the exposure can be performed, not only with a hot plate, but also by irradiation with infrared rays or a laser, hot-air blowing, or a method of inserting the wafer into an atmosphere having a temperature for baking.

Currently, most methods for heating a wafer are methods using a hot plate. By placing the silicon wafer on a hot plate, the resist film is heated by heat transfer from the wafer. The temperature at which to heat the resist film is adjusted by controlling the temperature of the hot plate.

[Step (iv)]

Step (iv) is a step of subjecting the resist film to development by dry etching after the baking. As the dry etching gas, it is possible to use a mixed gas in which a gas of oxygen, hydrogen, ammonia, fluorocarbon, chlorine, or bromine is diluted with nitrogen, argon, helium, carbon dioxide, carbon monoxide, sulfur dioxide, etc.

### [Resist Material]

As described above, the resist film is made of a resist material containing, as a base, a polymer having a repeating unit substituted with an acid-labile group containing silicon.

The silicon-containing acid-labile group is not particularly limited as long as it can protect a polar group, such as a carboxy group, of the repeating unit constituting the polymer main chain and can be removed by an acid. In particular, the repeating unit substituted with the silicon-containing acid-labile group is preferably represented by any one or more of the following formulae (a1) to (a3) (these repeating units are also referred to as repeating units-a).

The repeating unit constituting the main chain of the base polymer has a carboxy group, and the carboxy group is protected (substituted) with an acid-labile group. The acid-labile group is an organosilicon group, having a silicon atom. The resist film is formed in a state where the carboxy group bonded to the base polymer main chain is protected with the acid-labile group. Then, by exposing the resist film, deprotection is performed by the action of an acid.

Note that, in the following formulae, each of the groups substituting the carboxy group of the repeating unit, that is, the R¹—SI group, the ring Y¹ substituted with R⁵, and the ring Y² substituted with R⁶, is a silicon-containing acid-labile group.

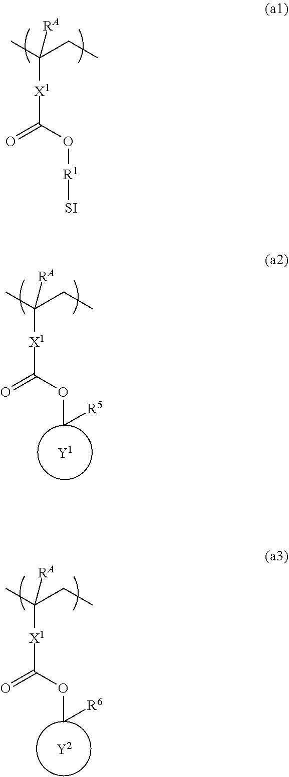

In the formulae, each R^{A} independently represents a hydrogen atom or a methyl group; R¹ represents a linear, branched, or cyclic divalent hydrocarbon group having 1 to 12 carbon atoms and optionally having a trimethylsilyl group or a trimethylsilyloxy group; SI is represented by R²R³R⁴Si and is an organosilicon group containing 1 to 4 silicon atoms; R², R³, and R⁴ each independently represent a trimethylsilyl group, a trimethylsilyloxy group, or a linear, branched, or cyclic monovalent aliphatic hydrocarbon group having 1 to 14 carbon atoms, optionally having a double bond or a triple bond, and optionally having a trimethylsilyl group or a trimethylsilyloxy group; R⁵ represents a linear, branched, or cyclic alkyl group having 1 to 6 carbon atoms and optionally having a silicon atom; R⁶ represents a linear, branched, or cyclic hydrocarbon group having 1 to 6 carbon atoms and having a silicon atom; X¹ represents a single bond, a phenylene group, a naphthylene group, or —C(═O)—R⁷—; R⁷ represents a phenylene group, a naphthylene group, or a linear, branched, or cyclic alkylene group having 1 to 10 carbon atoms and optionally having an oxygen atom, a sulfur atom, or a nitrogen atom; ring Y¹ represents a cyclic organosilicon group having one or more silicon atoms; and ring Y² represents a cyclic organic group not having a silicon atom.

Examples of a monomer to give the repeating unit represented by the formula (a1) (hereinafter, also referred to as repeating unit-a1) include ones shown below, but are not limited thereto. Note that, in the following formulae, R^{A} is as defined above, and the oxygen atom of the carboxy group and R¹ may be bonded via any of a primary, secondary, or tertiary carbon atom.

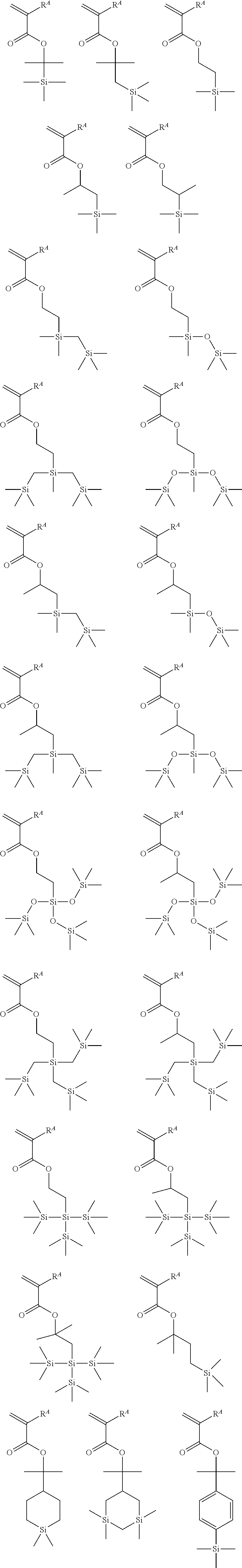

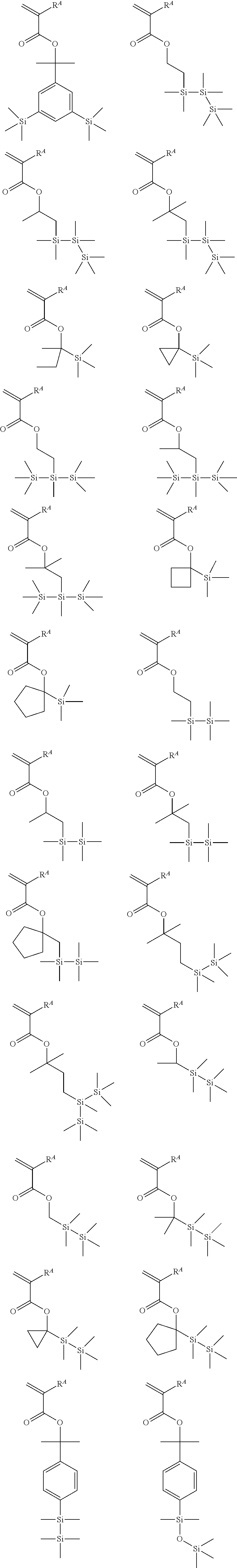

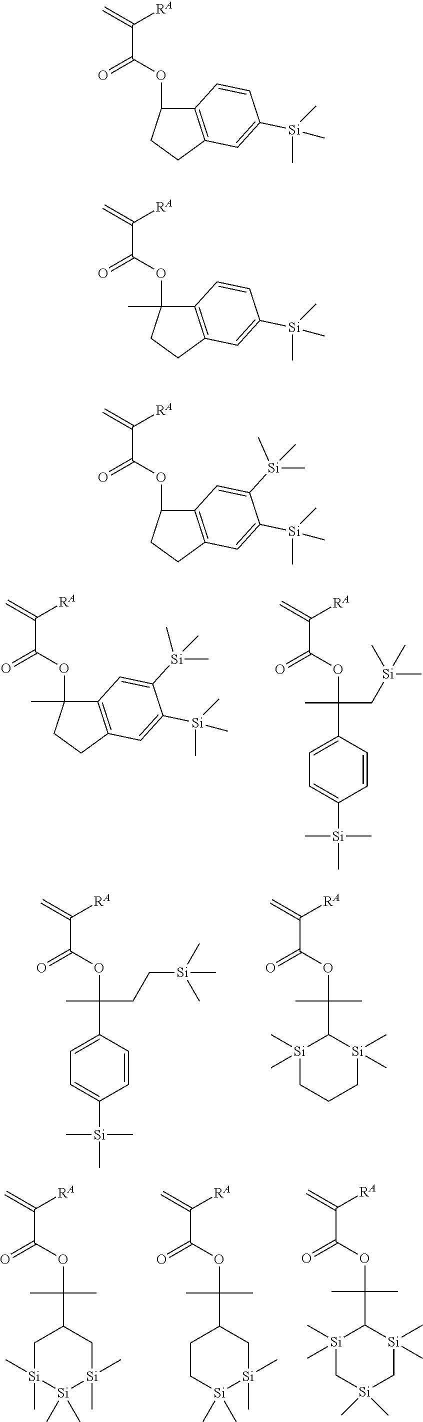

Examples of monomers to give the repeating units represented by the formulae (a2) and (a3) (hereinafter, also referred to as repeating units-a2 and -a3 respectively) include ones shown below, but are not limited thereto. Note that, in the following formulae, R^{A} is as defined above, and the oxygen atom of the carboxy group and the ring Y¹ or the ring Y² are bonded via a tertiary carbon atom constituting the ring.

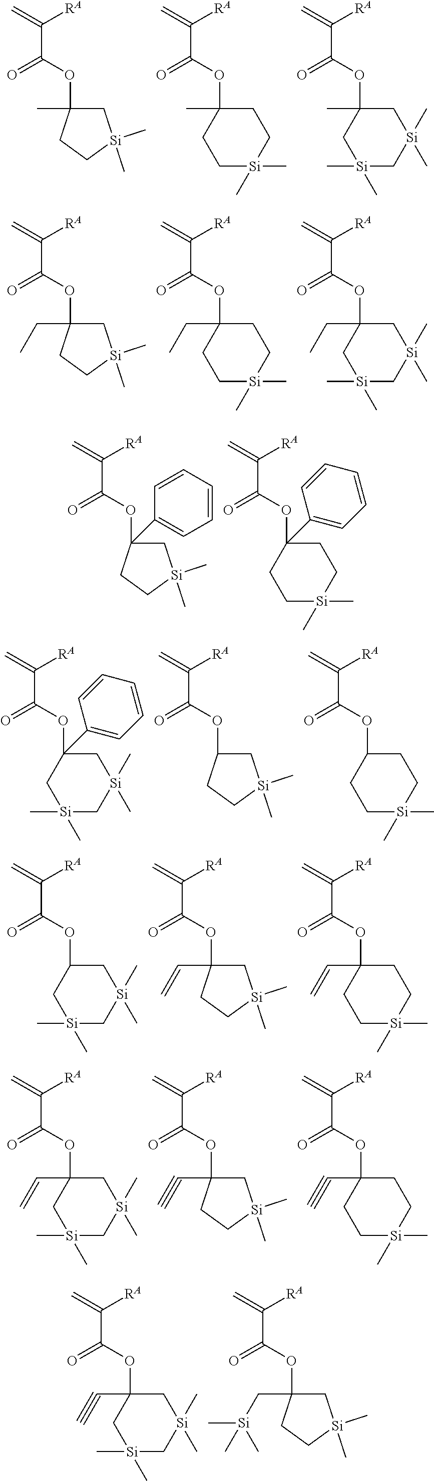

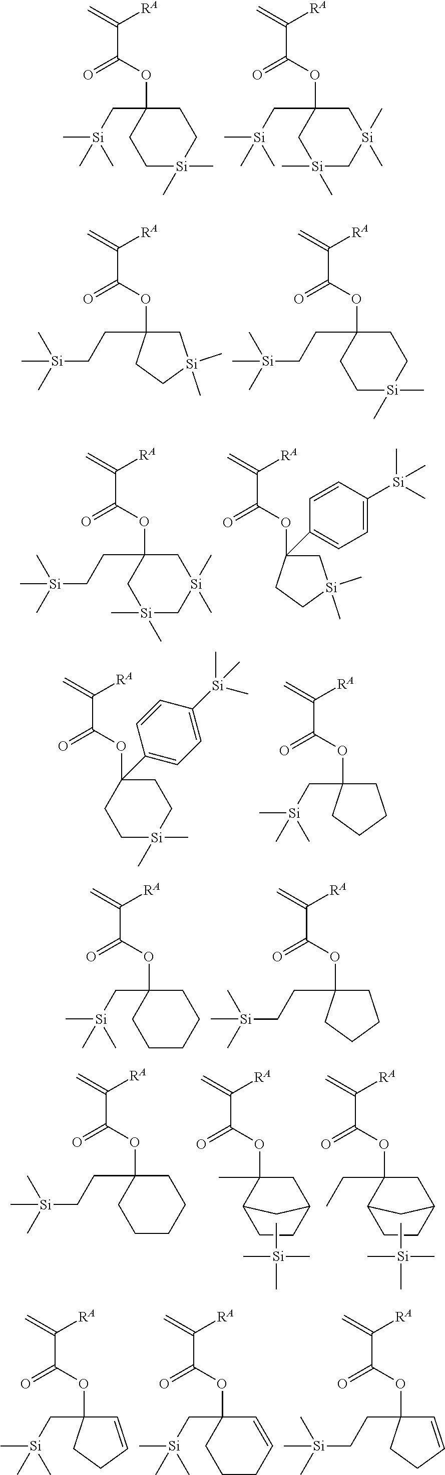

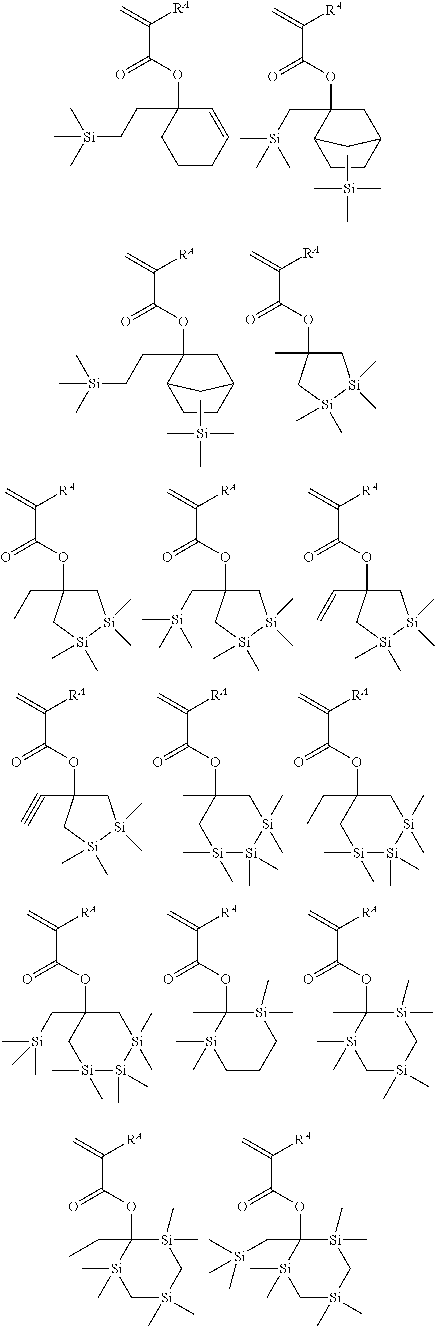

In the present invention, a repeating unit having a silicon-containing acid-labile group represented by any of the general formulae (a1) to (a3) can be contained, and a repeating unit having a conventional acid-labile group, not containing silicon, may also be contained by copolymerization.

Examples of such repeating units-ax of the conventional type respectively include those represented by the following formulae (ax1) and (ax2) (also referred to as repeating unit-ax1 and repeating unit-ax2 respectively, the same applying hereinafter).

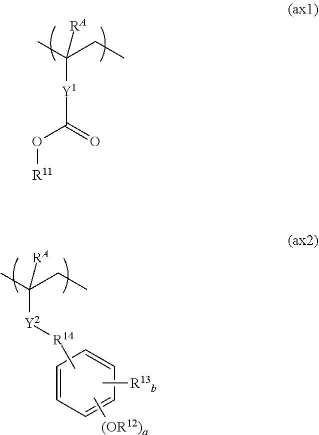

In the formulae (ax1) and (ax2), each R^{A} independently represents a hydrogen atom or a methyl group. The linking group Y¹ represents a single bond, a phenylene group, a naphthylene group, or a linking group having 1 to 12 carbon atoms, having an ester bond, an ether bond, or a lactone ring, and optionally having a halogen atom, a nitro group, a hydroxy group, an alkoxy group, an acyloxy group, or an alkoxycarbonyloxy group. The linking group Y² represents a single bond, an ester bond, or an amide bond. R¹¹ and R¹² each represent an acid-labile group. R¹³ represents a fluorine atom, a trifluoromethyl group, a cyano group, or an alkyl group having 1 to 6 carbon atoms. R¹⁴ represents a single bond or a linear or branched alkanediyl group having 1 to 6 carbon atoms, part of the carbon atoms optionally being substituted with an ether bond or an ester bond. “a” represents 1 or 2. “b” represents an integer of 0 to 4.

Examples of a monomer to give the repeating unit-ax1 include ones shown below, but are not limited thereto. Note that, in the following formulae, R^{A} and R¹¹ are as defined above.

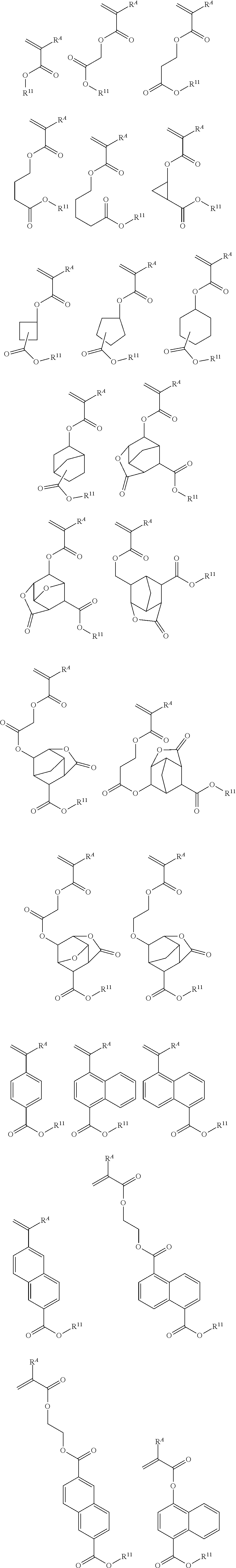

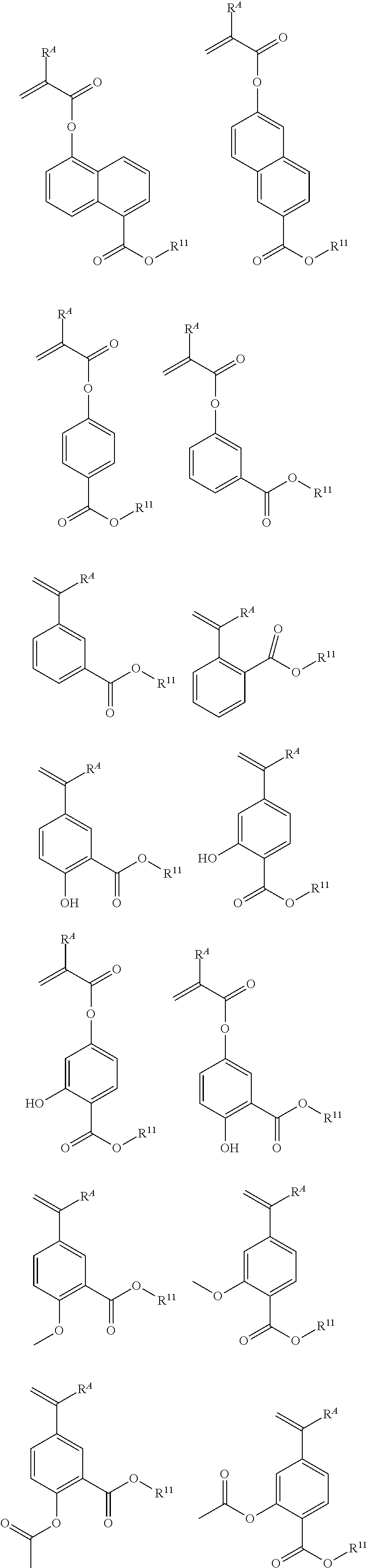

Examples of a monomer to give the repeating unit-ax2 include ones shown below, but are not limited thereto. Note that, in the following formulae, R^{A} and R¹² are as defined above.

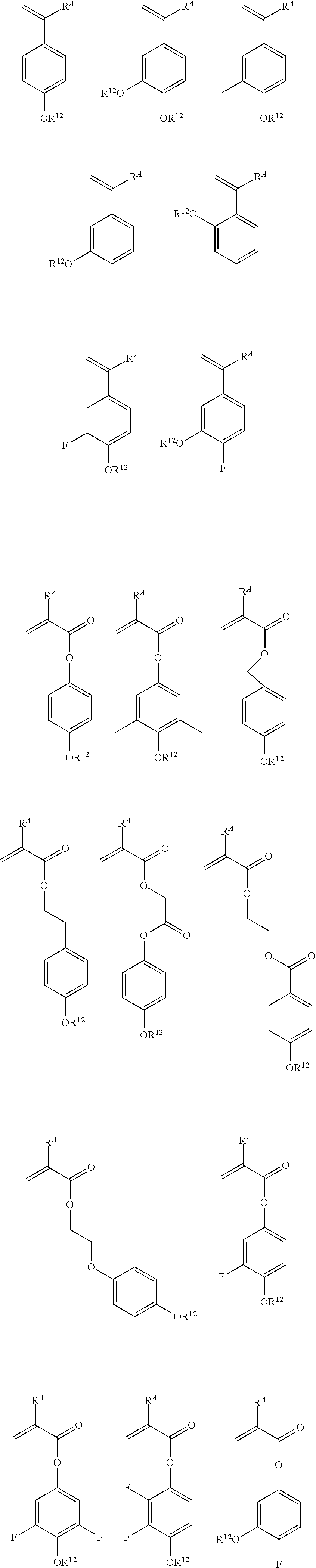

Various acid-labile groups can be selected as the acid-labile groups shown by R¹¹ or R¹². Examples thereof include ones shown by the following formulae (AL-1) to (AL-3).

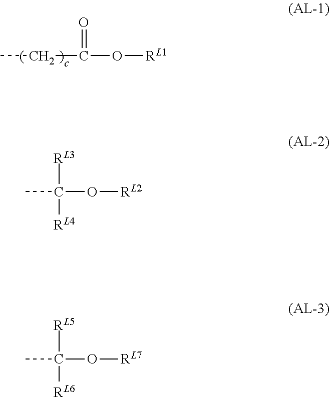

In the formula (AL-1), “c” represents an integer of 0 to 6. R^{L1} represents: a tertiary hydrocarbyl group having 4 to 20 carbon atoms, preferably 4 to 15 carbon atoms; a trihydrocarbylsilyl group in which hydrocarbyl groups are each a saturated hydrocarbyl group having 1 to 6 carbon atoms; a saturated hydrocarbyl group having 4 to 20 carbon atoms containing a carbonyl group, an ether bond, or an ester bond; or a group shown by the formula (AL-3).

The tertiary hydrocarbyl group shown by R^{L1} may be saturated or unsaturated, and may be branched or cyclic. Specific examples thereof include a tert-butyl group, a tert-pentyl group, a 1,1-diethylpropyl group, a 1-ethylcyclopentyl group, a 1-butylcyclopentyl group, a 1-ethylcyclohexyl group, a 1-butylcyclohexyl group, a 1-ethyl-2-cyclopentenyl group, a 1-ethyl-2-cyclohexenyl group, a 2-methyl-2-adamantyl group, etc. Examples of the trialkylsilyl group include a trimethylsilyl group, a triethylsilyl group, a dimethyl-tert-butylsilyl group, etc. The saturated hydrocarbyl group containing a carbonyl group, an ether bond, or an ester bond may be linear, branched, or cyclic, and is preferably cyclic. Specific examples thereof include a 3-oxocyclohexyl group, a 4-methyl-2-oxooxan-4-yl group, a 5-methyl-2-oxooxolan-5-yl group, a 2-tetrahydropyranyl group, a 2-tetrahydrofuranyl group, etc.

Examples of the acid-labile group shown by the formula (AL-1) include a tert-butoxycarbonyl group, a tert-butoxycarbonylmethyl group, a tert-pentyloxycarbonyl group, a tert-pentyloxycarbonylmethyl group, a 1,1-diethylpropyloxycarbonyl group, a 1,1-diethylpropyloxycarbonylmethyl group, a 1-ethylcyclopentyloxycarbonyl group, a 1-ethylcyclopentyloxycarbonylmethyl group, a 1-ethyl-2-cyclopentenyloxycarbonyl group, a 1-ethyl-2-cyclopentenyloxycarbonylmethyl group, a 1-ethoxyethoxycarbonylmethyl group, a 2-tetrahydropyranyloxycarbonylmethyl group, a 2-tetrahydrofuranyloxycarbonylmethyl group, etc.

Other examples of the acid-labile group shown by the formula (AL-1) include groups shown by the following formulae (AL-1)-1 to (AL-1)-10.

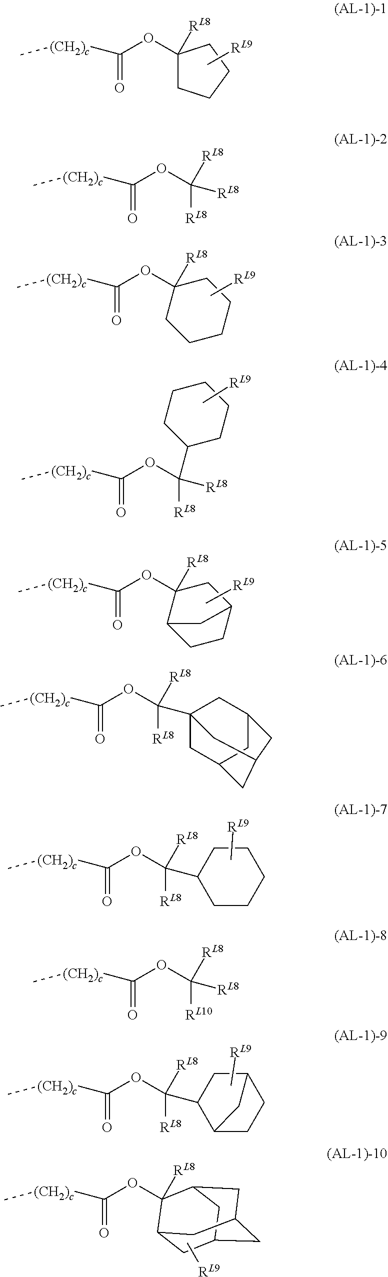

In the formulae, a broken line represents an attachment point.

In the formulae (AL-1)-1 to (AL-1)-10, “c” is as defined above. Each R^{L8} independently represents a saturated hydrocarbyl group having 1 to 10 carbon atoms or an aryl group having 6 to 20 carbon atoms. R^{L}D represents a hydrogen atom or a saturated hydrocarbyl group having 1 to 10 carbon atoms. R^{L10} represents a saturated hydrocarbyl group having 2 to 10 carbon atoms or an aryl group having 6 to 20 carbon atoms. The saturated hydrocarbyl groups may be linear, branched, or cyclic.

In the formula (AL-2), R^{L2} and R^{L3} each independently represent a hydrogen atom or a saturated hydrocarbyl group having 1 to 18 carbon atoms, preferably 1 to 10 carbon atoms. The saturated hydrocarbyl group may be linear, branched, or cyclic. Specific examples thereof include a methyl group, an ethyl group, a propyl group, an isopropyl group, an n-butyl group, a sec-butyl group, a tert-butyl group, a cyclopentyl group, a cyclohexyl group, a 2-ethylhexyl group, an n-octyl group, etc.

In the formula (AL-2), R^{L4} represents a hydrocarbyl group having 1 to 18 carbon atoms, preferably 1 to 10 carbon atoms, and optionally contains a heteroatom. The hydrocarbyl group may be saturated or unsaturated, and may be linear, branched, or cyclic. Examples of the hydrocarbyl group include saturated hydrocarbyl groups each having 1 to 18 carbon atoms, etc., and some of hydrogen atoms thereof may be substituted with a hydroxy group, an alkoxy group, an oxo group, an amino group, an alkylamino group, or the like. Examples of such substituted saturated hydrocarbyl groups include ones shown below, etc.

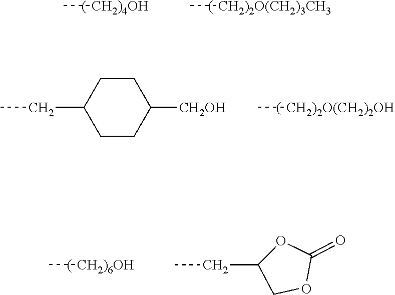

In the formulae, a broken line represents an attachment point.

R^{L2} and R^{L3}, R^{L2} and R^{L4}, or R^{L3} and R^{L4} optionally bond with each other to form a ring together with a carbon atom bonded therewith, or together with the carbon atom and an oxygen atom. In this case, R^{L2} and R^{L3}, R^{L2} and R^{L4}, or R^{L3} and R^{L4}, involved in the ring formation, each independently represent an alkanediyl group having 1 to 18 carbon atoms, preferably 1 to 10 carbon atoms. The number of carbon atoms in the ring obtained by bonding these is preferably 3 to 10, more preferably 4 to 10.

Examples of the linear and branched acid-labile groups shown by the formula (AL-2) include ones shown by the following formulae (AL-2)-1 to (AL-2)-69, but are not limited thereto. Note that, in the following formulae, each broken line represents an attachment point.

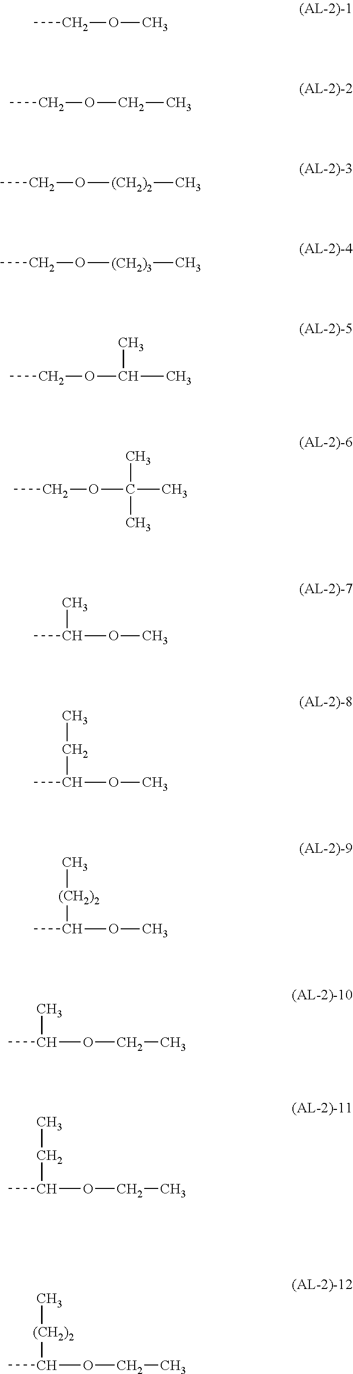

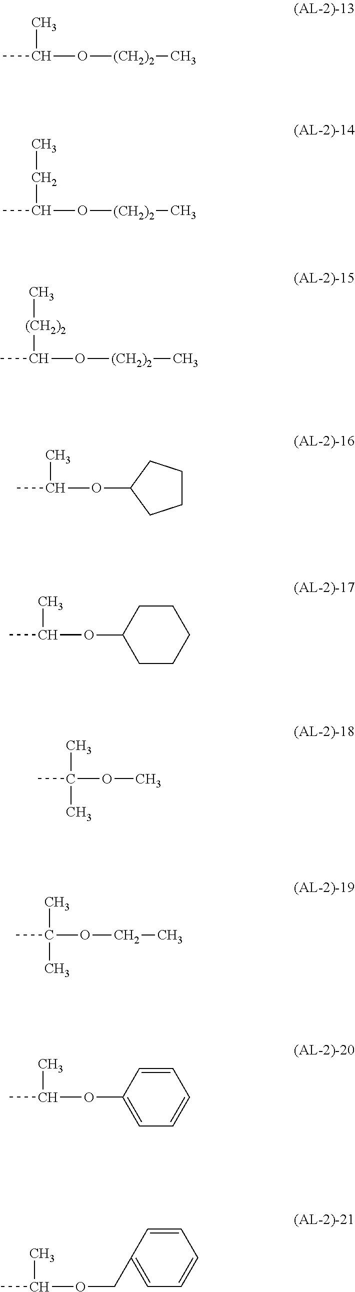

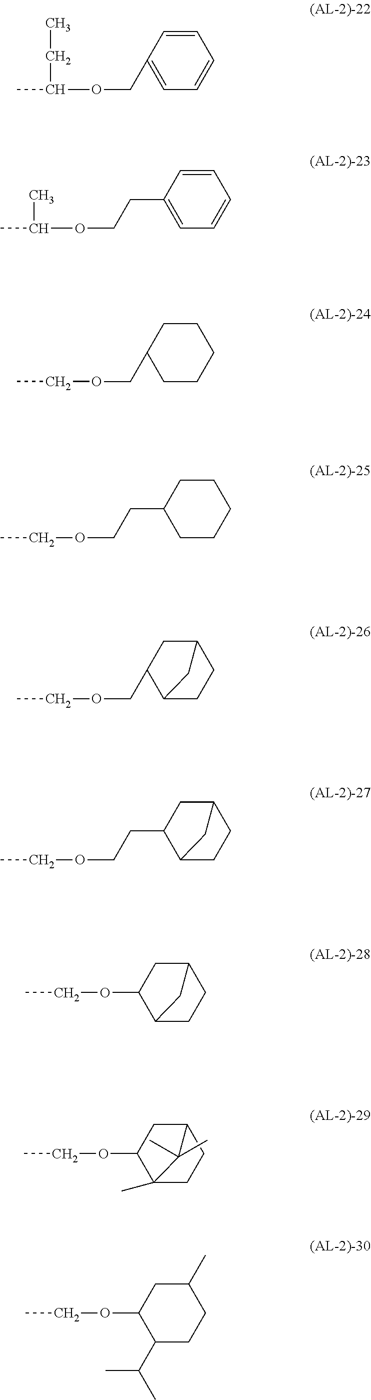

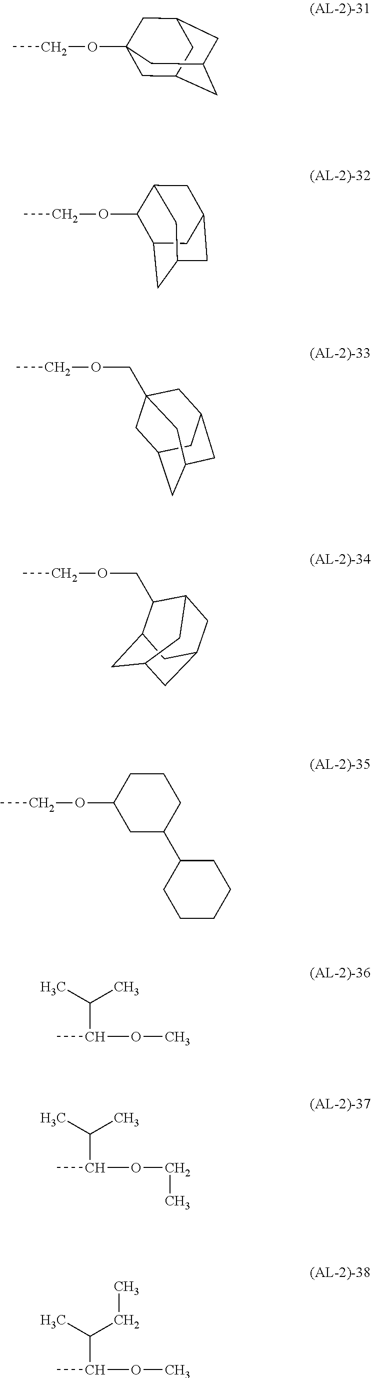

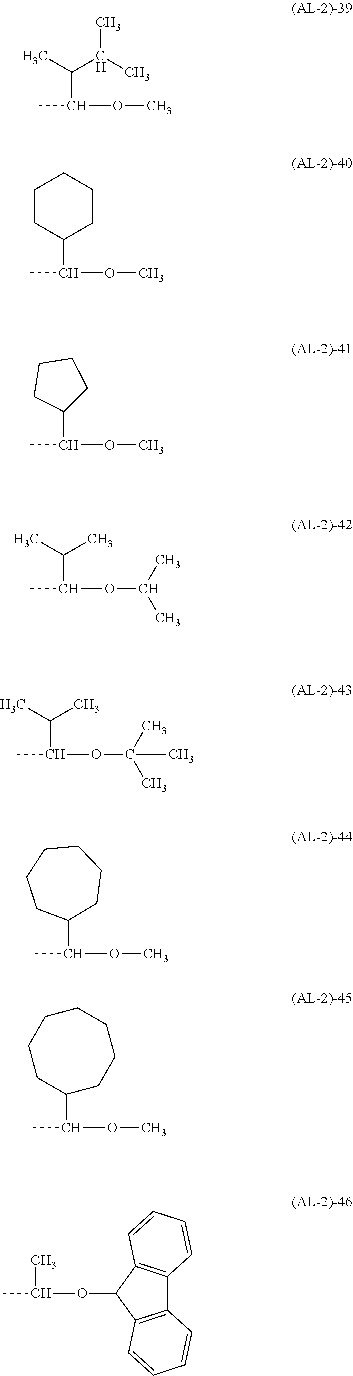

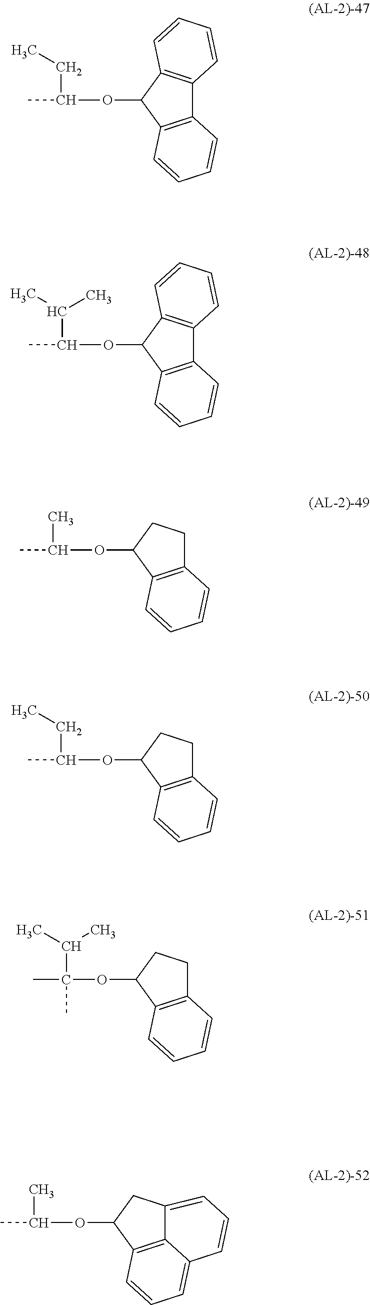

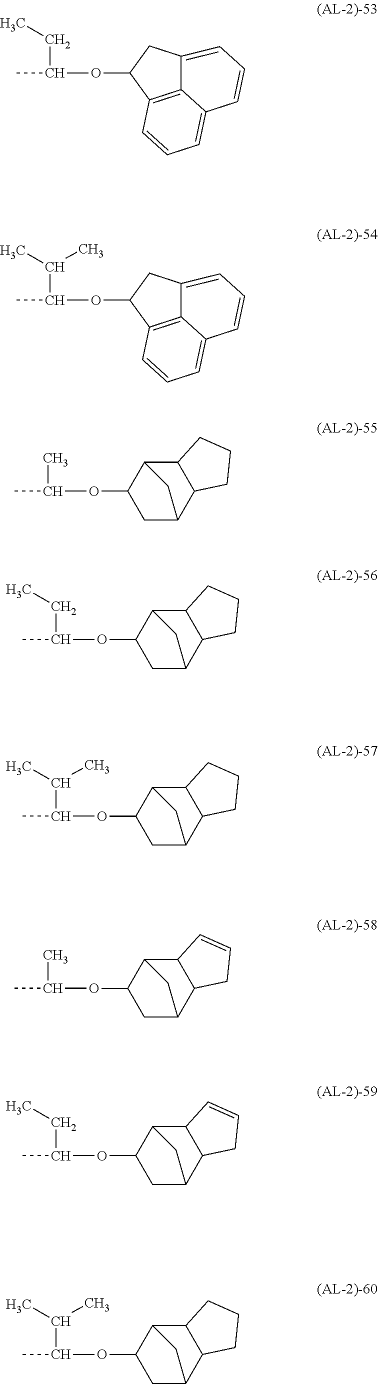

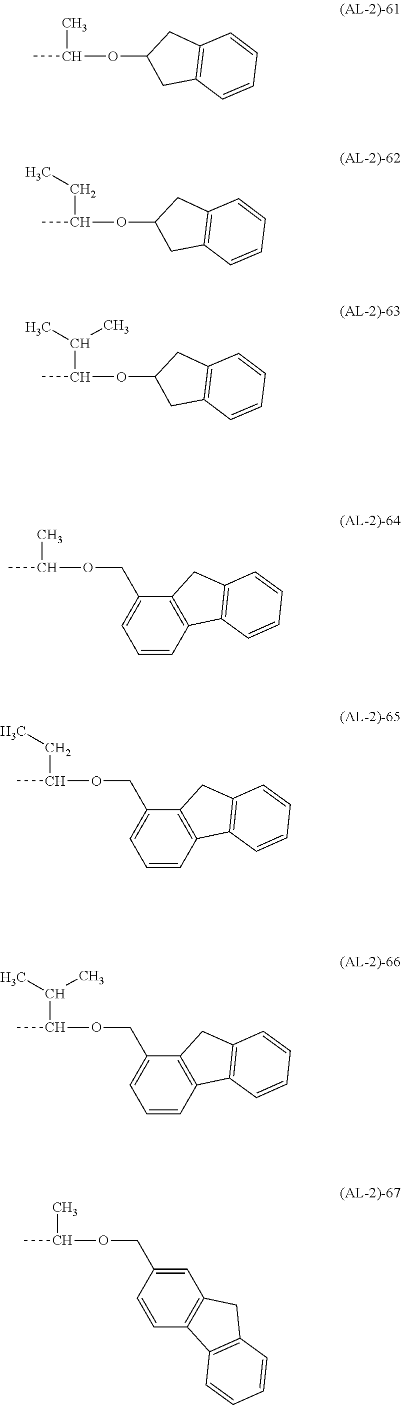

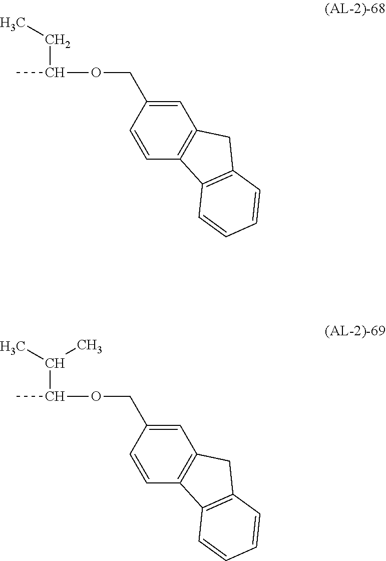

Examples of the cyclic acid-labile group shown by the formula (AL-2) include a tetrahydrofuran-2-yl group, a 2-methyltetrahydrofuran-2-yl group, a tetrahydropyran-2-yl group, a 2-methyltetrahydropyran-2-yl group, etc.

In addition, the examples of the acid-labile groups include groups shown by the following formula (AL-2a) or (AL-2b). The acid-labile group may crosslink the base polymer intermolecularly or intramolecularly.

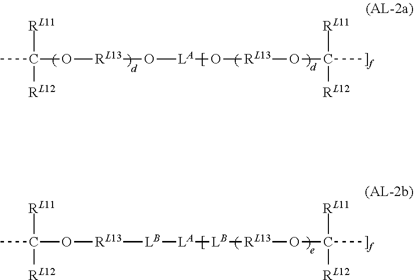

In the formulae, a broken line represents an attachment point.

In the formulae (AL-2a) and (AL-2b), R^{L11} and R^{L12} each independently represent a hydrogen atom or a saturated hydrocarbyl group having 1 to 8 carbon atoms. The saturated hydrocarbyl group may be linear, branched, or cyclic. Alternatively, R^{L11} and R^{L12} may bond with each other to form a ring together with a carbon atom bonded therewith. In this case, R^{L11} and R^{L12} each independently represent an alkanediyl group having 1 to 8 carbon atoms. Each R^{L13} independently represents a saturated hydrocarbylene group having 1 to 10 carbon atoms. The saturated hydrocarbylene group may be linear, branched, or cyclic. “d” and “e” each independently represent an integer of 0 to 10, preferably an integer of 0 to 5. “f” represents an integer of 1 to 7, preferably an integer of 1 to 3.

In the formula (AL-2a) or (AL-2b), L^{A} represents an aliphatic saturated hydrocarbon group having a valency of (f+1) with 1 to 50 carbon atoms, an alicyclic saturated hydrocarbon group having a valency of (f+1) with 3 to 50 carbon atoms, an aromatic hydrocarbon group having a valency of (f+1) with 6 to 50 carbon atoms, or a heterocyclic group having a valency of (f+1) with 3 to 50 carbon atoms. Some of the carbon atoms of these groups may be substituted with a heteroatom-containing group, and some hydrogen atoms bonded to the carbon atoms of these groups may be substituted with a hydroxy group, a carboxy group, an acyl group, or a fluorine atom. L^{A} is preferably an arylene group having 6 to 30 carbon atoms, a saturated hydrocarbon group, such as a saturated hydrocarbylene group, a trivalent saturated hydrocarbon group, and a tetravalent saturated hydrocarbon group each of which have 1 to 20 carbon atoms, or the like. The saturated hydrocarbon groups may be linear, branched, or cyclic. L^{B} represents —C(═O)—O—, —NH—C(═O)—O—, or —NH—C(═O)—NH—.

Examples of the crosslinking acetal groups shown by the formulae (AL-2a) and (AL-2b) include groups shown by the following formulae (AL-2)-70 to (AL-2)-77, etc.

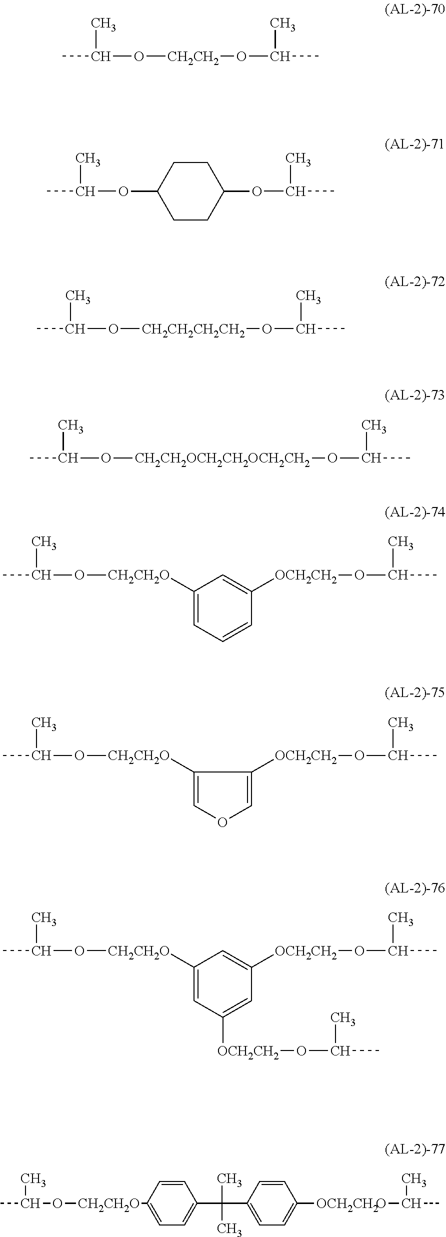

In the formulae, a broken line represents an attachment point.

In the formula (AL-3), R^{L5}, R^{L6}, and R^{L7} each independently represent a hydrocarbyl group having 1 to 20 carbon atoms, and optionally contain a heteroatom, such as an oxygen atom, a sulfur atom, a nitrogen atom, and a fluorine atom. The hydrocarbyl group may be saturated or unsaturated, and may be linear, branched, or cyclic. Specific examples thereof include alkyl groups having 1 to 20 carbon atoms, cyclic saturated hydrocarbyl groups having 3 to 20 carbon atoms, alkenyl groups having 2 to 20 carbon atoms, cyclic unsaturated hydrocarbyl groups having 3 to 20 carbon atoms, aryl groups having 6 to 10 carbon atoms, etc. Alternatively, R^{L5} and R^{L6}, R^{L5} and R^{L7}, or R^{L6} and R^{L7}, may bond with each other to form an alicyclic group having 3 to 20 carbon atoms, together with the carbon atom bonded therewith.

Examples of the group shown by the formula (AL-3) include a tert-butyl group, a 1,1-diethylpropyl group, a 1-ethylnorbornyl group, a 1-methylcyclopentyl group, a 1-isopropylcyclopentyl group, a 1-ethylcyclopentyl group, a 1-methylcyclohexyl group, a 2-(2-methyl)adamantyl group, a 2-(2-ethyl)adamantyl group, a tert-pentyl group, etc.

The examples of the group shown by the formula (AL-3) also include groups shown by the following formulae (AL-3)-1 to (AL-3)-19.

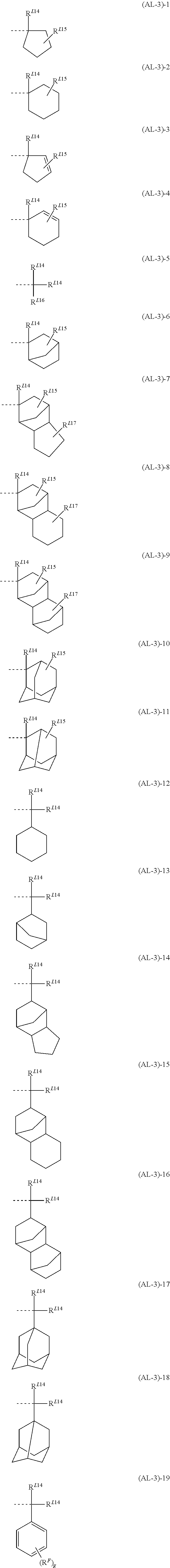

In the formulae, a broken line represents an attachment point.

In the formulae (AL-3)-1 to (AL-3)-19, each R^{L14} independently represents a hydrogen atom, a saturated hydrocarbyl group having 1 to 8 carbon atoms, or an aryl group having 6 to 20 carbon atoms. R^{L15} and R^{L17} each independently represent a hydrogen atom or a saturated hydrocarbyl group having 1 to 20 carbon atoms. R^{L16} represents an aryl group having 6 to 20 carbon atoms. The saturated hydrocarbyl groups may be linear, branched, or cyclic. The aryl groups are preferably a phenyl group or the like. RF represents a fluorine atom or a trifluoromethyl group. “g” represents an integer of 1 to 5.

Examples of the acid-labile group further include groups shown by the following formula (AL-3)-20 or (AL-3)-21. The acid-labile group may crosslink the polymer intramolecularly or intermolecularly.

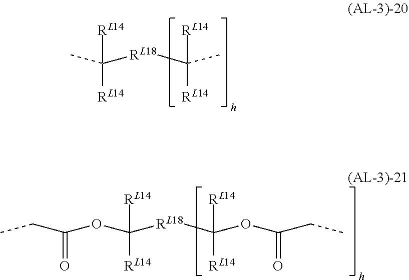

In the formulae, a broken line represents an attachment point.

In the formulae (AL-3)-20 and (AL-3)-21, R^{L14} is as defined above. R^{L18} represents a saturated hydrocarbylene group having a valency of (h+1) and having 1 to 20 carbon atoms or represents an arylene group having a valency of (h+1) and having 6 to 20 carbon atoms, and optionally contains a heteroatom such as an oxygen atom, a sulfur atom, or a nitrogen atom. The saturated hydrocarbylene group may be linear, branched, or cyclic. “h” represents an integer of 1 to 3.

Examples of a monomer to give the repeating unit containing the acid-labile group shown by the formula (AL-3) include (meth)acrylate having an exo-form structure shown by the following formula (AL-3)-22.

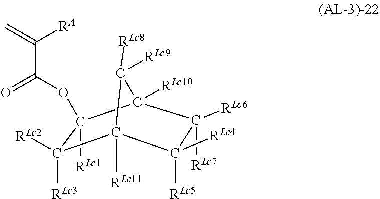

In the formula (AL-3)-22, R^{A} is as defined above. R^{Lc1} represents a saturated hydrocarbyl group having 1 to 8 carbon atoms or an aryl group having 6 to 20 carbon atoms and optionally containing a substituent. The saturated hydrocarbyl group may be linear, branched, or cyclic. R^{Lc2} to R^{Lc11} each independently represent a hydrogen atom or a hydrocarbyl group having 1 to 15 carbon atoms and optionally containing a heteroatom. Examples of the heteroatom include an oxygen atom, etc. Examples of the hydrocarbyl group include alkyl groups having 1 to 15 carbon atoms, aryl groups having 6 to 15 carbon atoms, etc. R^{Lc2} and R^{Lc3}, R^{Lc4} and R^{Lc6}, R^{Lc4} and R^{Lc7}, R^{Lc5} and R^{Lc7}, R^{Lc5} and R^{L11}, R^{Lc6} and R^{Lc10}, R^{Lc8} and R^{Lc9}, or R^{Lc9} and R^{Lc}1 may bond with each other to form a ring together with a carbon atom bonded therewith. In this case, a group involved in the bonding is a hydrocarbylene group having 1 to 15 carbon atoms and optionally containing a heteroatom. Alternatively, R^{Lc2} and R^{Lc11}, R^{Lc8} and R^{Lc11}, or R^{Lc4} and R^{Lc6}, all pairs of which are bonded to carbon atoms next to each other, may directly bond with each other to form a double bond. Note that the formula also represents an enantiomer.

Examples of the monomer shown by the formula (AL-3)-22 to give the repeating unit include ones disclosed in JP 2000-327633 A, etc. Specific examples thereof include ones shown below, but are not limited thereto. Note that, in the following formulae, R^{A} is as defined above.

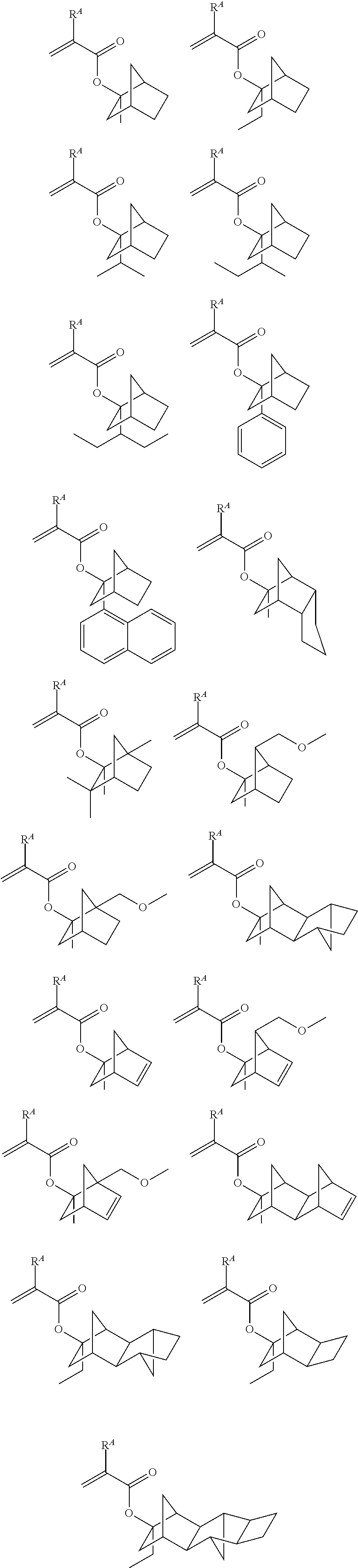

Other examples of the monomer to give the repeating unit containing the acid-labile group shown by the formula (AL-3) include (meth)acrylate containing a furandiyl group, a tetrahydrofurandiyl group, or an oxanorbornanediyl group, as shown by the following formula (AL-3)-23.

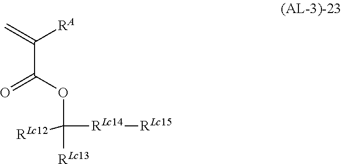

In the formula (AL-3)-23, R^{A} is as defined above. R^{Lc12} and R^{Lc13} each independently represent a hydrocarbyl group having 1 to 10 carbon atoms. R^{Lc12} and R^{Lc13} may bond with each other to form an alicyclic group together with a carbon atom bonded therewith. R^{Lc14} represents a furandiyl group, a tetrahydrofurandiyl group, or an oxanorbornanediyl group. R^{Lc15} represents a hydrogen atom, or a hydrocarbyl group having 1 to 10 carbon atoms and optionally containing a heteroatom. The hydrocarbyl groups may be linear, branched, or cyclic. Specific examples thereof include a saturated hydrocarbyl group having 1 to 10 carbon atoms, etc.

Examples of the monomer shown by the formula (AL-3)-23 to give the repeating unit include ones shown below, but are not limited thereto. Note that, in the following formulae, R^{A} is as defined above, Ac represents an acetyl group, and Me represents a methyl group.

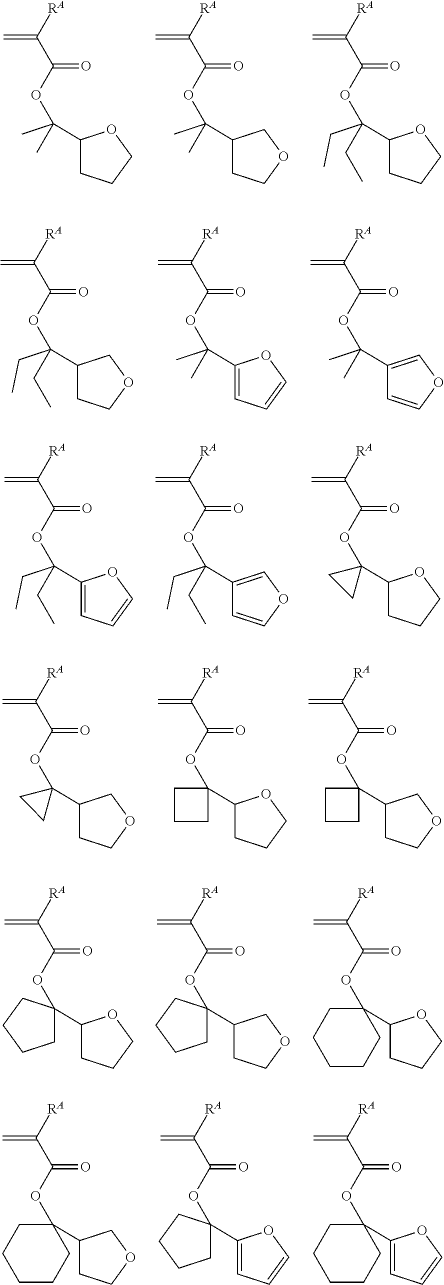

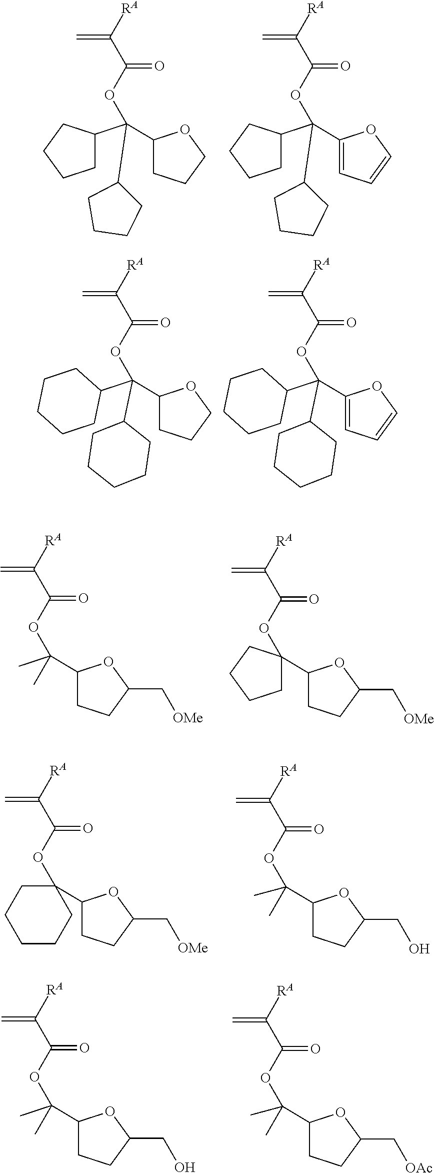

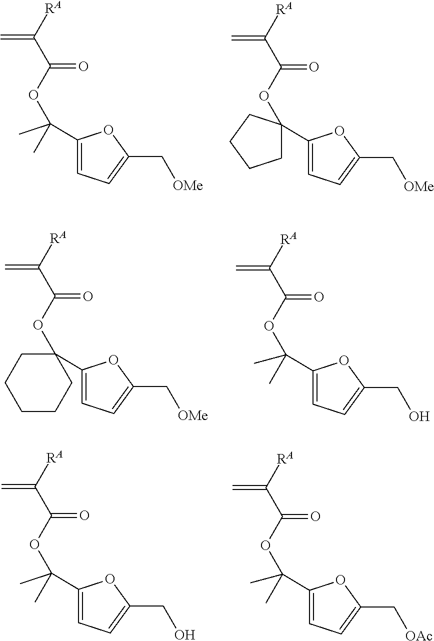

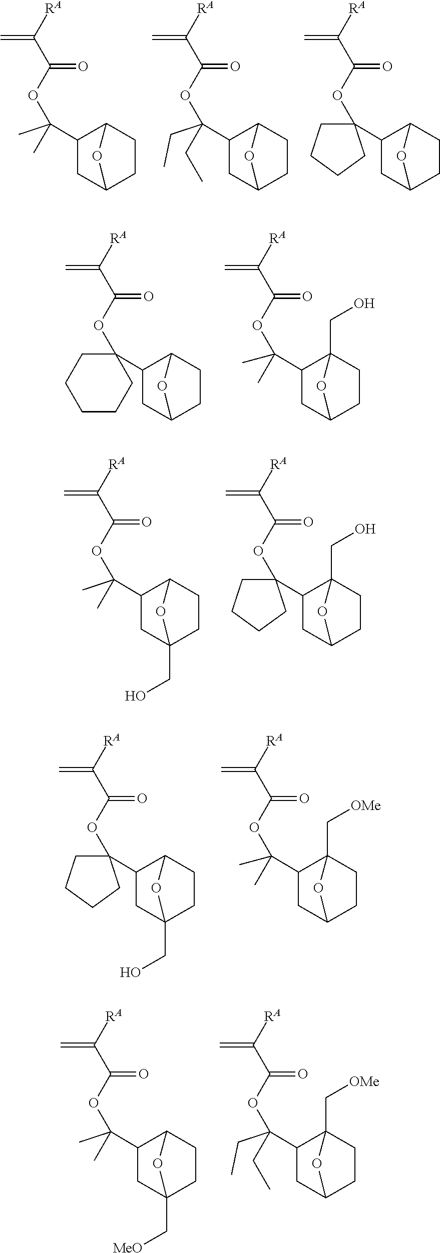

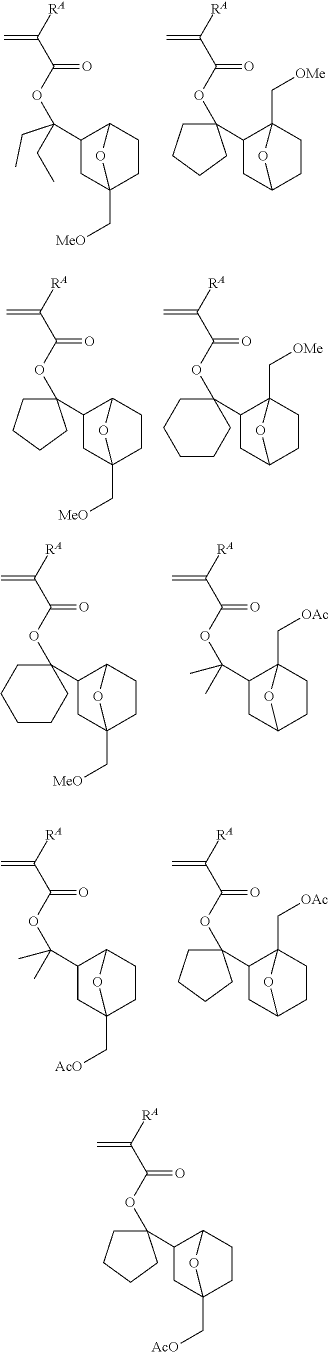

The base polymer preferably includes, in addition to the repeating unit-a, a polymer having a repeating unit-b having an acid-generating moiety.

When such a polymer incorporating an acid-generating moiety (polymer-bound acid generator) is contained, a suitable acid-generating function in the resist material can be achieved.

The base polymer preferably further contains a repeating unit-b having at least one acid generator selected from repeating units represented by the following formulae (b1) to (b5).

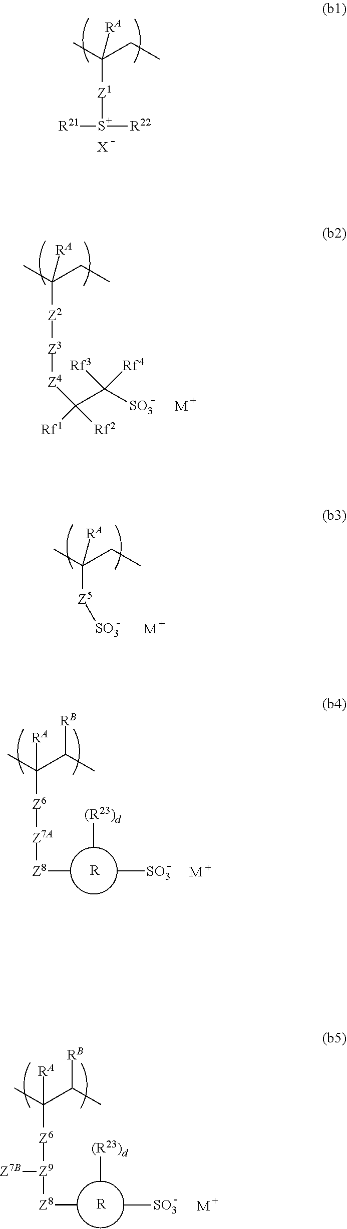

In the formulae, each R^{A} independently represents a hydrogen atom or a methyl group; each R^{B} independently represents a hydrogen atom or is optionally bonded to Z⁶ to form a ring; Z¹ represents a single bond, an aliphatic hydrocarbylene group having 1 to 6 carbon atoms, a phenylene group, a naphthylene group, a group having 7 to 18 carbon atoms derived from a combination of these groups, —O—Z¹¹—, —C(═O)—O—Z¹¹—, or —C(═O)—NH—Z¹¹—; Z¹¹ represents an aliphatic hydrocarbylene group having 1 to 6 carbon atoms, a phenylene group, a naphthylene group, or a group having 7 to 18 carbon atoms derived from a combination of these groups, Z¹¹ optionally containing a carbonyl group, an ester bond, an ether bond, or a hydroxy group; Z² represents a single bond or an ester bond; Z³ represents a single bond, —Z³¹—C(═O)—O—, or —Z³¹—O—; Z³¹ represents a hydrocarbylene group having 1 to 12 carbon atoms, a phenylene group, or a group having 7 to 18 carbon atoms derived from a combination of these groups, Z³¹ optionally containing a carbonyl group, a nitro group, a cyano group, an ester bond, an ether bond, a urethane bond, a fluorine atom, an iodine atom, or a bromine atom; Z⁴ represents a single bond, a methylene group, or an ethylene group; Z⁵ represents a single bond, a methylene group, an ethylene group, a phenylene group, a methylphenylene group, a dimethylphenylene group, a fluorinated phenylene group, a phenylene group substituted with a trifluoromethyl group, —O—Z⁵¹—, —C(═O)—O—Z⁵¹—, or —C(═O)—NH—Z⁵¹—; Z⁵¹ represents an aliphatic hydrocarbylene group having 1 to 6 carbon atoms, a phenylene group, a methylphenylene group, a dimethylphenylene group, a fluorinated phenylene group, or a phenylene group substituted with a trifluoromethyl group, Z⁵¹ optionally containing a carbonyl group, an ester bond, an ether bond, a hydroxy group, or a halogen atom; Z⁶ represents a single bond, a phenylene group, a naphthylene ring, an ester bond, or an amide bond; Z^{7A} represents a single bond or a divalent organic group having 1 to 24 carbon atoms, Z^{7A} optionally having at least one selected from a halogen atom, an oxygen atom, a nitrogen atom, and a sulfur atom; Z^{7B} represents a monovalent organic group having 1 to 10 carbon atoms, Z^{7B} optionally having at least one selected from a halogen atom, an oxygen atom, a nitrogen atom, and a sulfur atom; Z⁸ represents a single bond, an ether bond, an ester bond, a thioether bond, or an alkanediyl group having 1 to 6 carbon atoms; Z⁹ represents a trivalent organic group having 1 to 12 carbon atoms, Z⁹ optionally having at least one selected from an oxygen atom, a nitrogen atom, and a sulfur atom; Rf¹ to Rf⁴ each independently represent a hydrogen atom, a fluorine atom, or a trifluoromethyl group, provided that at least one of Rf¹ to Rf⁴ is a fluorine atom or a trifluoromethyl group, Rf¹ and Rf² optionally being combined to form a carbonyl group together with the carbon atom bonded to Rf¹ and Rf²; R²¹ and R²² each independently represent a halogen atom or a hydrocarbyl group having 1 to 20 carbon atoms and optionally containing a heteroatom; R²³ represents a saturated hydrocarbyl group having 1 to 10 carbon atoms, an aryl group having 6 to 10 carbon atoms, a fluorine atom, an iodine atom, a trifluoromethoxy group, a difluoromethoxy group, a cyano group, or a nitro group; ring R represents a (d+2)-valent aromatic hydrocarbon group having 6 to 10 carbon atoms; “d” represents an integer of 0 to 5; X⁻ represents a non-nucleophilic counter ion; and M⁺ represents a sulfonium cation or an iodonium cation.

Examples of a monomer to give the repeating unit-b1 include ones shown below, but are not limited thereto. Note that, in the following formulae, R^{A} is as defined above.

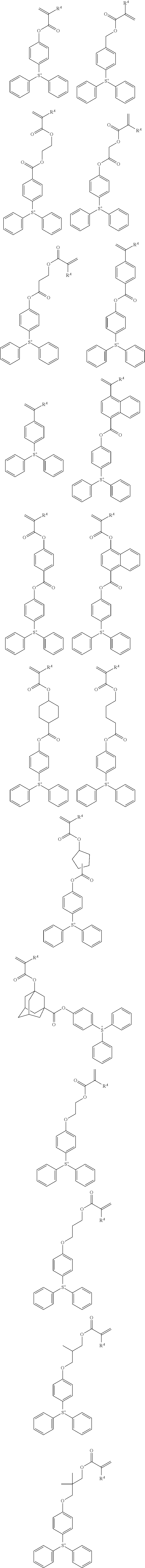

In the formula (b1), X⁻ represents a non-nucleophilic counter ion. Examples of the non-nucleophilic counter ion include halide ions, such as chloride and bromide ions; fluoroalkylsulfonate ions, such as triflate, 1,1,1-trifluoroethanesulfonate, and nonafluorobutanesulfonate ions; arylsulfonate ions, such as tosylate, benzenesulfonate, 4-fluorobenzenesulfonate, and 1,2,3,4,5-pentafluorobenzenesulfonate ions; alkylsulfonate ions, such as mesylate and butanesulfonate ions; imidic acid ions, such as bis(trifluoromethylsulfonyl)imide, bis(perfluoroethylsulfonyl)imide and bis(perfluorobutylsulfonyl)imide ions; and methide acid ions such as tris(trifluoromethylsulfonyl)methide and tris(perfluoroethylsulfonyl)methide ions.

Examples of the non-nucleophilic counter ion further include: sulfonate ions represented by the following formula (b1-1), having a substituting fluorine atom at a position; sulfonate ions represented by the following formula (b1-2), having a substituting fluorine atom at a position and having a substituting trifluoromethyl group at B position; etc.

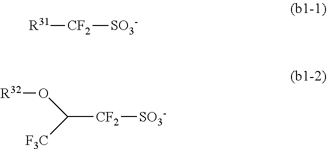

In the formula (b1-1), R³¹ represents a hydrogen atom, an alkyl group having 1 to 20 carbon atoms, an alkenyl group having 2 to 20 carbon atoms, or an aryl group having 6 to 20 carbon atoms, and optionally contains an ether bond, an ester bond, a carbonyl group, a lactone ring, or a fluorine atom. The alkyl group and the alkenyl group may be linear, branched, or cyclic.

In the formula (b1-2), R³² represents a hydrogen atom, an alkyl group having 1 to 30 carbon atoms, an acyl group having 2 to 30 carbon atoms, an alkenyl group having 2 to 20 carbon atoms, an aryl group having 6 to 20 carbon atoms, or an aryloxy group having 6 to 20 carbon atoms, and optionally contains an ether bond, an ester bond, a carbonyl group, or a lactone ring. The alkyl group, acyl group, and alkenyl group may be linear, branched, or cyclic.

Examples of the non-nucleophilic counter ion also include an anion containing bromine or iodine, represented by the following formula (b1-3).

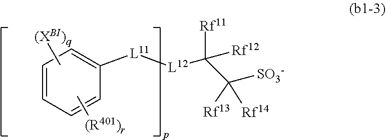

In the general formula (b1-3), “p” represents an integer that satisfies 1≤p≤3. “q” and “r” represent integers that satisfy 1≤q≤5, 0≤r≤3, and 1≤q+r≤−5. “q” is preferably an integer that satisfies 1≤q≤3, more preferably 2 or 3. “r” is preferably an integer that satisfies 0≤r≤2.

In the general formula (b1-3), X^{BI} represents an iodine atom or a bromine atom, and when “p” and/or “q” is 2 or more, the X^{BI}s may be identical to or different from each other.

In the general formula (b1-3), L¹¹ represents a single bond, an ether bond, an ester bond, or a saturated hydrocarbylene group having 1 to 6 carbon atoms and optionally having an ether bond or an ester bond. The saturated hydrocarbylene group may be linear, branched, or cyclic.

In the general formula (b1-3), L¹² represents, when “p” is 1, a single bond or a divalent linking group having 1 to 20 carbon atoms, and when “p” is 2 or 3, a (p+1)-valent linking group having 1 to 20 carbon atoms. The linking group optionally contains an oxygen atom, a sulfur atom, or a nitrogen atom.

In the general formula (b1-3), R⁴⁰¹ represents a hydroxy group, a carboxy group, a fluorine atom, a chlorine atom, a bromine atom, or an amino group; a hydrocarbyl group having 1 to 20 carbon atoms, a hydrocarbyloxy group having 1 to 20 carbon atoms, a hydrocarbylcarbonyl group having 2 to 20 carbon atoms, a hydrocarbyloxycarbonyl group having 2 to 20 carbon atoms, a hydrocarbylcarbonyloxy group having 2 to 20 carbon atoms, or a hydrocarbylsulfonyloxy group having 1 to 20 carbon atoms, each optionally containing a fluorine atom, a chlorine atom, a bromine atom, a hydroxy group, an amino group, an ether bond, an ester bond, or an amide bond; or —N(R^{401A})(R^{401B}), —N(R^{401C})—C(═O)—R^{401D}, or —N(R^{401C})—C(═O)—O—R^{401D}. R^{401A} and R^{401B} each independently represent a hydrogen atom or a saturated hydrocarbyl group having 1 to 6 carbon atoms. R^{401C} represents a hydrogen atom or a saturated hydrocarbyl group having 1 to 6 carbon atoms, and optionally contains a halogen atom, a hydroxy group, a saturated hydrocarbyloxy group having 1 to 6 carbon atoms, a saturated hydrocarbylcarbonyl group having 2 to 6 carbon atoms, or a saturated hydrocarbylcarbonyloxy group having 2 to 6 carbon atoms. R^{401D} represents an aliphatic hydrocarbyl group having 1 to 16 carbon atoms, an aryl group having 6 to 14 carbon atoms, or an aralkyl group having 7 to 15 carbon atoms, and optionally contains a halogen atom, a hydroxy group, a saturated hydrocarbyloxy group having 1 to 6 carbon atoms, a saturated hydrocarbylcarbonyl group having 2 to 6 carbon atoms, or a saturated hydrocarbylcarbonyloxy group having 2 to 6 carbon atoms. The aliphatic hydrocarbyl group may be saturated or unsaturated, and may be linear, branched, or cyclic. The saturated hydrocarbyl group, saturated hydrocarbyloxy group, saturated hydrocarbyloxycarbonyl group, saturated hydrocarbylcarbonyl group, and saturated hydrocarbylcarbonyloxy group may be linear, branched, or cyclic. When the “p” and/or “r” is 2 or more, the R⁴⁰¹s may be identical to or different from each other.

Among the above, as R⁴⁰¹, a hydroxy group, —N(R^{401C})—C(═O)—R^{401D}, —N(R^{401C})—C(═O)—O—R^{401D}, a fluorine atom, a chlorine atom, a bromine atom, a methyl group, a methoxy group, etc. are preferable.

In the general formula (b1-3), Rf¹¹ to Rf¹⁴ each independently represent a hydrogen atom, a fluorine atom, or a trifluoromethyl group, provided that at least one of Rf¹¹ to Rf¹⁴ is a fluorine atom or a trifluoromethyl group. In addition, Rf¹¹ and Rf¹² are optionally combined to form a carbonyl group. In particular, it is preferable that both Rf¹³ and Rf¹⁴ are fluorine atoms.

Specific examples of the anion shown in the formula (b1-3) include the following.

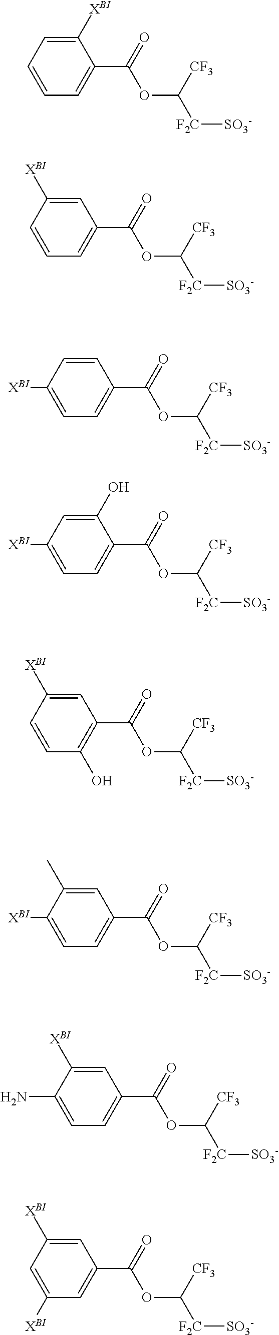

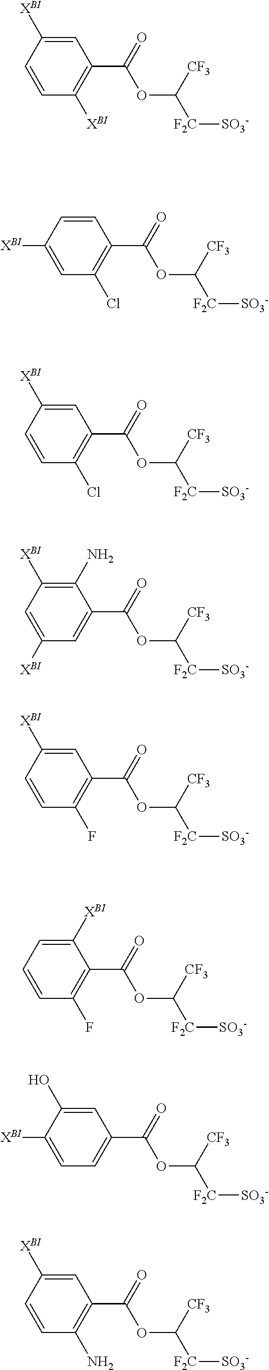

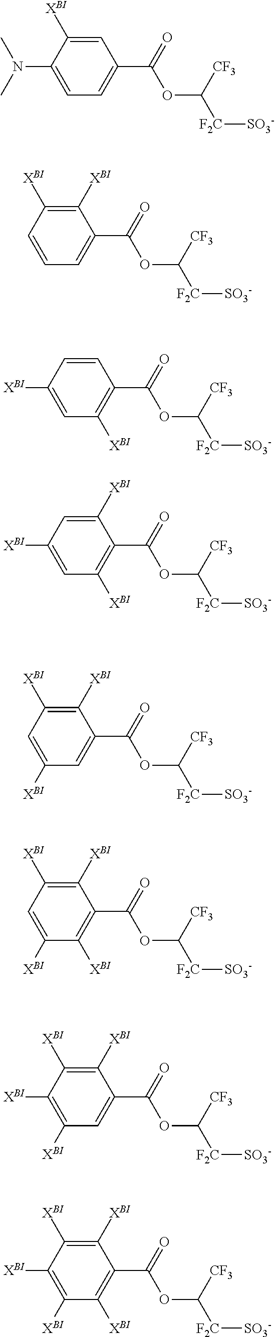

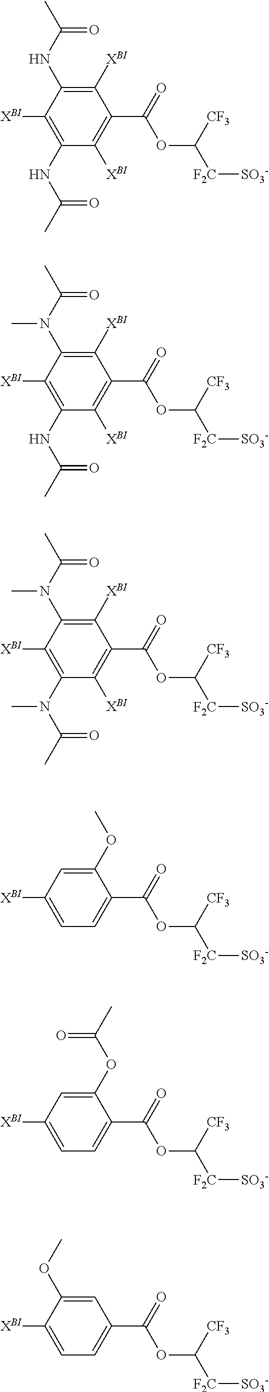

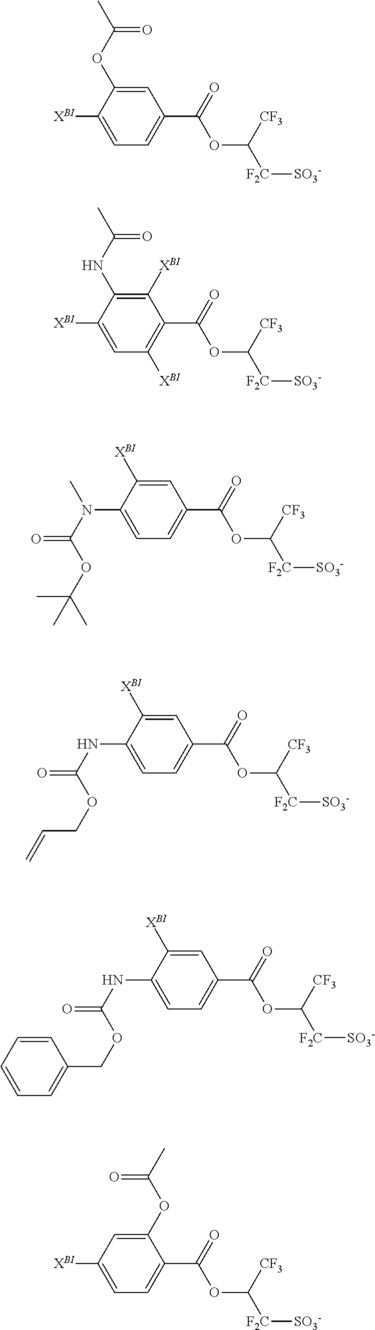

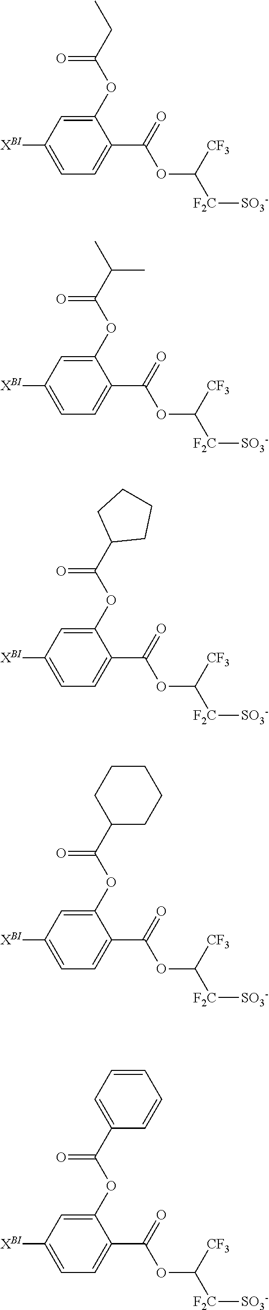

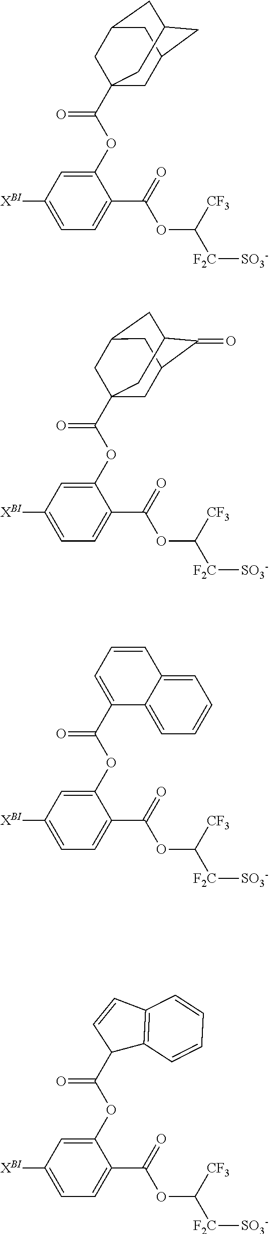

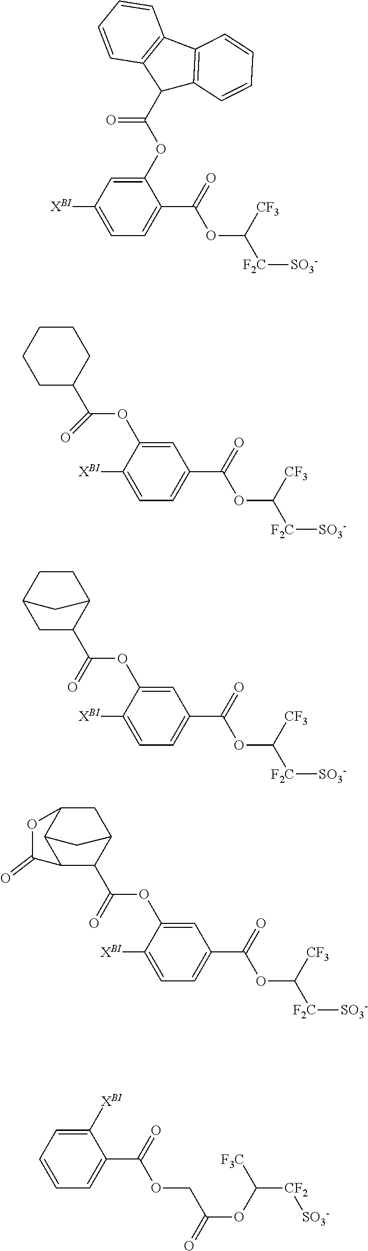

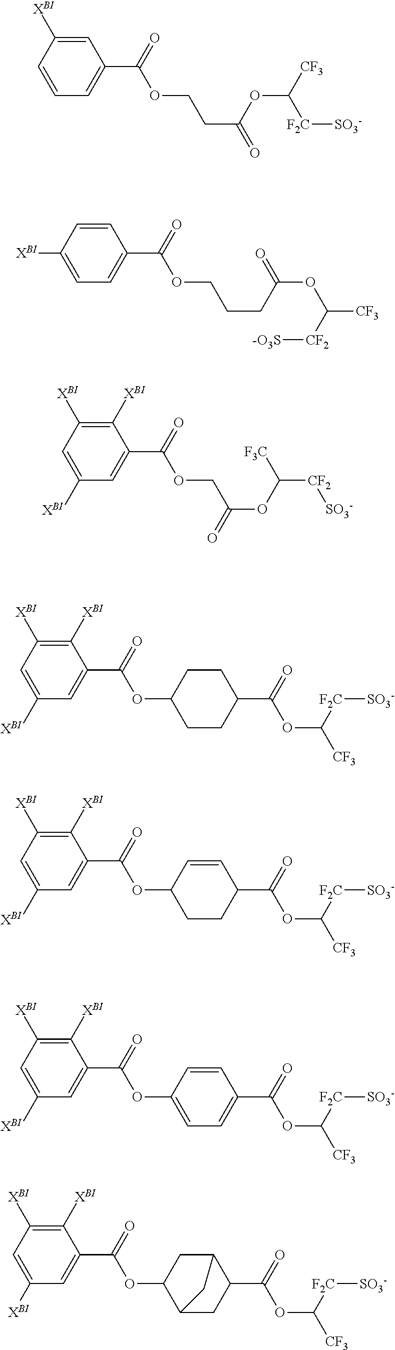

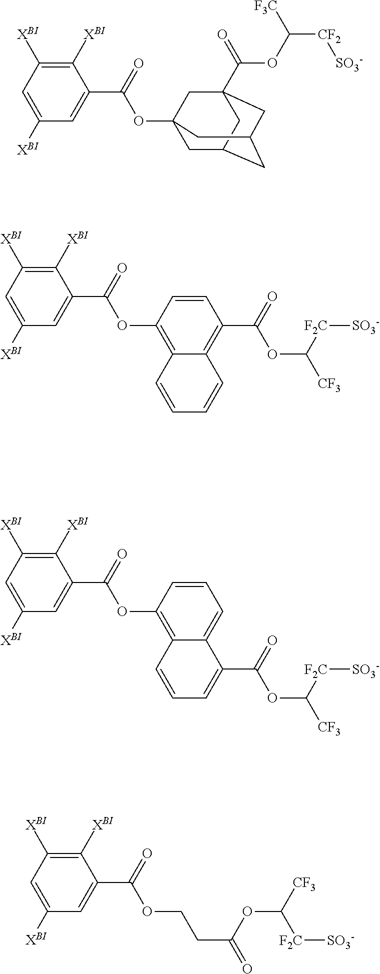

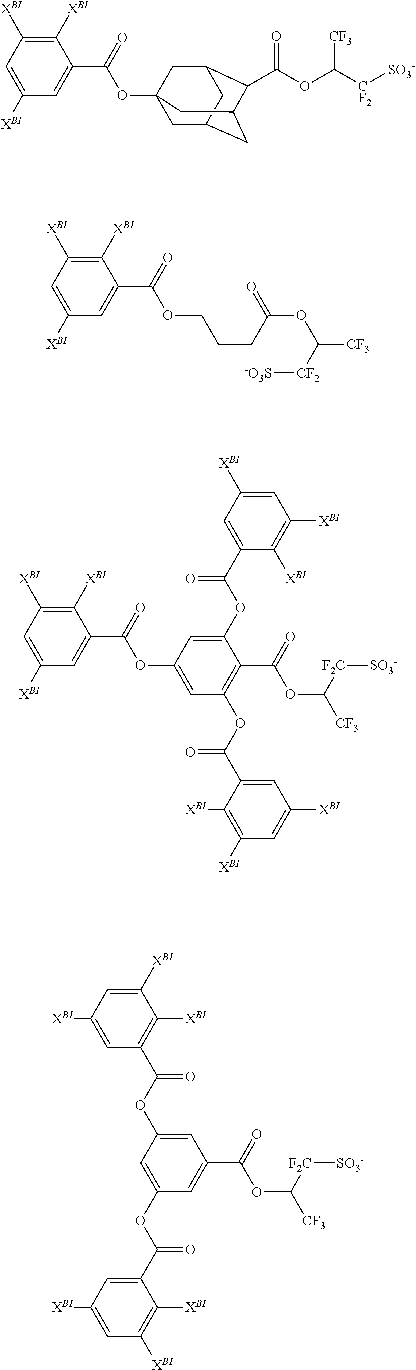

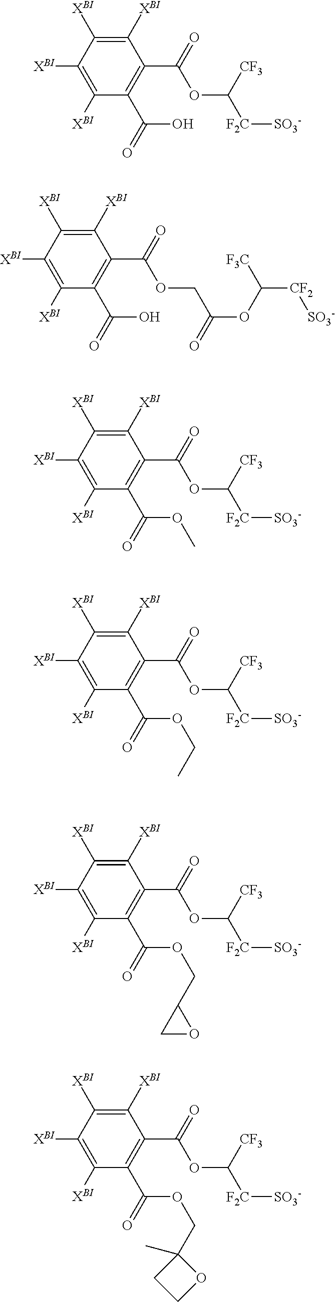

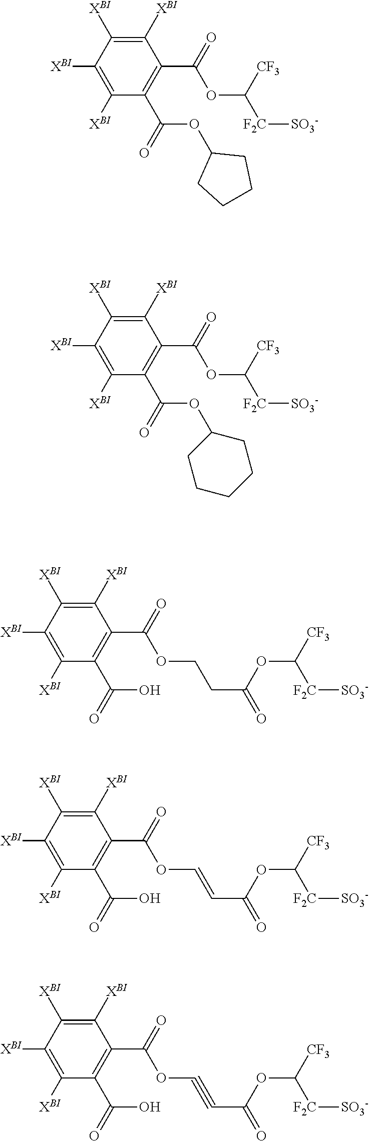

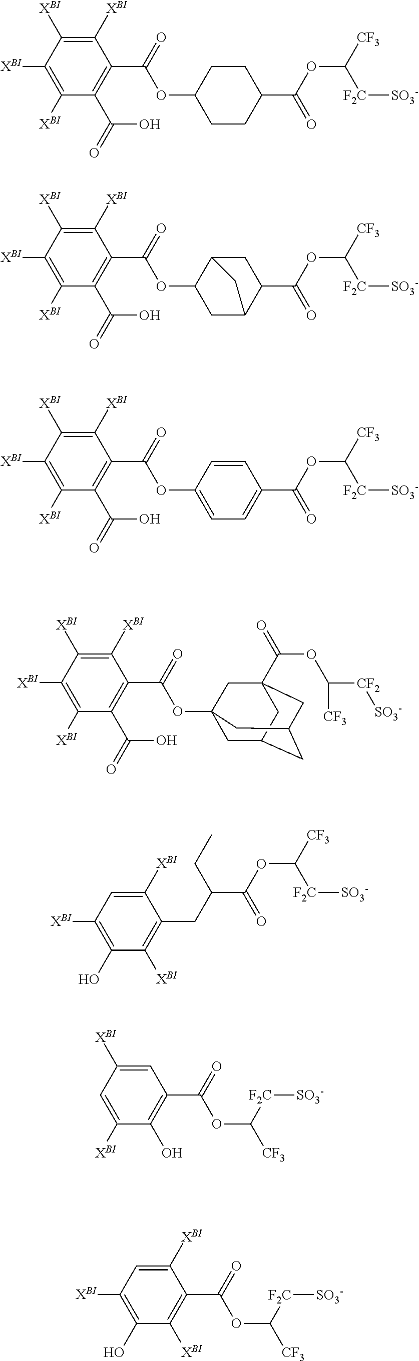

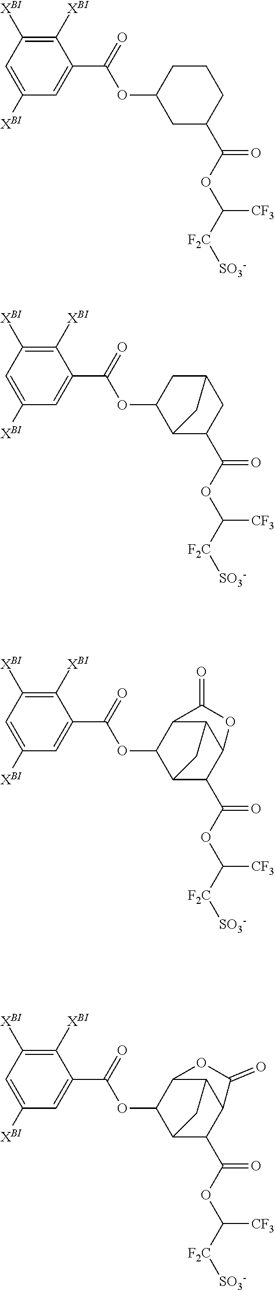

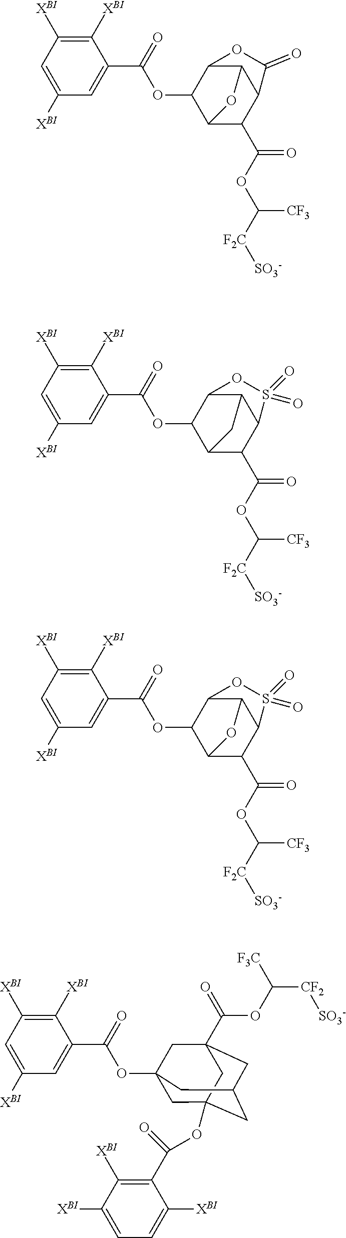

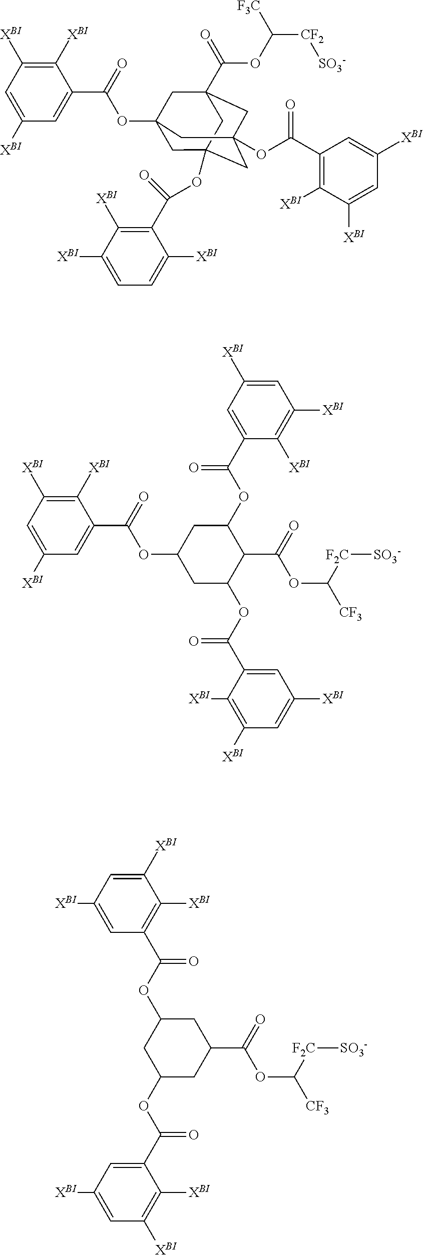

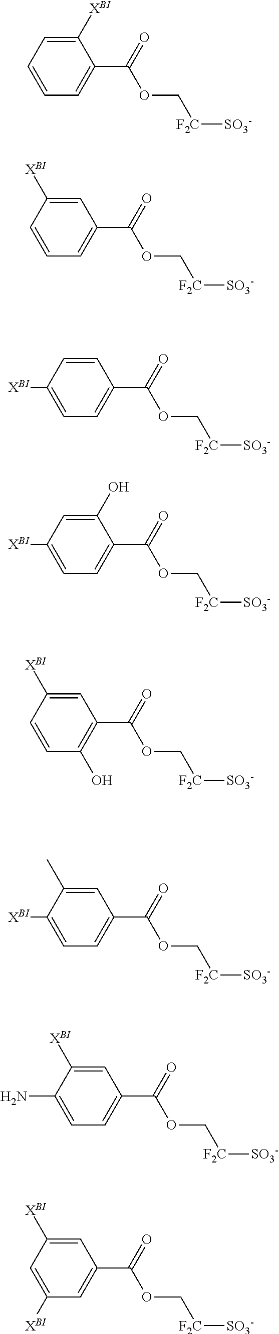

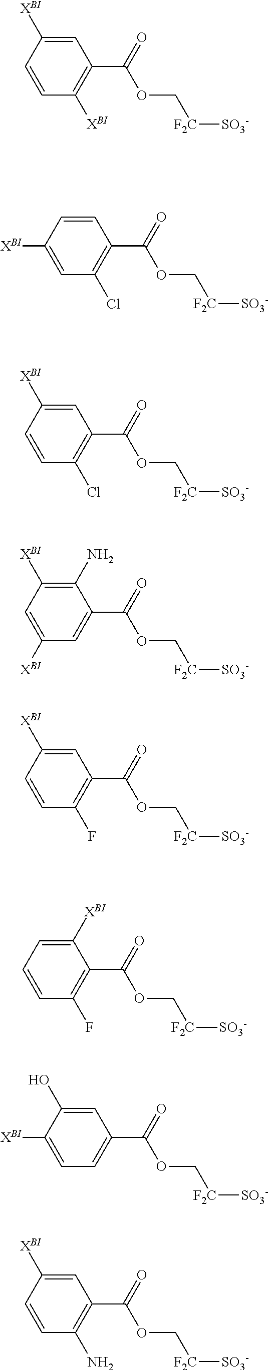

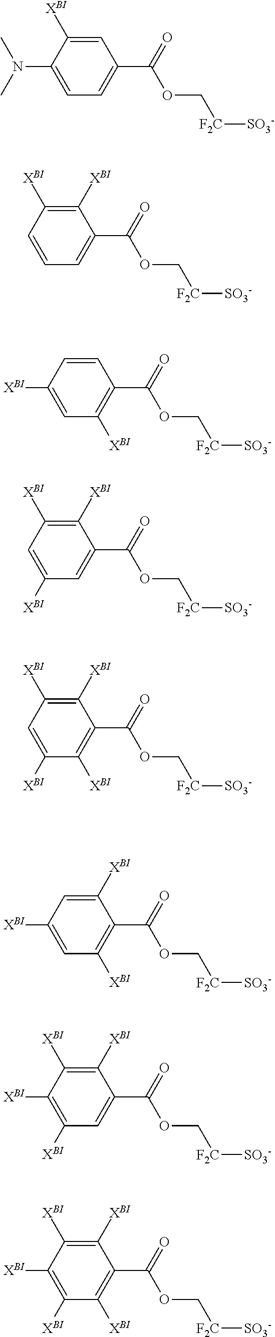

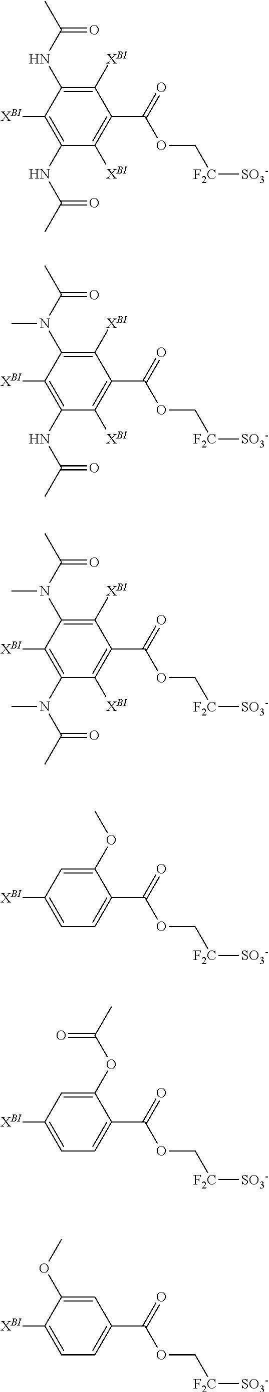

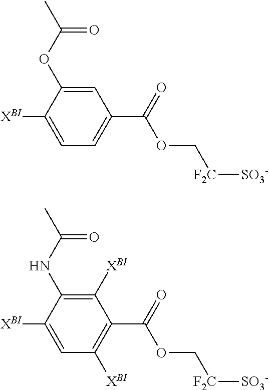

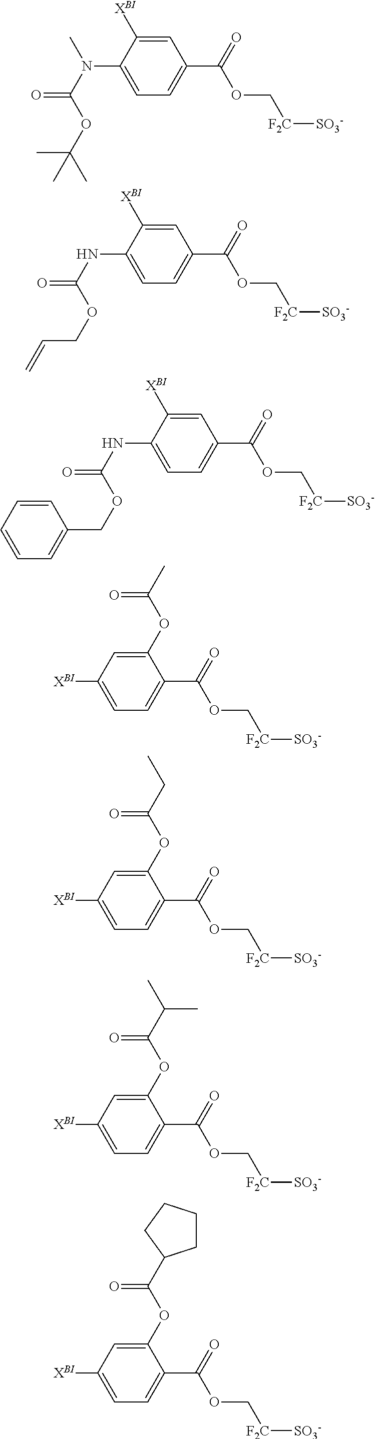

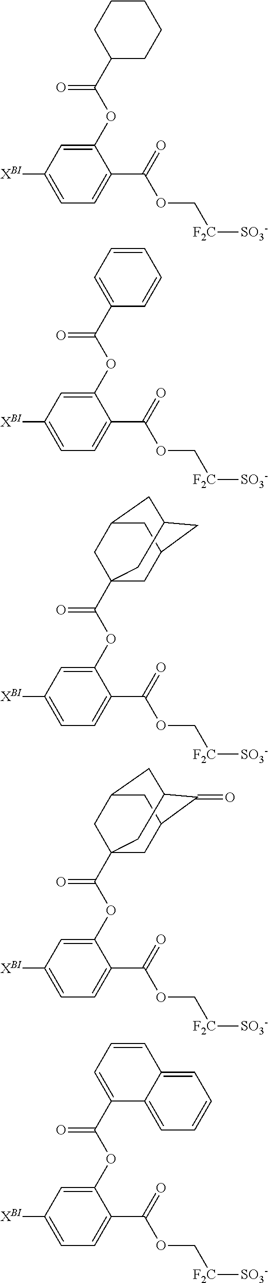

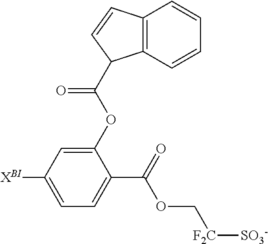

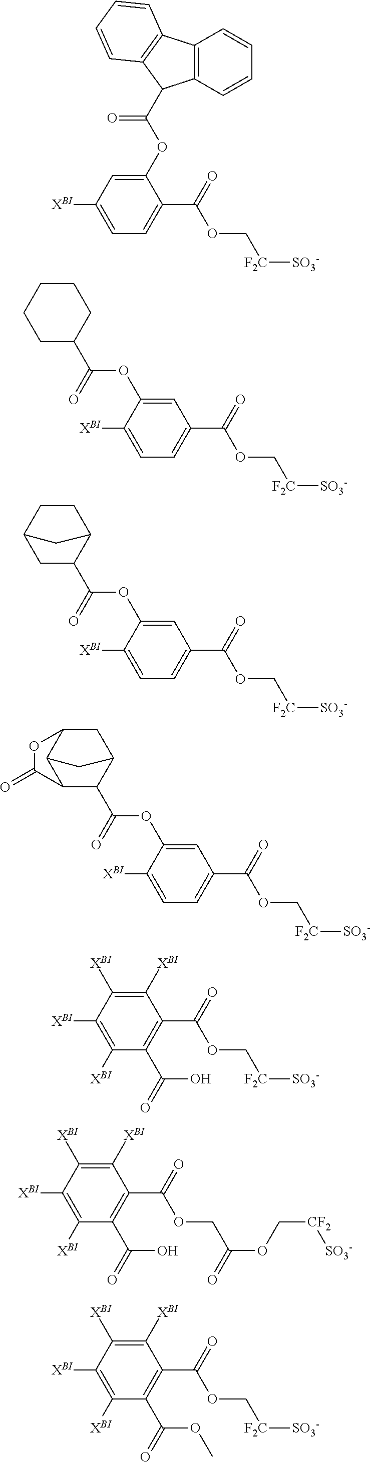

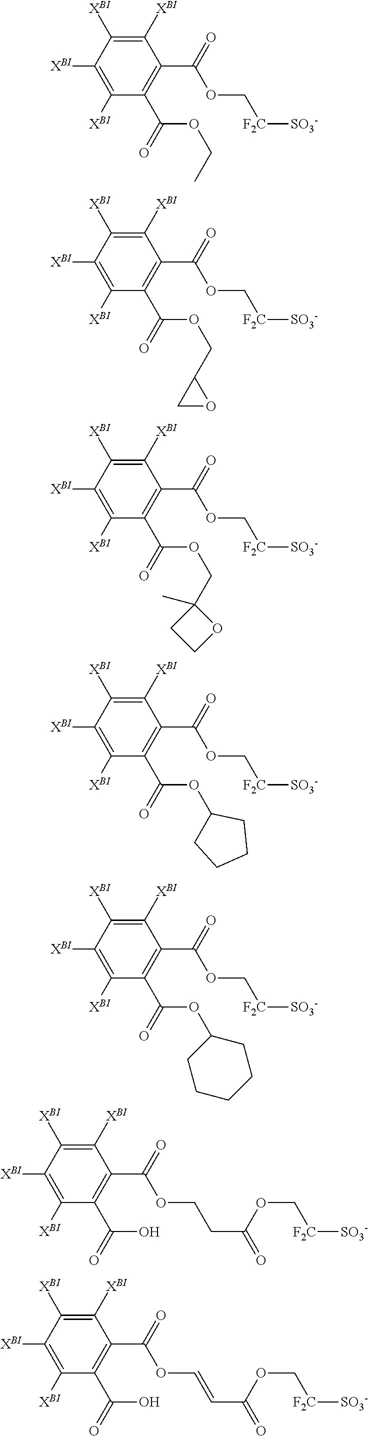

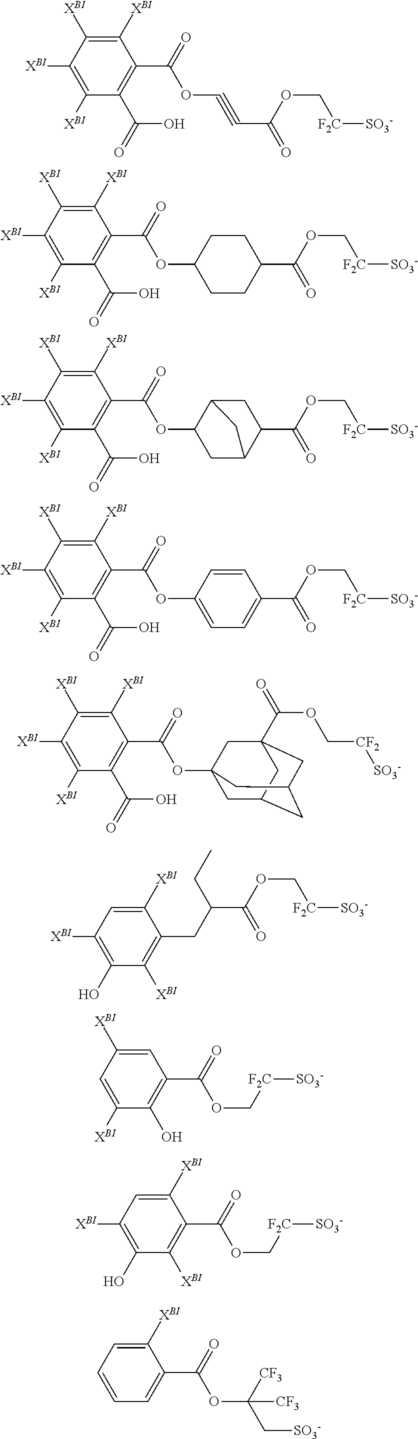

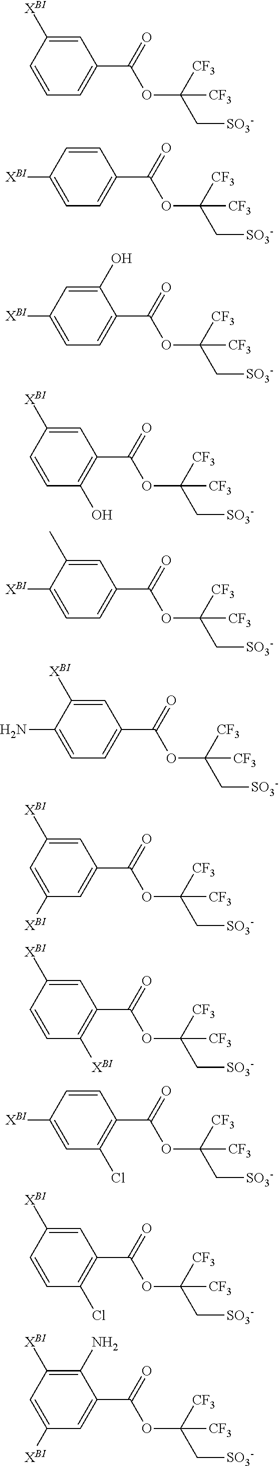

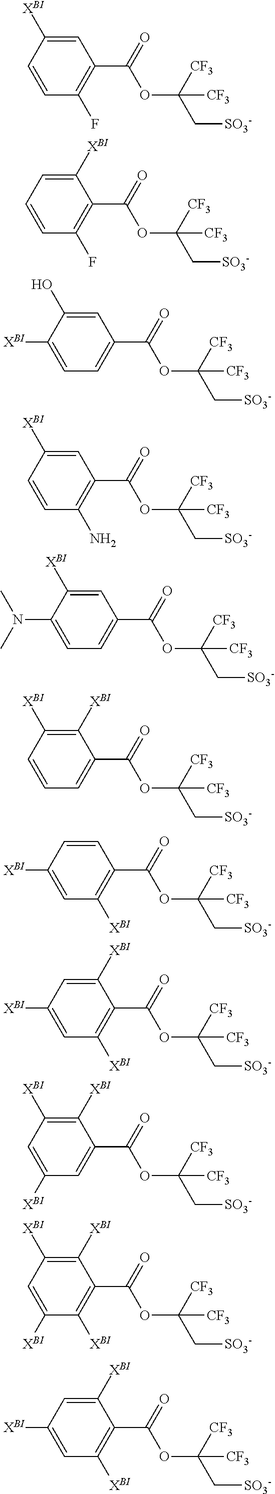

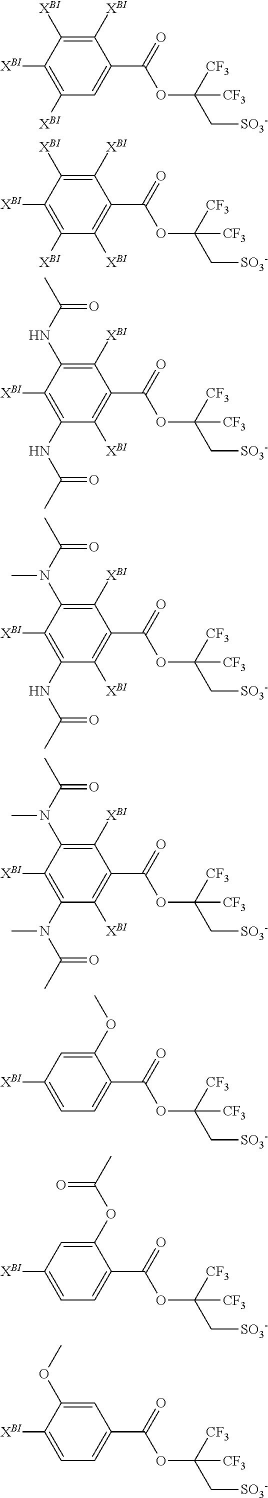

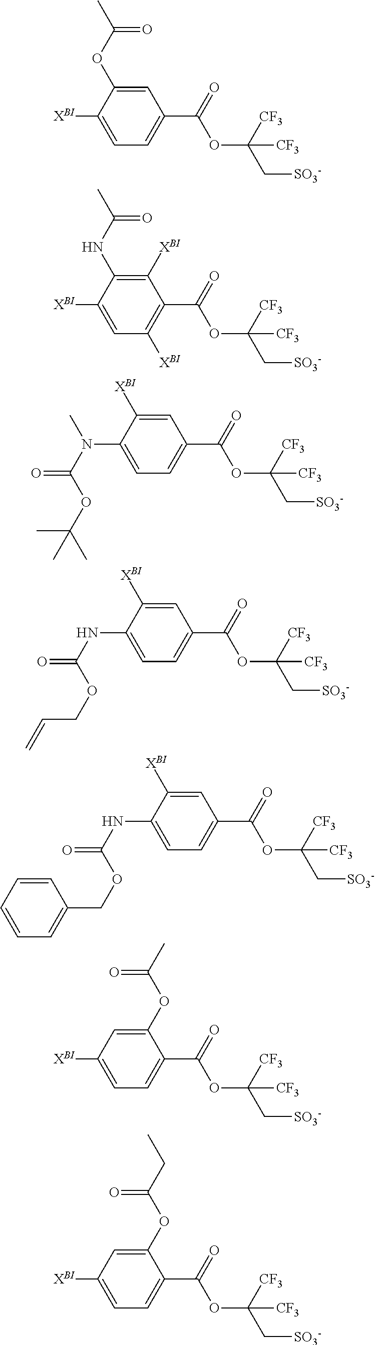

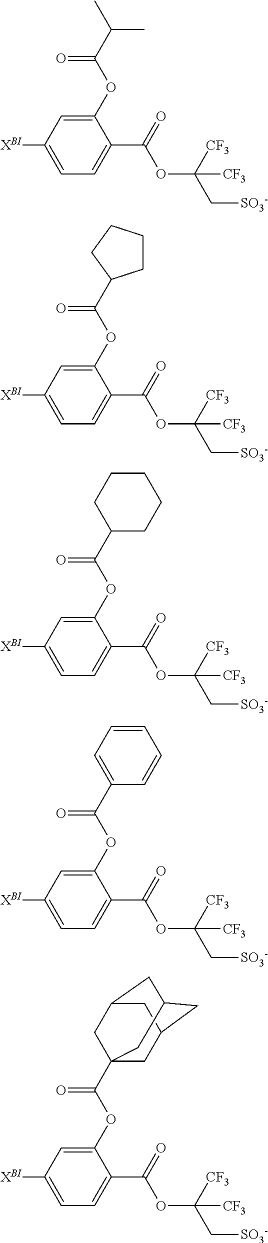

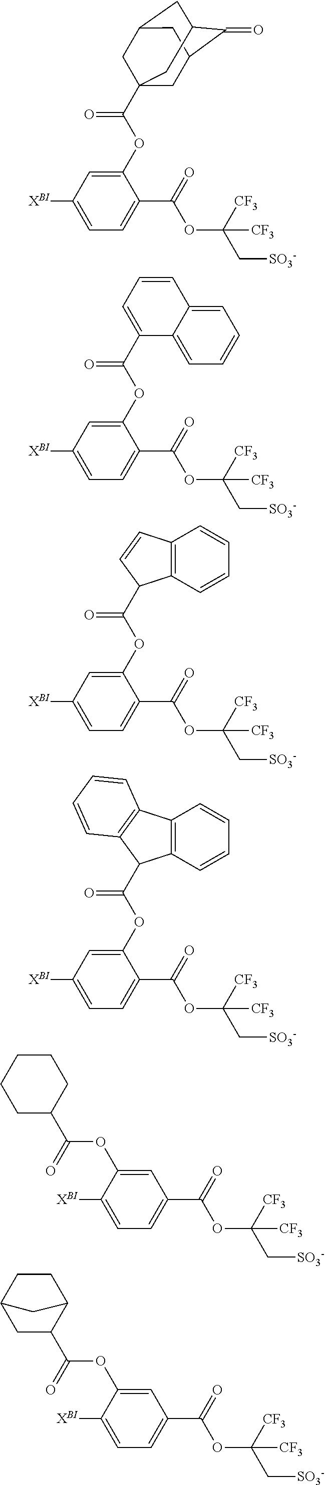

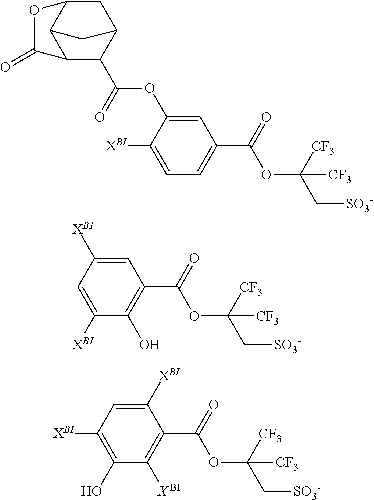

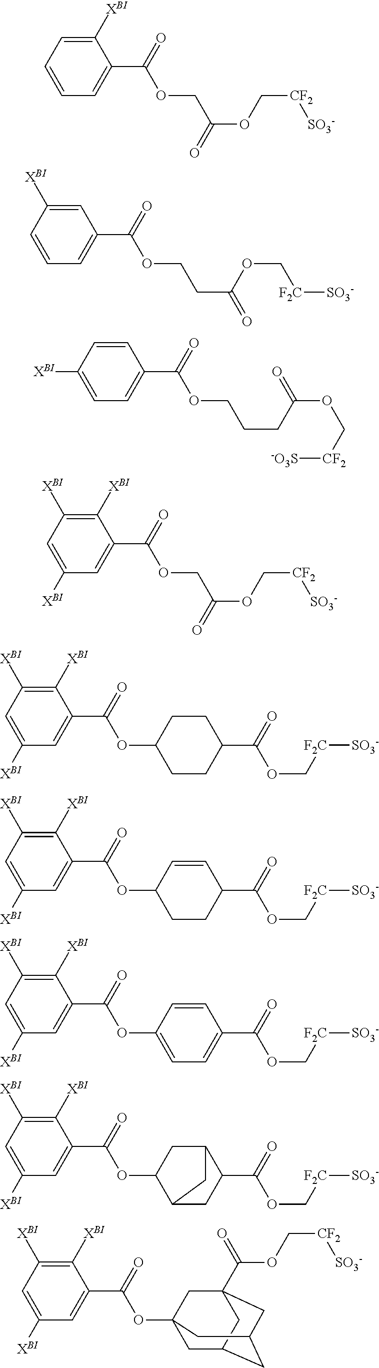

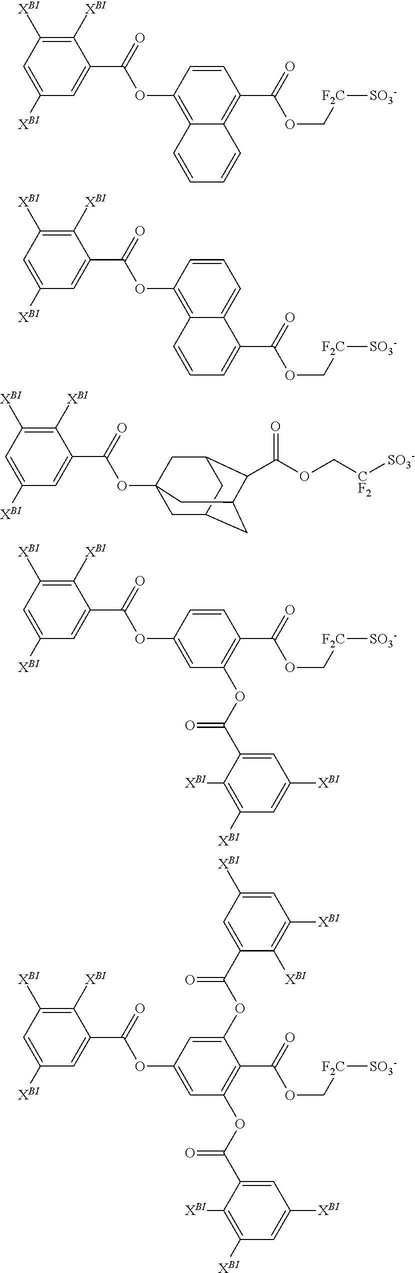

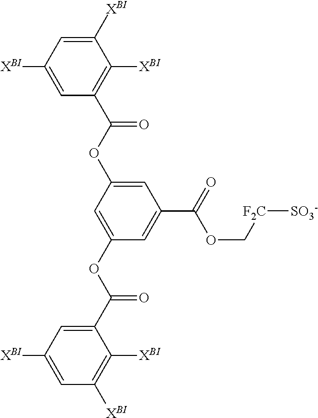

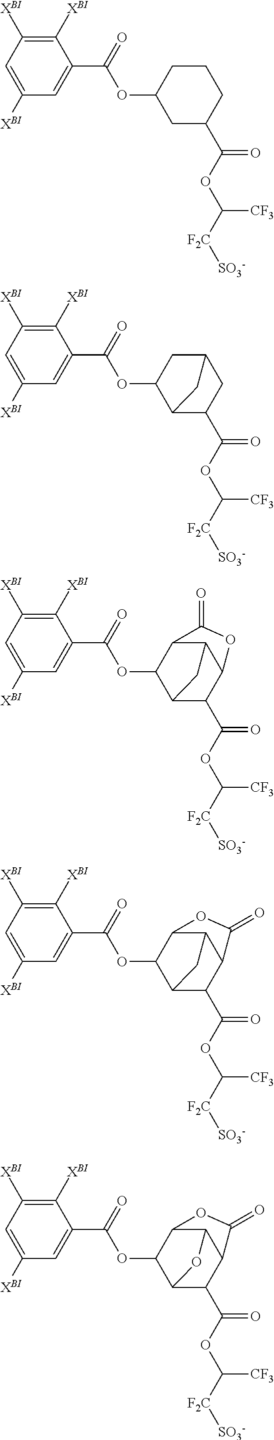

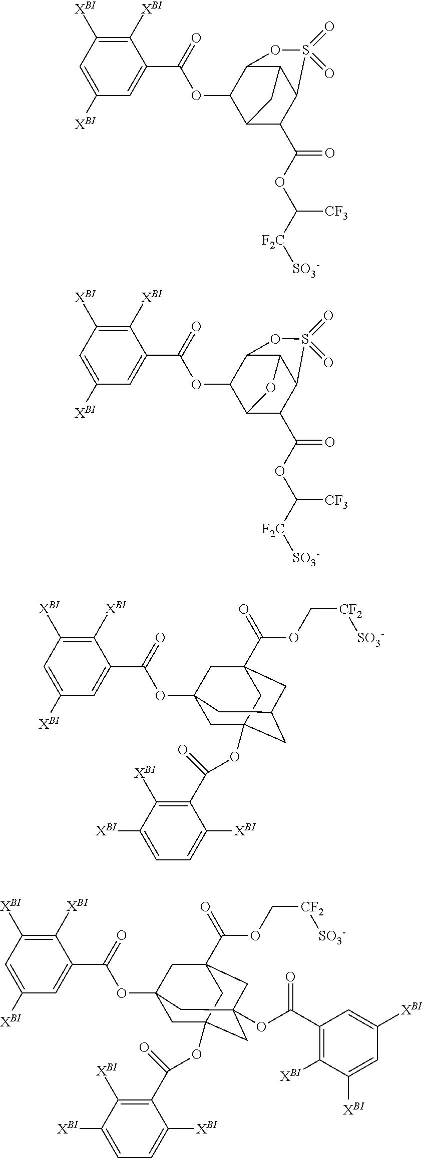

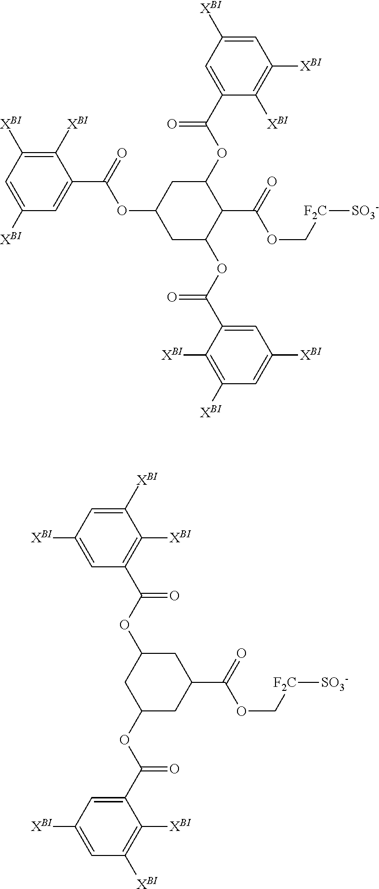

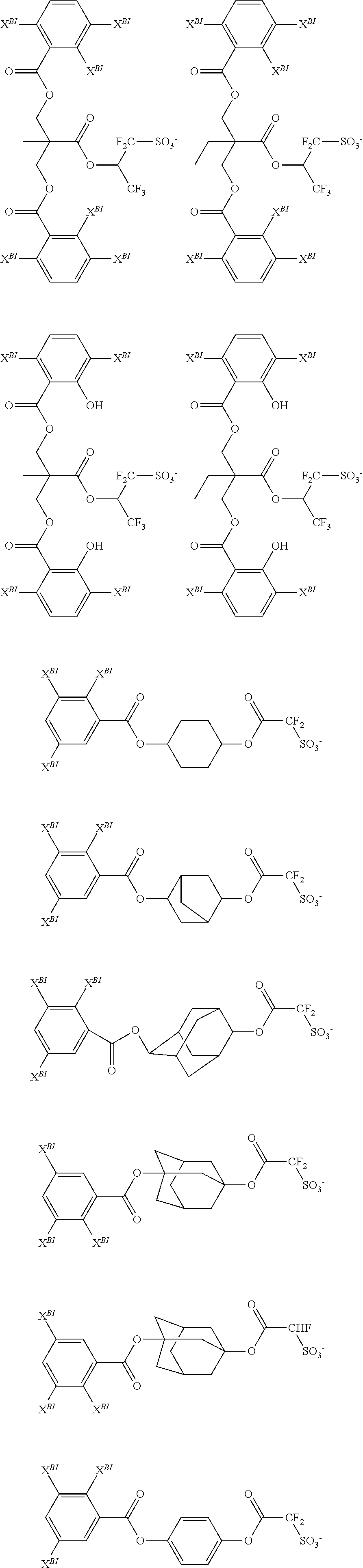

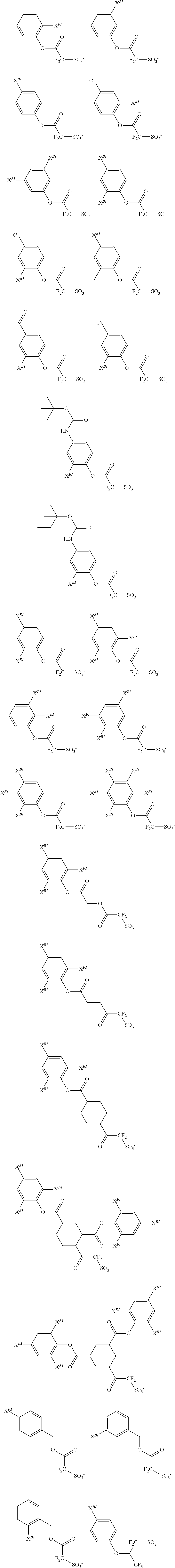

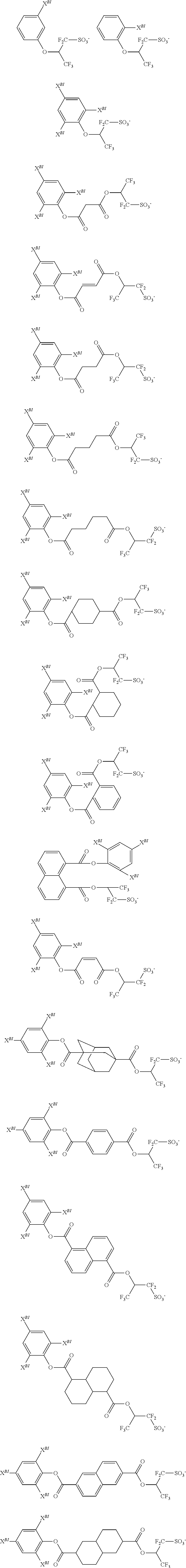

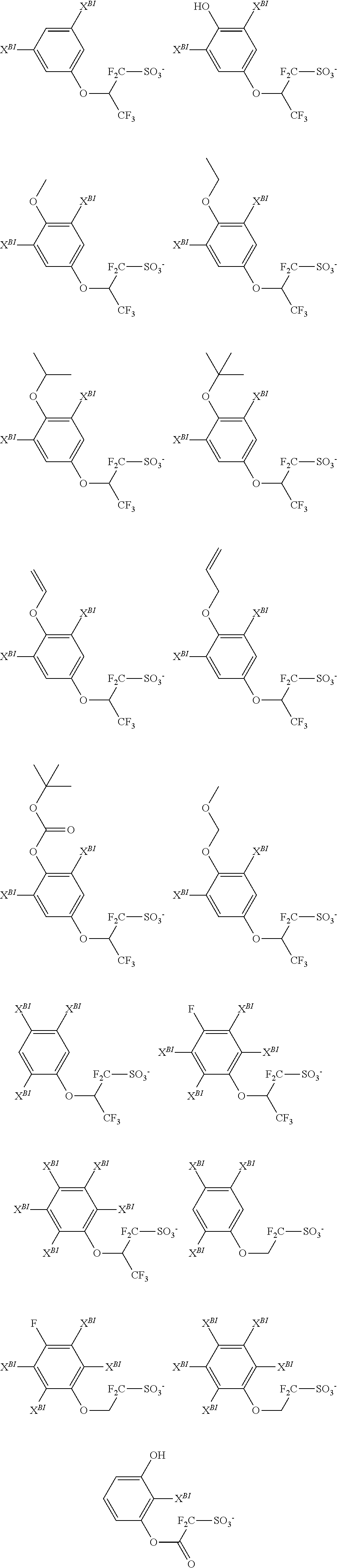

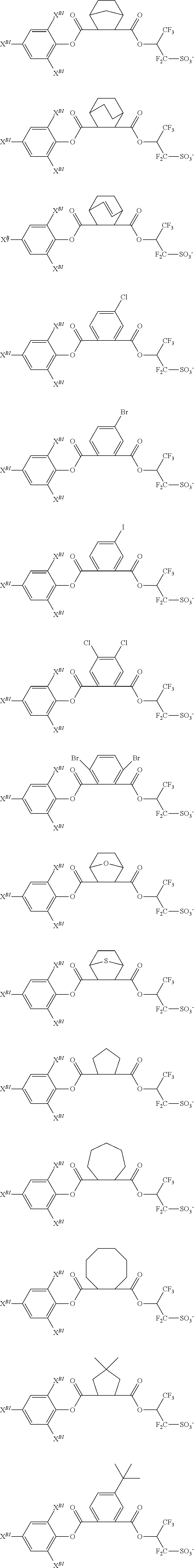

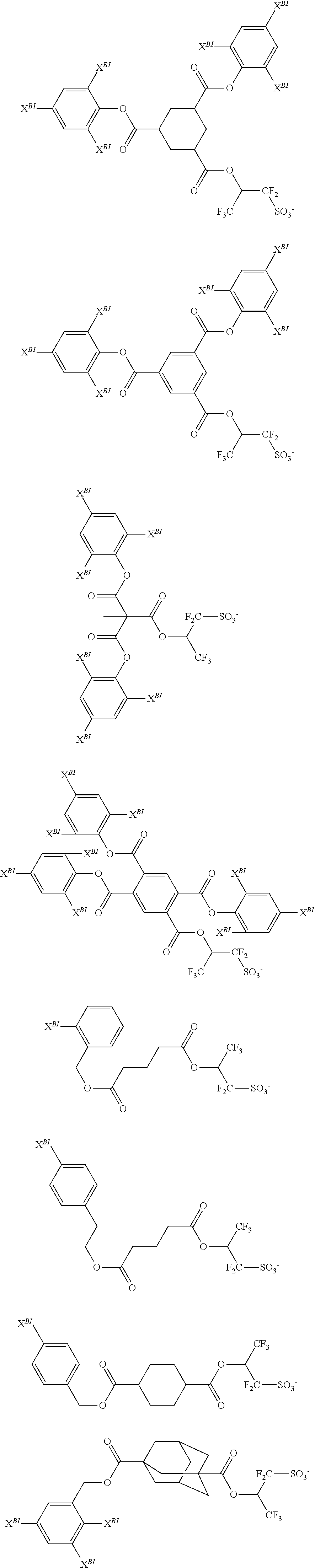

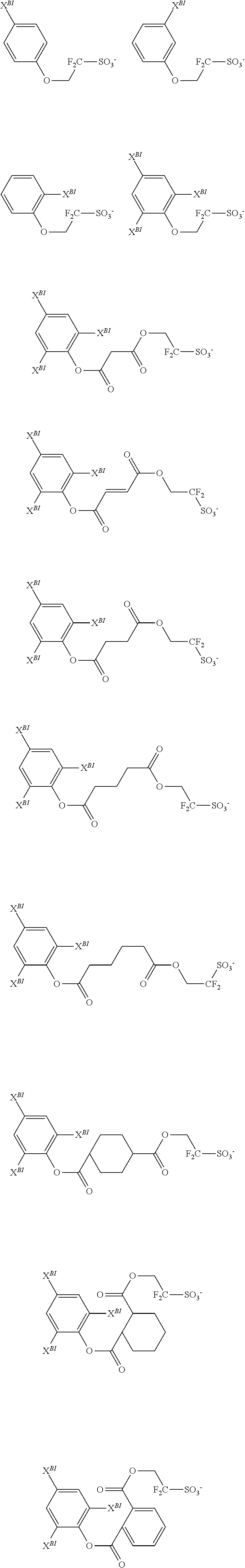

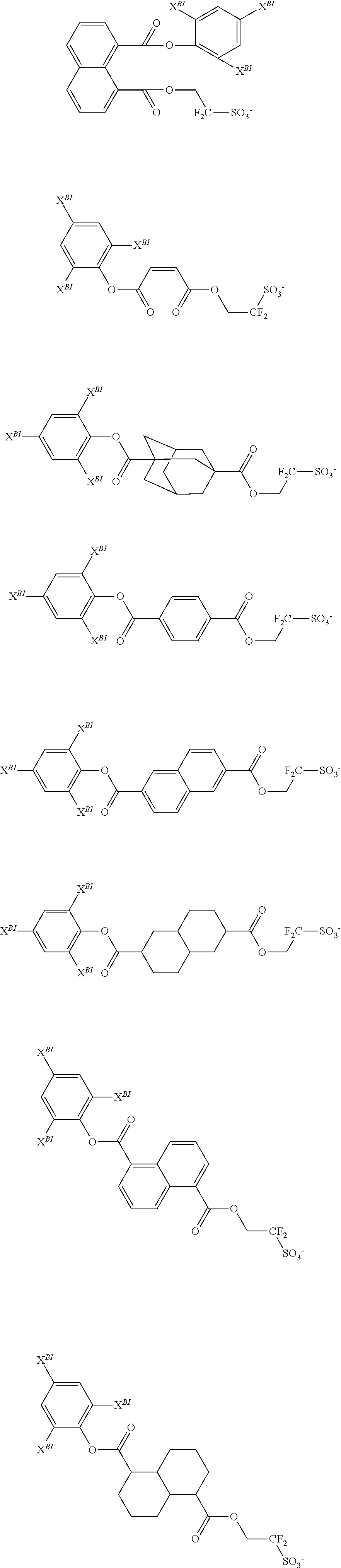

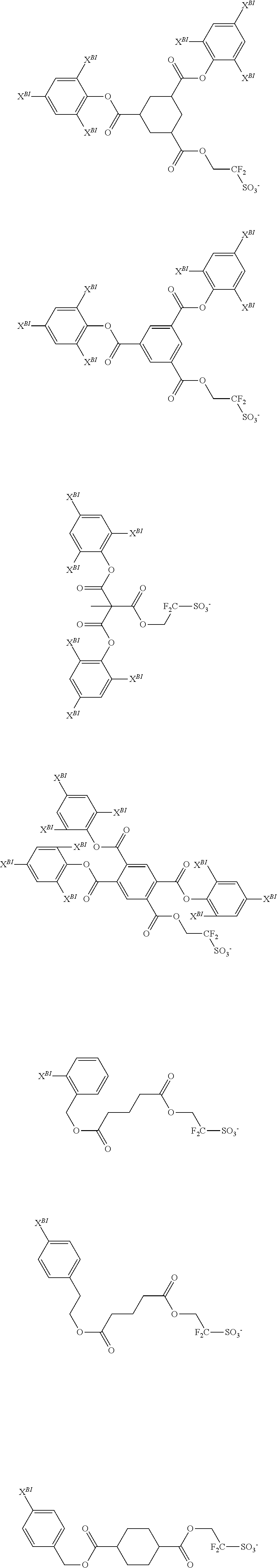

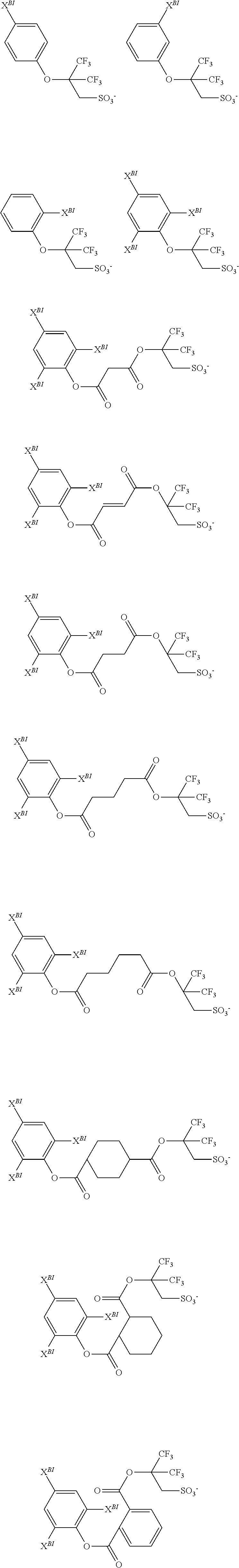

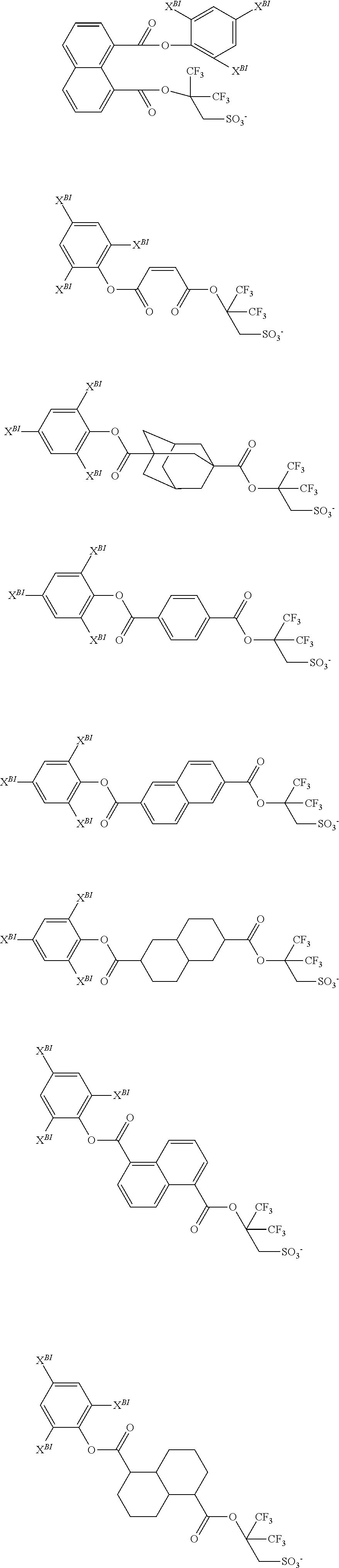

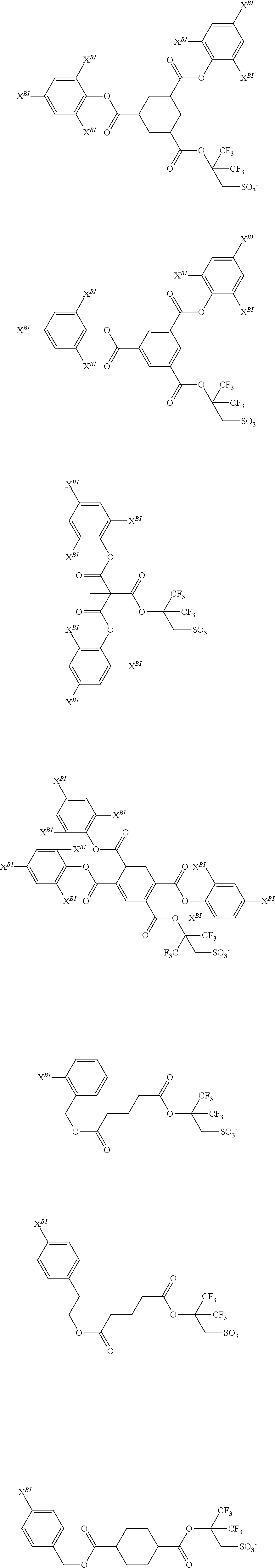

In the above, X^{BI} represents a bromine atom or an iodine atom.

Examples of an anion of a monomer to give the repeating unit-b2 include those shown below, but are not limited thereto. Note that, in the following formulae, R^{A} is as defined above.

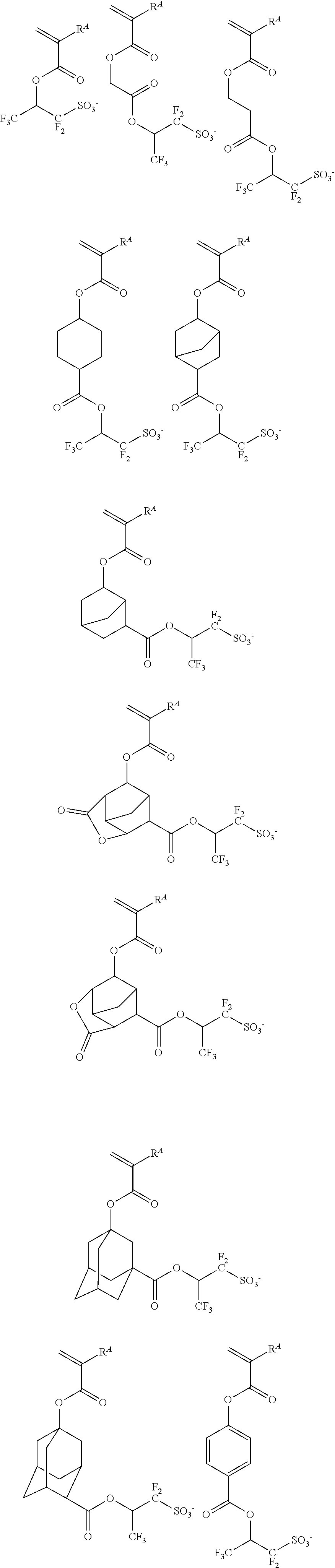

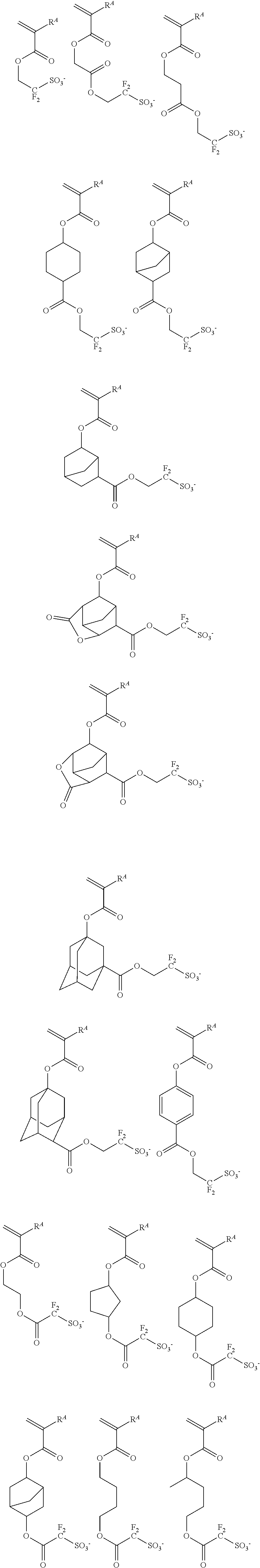

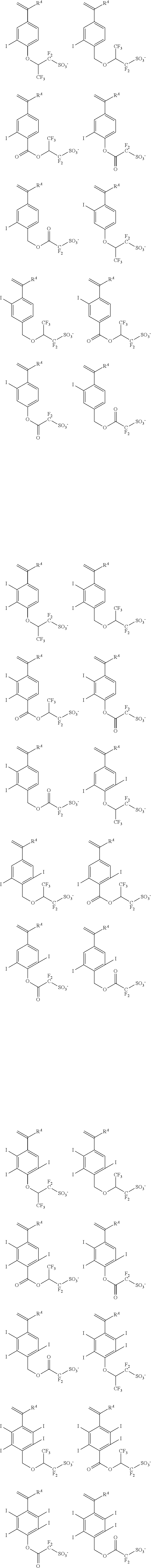

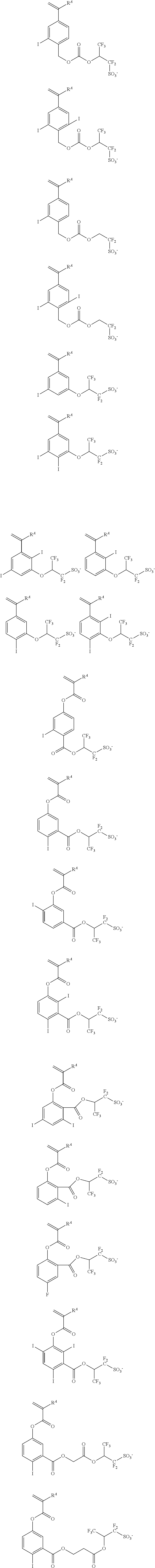

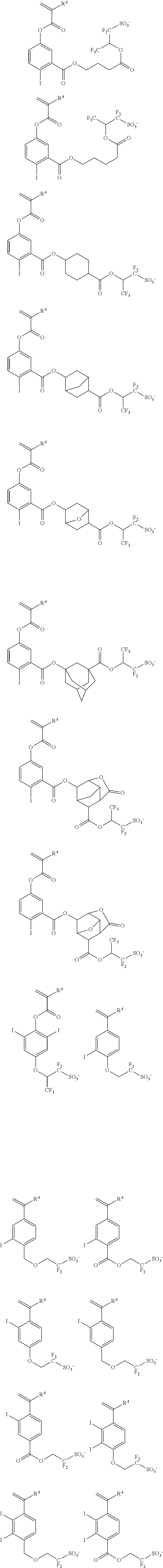

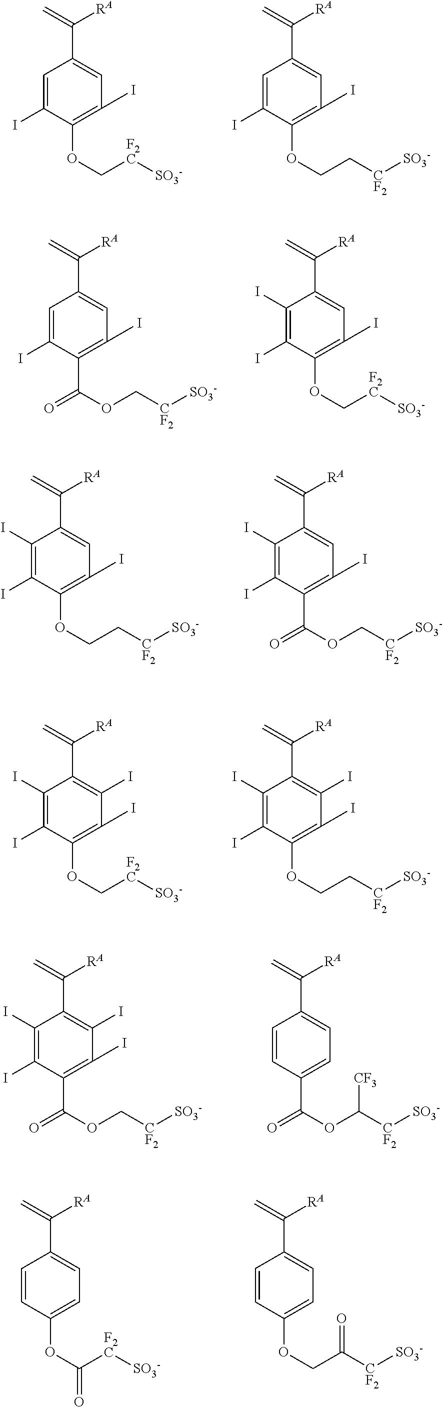

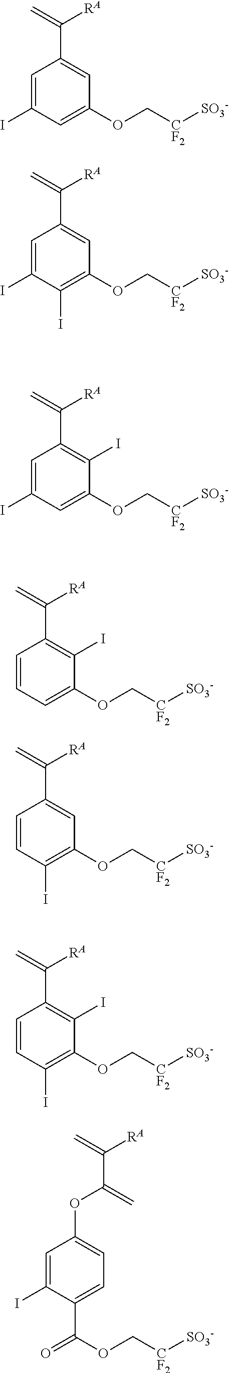

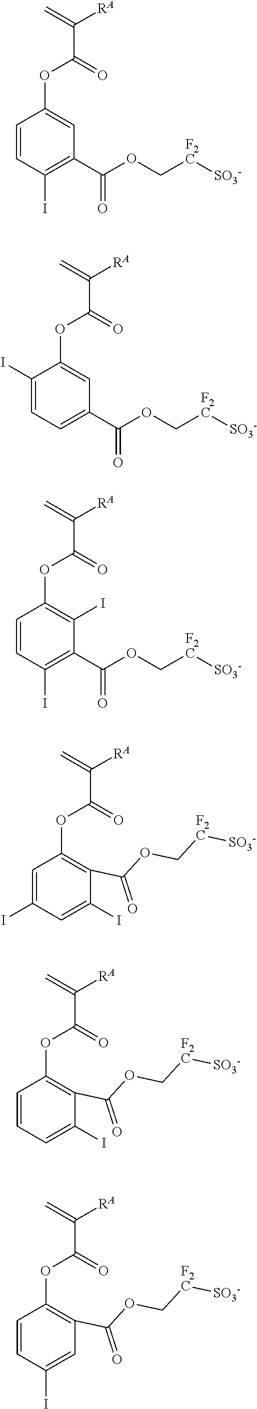

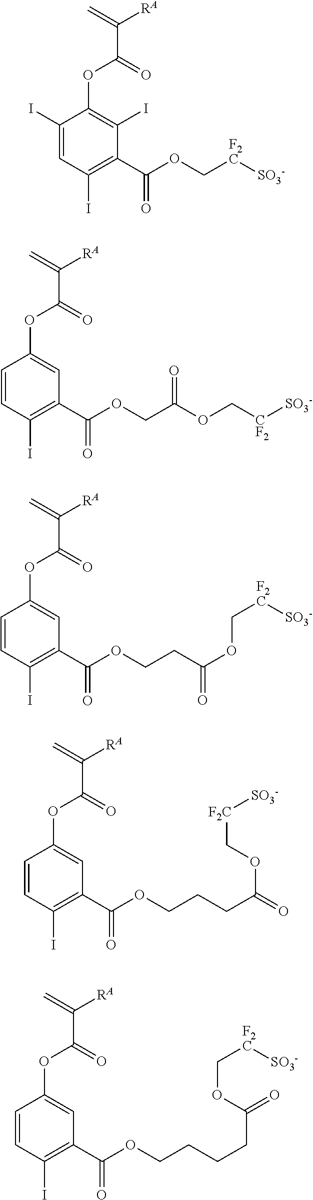

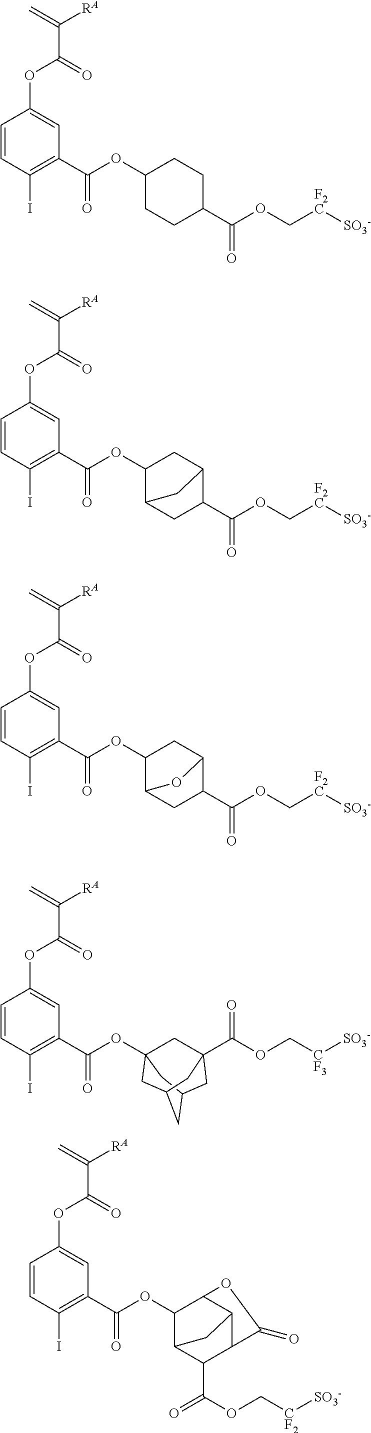

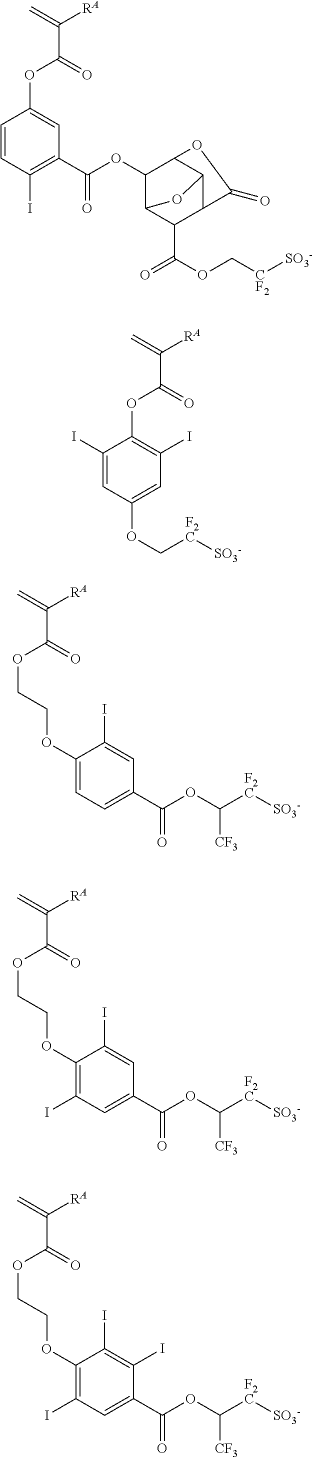

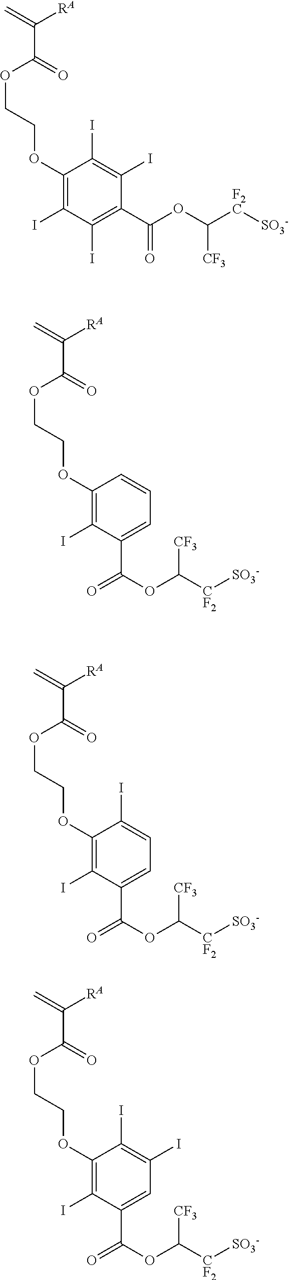

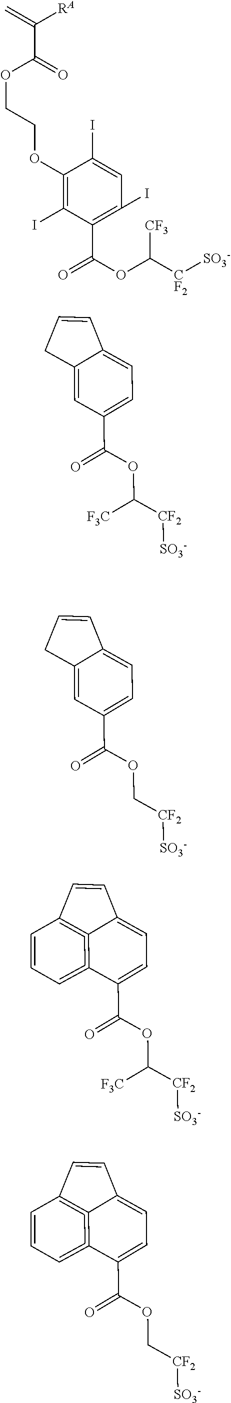

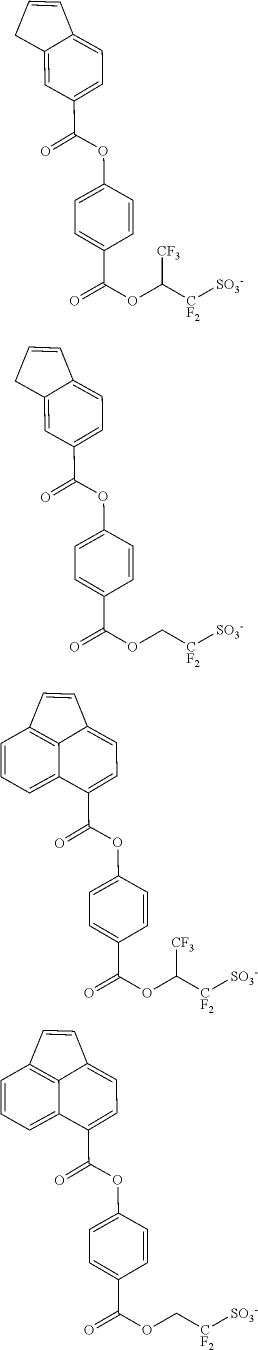

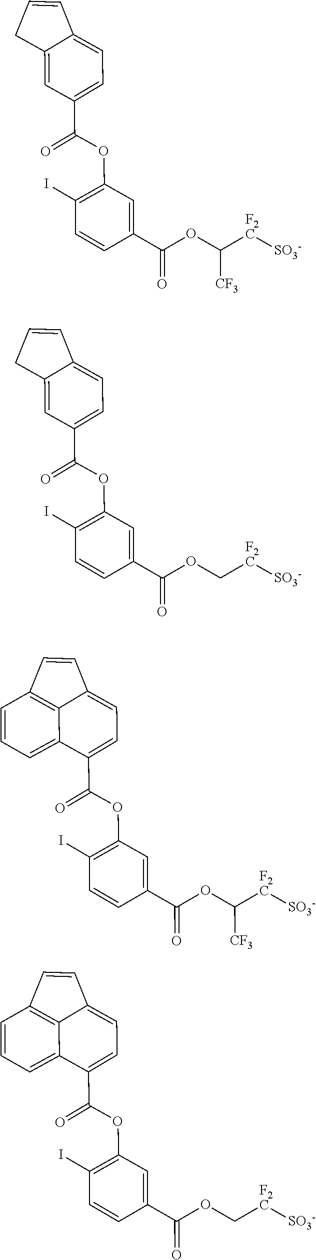

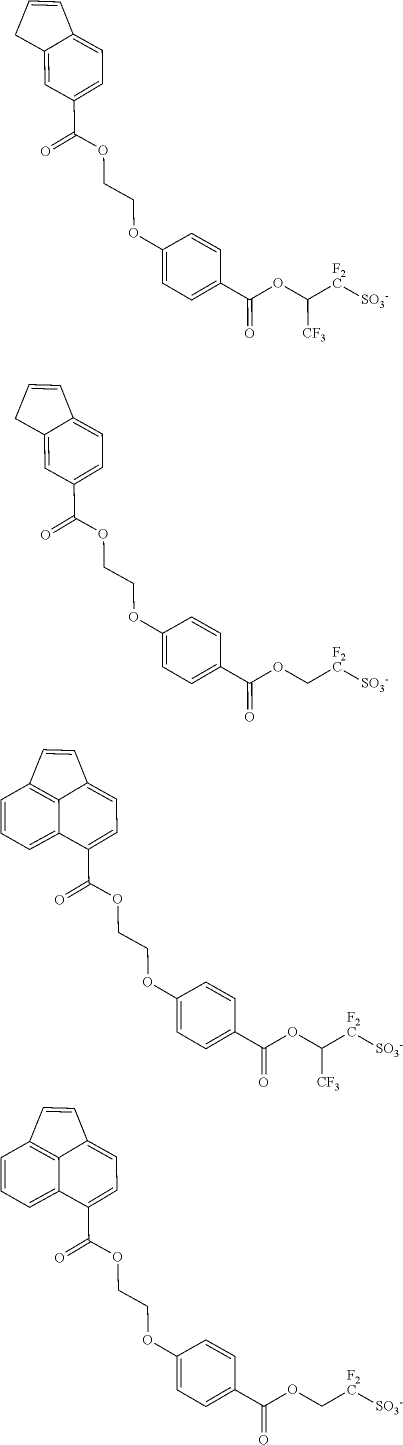

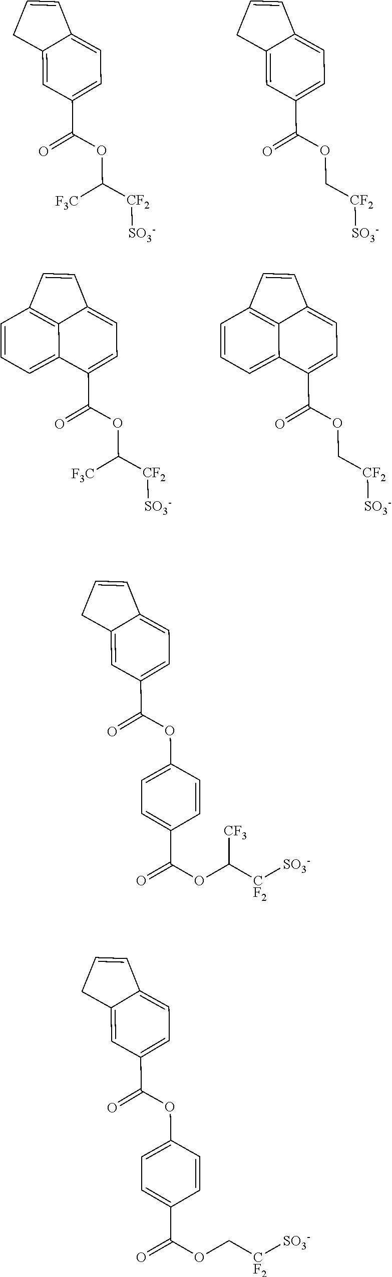

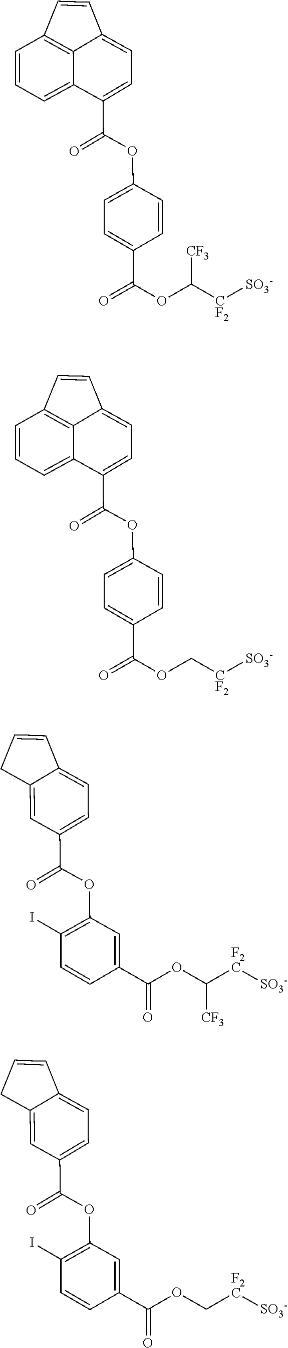

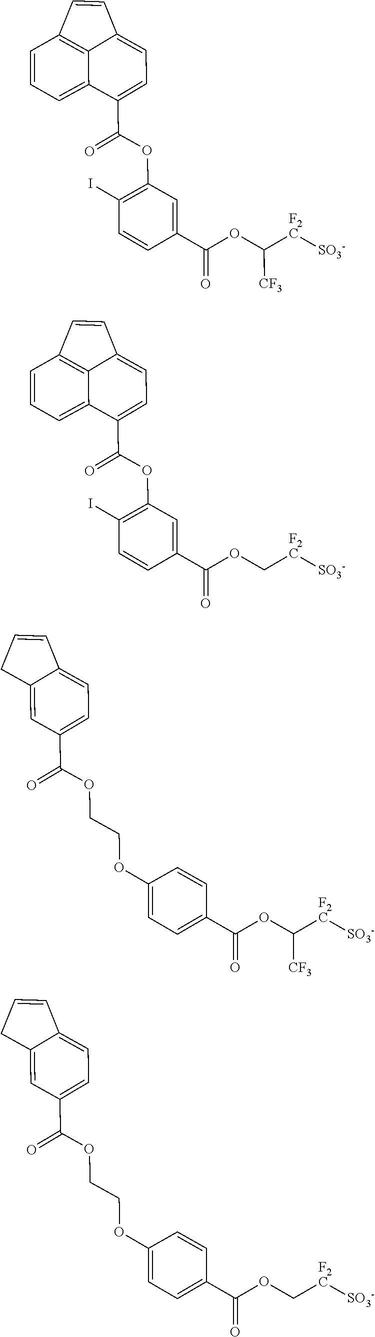

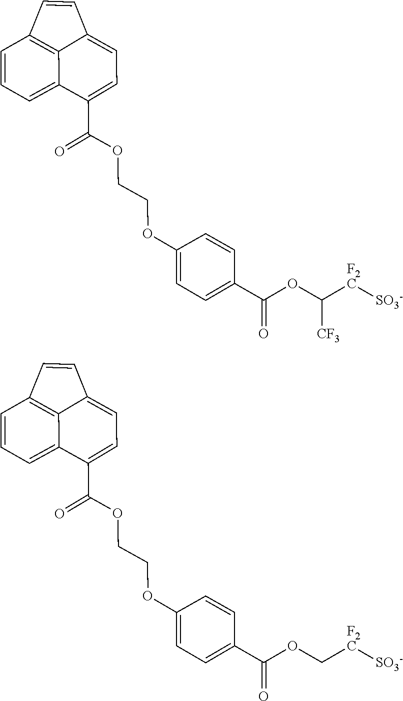

Examples of an anion of a monomer to give the repeating unit-b3 include those shown below, but are not limited thereto. Note that, in the following formulae, R^{A} is as defined above.

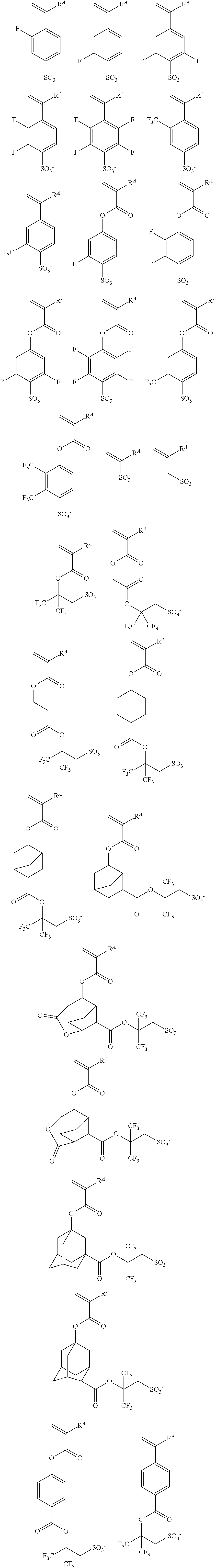

Specific examples of anions of the repeating units-b4 and -b5 include those shown below, but are not limited thereto. Note that, in the following formulae, X^{BI} represents an iodine atom or a bromine atom.

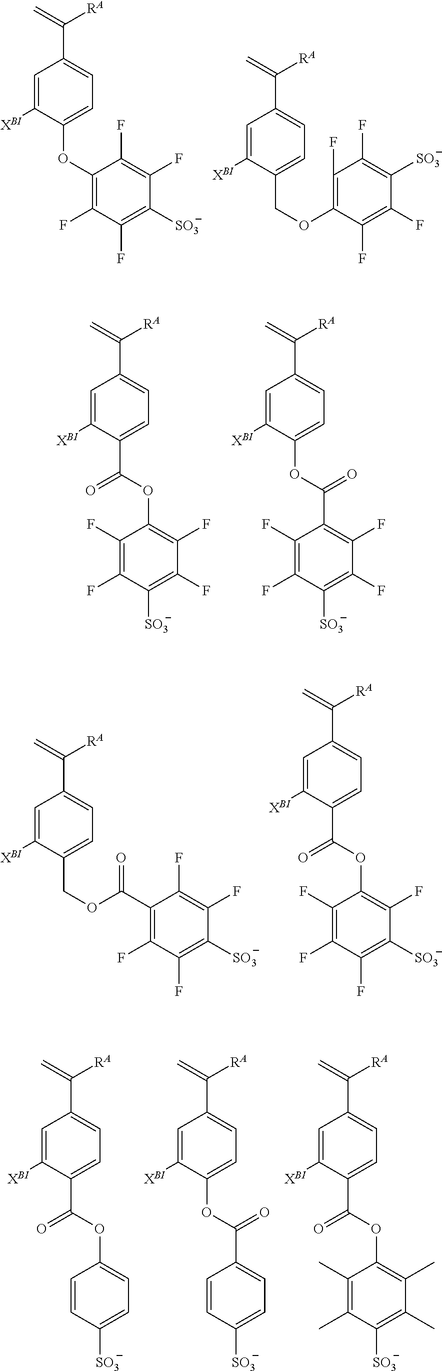

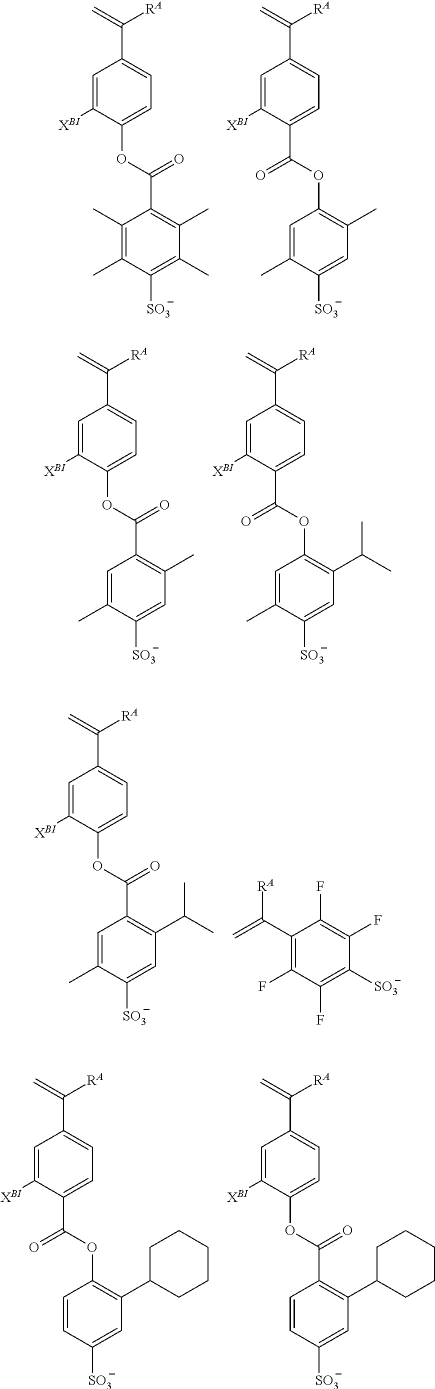

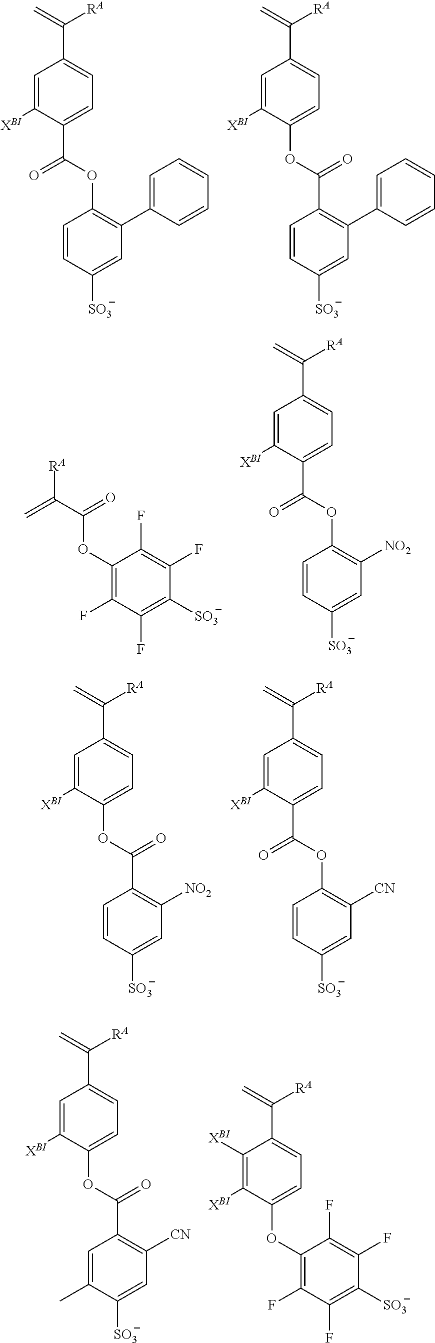

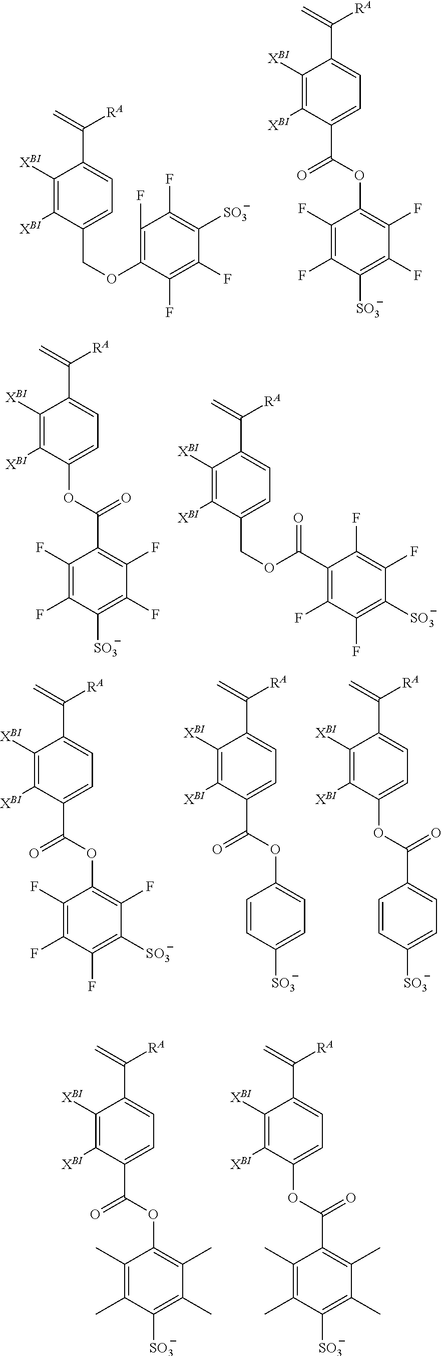

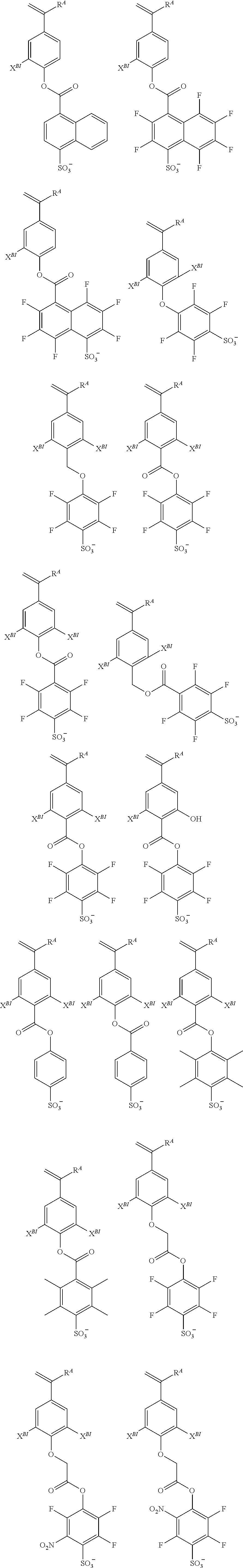

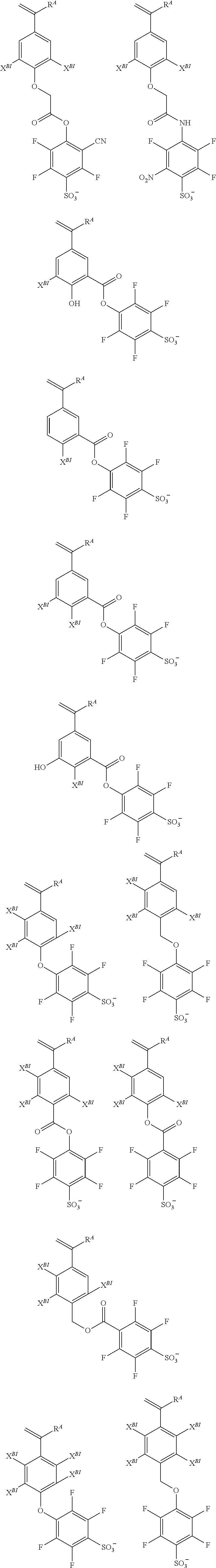

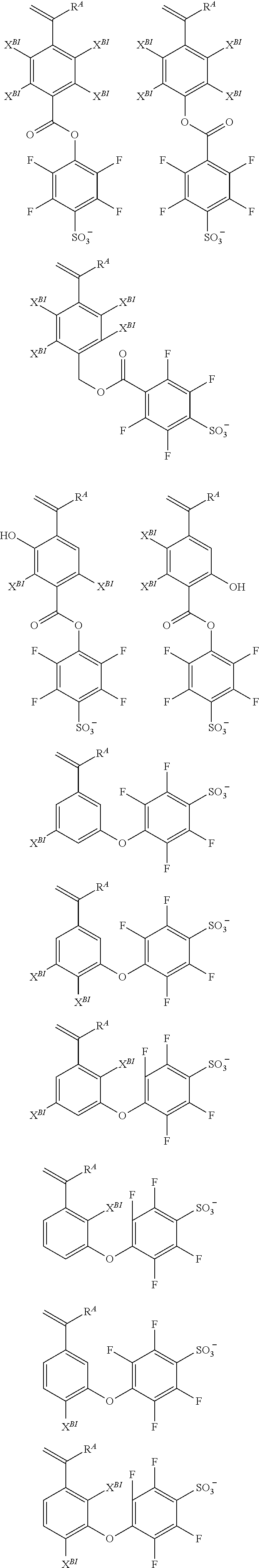

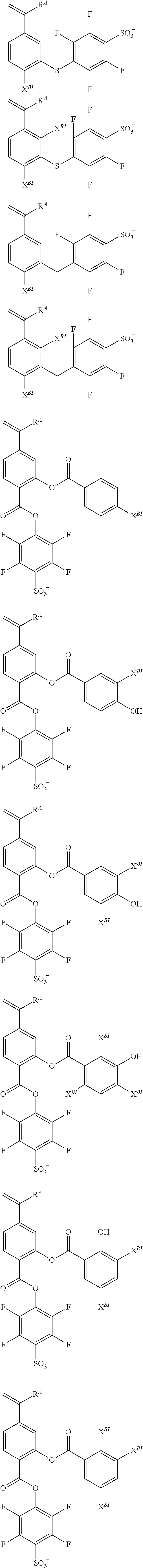

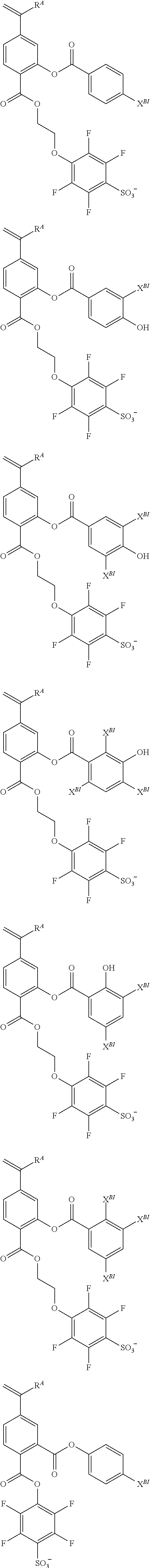

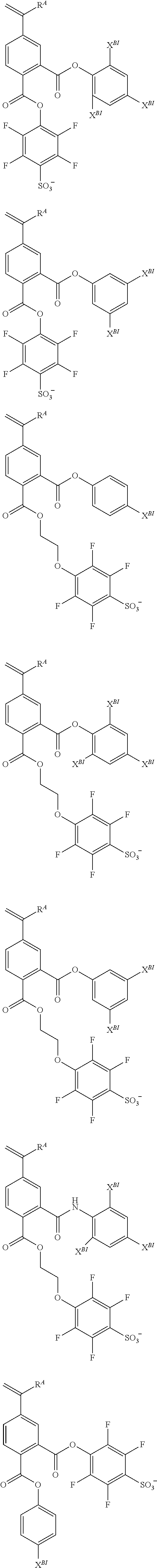

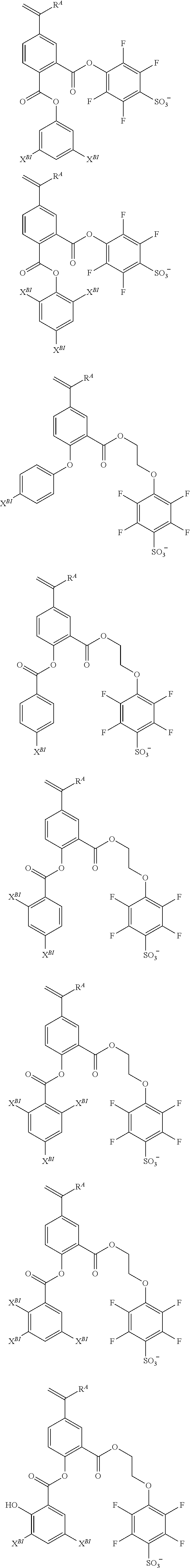

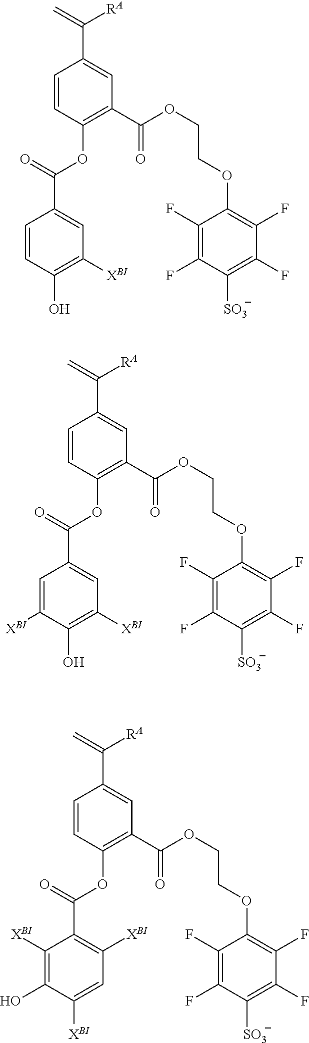

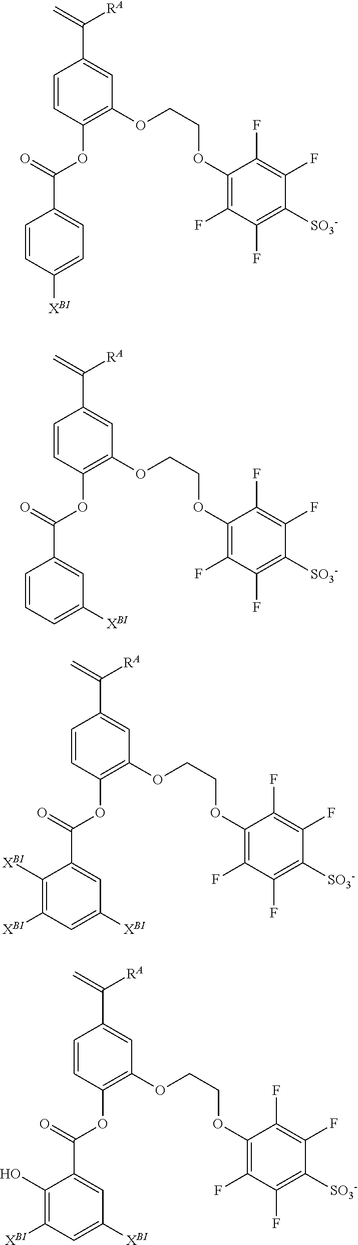

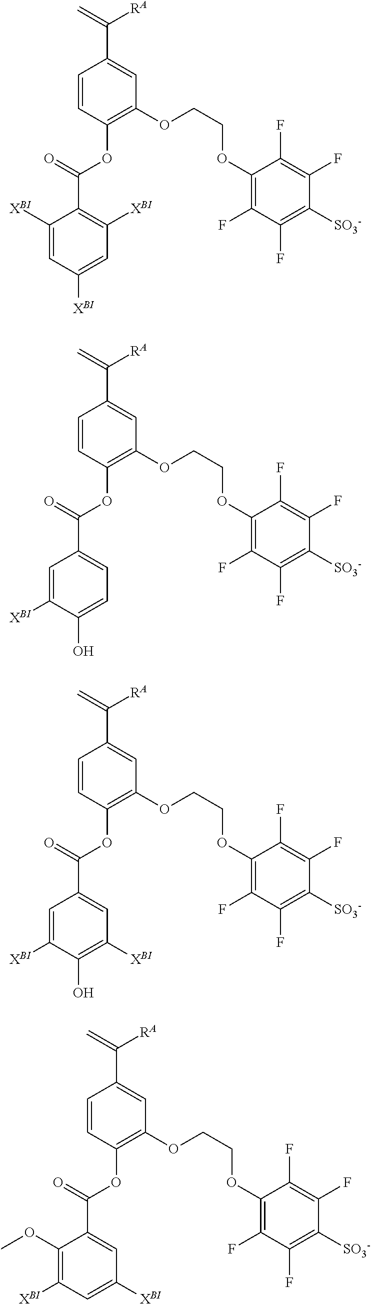

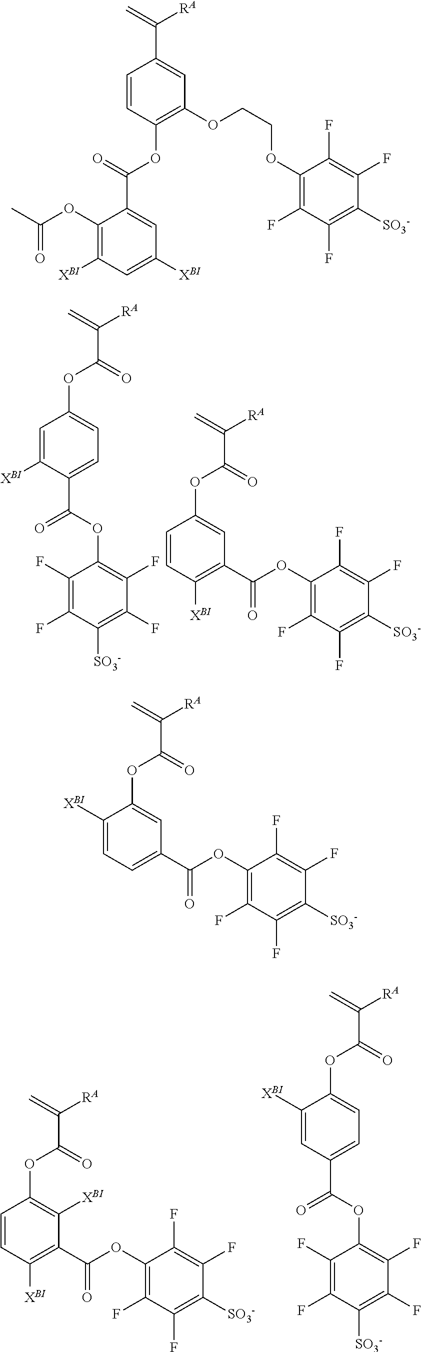

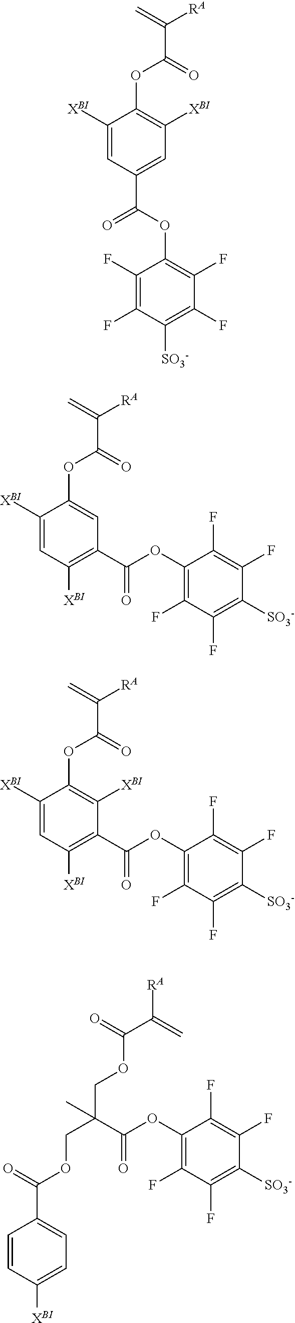

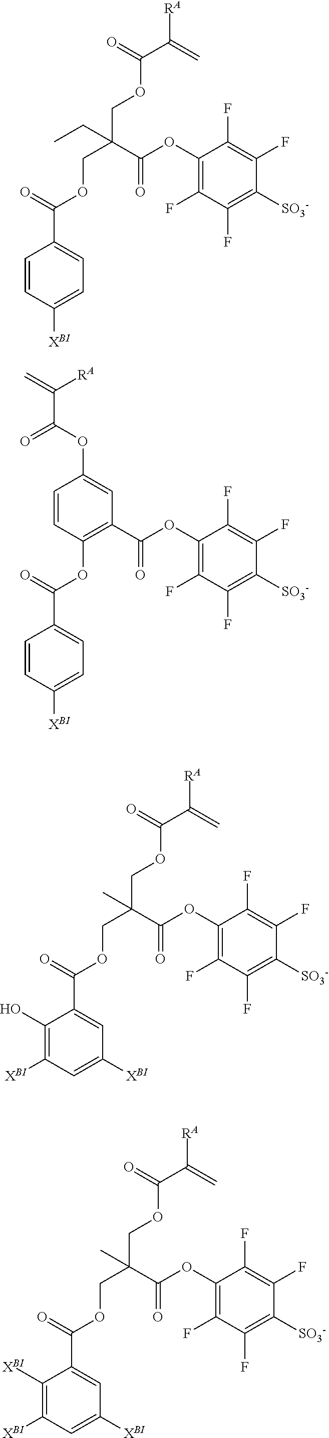

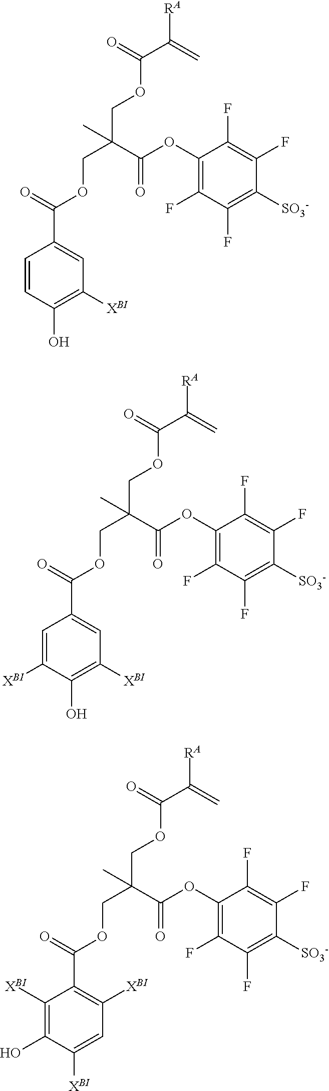

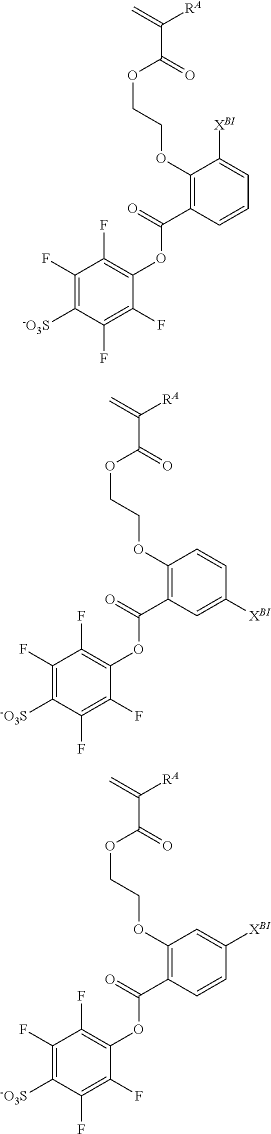

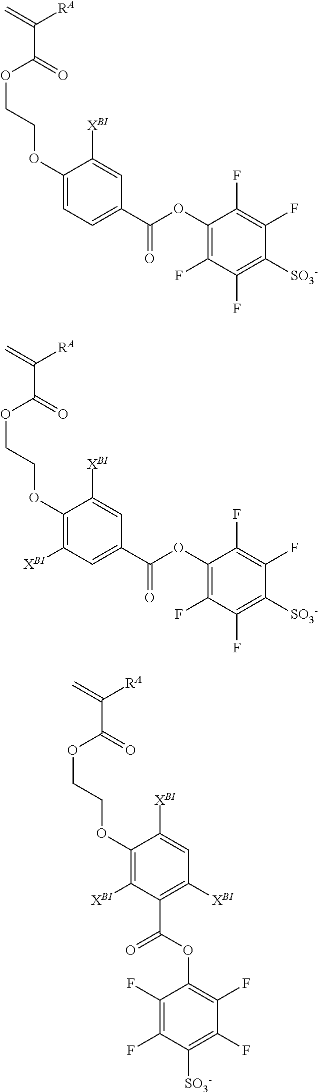

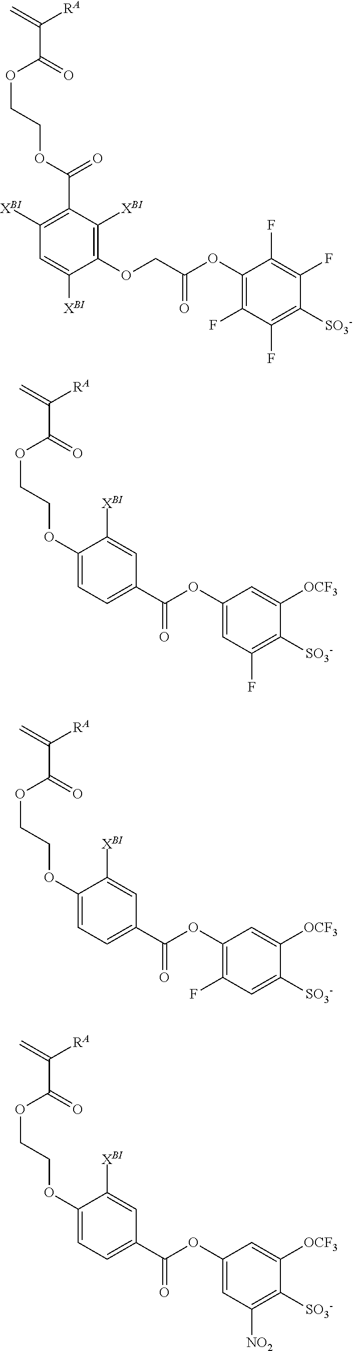

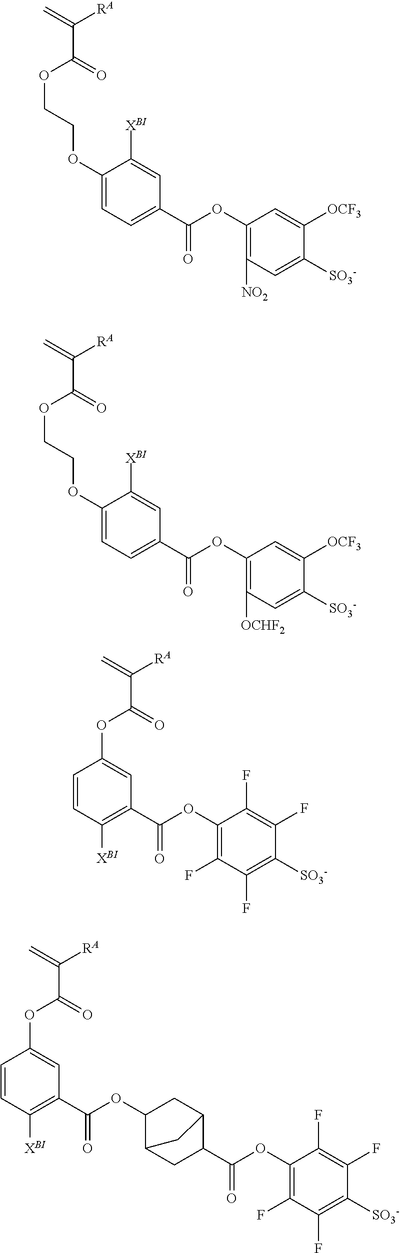

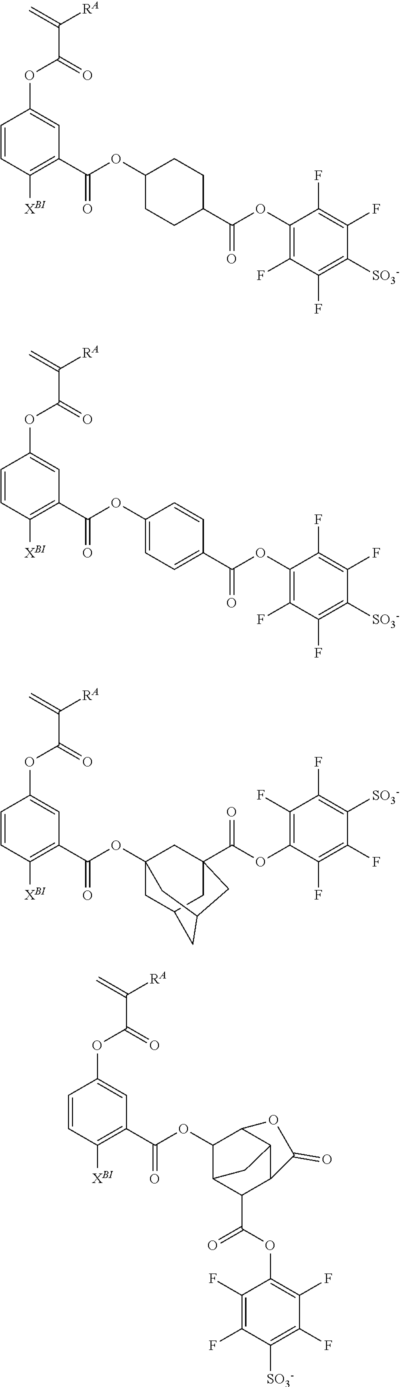

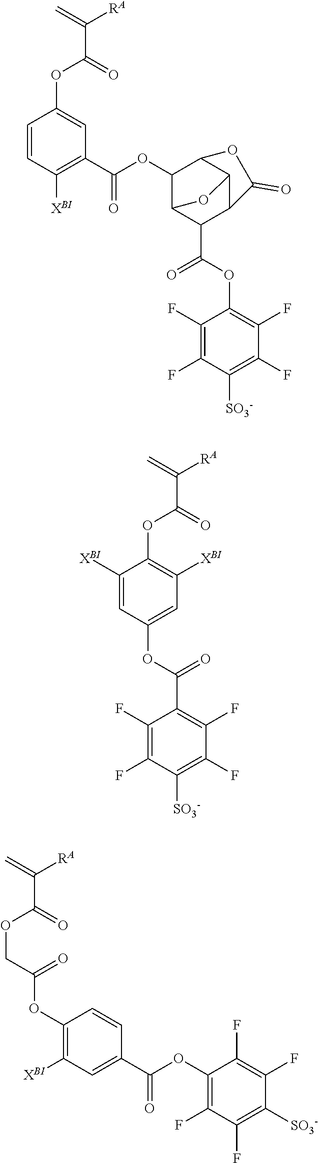

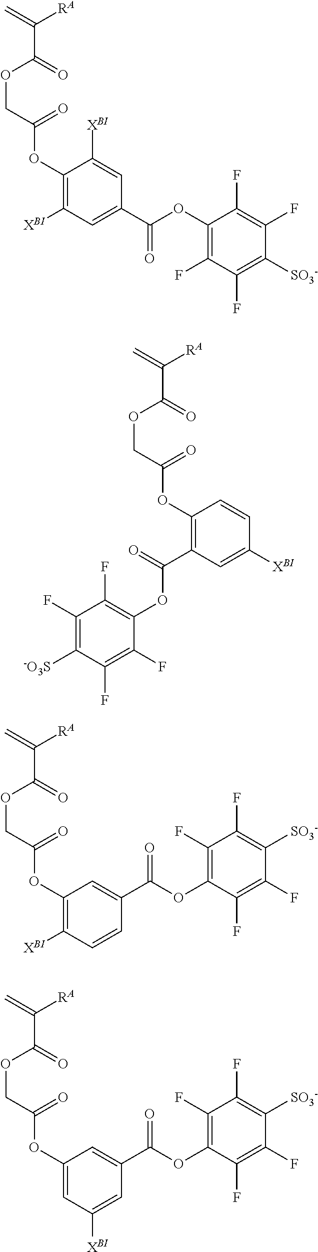

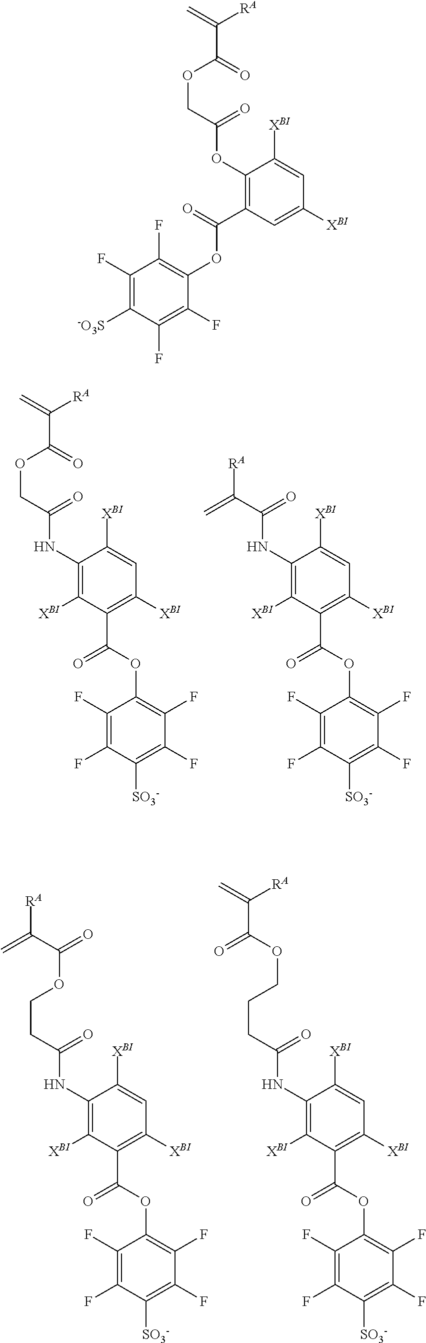

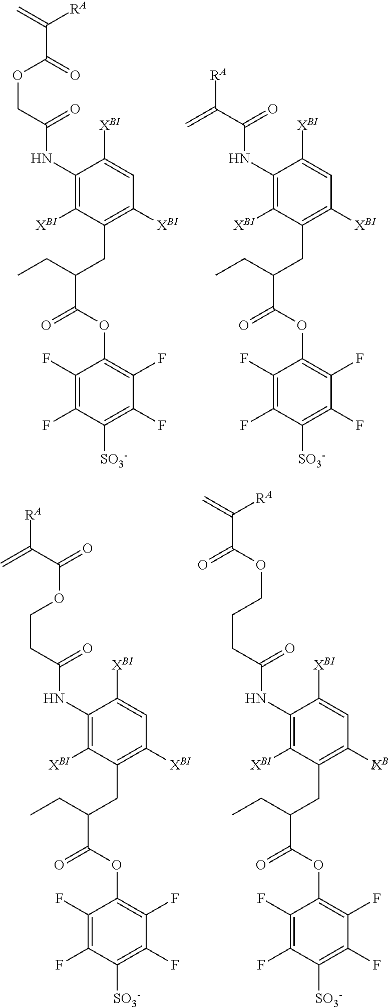

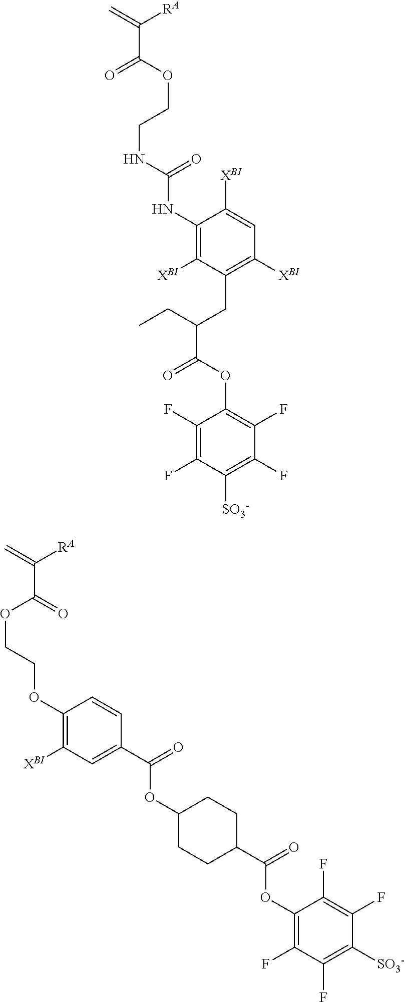

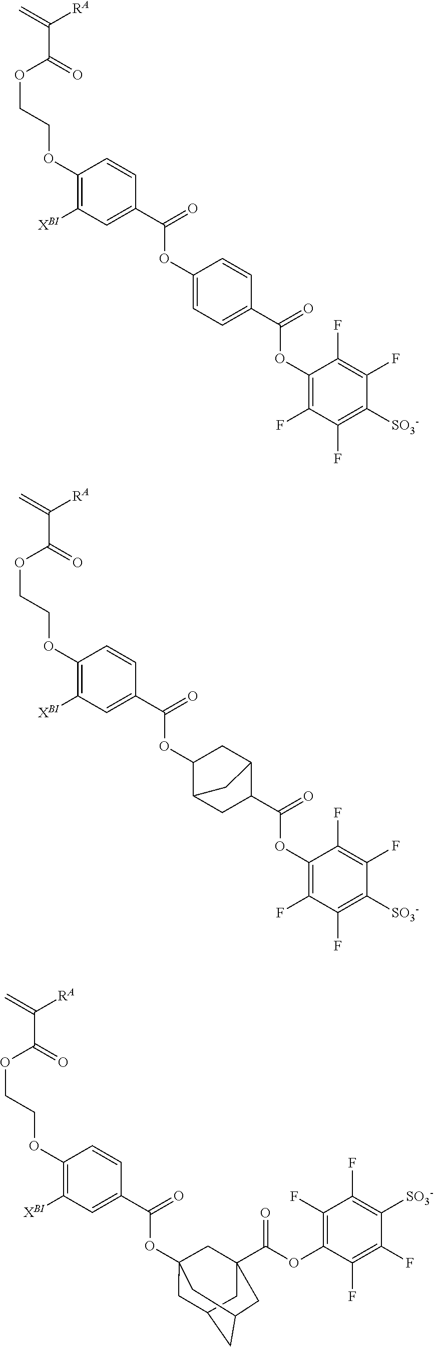

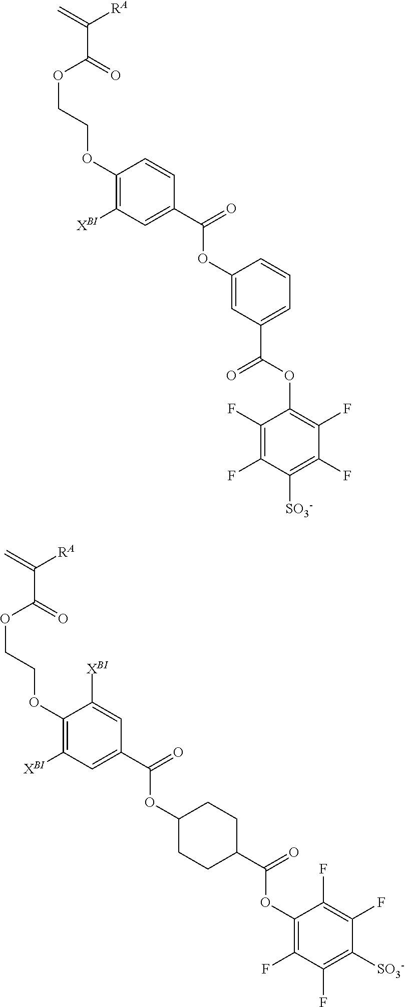

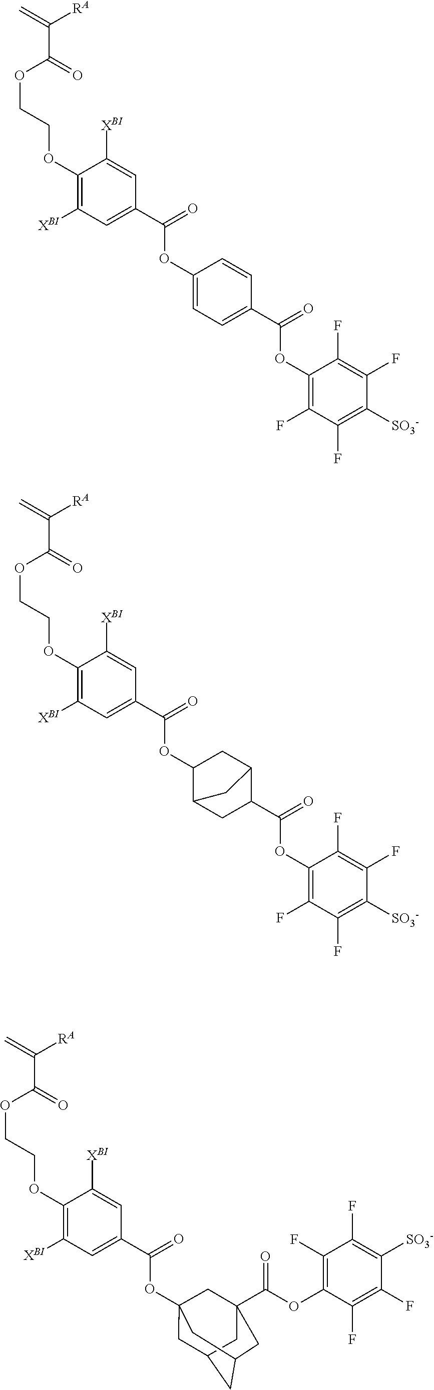

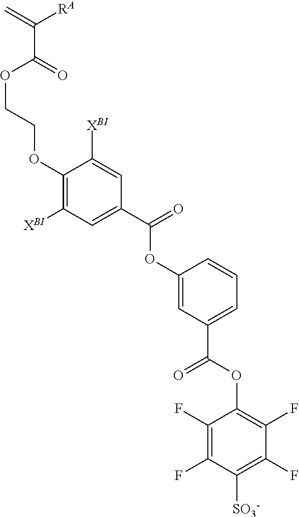

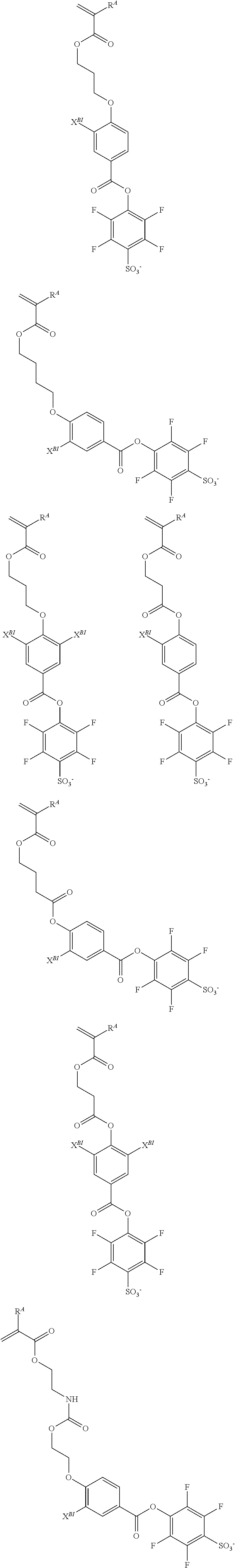

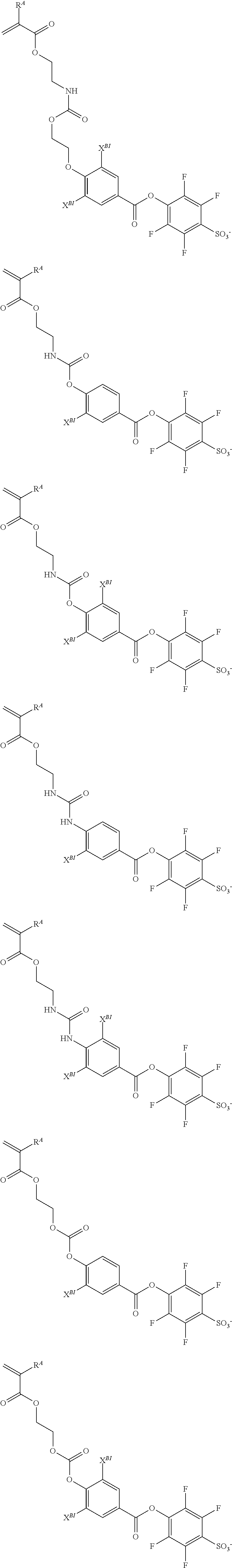

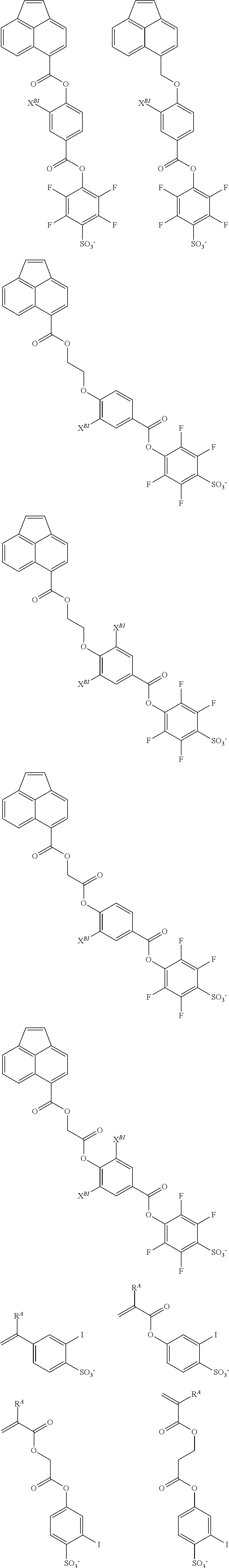

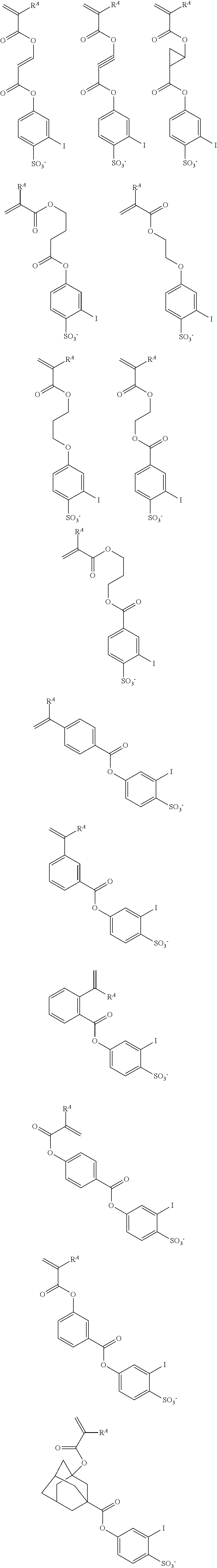

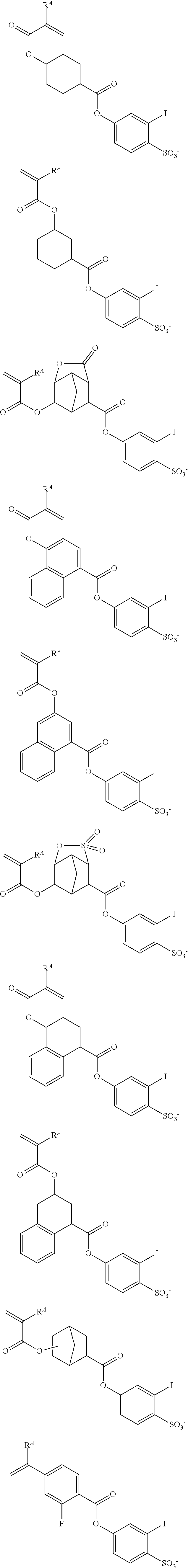

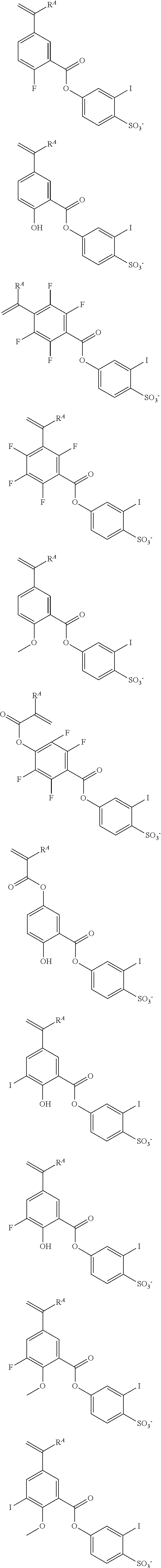

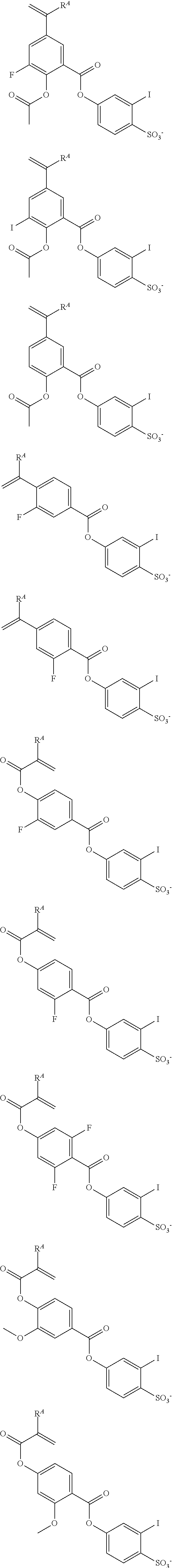

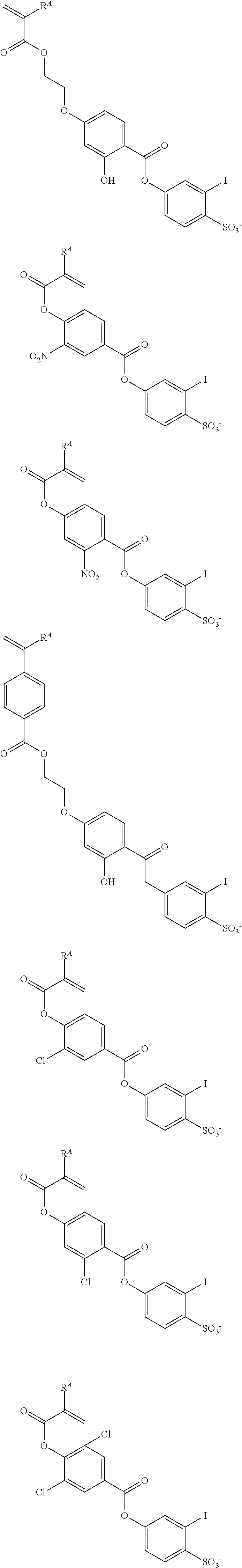

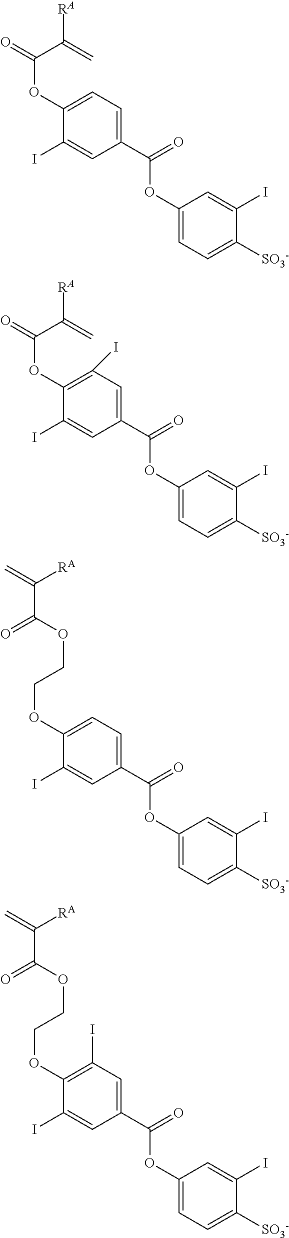

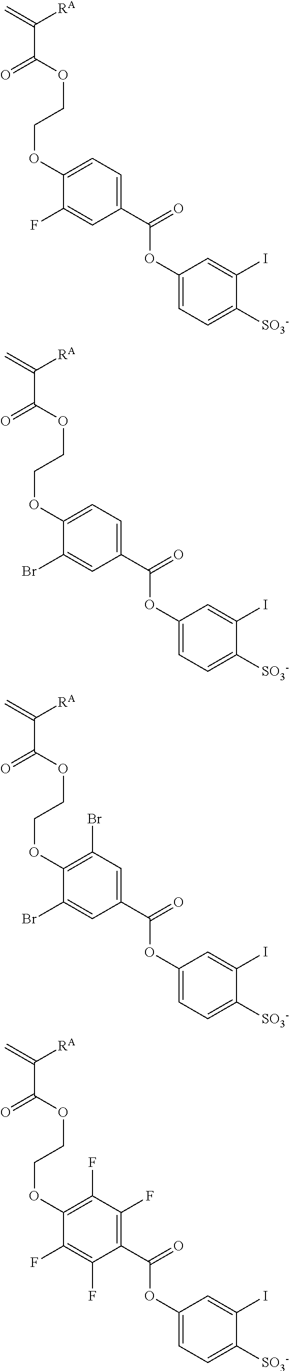

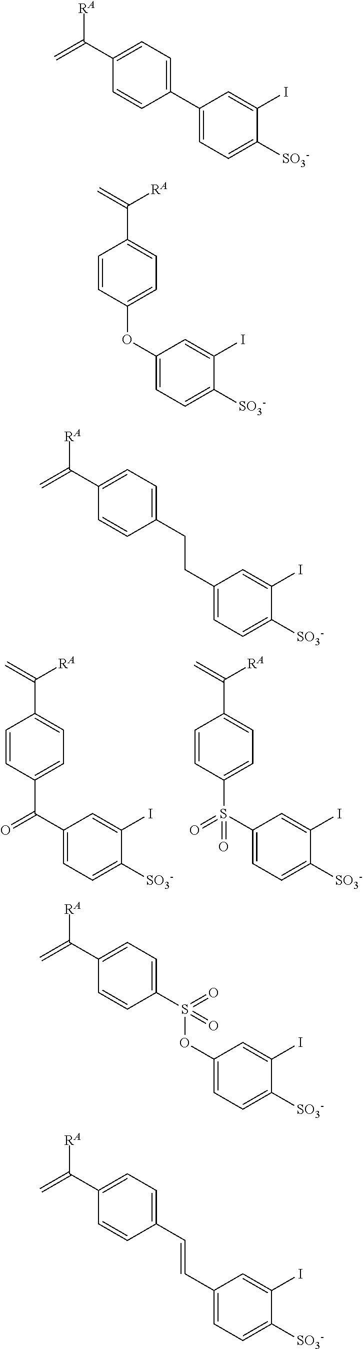

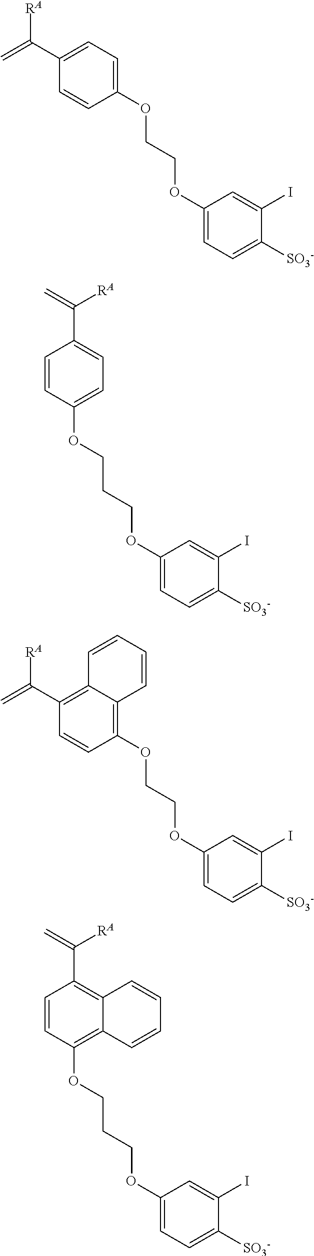

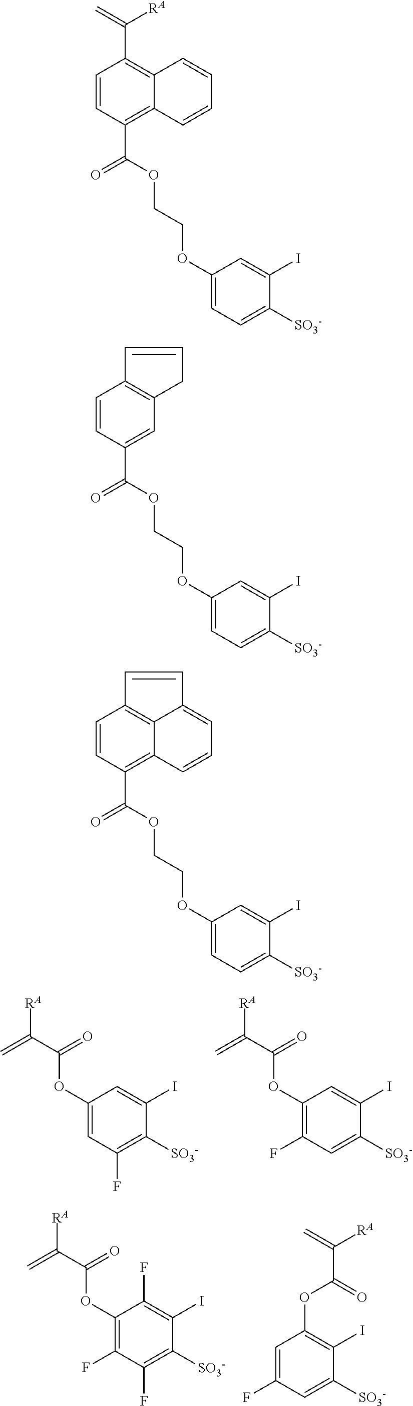

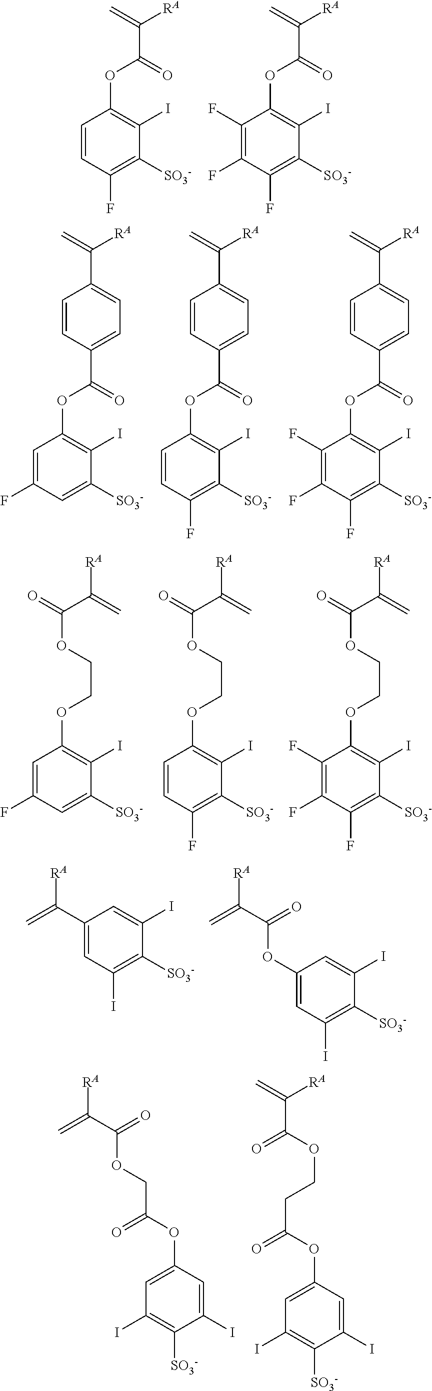

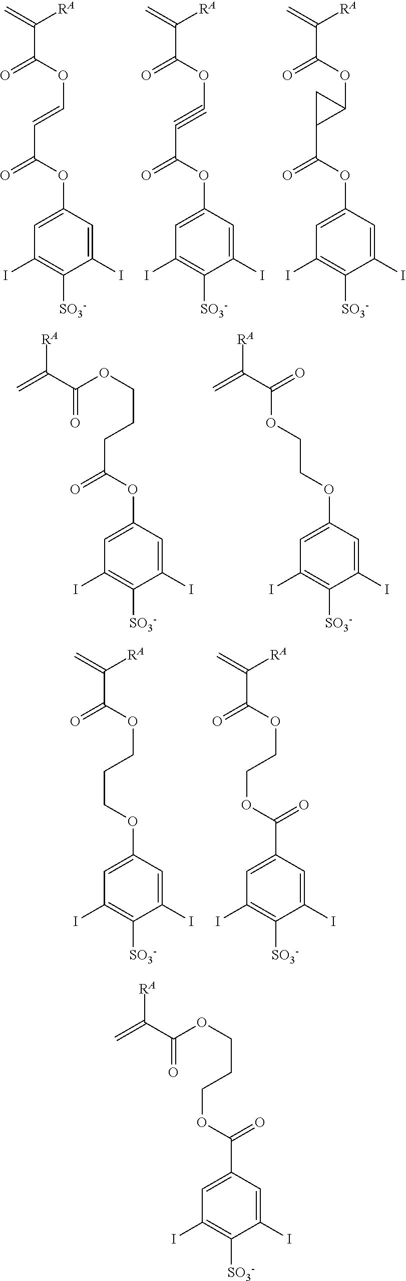

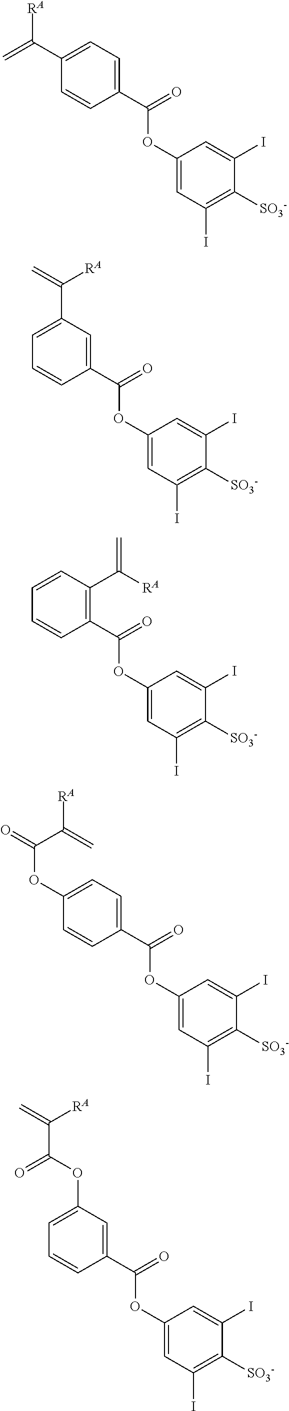

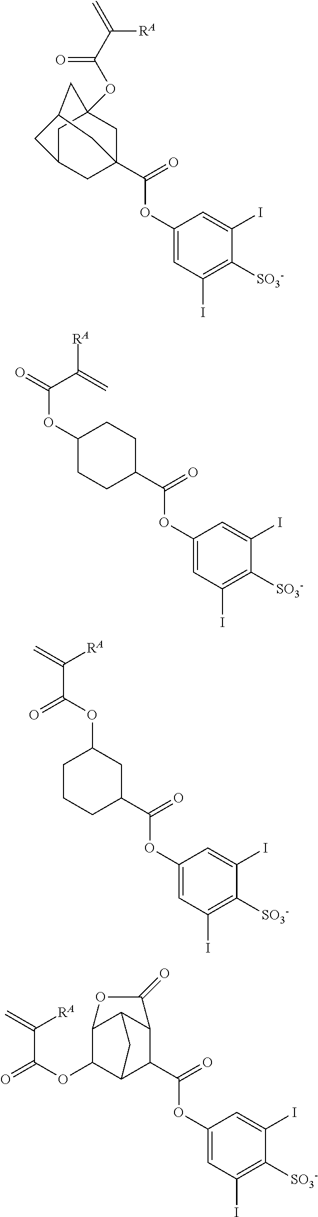

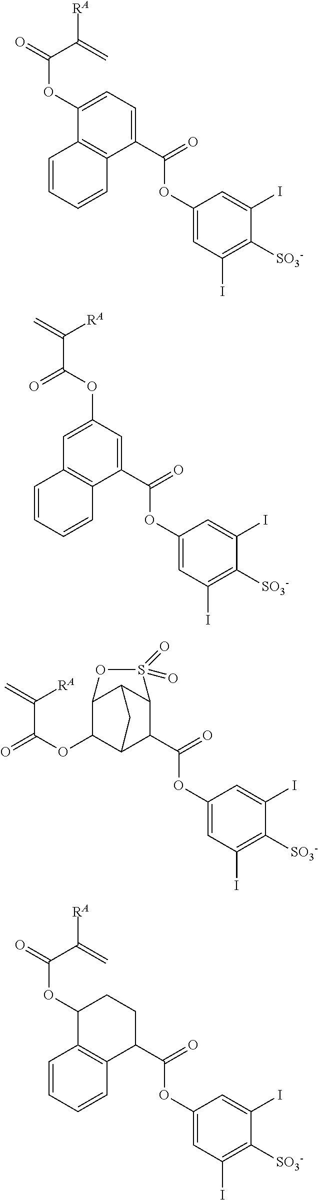

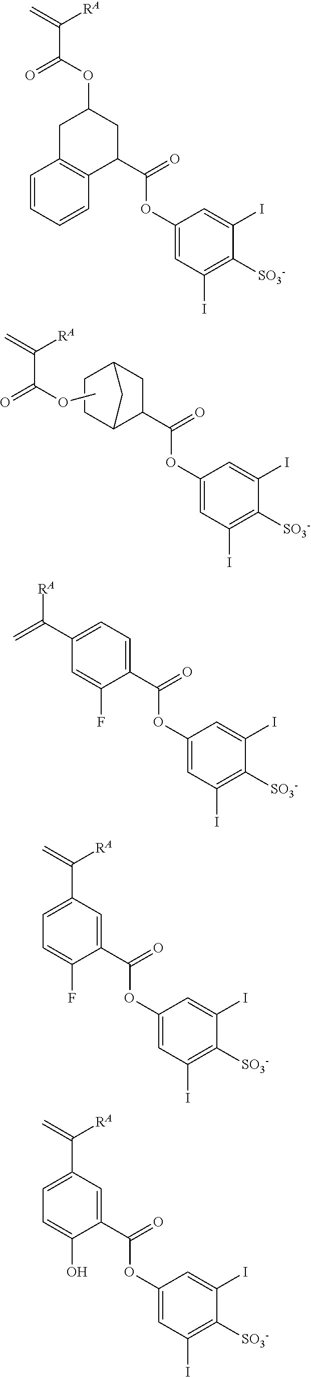

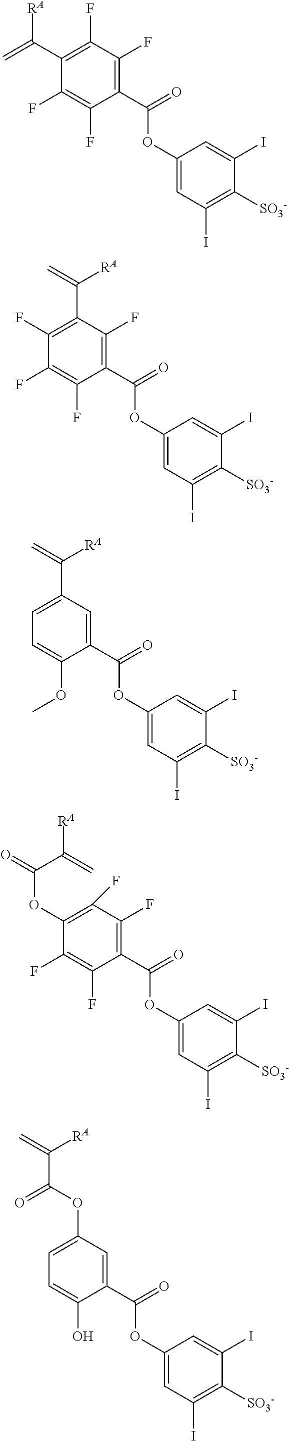

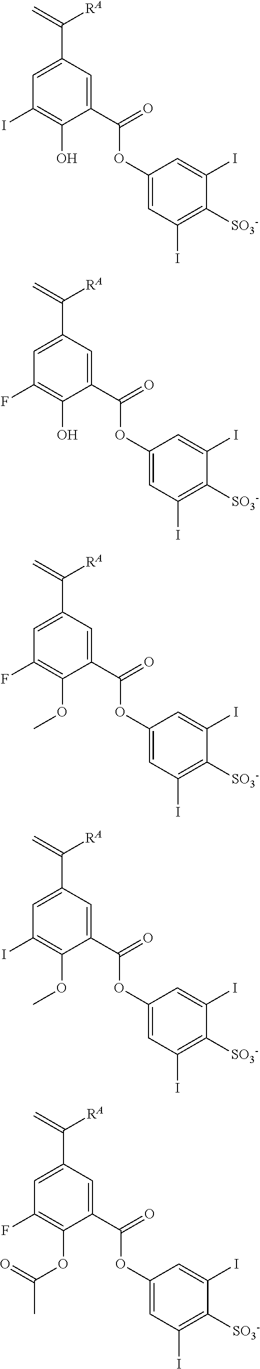

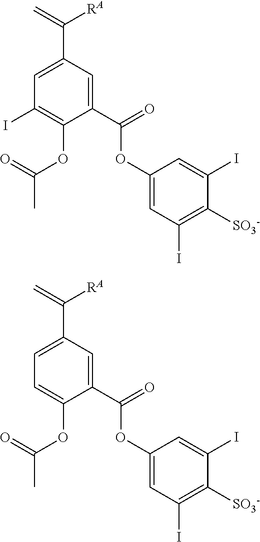

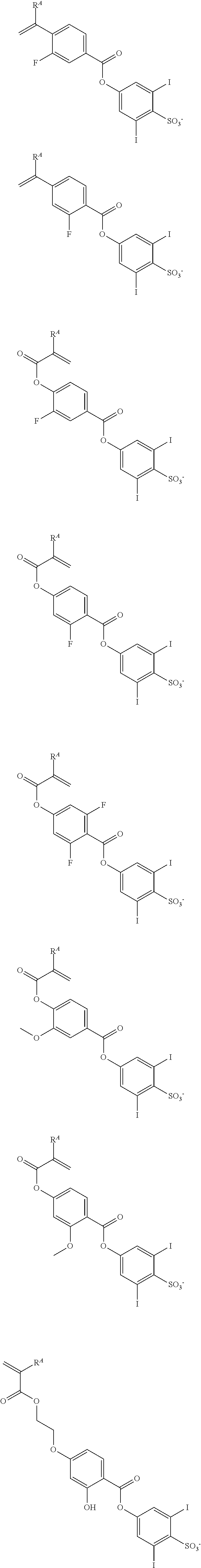

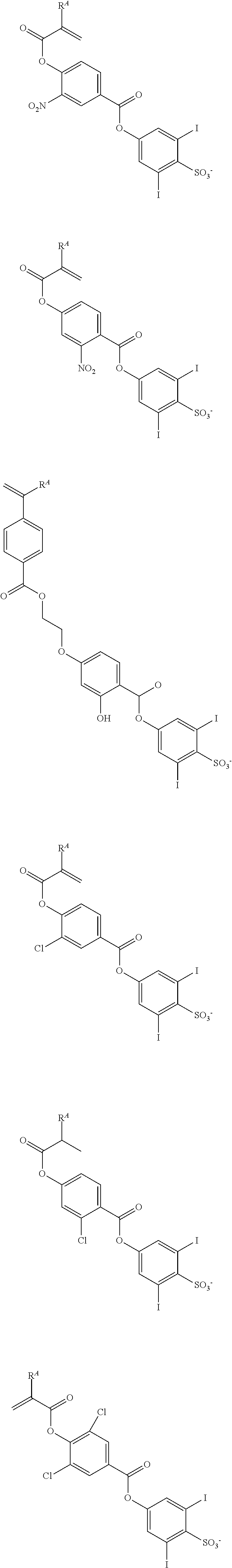

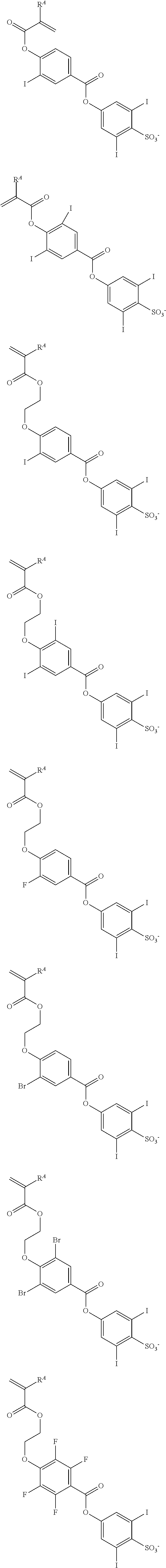

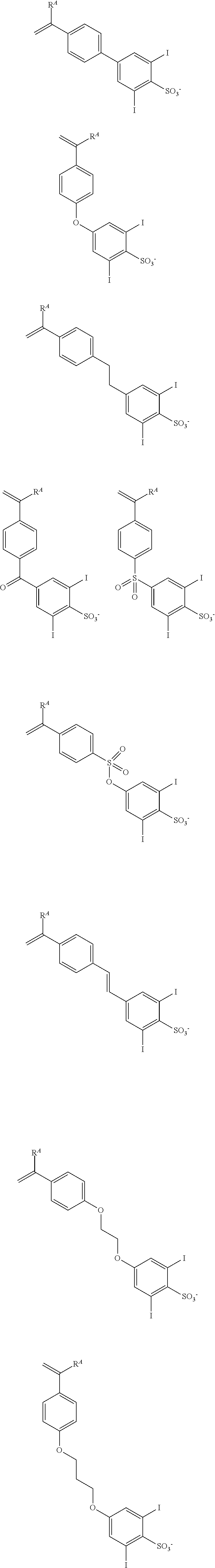

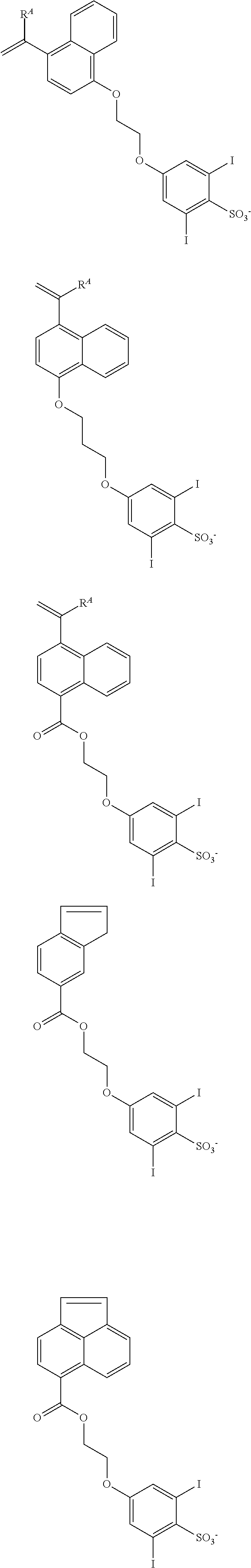

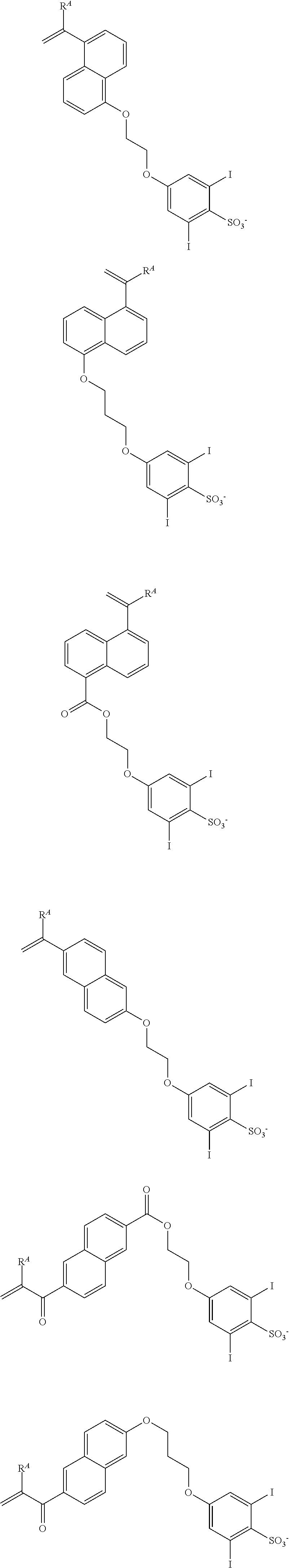

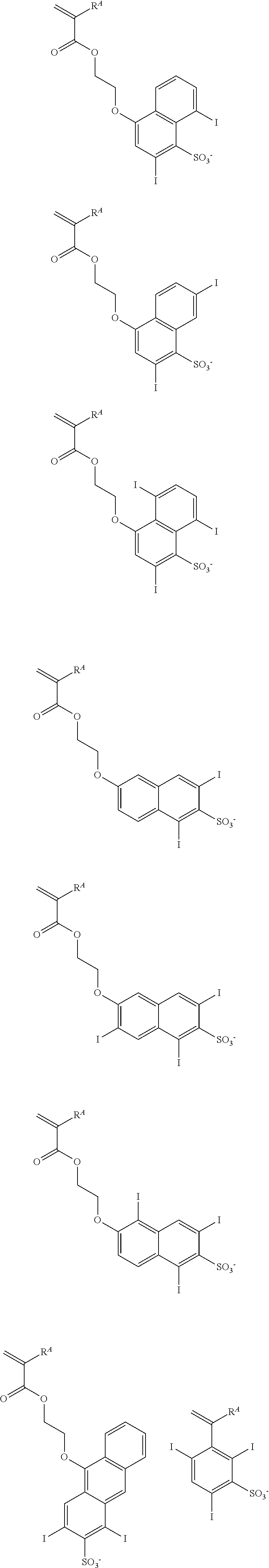

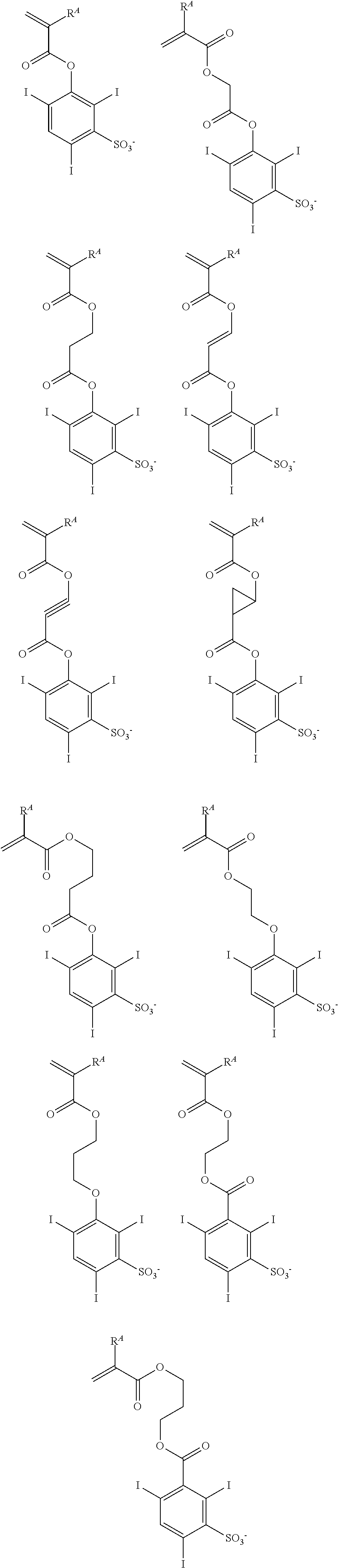

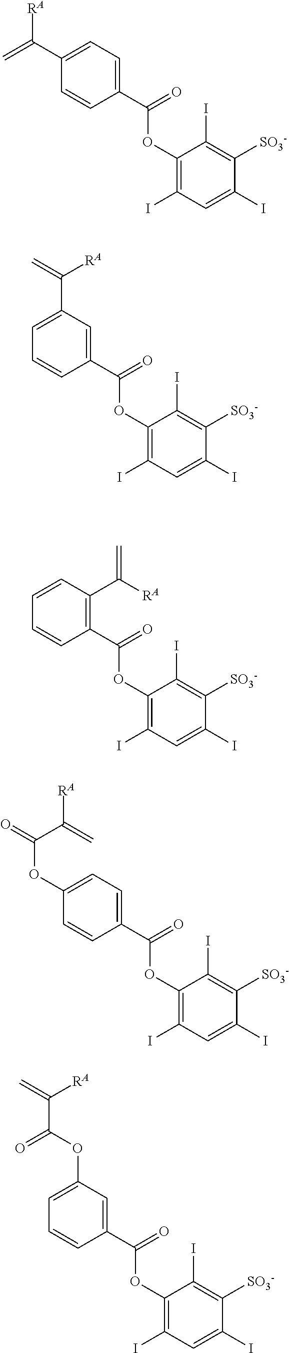

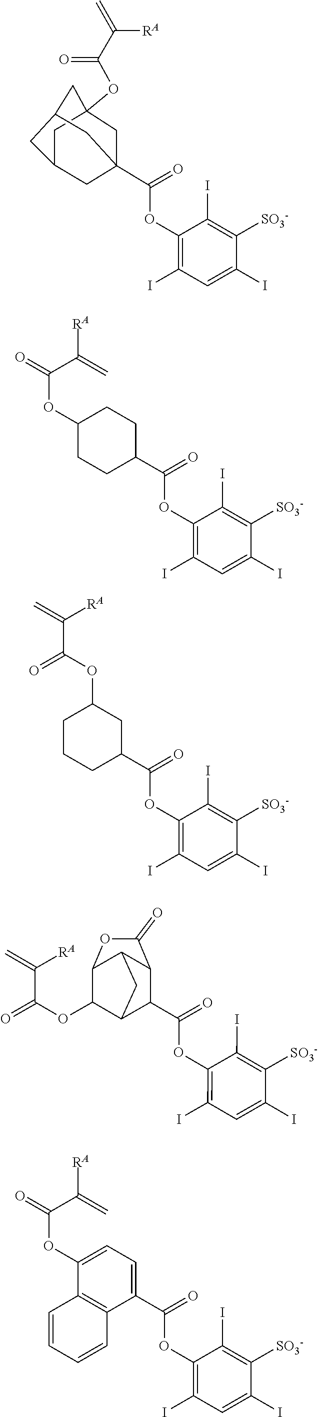

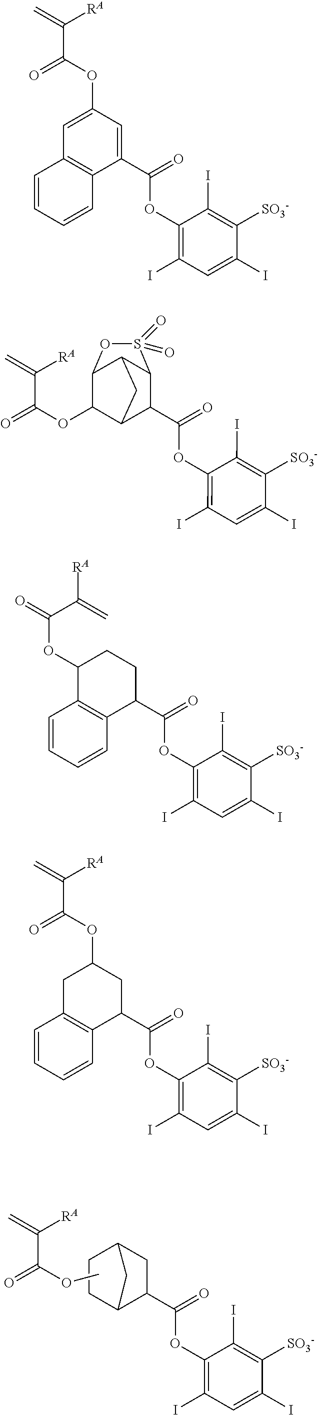

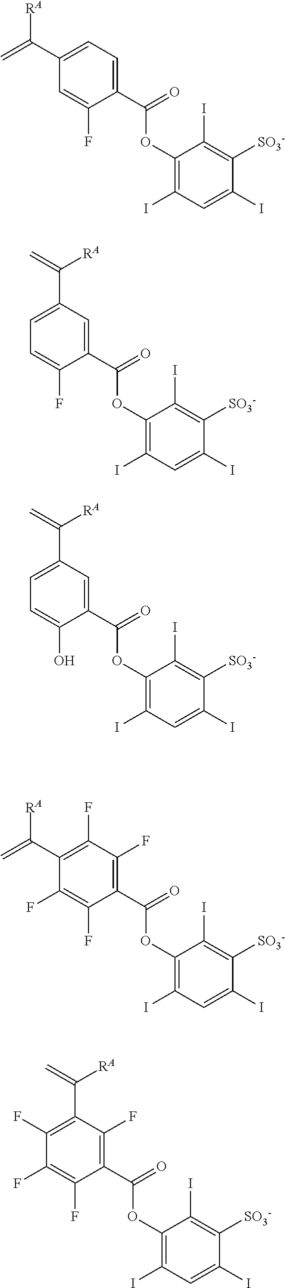

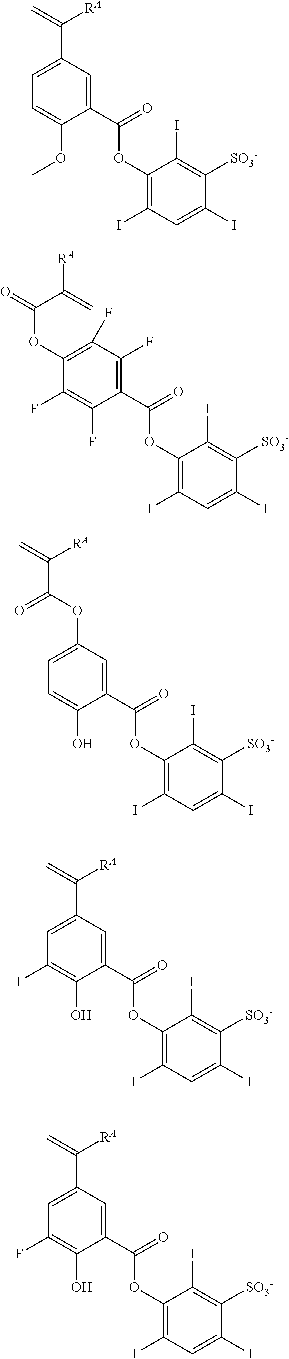

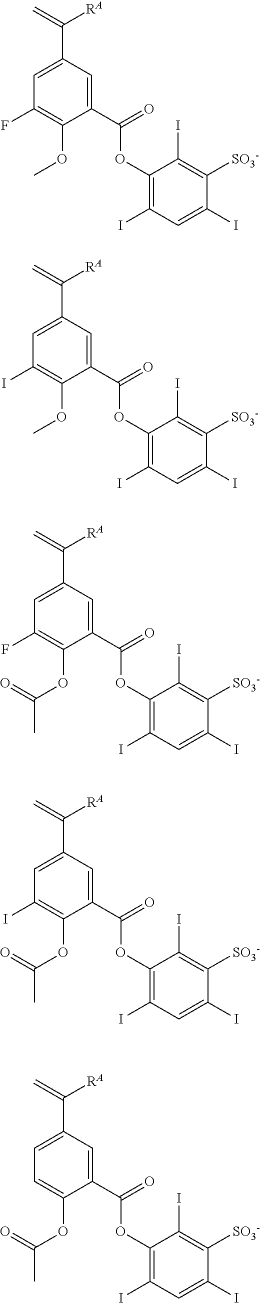

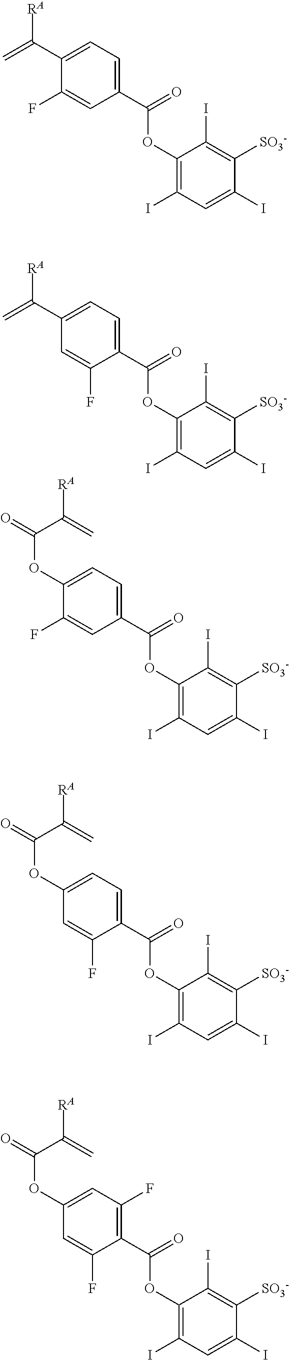

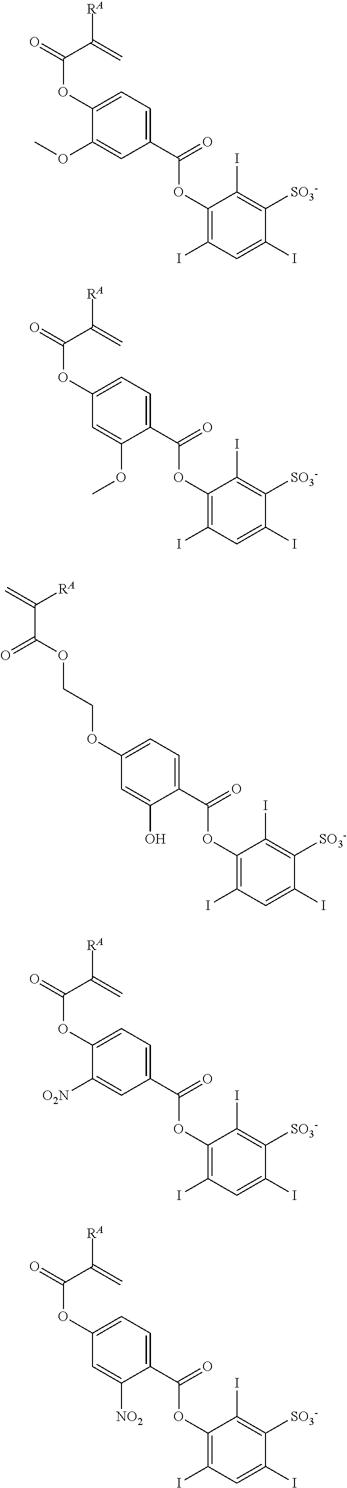

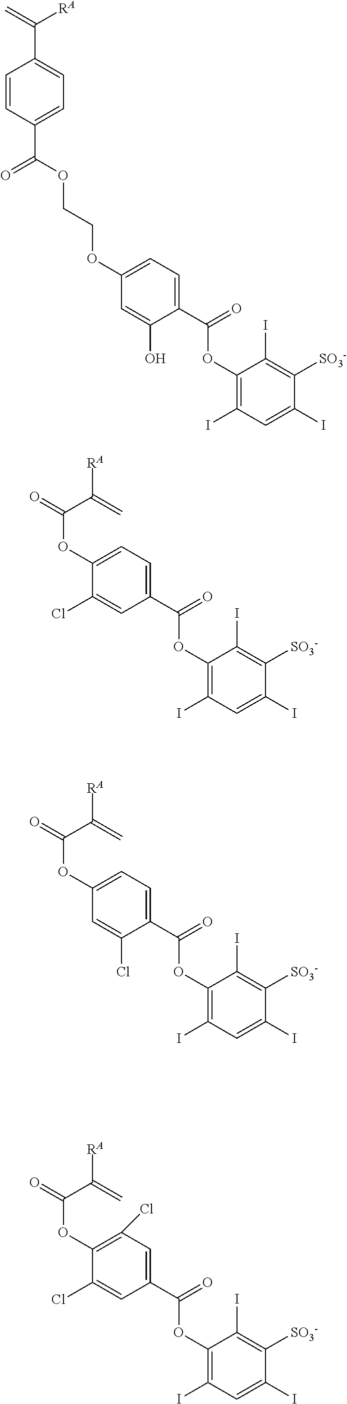

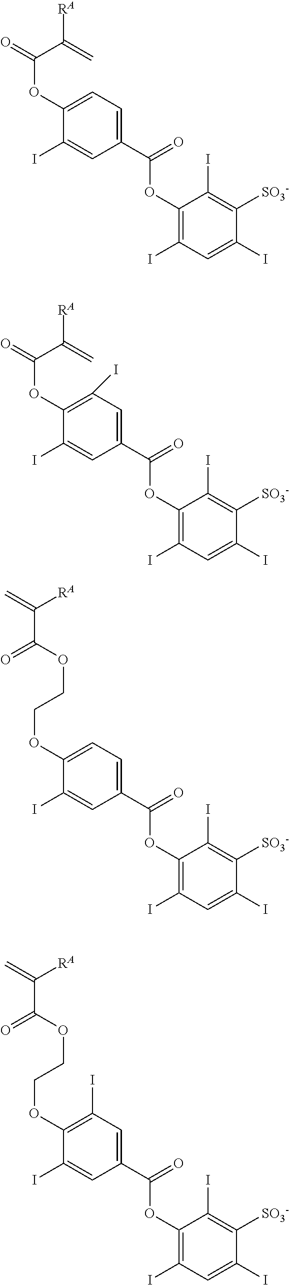

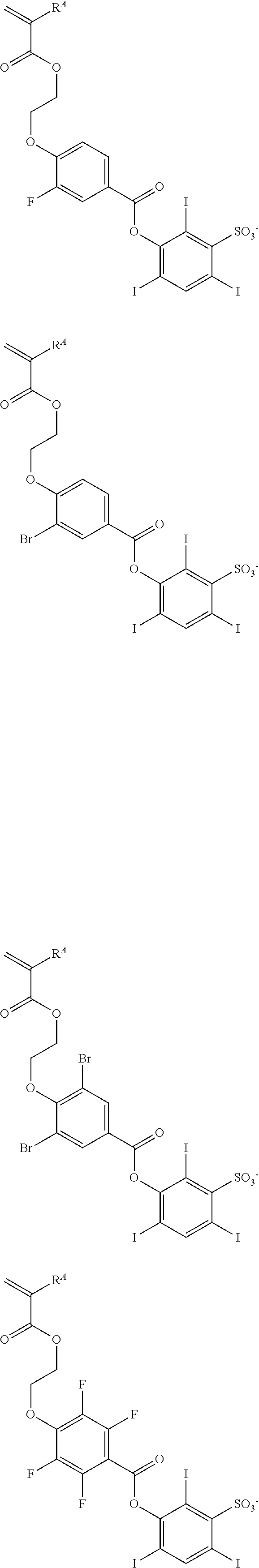

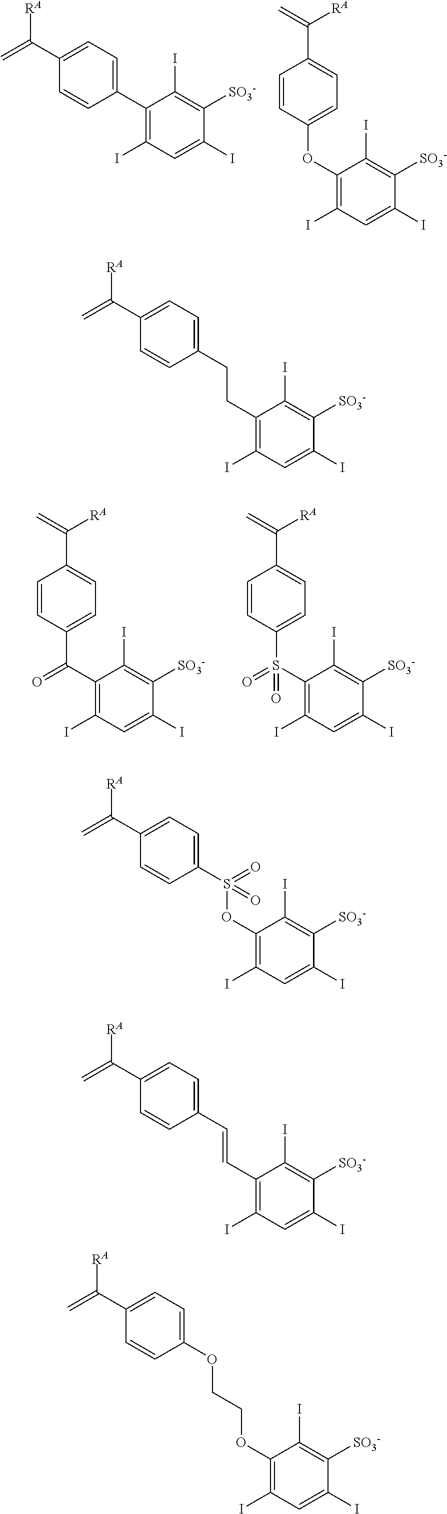

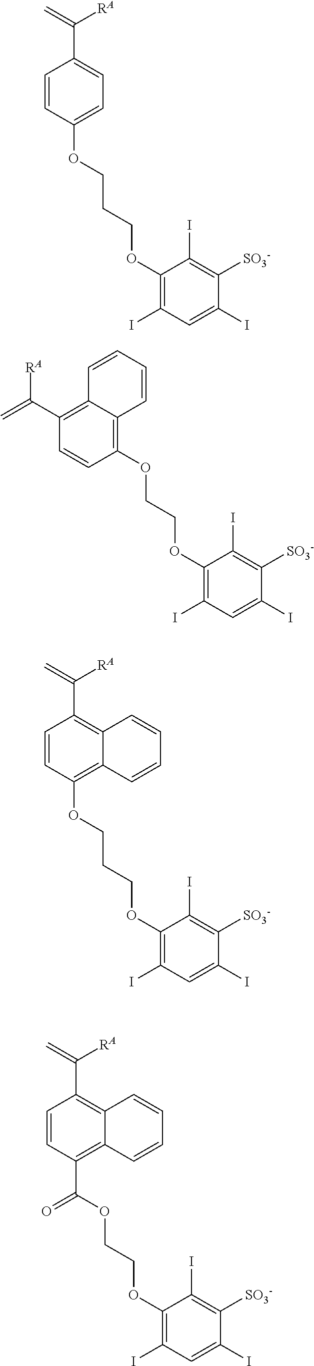

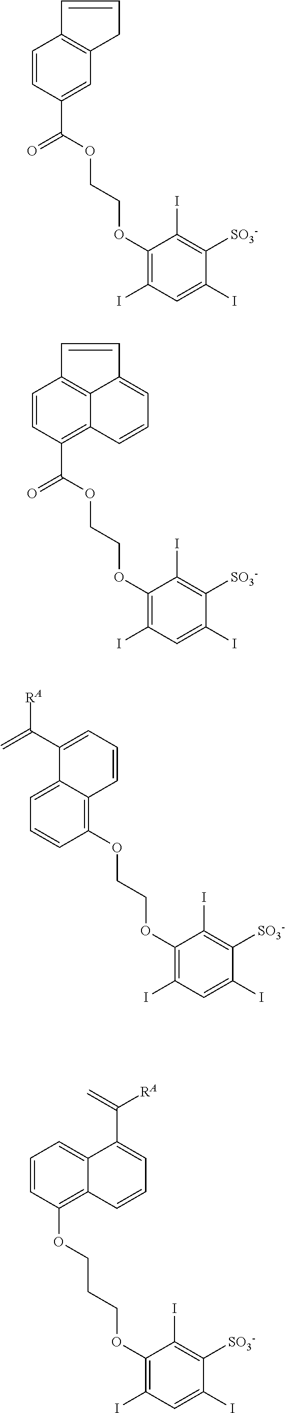

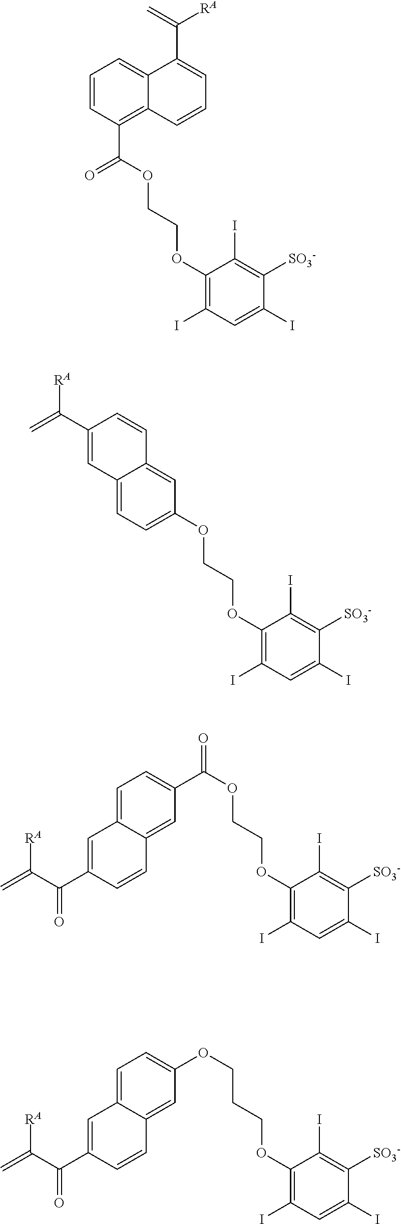

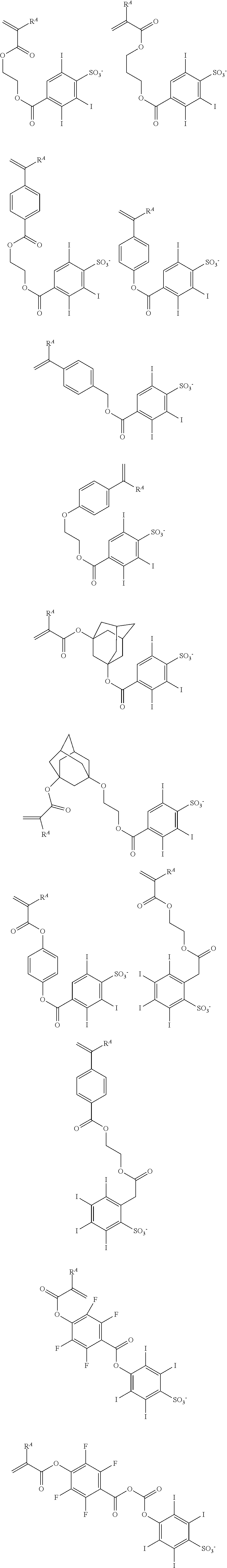

The base polymer preferably contains, as the repeating unit-b having the acid-generating moiety, any one or more repeating units selected from the repeating units represented by any of the formulae (b2) to (b5) in which Z, Z^{7A}, Z^{7B}, or M⁺ contains one or more iodine atoms.

Specific examples of the sulfonium cation represented by M⁺ include the following, but are not limited thereto.

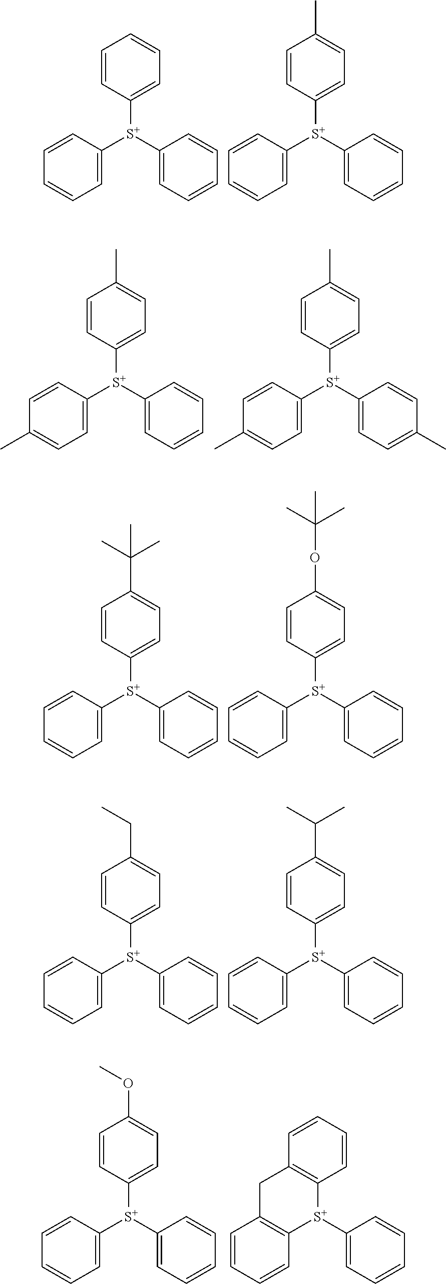

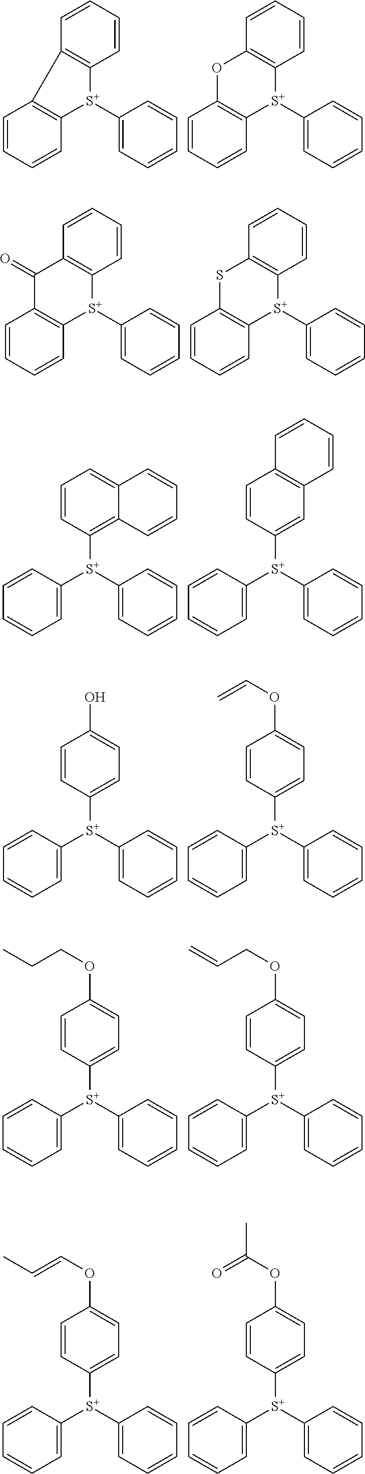

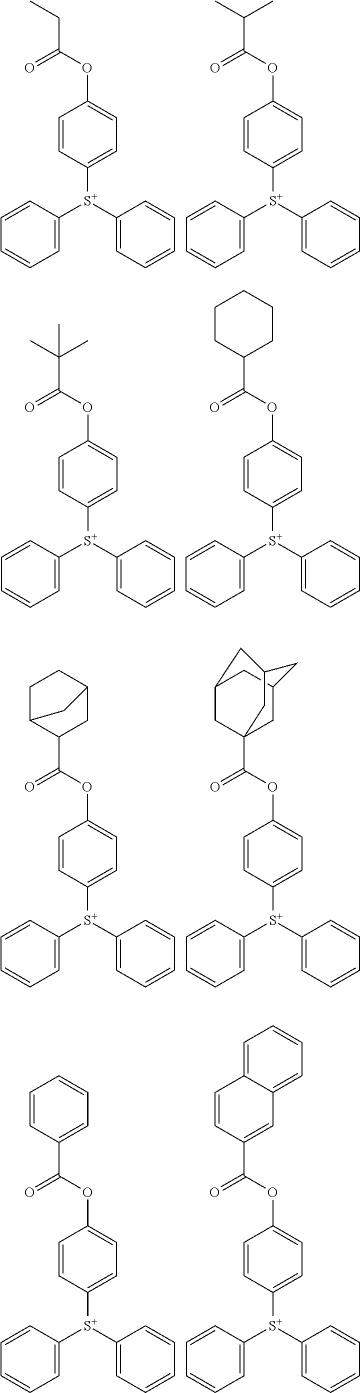

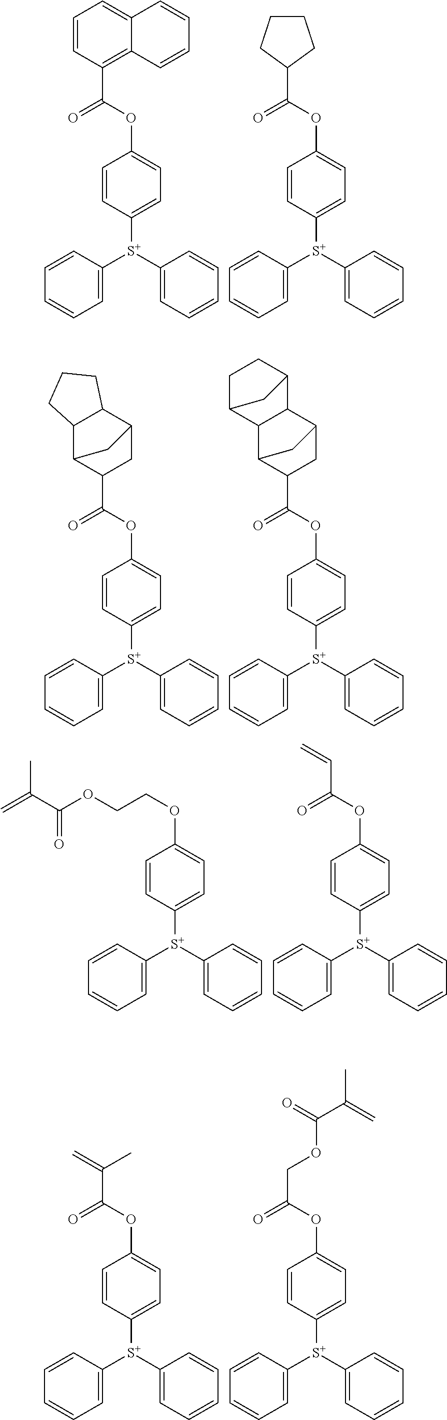

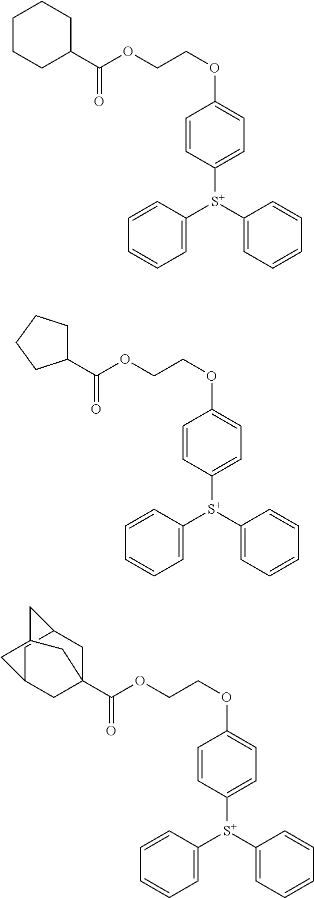 [SMILES: O=C(OCCOc1ccc([S+](c2ccccc2)c2ccccc2)cc1)C1CCCCC1 ; O=C(OCCOc1ccc([S+](c2ccccc2)c2ccccc2)cc1)C1CCCC1 ; O=C(OCCOc1ccc([S+](c2ccccc2)c2ccccc2)cc1)C12CC3CC(CC(C3)C1)C2]

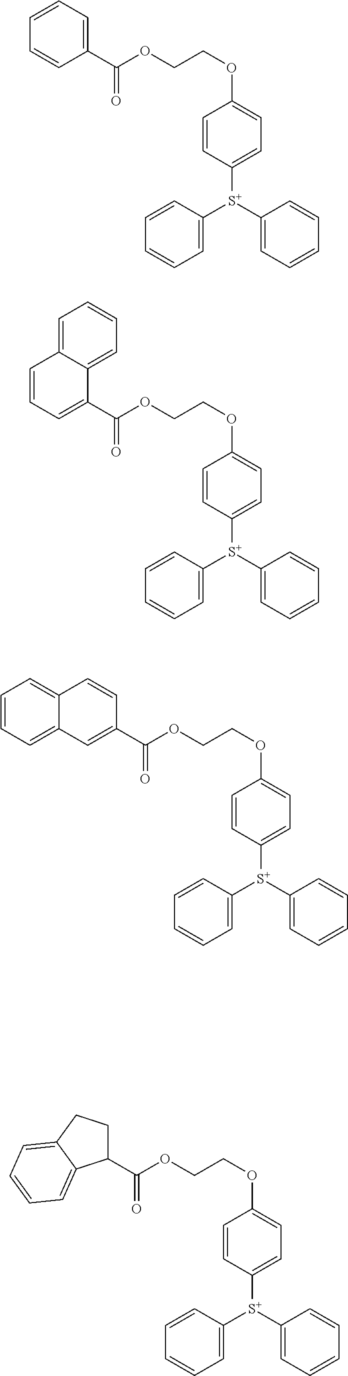 [SMILES: O=C(OCCOc1ccc([S+](c2ccccc2)c2ccccc2)cc1)c1ccccc1 ; O=C(OCCOc1ccc([S+](c2ccccc2)c2ccccc2)cc1)c1cccc2ccccc12 ; O=C(OCCOc1ccc([S+](c2ccccc2)c2ccccc2)cc1)c1ccc2ccccc2c1 ; O=C(OCCOc1ccc([S+](c2ccccc2)c2ccccc2)cc1)C1CCc2ccccc21]

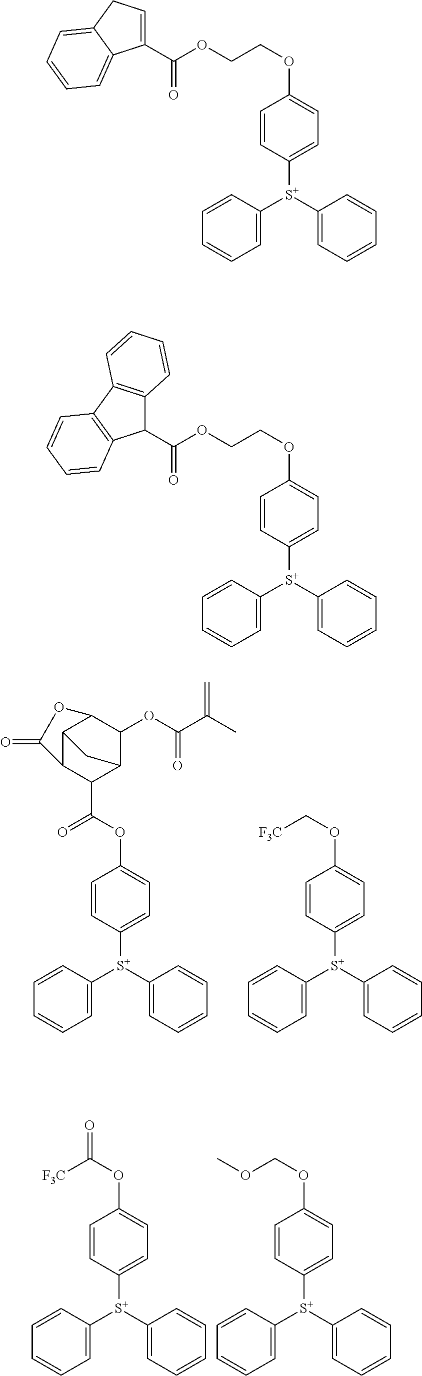 [SMILES: O=C(OCCOc1ccc([S+](c2ccccc2)c2ccccc2)cc1)C1=CCc2ccccc21 ; O=C(OCCOc1ccc([S+](c2ccccc2)c2ccccc2)cc1)C1c2ccccc2-c2ccccc21 ; C=C(C)C(=O)OC1C2CC3C1OC(=O)C3C2C(=O)Oc1ccc([S+](c2ccccc2)c2ccccc2)cc1 ; FC(F)(F)COc1ccc([S+](c2ccccc2)c2ccccc2)cc1 ; O=C(Oc1ccc([S+](c2ccccc2)c2ccccc2)cc1)C(F)(F)F ; COCOc1ccc([S+](c2ccccc2)c2ccccc2)cc1]

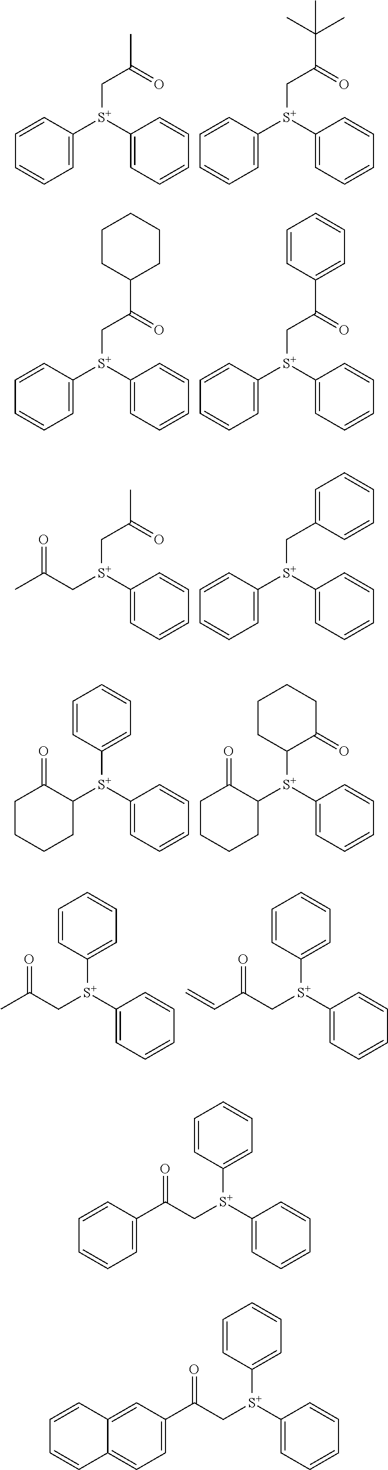

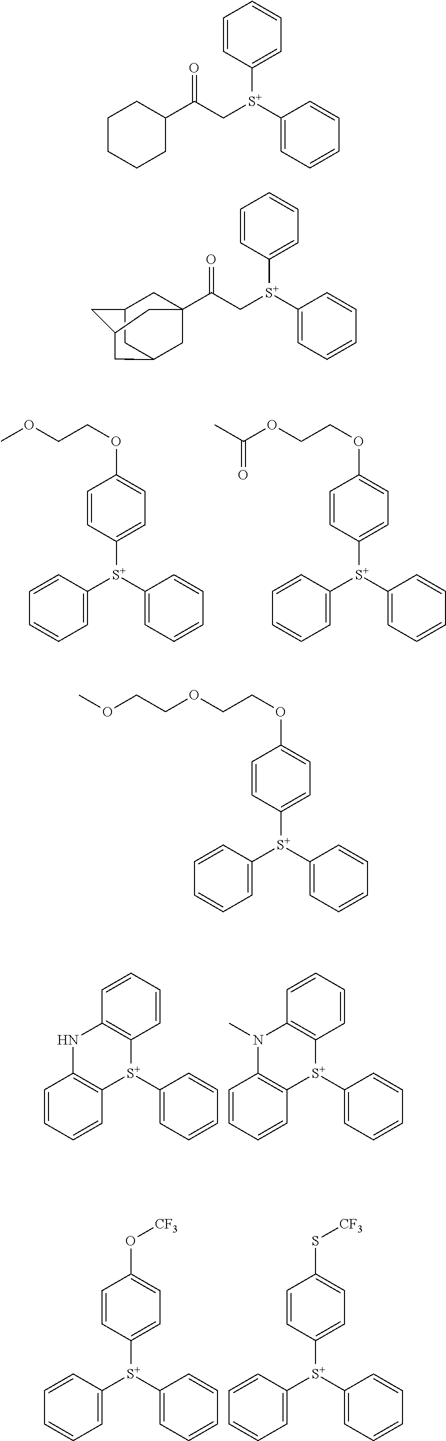

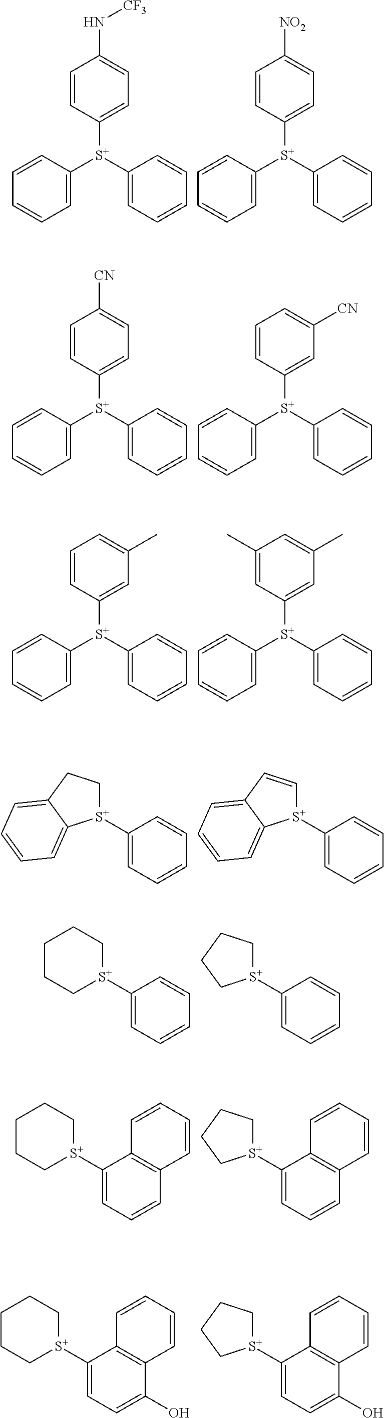

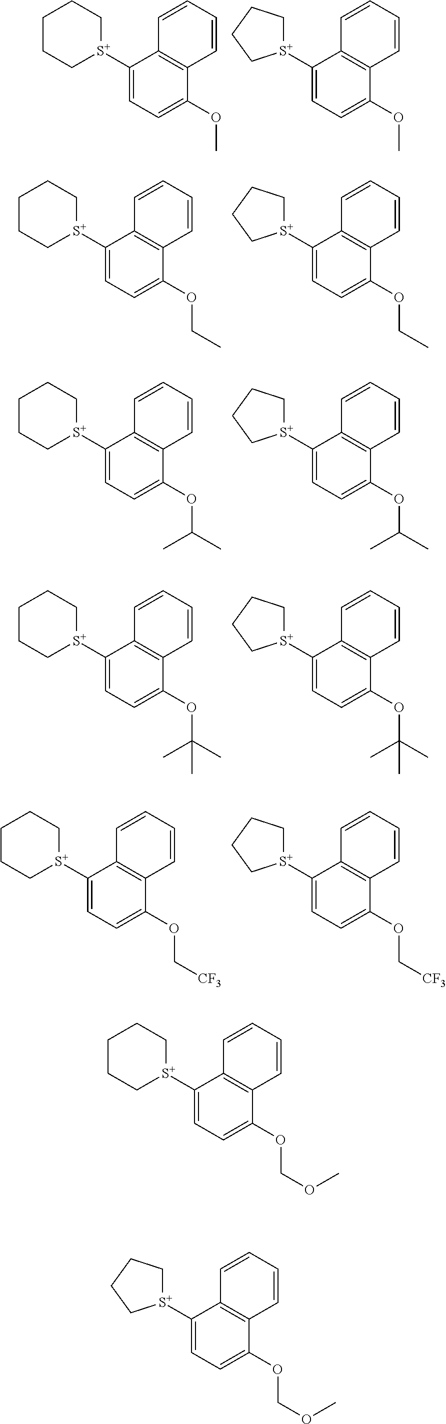

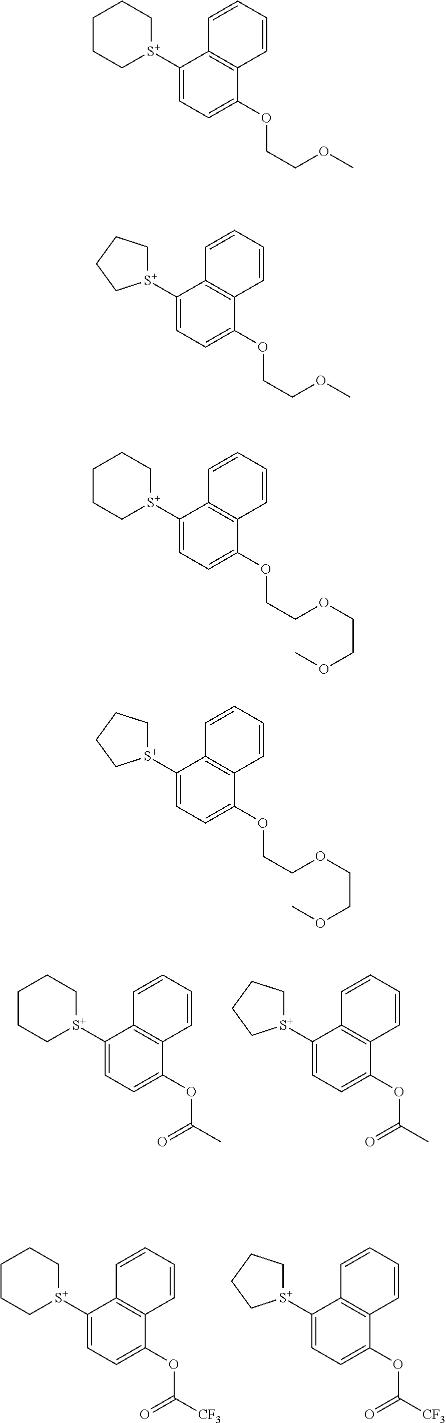

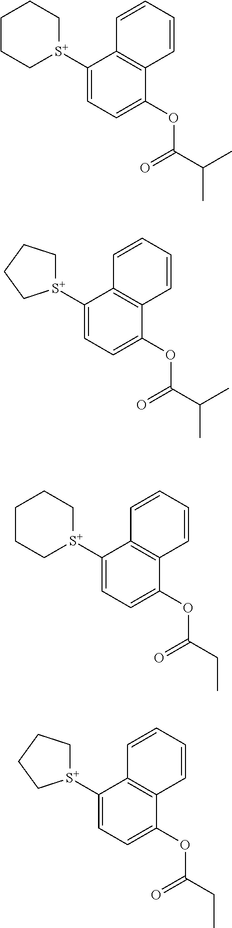 [SMILES: CC(C)C(=O)Oc1ccc([S+]2CCCCC2)c2ccccc12 ; CC(C)C(=O)Oc1ccc([S+]2CCCC2)c2ccccc12 ; CCC(=O)Oc1ccc([S+]2CCCCC2)c2ccccc12 ; CCC(=O)Oc1ccc([S+]2CCCC2)c2ccccc12]

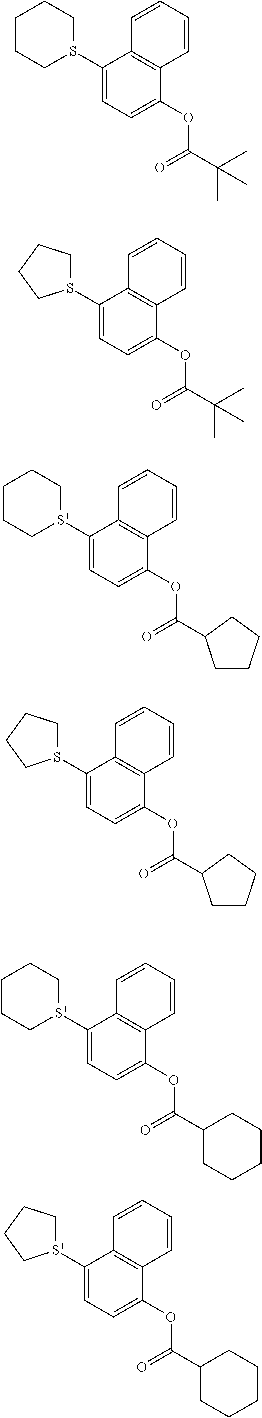 [SMILES: CC(C)(C)C(=O)Oc1ccc([S+]2CCCCC2)c2ccccc12 ; CC(C)(C)C(=O)Oc1ccc([S+]2CCCC2)c2ccccc12 ; O=C(Oc1ccc([S+]2CCCCC2)c2ccccc12)C1CCCC1 ; O=C(Oc1ccc([S+]2CCCC2)c2ccccc12)C1CCCC1 ; O=C(Oc1ccc([S+]2CCCCC2)c2ccccc12)C1CCCCC1 ; O=C(Oc1ccc([S+]2CCCC2)c2ccccc12)C1CCCCC1]

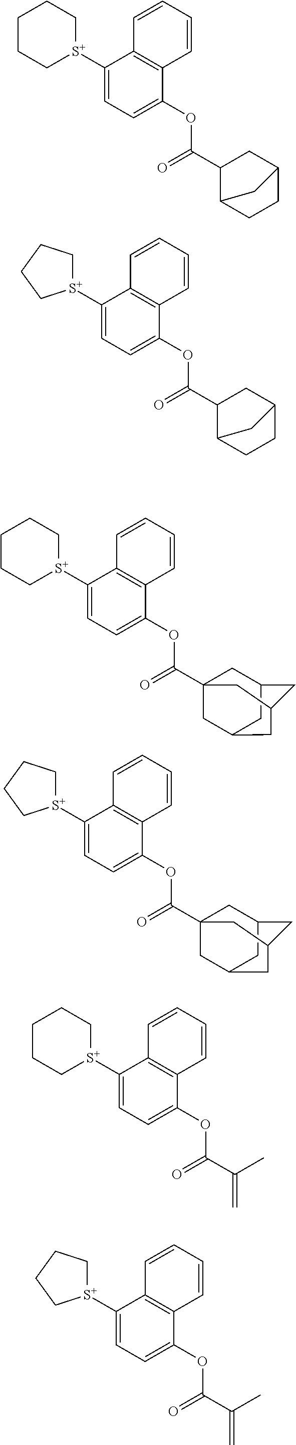 [SMILES: O=C(Oc1ccc([S+]2CCCCC2)c2ccccc12)C1CC2CCC1C2 ; O=C(Oc1ccc([S+]2CCCC2)c2ccccc12)C1CC2CCC1C2 ; O=C(Oc1ccc([S+]2CCCCC2)c2ccccc12)C12CC3CC(CC(C3)C1)C2 ; O=C(Oc1ccc([S+]2CCCC2)c2ccccc12)C12CC3CC(CC(C3)C1)C2 ; C=C(C)C(=O)Oc1ccc([S+]2CCCCC2)c2ccccc12 ; C=C(C)C(=O)Oc1ccc([S+]2CCCC2)c2ccccc12]

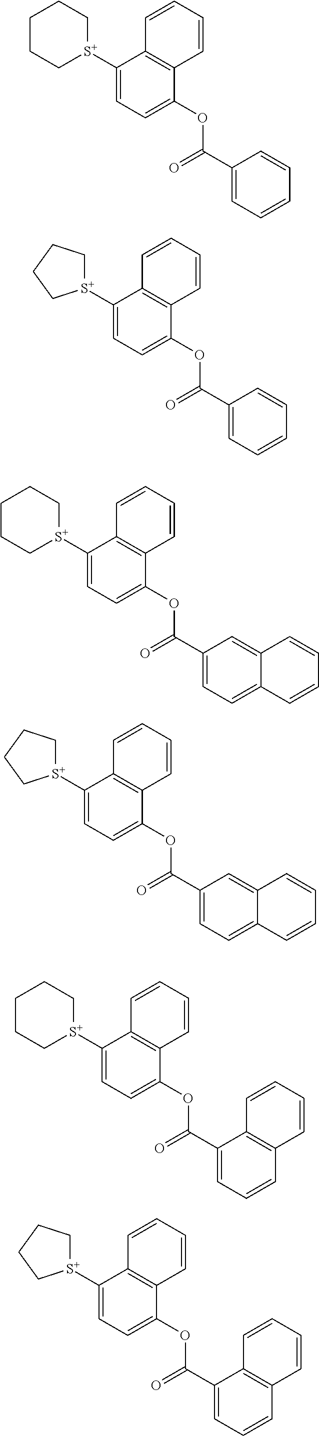 [SMILES: O=C(Oc1ccc([S+]2CCCCC2)c2ccccc12)c1ccccc1 ; O=C(Oc1ccc([S+]2CCCC2)c2ccccc12)c1ccccc1 ; O=C(Oc1ccc([S+]2CCCCC2)c2ccccc12)c1ccc2ccccc2c1 ; O=C(Oc1ccc([S+]2CCCC2)c2ccccc12)c1ccc2ccccc2c1 ; O=C(Oc1ccc([S+]2CCCCC2)c2ccccc12)c1cccc2ccccc12 ; O=C(Oc1ccc([S+]2CCCC2)c2ccccc12)c1cccc2ccccc12]

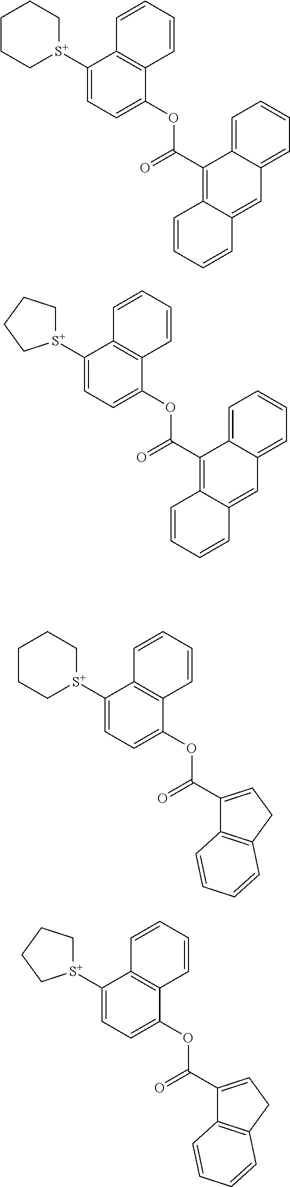 [SMILES: O=C(Oc1ccc([S+]2CCCCC2)c2ccccc12)c1c2ccccc2cc2ccccc12 ; O=C(Oc1ccc([S+]2CCCC2)c2ccccc12)c1c2ccccc2cc2ccccc12 ; O=C(Oc1ccc([S+]2CCCCC2)c2ccccc12)C1=CCc2ccccc21 ; O=C(Oc1ccc([S+]2CCCC2)c2ccccc12)C1=CCc2ccccc21]

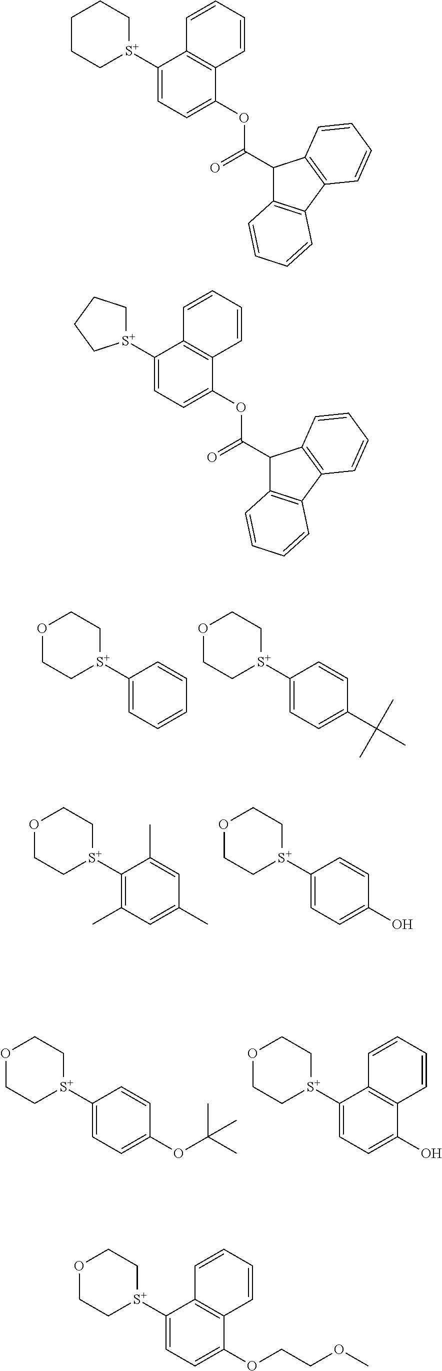

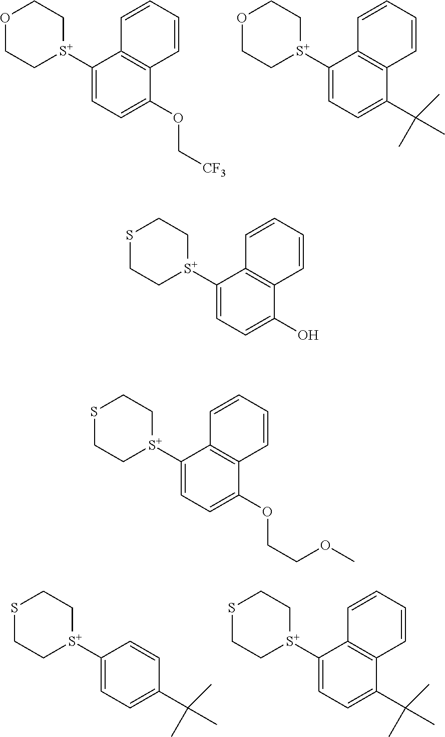 [SMILES: FC(F)(F)COc1ccc([S+]2CCOCC2)c2ccccc12 ; CC(C)(C)c1ccc([S+]2CCOCC2)c2ccccc12 ; Oc1ccc([S+]2CCSCC2)c2ccccc12 ; COCCOc1ccc([S+]2CCSCC2)c2ccccc12 ; CC(C)(C)c1ccc([S+]2CCSCC2)cc1 ; CC(C)(C)c1ccc([S+]2CCSCC2)c2ccccc12]

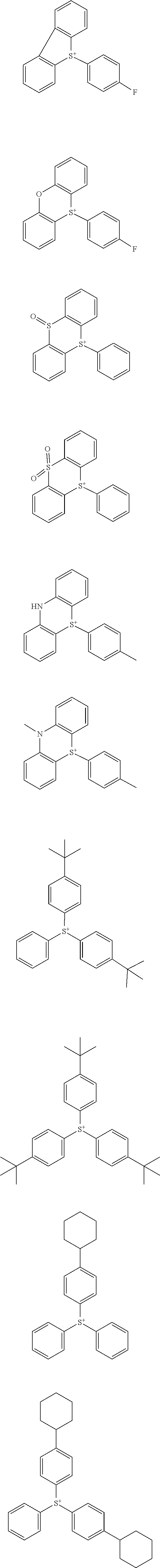

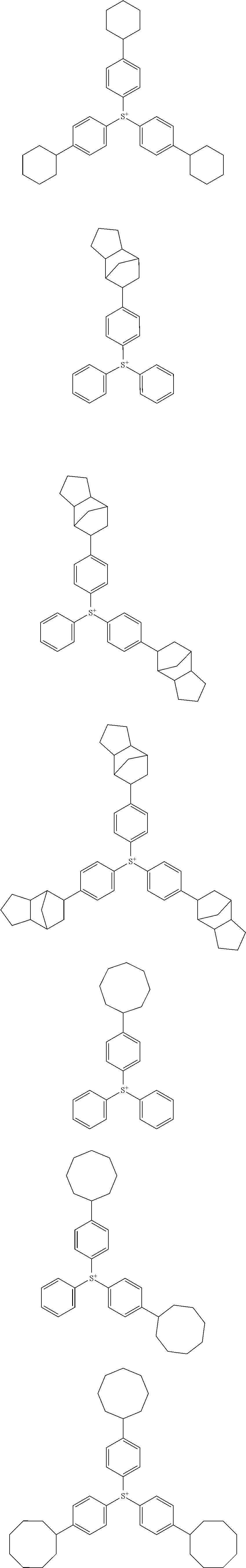

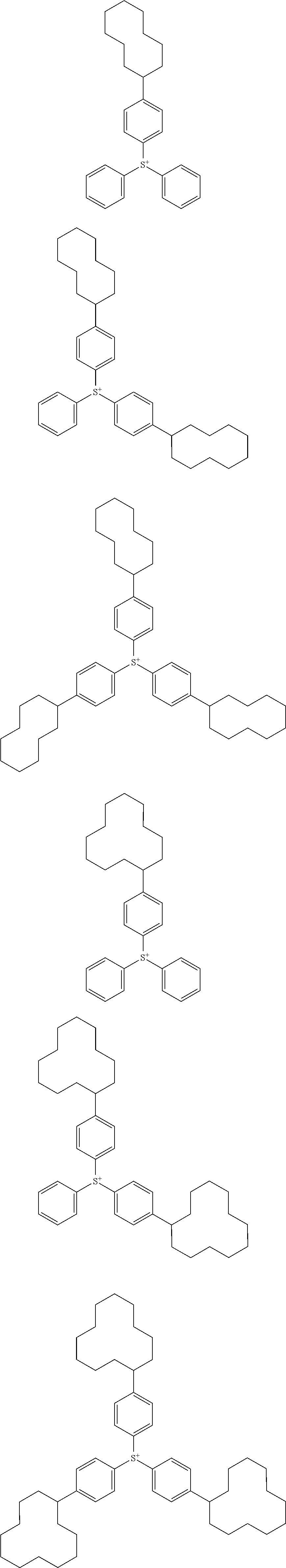 [SMILES: c1ccc([S+](c2ccccc2)c2ccc(C3CCCCCCCCC3)cc2)cc1 ; c1ccc([S+](c2ccc(C3CCCCCCCCC3)cc2)c2ccc(C3CCCCCCCCC3)cc2)cc1 ; c1cc([S+](c2ccc(C3CCCCCCCCC3)cc2)c2ccc(C3CCCCCCCCC3)cc2)ccc1C1CCCCCCCCC1 ; c1ccc([S+](c2ccccc2)c2ccc(C3CCCCCCCCCCC3)cc2)cc1 ; c1ccc([S+](c2ccc(C3CCCCCCCCCCC3)cc2)c2ccc(C3CCCCCCCCCCC3)cc2)cc1 ; c1cc([S+](c2ccc(C3CCCCCCCCCCC3)cc2)c2ccc(C3CCCCCCCCCCC3)cc2)ccc1C1CCCCCCCCCCC1]

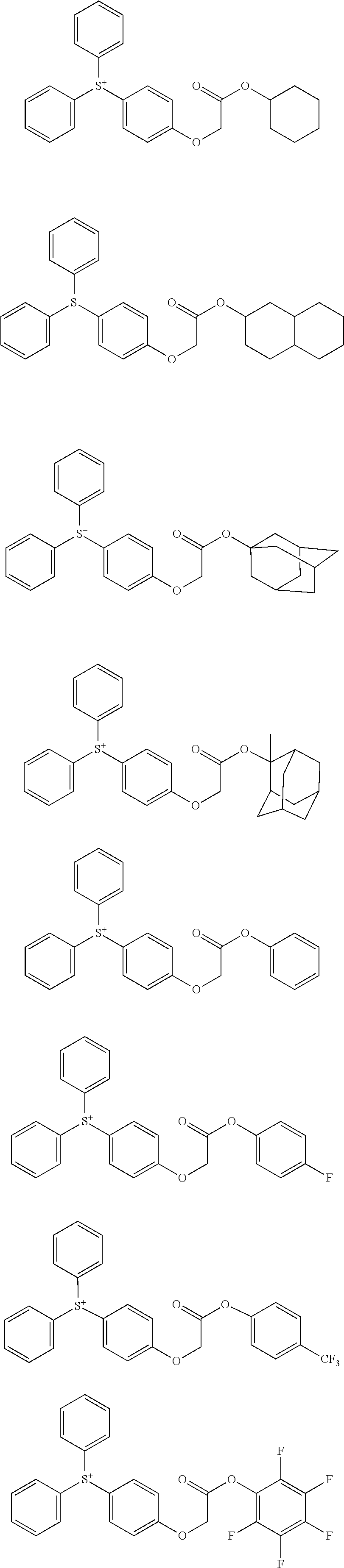

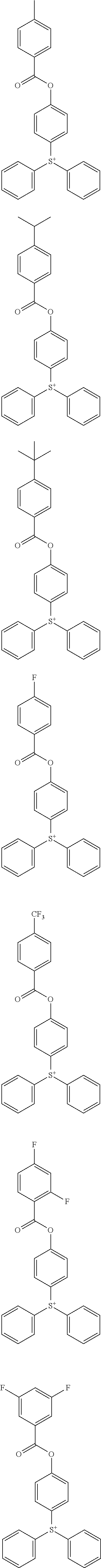

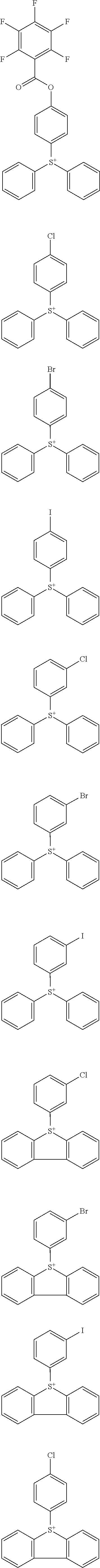

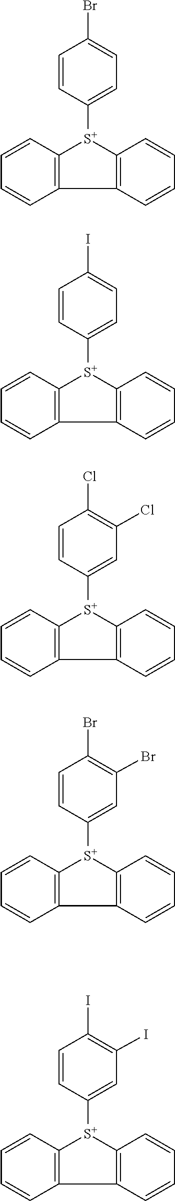 [SMILES: Brc1ccc(-[s+]2c3ccccc3c3ccccc32)cc1 ; Ic1ccc(-[s+]2c3ccccc3c3ccccc32)cc1 ; Clc1ccc(-[s+]2c3ccccc3c3ccccc32)cc1Cl ; Brc1ccc(-[s+]2c3ccccc3c3ccccc32)cc1Br ; Ic1ccc(-[s+]2c3ccccc3c3ccccc32)cc1I]

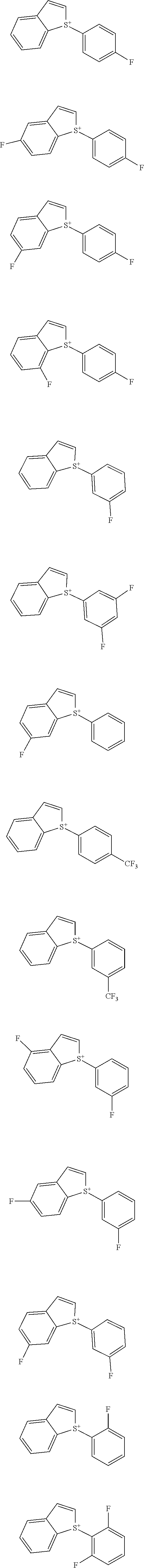

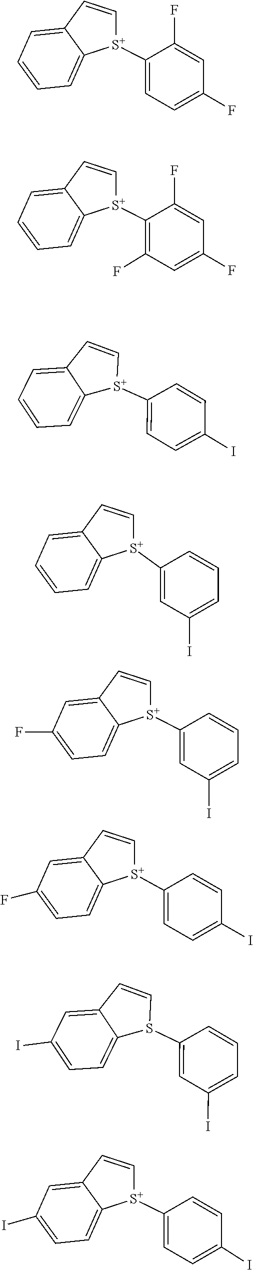

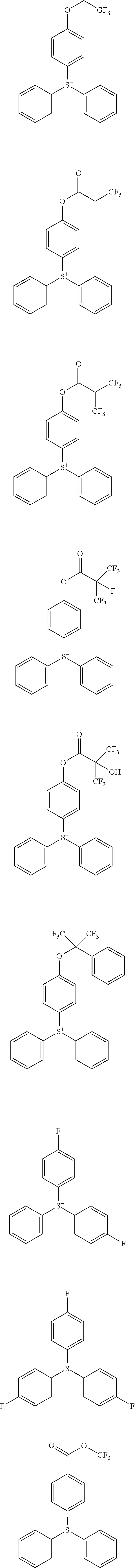

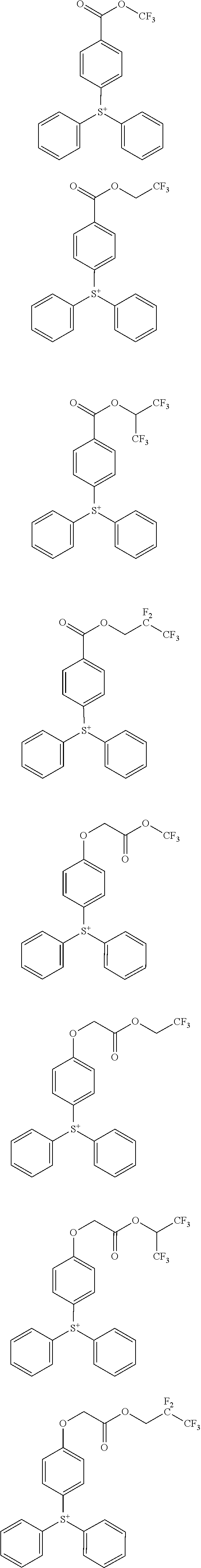

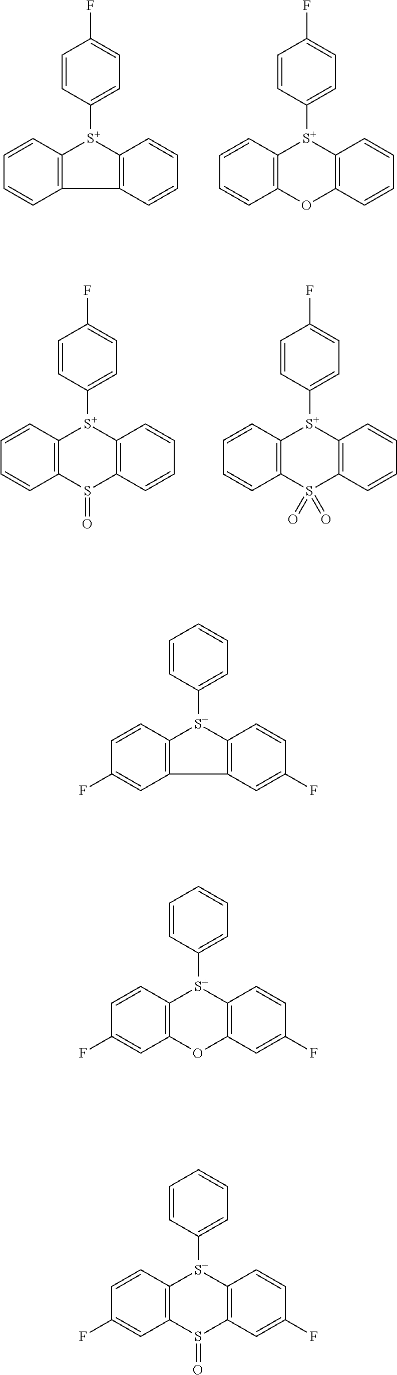

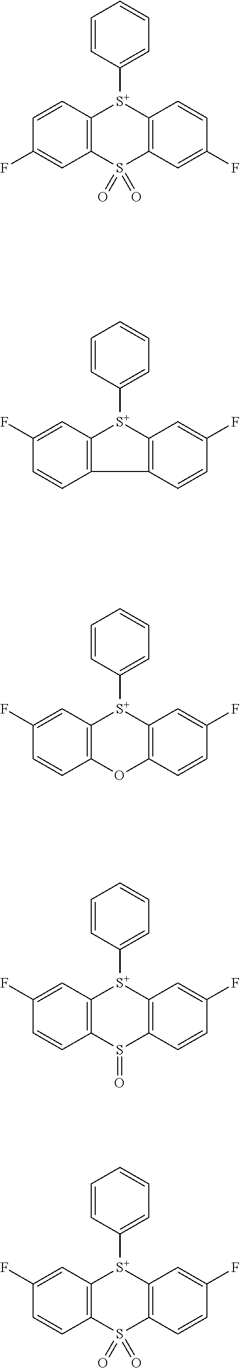 [SMILES: O=S1(=O)c2cc(F)ccc2[S+](c2ccccc2)c2ccc(F)cc21 ; Fc1ccc2c3ccc(F)cc3[s+](-c3ccccc3)c2c1 ; Fc1ccc2c(c1)[S+](c1ccccc1)c1cc(F)ccc1O2 ; O=S1c2ccc(F)cc2[S+](c2ccccc2)c2cc(F)ccc21 ; O=S1(=O)c2ccc(F)cc2[S+](c2ccccc2)c2cc(F)ccc21]

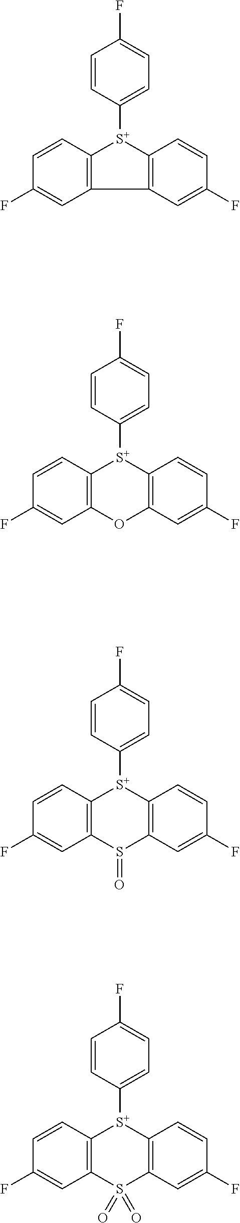 [SMILES: Fc1ccc(-[s+]2c3ccc(F)cc3c3cc(F)ccc32)cc1 ; Fc1ccc([S+]2c3ccc(F)cc3Oc3cc(F)ccc32)cc1 ; O=S1c2cc(F)ccc2[S+](c2ccc(F)cc2)c2ccc(F)cc21 ; O=S1(=O)c2cc(F)ccc2[S+](c2ccc(F)cc2)c2ccc(F)cc21]

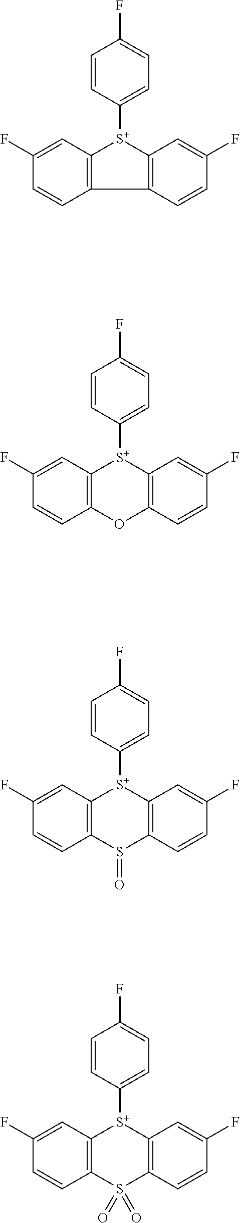 [SMILES: Fc1ccc(-[s+]2c3cc(F)ccc3c3ccc(F)cc32)cc1 ; Fc1ccc([S+]2c3cc(F)ccc3Oc3ccc(F)cc32)cc1 ; O=S1c2ccc(F)cc2[S+](c2ccc(F)cc2)c2cc(F)ccc21 ; O=S1(=O)c2ccc(F)cc2[S+](c2ccc(F)cc2)c2cc(F)ccc21]

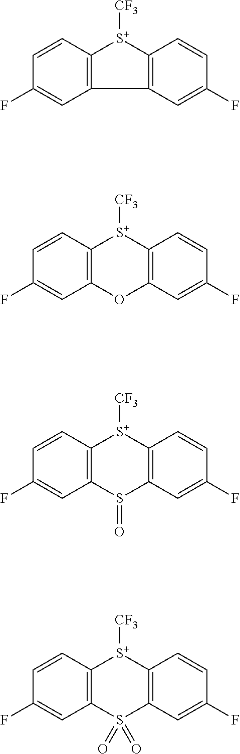 [SMILES: Fc1ccc2c(c1)c1cc(F)ccc1[s+]2C(F)(F)F ; Fc1ccc2c(c1)Oc1cc(F)ccc1[S+]2C(F)(F)F ; O=S1c2cc(F)ccc2[S+](C(F)(F)F)c2ccc(F)cc21 ; O=S1(=O)c2cc(F)ccc2[S+](C(F)(F)F)c2ccc(F)cc21]

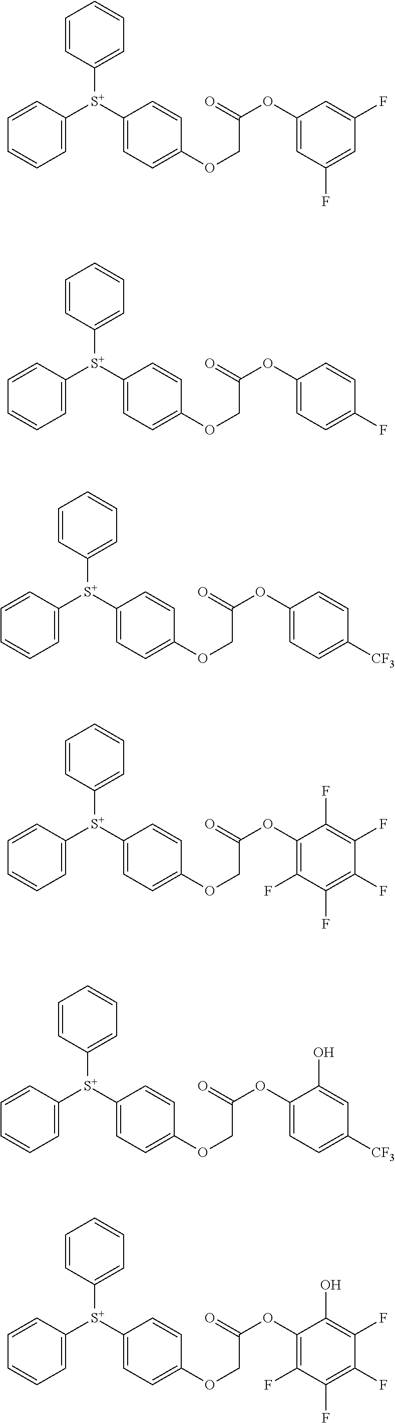 [SMILES: O=C(COc1ccc([S+](c2ccccc2)c2ccccc2)cc1)Oc1cc(F)cc(F)c1 ; O=C(COc1ccc([S+](c2ccccc2)c2ccccc2)cc1)Oc1ccc(F)cc1 ; O=C(COc1ccc([S+](c2ccccc2)c2ccccc2)cc1)Oc1ccc(C(F)(F)F)cc1 ; O=C(COc1ccc([S+](c2ccccc2)c2ccccc2)cc1)Oc1c(F)c(F)c(F)c(F)c1F ; O=C(COc1ccc([S+](c2ccccc2)c2ccccc2)cc1)Oc1ccc(C(F)(F)F)cc1O ; O=C(COc1ccc([S+](c2ccccc2)c2ccccc2)cc1)Oc1c(O)c(F)c(F)c(F)c1F]

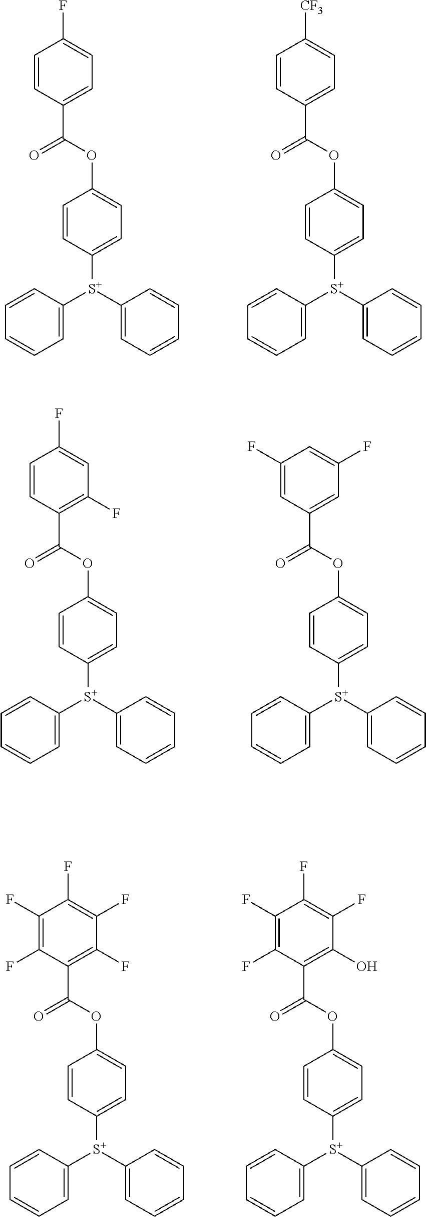 [SMILES: O=C(Oc1ccc([S+](c2ccccc2)c2ccccc2)cc1)c1ccc(F)cc1 ; O=C(Oc1ccc([S+](c2ccccc2)c2ccccc2)cc1)c1ccc(C(F)(F)F)cc1 ; O=C(Oc1ccc([S+](c2ccccc2)c2ccccc2)cc1)c1ccc(F)cc1F ; O=C(Oc1ccc([S+](c2ccccc2)c2ccccc2)cc1)c1cc(F)cc(F)c1 ; O=C(Oc1ccc([S+](c2ccccc2)c2ccccc2)cc1)c1c(F)c(F)c(F)c(F)c1F ; O=C(Oc1ccc([S+](c2ccccc2)c2ccccc2)cc1)c1c(O)c(F)c(F)c(F)c1F]

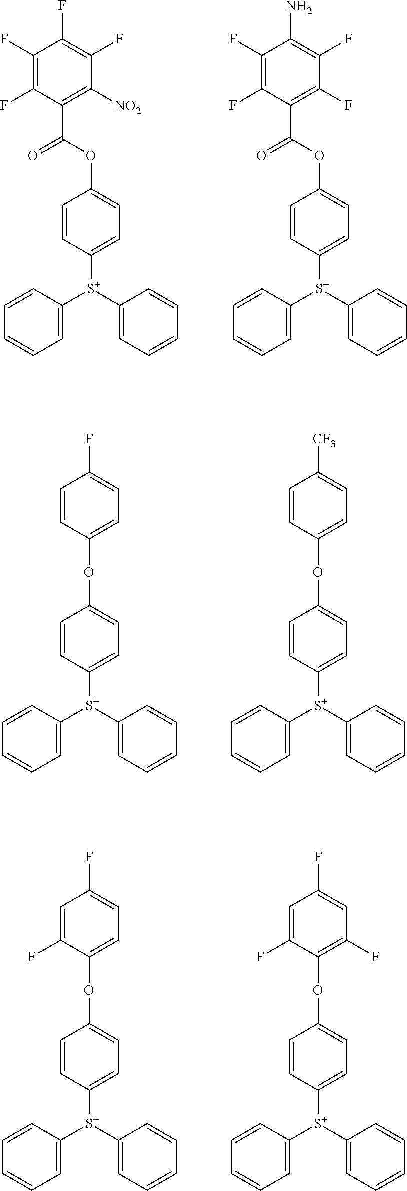 [SMILES: O=C(Oc1ccc([S+](c2ccccc2)c2ccccc2)cc1)c1c(F)c(F)c(F)c(F)c1[N+](=O)[O-] ; Nc1c(F)c(F)c(C(=O)Oc2ccc([S+](c3ccccc3)c3ccccc3)cc2)c(F)c1F ; Fc1ccc(Oc2ccc([S+](c3ccccc3)c3ccccc3)cc2)cc1 ; FC(F)(F)c1ccc(Oc2ccc([S+](c3ccccc3)c3ccccc3)cc2)cc1 ; Fc1ccc(Oc2ccc([S+](c3ccccc3)c3ccccc3)cc2)c(F)c1 ; Fc1cc(F)c(Oc2ccc([S+](c3ccccc3)c3ccccc3)cc2)c(F)c1]

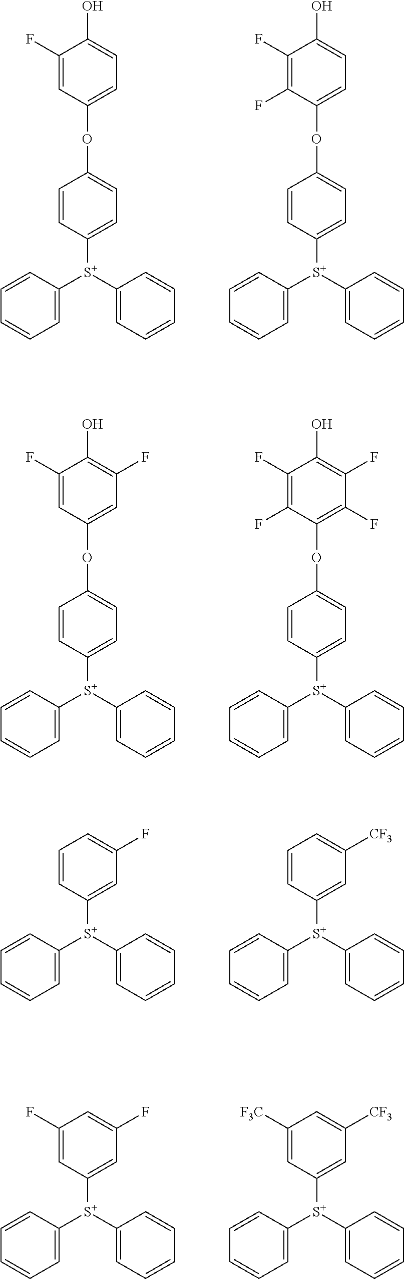

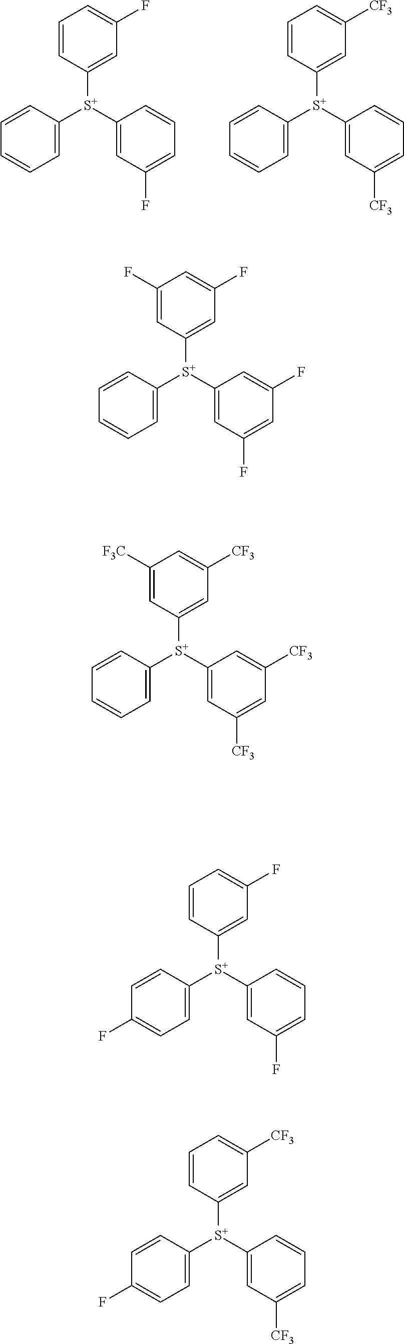 [SMILES: Fc1cccc([S+](c2ccccc2)c2cccc(F)c2)c1 ; FC(F)(F)c1cccc([S+](c2ccccc2)c2cccc(C(F)(F)F)c2)c1 ; Fc1cc(F)cc([S+](c2ccccc2)c2cc(F)cc(F)c2)c1 ; FC(F)(F)c1cc([S+](c2ccccc2)c2cc(C(F)(F)F)cc(C(F)(F)F)c2)cc(C(F)(F)F)c1 ; Fc1ccc([S+](c2cccc(F)c2)c2cccc(F)c2)cc1 ; Fc1ccc([S+](c2cccc(C(F)(F)F)c2)c2cccc(C(F)(F)F)c2)cc1]

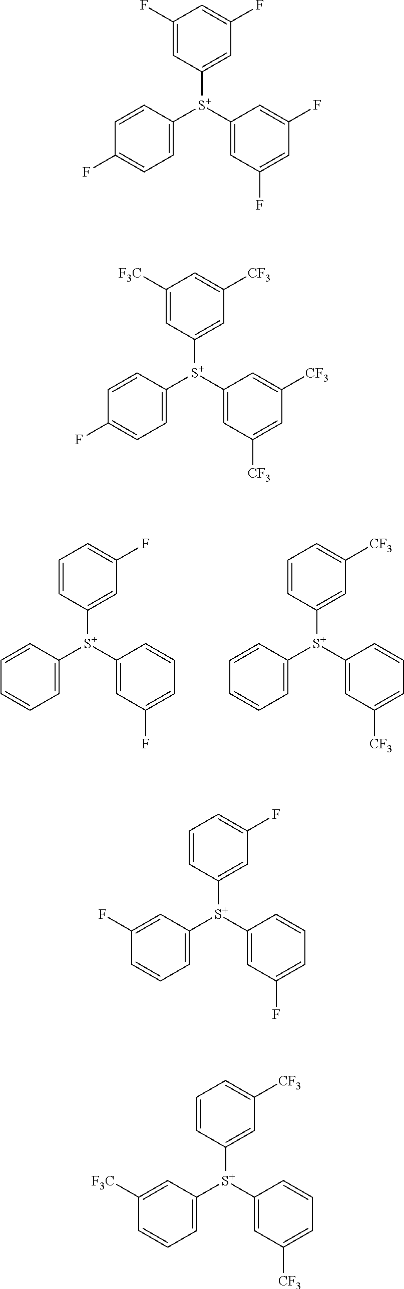 [SMILES: Fc1ccc([S+](c2cc(F)cc(F)c2)c2cc(F)cc(F)c2)cc1 ; Fc1ccc([S+](c2cc(C(F)(F)F)cc(C(F)(F)F)c2)c2cc(C(F)(F)F)cc(C(F)(F)F)c2)cc1 ; Fc1cccc([S+](c2ccccc2)c2cccc(F)c2)c1 ; FC(F)(F)c1cccc([S+](c2ccccc2)c2cccc(C(F)(F)F)c2)c1 ; Fc1cccc([S+](c2cccc(F)c2)c2cccc(F)c2)c1 ; FC(F)(F)c1cccc([S+](c2cccc(C(F)(F)F)c2)c2cccc(C(F)(F)F)c2)c1]

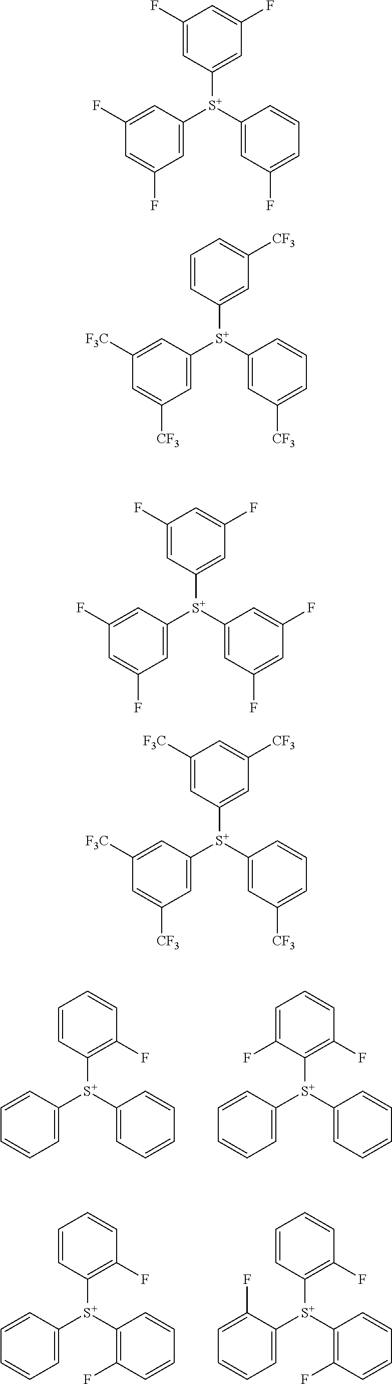

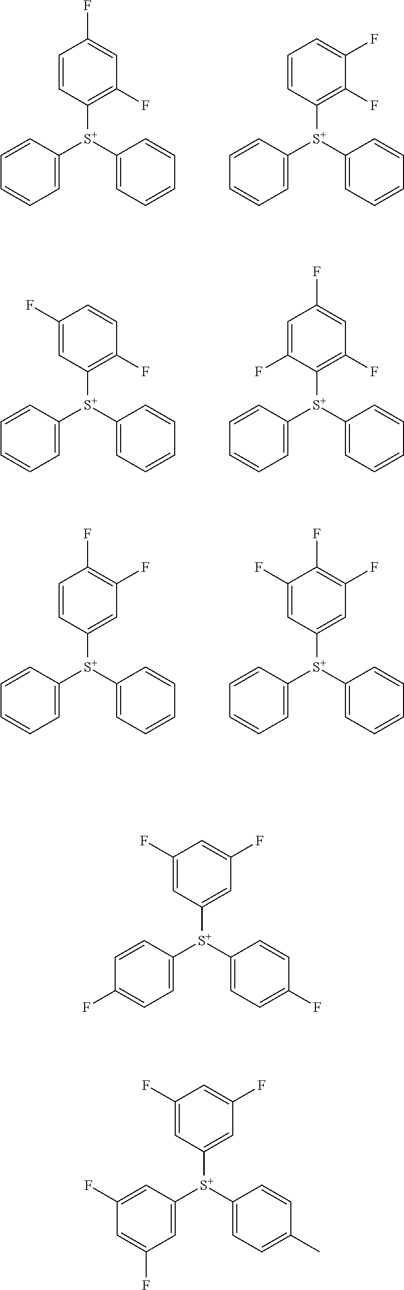

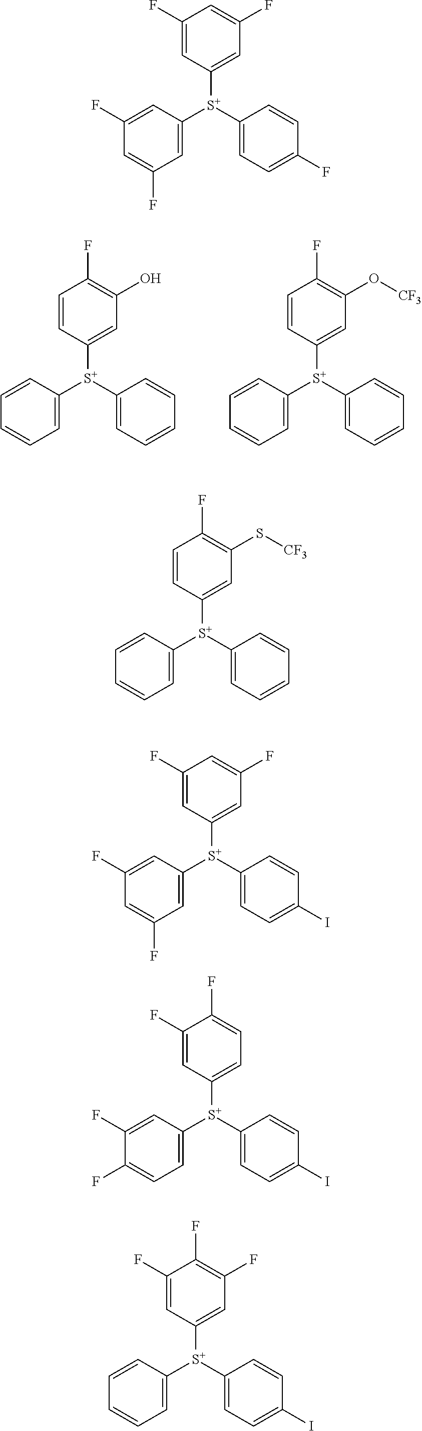

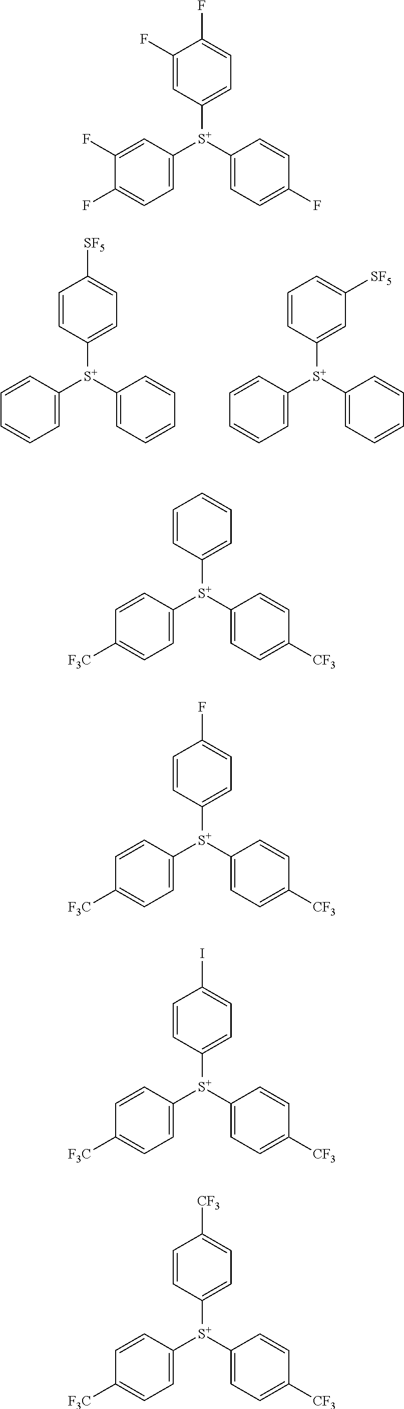

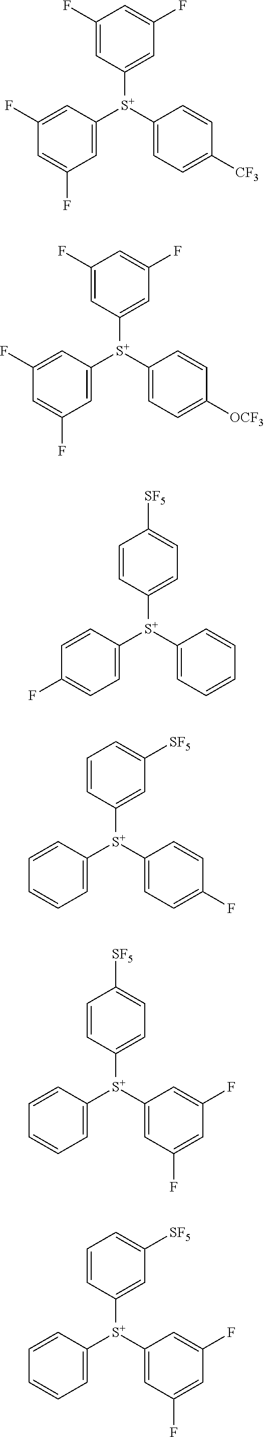

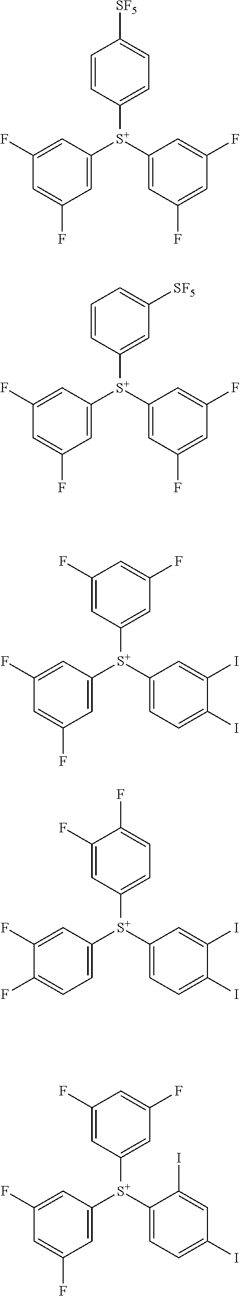

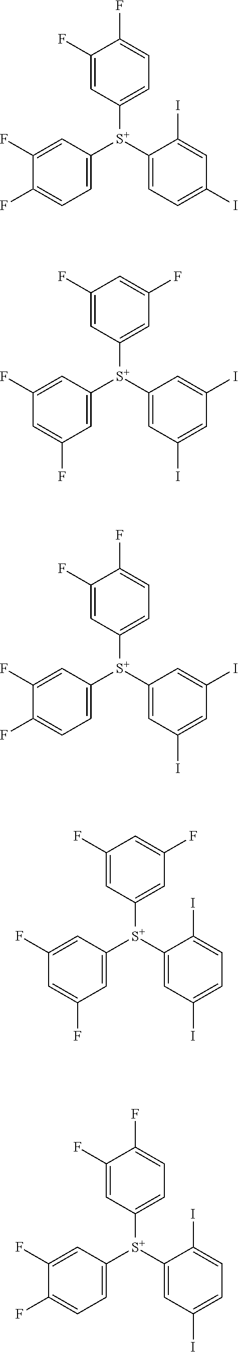 [SMILES: Fc1ccc([S+](c2ccc(F)c(F)c2)c2ccc(I)cc2I)cc1F ; Fc1cc(F)cc([S+](c2cc(F)cc(F)c2)c2cc(I)cc(I)c2)c1 ; Fc1ccc([S+](c2cc(I)cc(I)c2)c2ccc(F)c(F)c2)cc1F ; Fc1cc(F)cc([S+](c2cc(F)cc(F)c2)c2cc(I)ccc2I)c1 ; Fc1ccc([S+](c2ccc(F)c(F)c2)c2cc(I)ccc2I)cc1F]

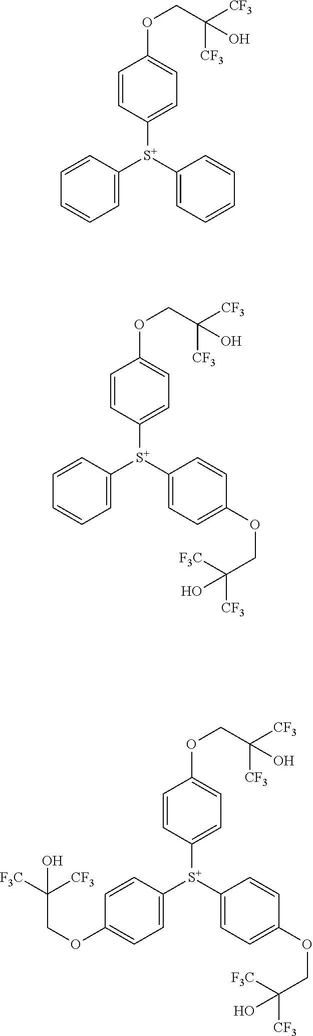 [SMILES: OC(COc1ccc([S+](c2ccccc2)c2ccccc2)cc1)(C(F)(F)F)C(F)(F)F ; OC(COc1ccc([S+](c2ccccc2)c2ccc(OCC(O)(C(F)(F)F)C(F)(F)F)cc2)cc1)(C(F)(F)F)C(F)(F)F ; OC(COc1ccc([S+](c2ccc(OCC(O)(C(F)(F)F)C(F)(F)F)cc2)c2ccc(OCC(O)(C(F)(F)F)C(F)(F)F)cc2)cc1)(C(F)(F)F)C(F)(F)F]

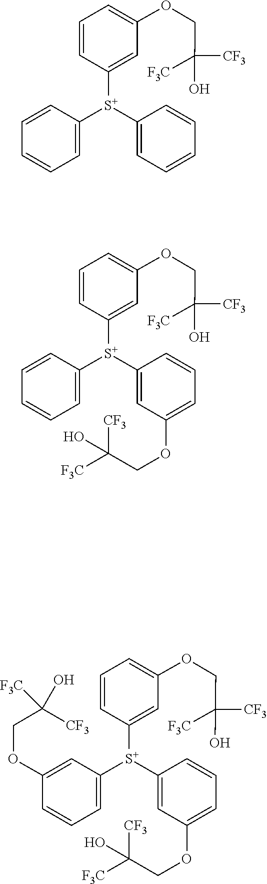 [SMILES: OC(COc1cccc([S+](c2ccccc2)c2ccccc2)c1)(C(F)(F)F)C(F)(F)F ; OC(COc1cccc([S+](c2ccccc2)c2cccc(OCC(O)(C(F)(F)F)C(F)(F)F)c2)c1)(C(F)(F)F)C(F)(F)F ; OC(COc1cccc([S+](c2cccc(OCC(O)(C(F)(F)F)C(F)(F)F)c2)c2cccc(OCC(O)(C(F)(F)F)C(F)(F)F)c2)c1)(C(F)(F)F)C(F)(F)F]

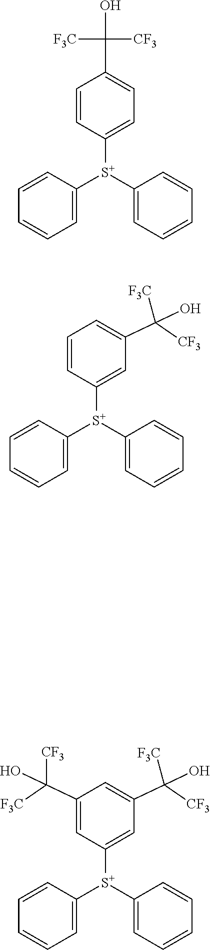 [SMILES: OC(c1ccc([S+](c2ccccc2)c2ccccc2)cc1)(C(F)(F)F)C(F)(F)F ; OC(c1cccc([S+](c2ccccc2)c2ccccc2)c1)(C(F)(F)F)C(F)(F)F ; OC(c1cc([S+](c2ccccc2)c2ccccc2)cc(C(O)(C(F)(F)F)C(F)(F)F)c1)(C(F)(F)F)C(F)(F)F]

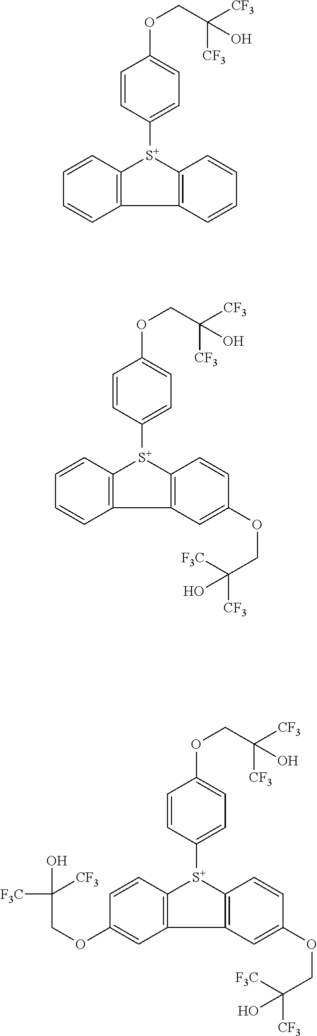 [SMILES: OC(COc1ccc(-[s+]2c3ccccc3c3ccccc32)cc1)(C(F)(F)F)C(F)(F)F ; OC(COc1ccc(-[s+]2c3ccccc3c3cc(OCC(O)(C(F)(F)F)C(F)(F)F)ccc32)cc1)(C(F)(F)F)C(F)(F)F ; OC(COc1ccc(-[s+]2c3ccc(OCC(O)(C(F)(F)F)C(F)(F)F)cc3c3cc(OCC(O)(C(F)(F)F)C(F)(F)F)ccc32)cc1)(C(F)(F)F)C(F)(F)F]

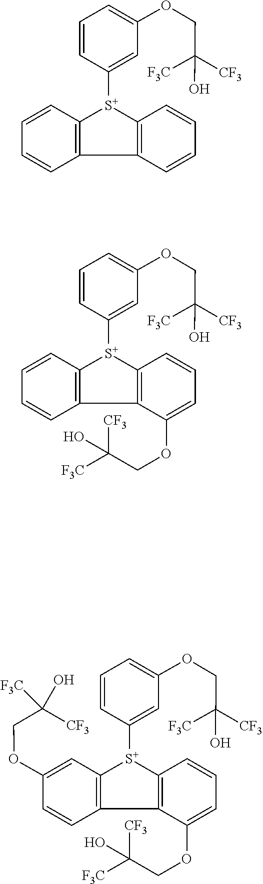 [SMILES: OC(COc1cccc(-[s+]2c3ccccc3c3ccccc32)c1)(C(F)(F)F)C(F)(F)F ; OC(COc1cccc(-[s+]2c3ccccc3c3c(OCC(O)(C(F)(F)F)C(F)(F)F)cccc32)c1)(C(F)(F)F)C(F)(F)F ; OC(COc1cccc(-[s+]2c3cc(OCC(O)(C(F)(F)F)C(F)(F)F)ccc3c3c(OCC(O)(C(F)(F)F)C(F)(F)F)cccc32)c1)(C(F)(F)F)C(F)(F)F]

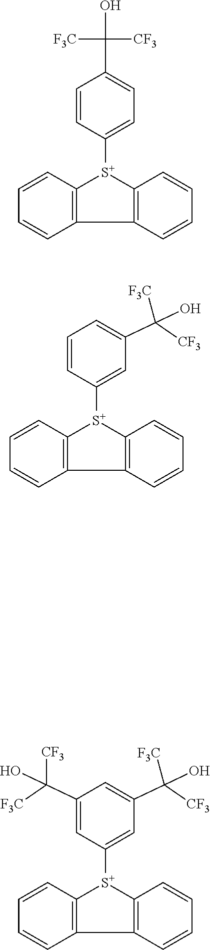 [SMILES: OC(c1ccc(-[s+]2c3ccccc3c3ccccc32)cc1)(C(F)(F)F)C(F)(F)F ; OC(c1cccc(-[s+]2c3ccccc3c3ccccc32)c1)(C(F)(F)F)C(F)(F)F ; OC(c1cc(-[s+]2c3ccccc3c3ccccc32)cc(C(O)(C(F)(F)F)C(F)(F)F)c1)(C(F)(F)F)C(F)(F)F]

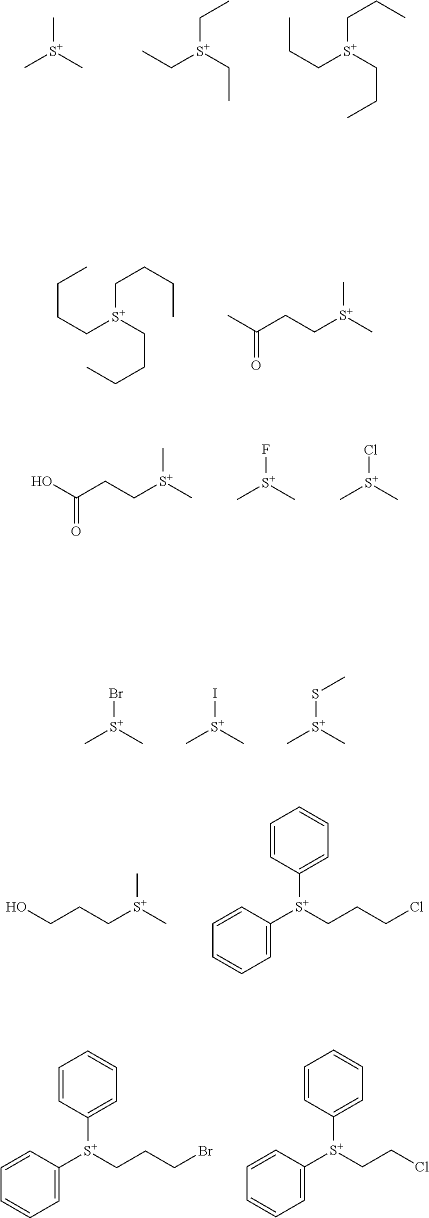

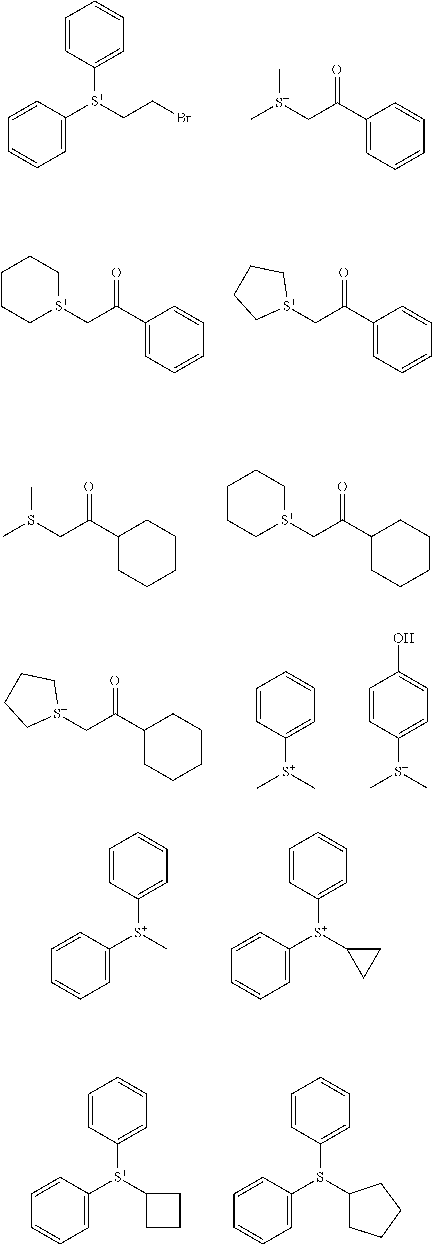

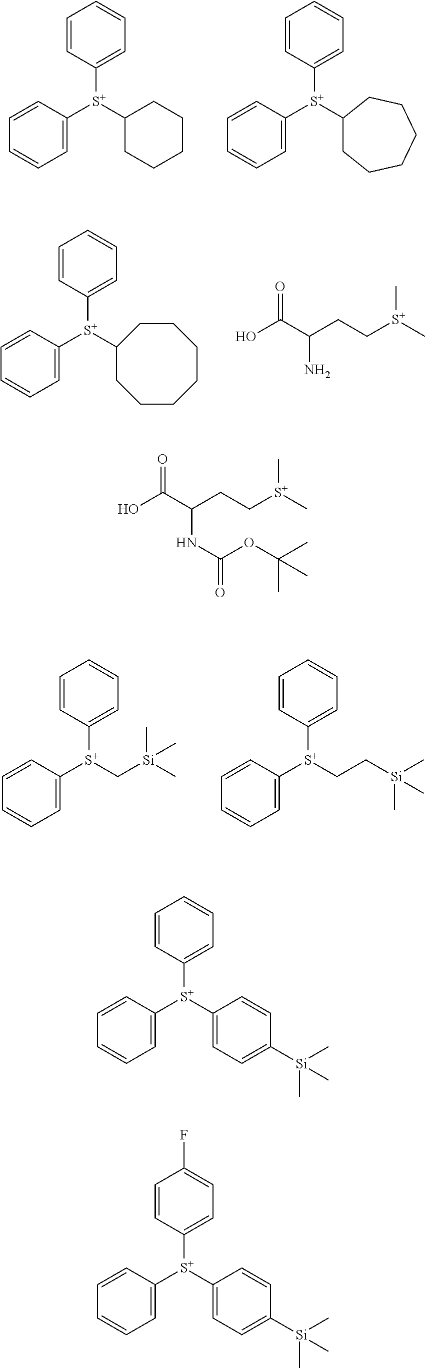

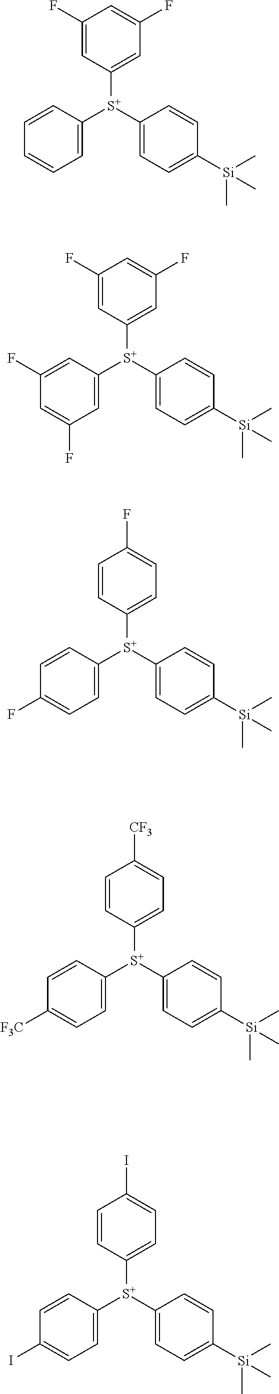 [SMILES: C[Si](C)(C)c1ccc([S+](c2ccccc2)c2cc(F)cc(F)c2)cc1 ; C[Si](C)(C)c1ccc([S+](c2cc(F)cc(F)c2)c2cc(F)cc(F)c2)cc1 ; C[Si](C)(C)c1ccc([S+](c2ccc(F)cc2)c2ccc(F)cc2)cc1 ; C[Si](C)(C)c1ccc([S+](c2ccc(C(F)(F)F)cc2)c2ccc(C(F)(F)F)cc2)cc1 ; C[Si](C)(C)c1ccc([S+](c2ccc(I)cc2)c2ccc(I)cc2)cc1]

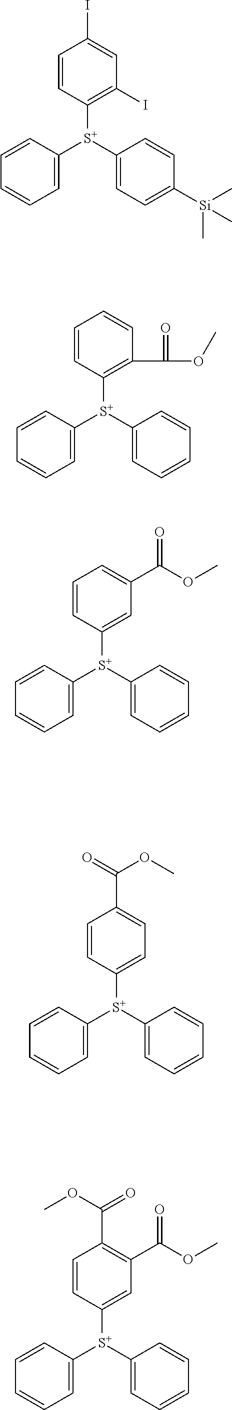 [SMILES: C[Si](C)(C)c1ccc([S+](c2ccccc2)c2ccc(I)cc2I)cc1 ; COC(=O)c1ccccc1[S+](c1ccccc1)c1ccccc1 ; COC(=O)c1cccc([S+](c2ccccc2)c2ccccc2)c1 ; COC(=O)c1ccc([S+](c2ccccc2)c2ccccc2)cc1 ; COC(=O)c1ccc([S+](c2ccccc2)c2ccccc2)cc1C(=O)OC]

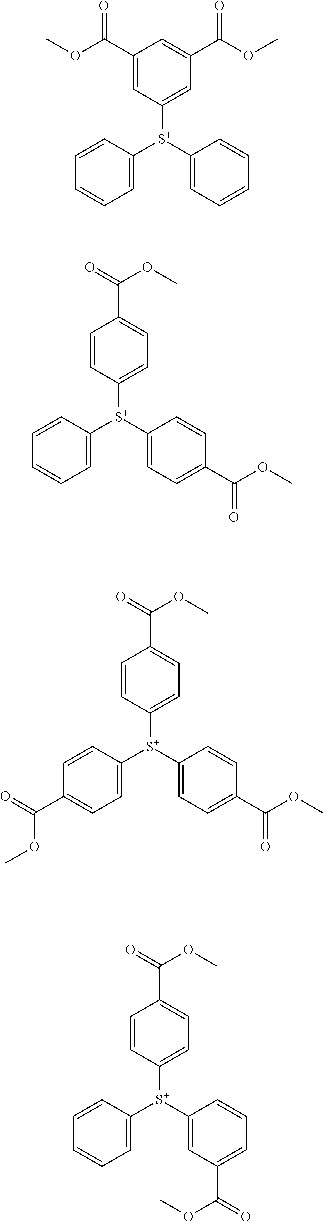

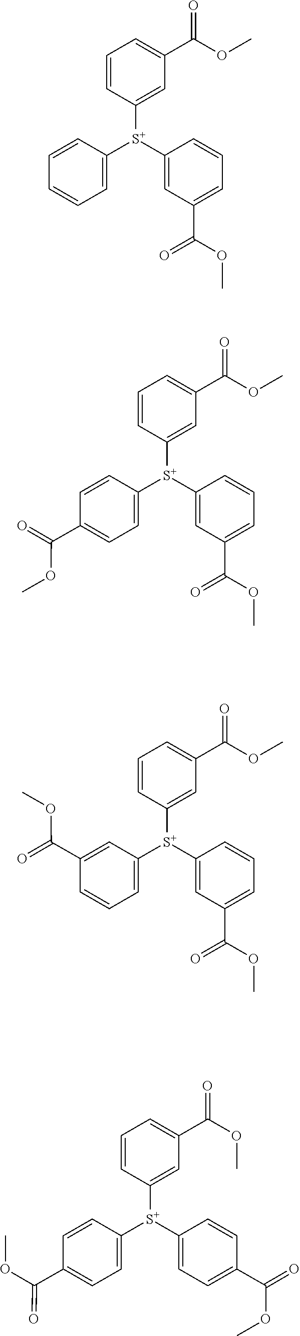

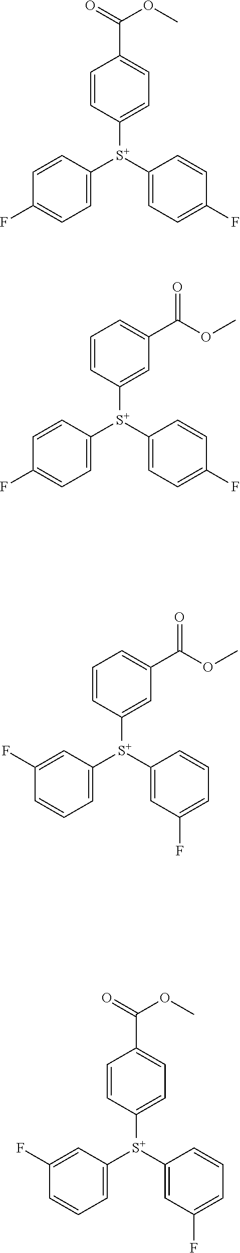 [SMILES: COC(=O)c1ccc([S+](c2ccc(F)cc2)c2ccc(F)cc2)cc1 ; COC(=O)c1cccc([S+](c2ccc(F)cc2)c2ccc(F)cc2)c1 ; COC(=O)c1cccc([S+](c2cccc(F)c2)c2cccc(F)c2)c1 ; COC(=O)c1ccc([S+](c2cccc(F)c2)c2cccc(F)c2)cc1]

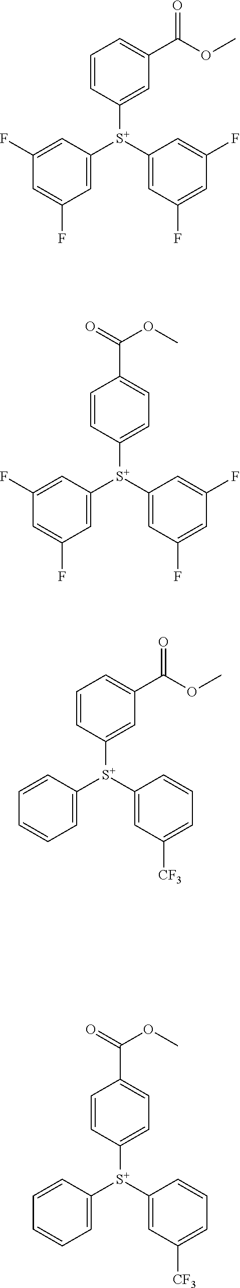 [SMILES: COC(=O)c1cccc([S+](c2cc(F)cc(F)c2)c2cc(F)cc(F)c2)c1 ; COC(=O)c1ccc([S+](c2cc(F)cc(F)c2)c2cc(F)cc(F)c2)cc1 ; COC(=O)c1cccc([S+](c2ccccc2)c2cccc(C(F)(F)F)c2)c1 ; COC(=O)c1ccc([S+](c2ccccc2)c2cccc(C(F)(F)F)c2)cc1]

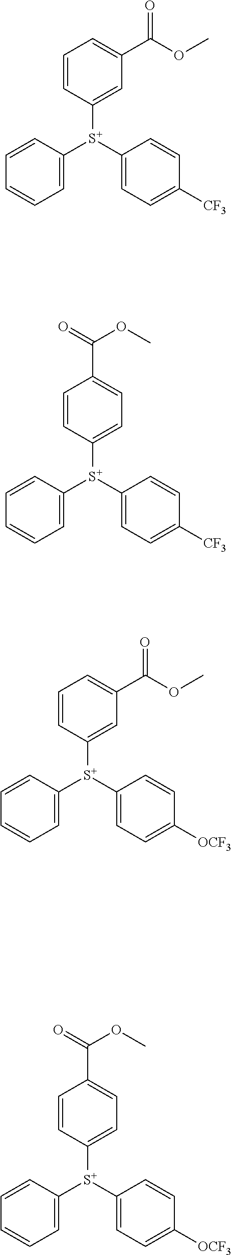 [SMILES: COC(=O)c1cccc([S+](c2ccccc2)c2ccc(C(F)(F)F)cc2)c1 ; COC(=O)c1ccc([S+](c2ccccc2)c2ccc(C(F)(F)F)cc2)cc1 ; COC(=O)c1cccc([S+](c2ccccc2)c2ccc(OC(F)(F)F)cc2)c1 ; COC(=O)c1ccc([S+](c2ccccc2)c2ccc(OC(F)(F)F)cc2)cc1]

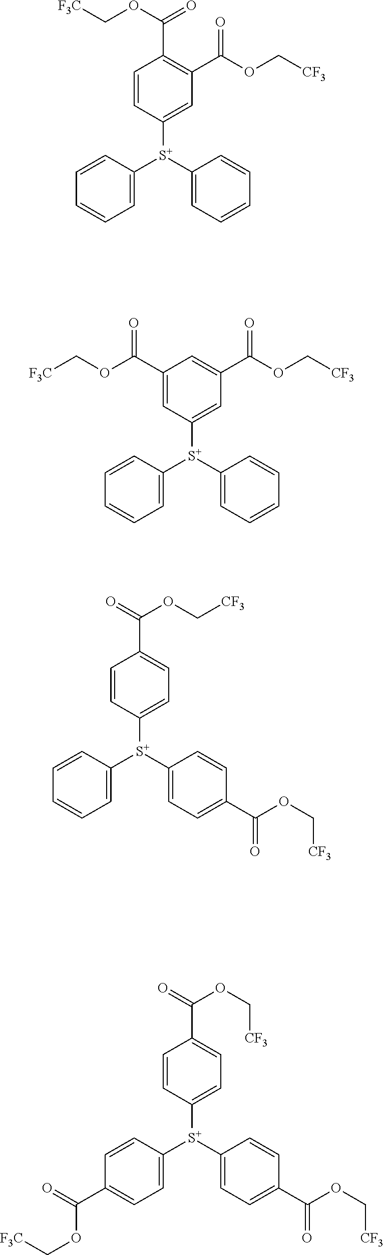 [SMILES: O=C(OCC(F)(F)F)c1ccc([S+](c2ccccc2)c2ccccc2)cc1C(=O)OCC(F)(F)F ; O=C(OCC(F)(F)F)c1cc(C(=O)OCC(F)(F)F)cc([S+](c2ccccc2)c2ccccc2)c1 ; O=C(OCC(F)(F)F)c1ccc([S+](c2ccccc2)c2ccc(C(=O)OCC(F)(F)F)cc2)cc1 ; O=C(OCC(F)(F)F)c1ccc([S+](c2ccc(C(=O)OCC(F)(F)F)cc2)c2ccc(C(=O)OCC(F)(F)F)cc2)cc1]

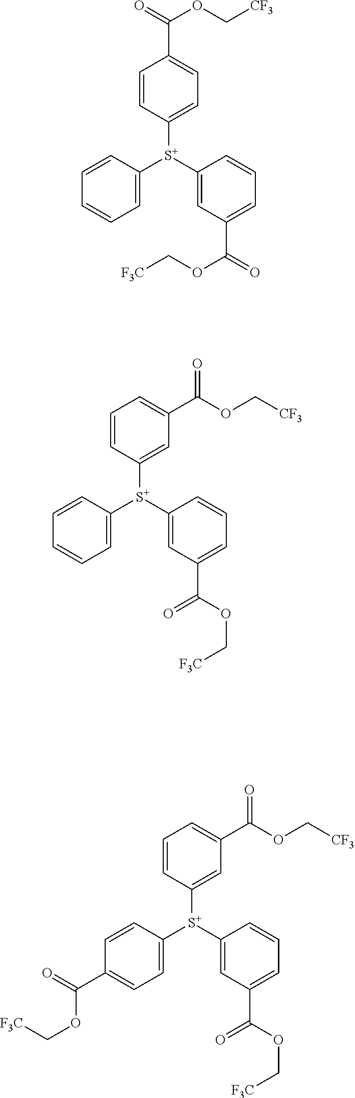 [SMILES: O=C(OCC(F)(F)F)c1ccc([S+](c2ccccc2)c2cccc(C(=O)OCC(F)(F)F)c2)cc1 ; O=C(OCC(F)(F)F)c1cccc([S+](c2ccccc2)c2cccc(C(=O)OCC(F)(F)F)c2)c1 ; O=C(OCC(F)(F)F)c1ccc([S+](c2cccc(C(=O)OCC(F)(F)F)c2)c2cccc(C(=O)OCC(F)(F)F)c2)cc1]

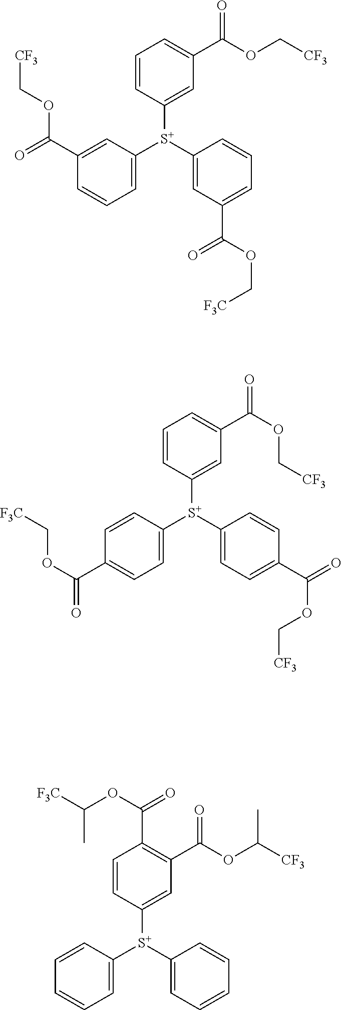 [SMILES: O=C(OCC(F)(F)F)c1cccc([S+](c2cccc(C(=O)OCC(F)(F)F)c2)c2cccc(C(=O)OCC(F)(F)F)c2)c1 ; O=C(OCC(F)(F)F)c1ccc([S+](c2ccc(C(=O)OCC(F)(F)F)cc2)c2cccc(C(=O)OCC(F)(F)F)c2)cc1 ; CC(OC(=O)c1ccc([S+](c2ccccc2)c2ccccc2)cc1C(=O)OC(C)C(F)(F)F)C(F)(F)F]

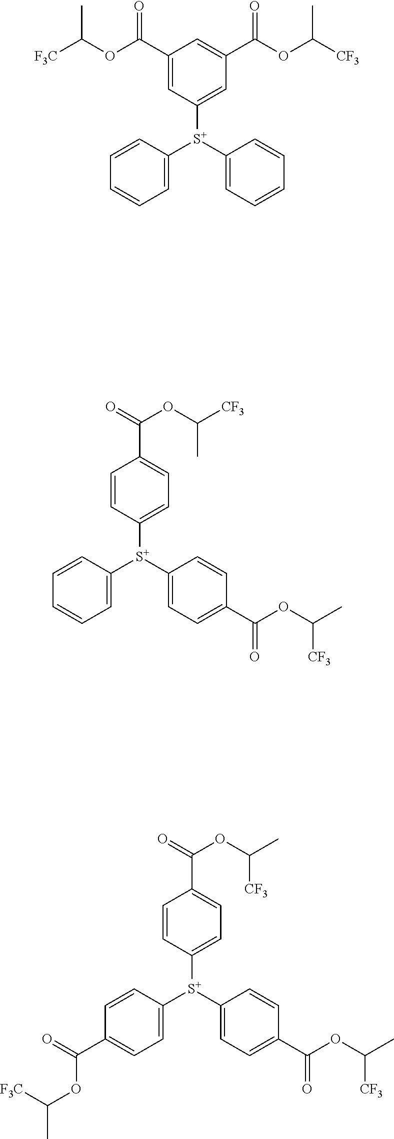 [SMILES: CC(OC(=O)c1cc(C(=O)OC(C)C(F)(F)F)cc([S+](c2ccccc2)c2ccccc2)c1)C(F)(F)F ; CC(OC(=O)c1ccc([S+](c2ccccc2)c2ccc(C(=O)OC(C)C(F)(F)F)cc2)cc1)C(F)(F)F ; CC(OC(=O)c1ccc([S+](c2ccc(C(=O)OC(C)C(F)(F)F)cc2)c2ccc(C(=O)OC(C)C(F)(F)F)cc2)cc1)C(F)(F)F]

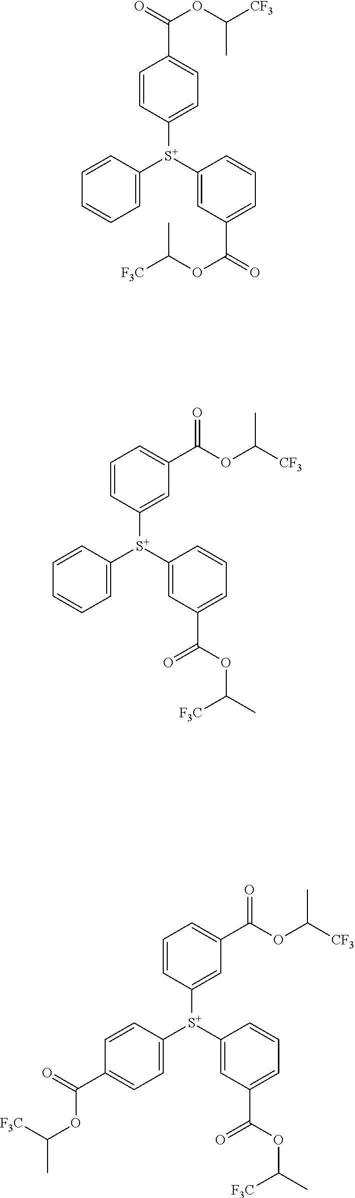 [SMILES: CC(OC(=O)c1ccc([S+](c2ccccc2)c2cccc(C(=O)OC(C)C(F)(F)F)c2)cc1)C(F)(F)F ; CC(OC(=O)c1cccc([S+](c2ccccc2)c2cccc(C(=O)OC(C)C(F)(F)F)c2)c1)C(F)(F)F ; CC(OC(=O)c1ccc([S+](c2cccc(C(=O)OC(C)C(F)(F)F)c2)c2cccc(C(=O)OC(C)C(F)(F)F)c2)cc1)C(F)(F)F]

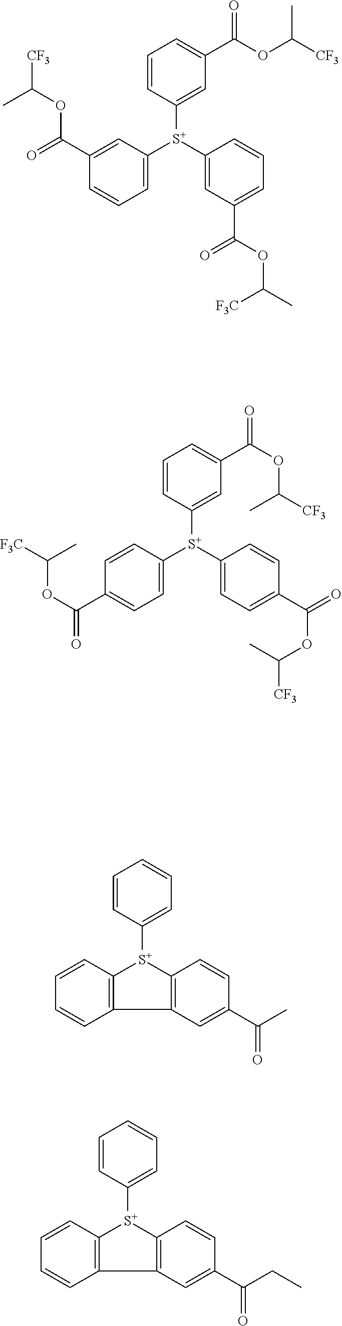 [SMILES: CC(OC(=O)c1cccc([S+](c2cccc(C(=O)OC(C)C(F)(F)F)c2)c2cccc(C(=O)OC(C)C(F)(F)F)c2)c1)C(F)(F)F ; CC(OC(=O)c1ccc([S+](c2ccc(C(=O)OC(C)C(F)(F)F)cc2)c2cccc(C(=O)OC(C)C(F)(F)F)c2)cc1)C(F)(F)F ; CC(=O)c1ccc2c(c1)c1ccccc1[s+]2-c1ccccc1 ; CCC(=O)c1ccc2c(c1)c1ccccc1[s+]2-c1ccccc1]

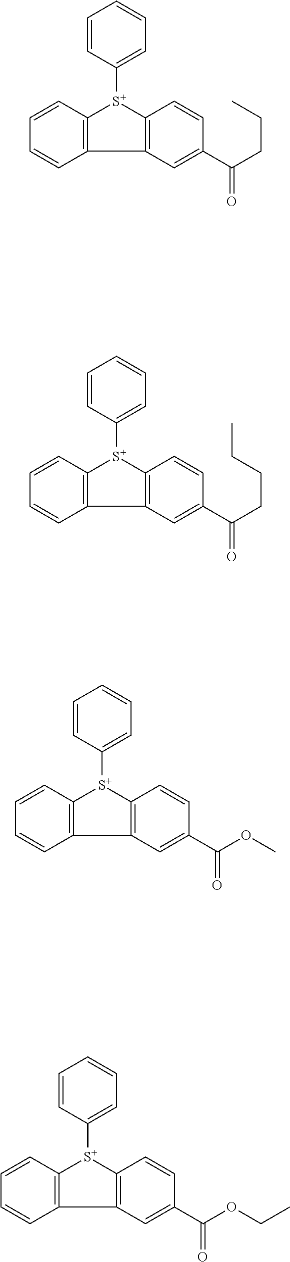 [SMILES: CCCC(=O)c1ccc2c(c1)c1ccccc1[s+]2-c1ccccc1 ; CCCCC(=O)c1ccc2c(c1)c1ccccc1[s+]2-c1ccccc1 ; COC(=O)c1ccc2c(c1)c1ccccc1[s+]2-c1ccccc1 ; CCOC(=O)c1ccc2c(c1)c1ccccc1[s+]2-c1ccccc1]

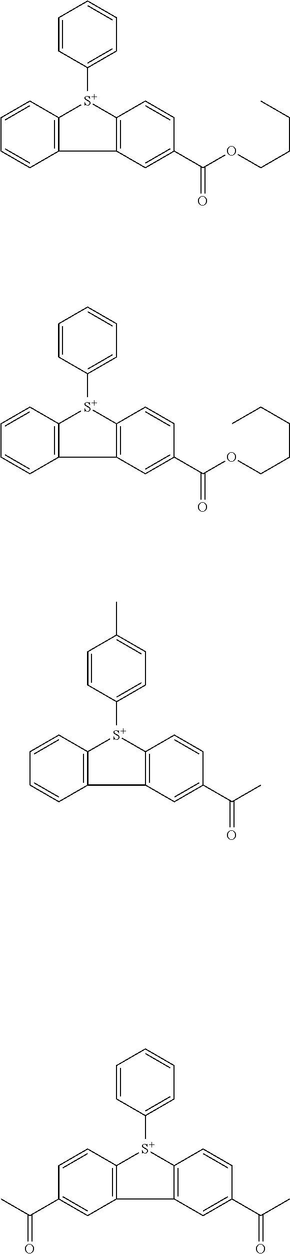

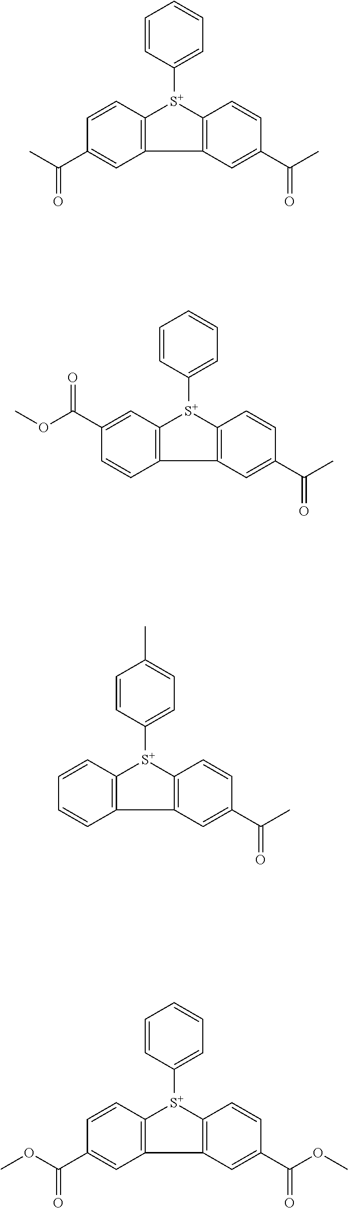

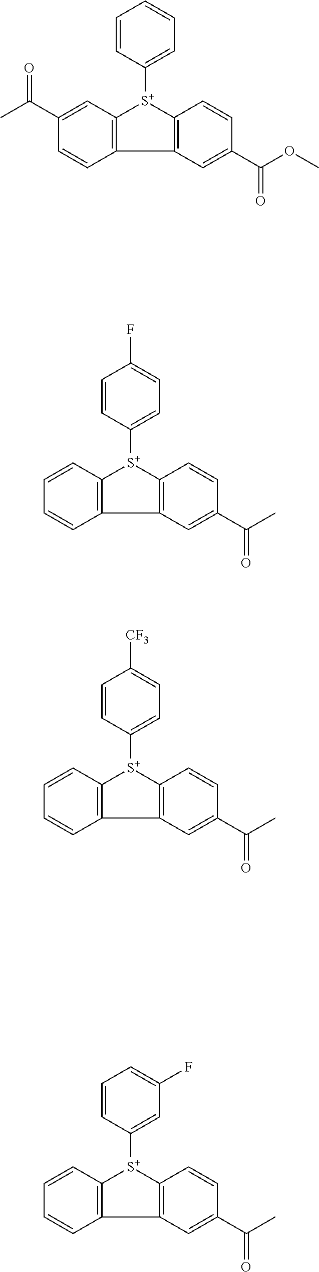 [SMILES: COC(=O)c1ccc2c(c1)c1ccc(C(C)=O)cc1[s+]2-c1ccccc1 ; CC(=O)c1ccc2c(c1)c1ccccc1[s+]2-c1ccc(F)cc1 ; CC(=O)c1ccc2c(c1)c1ccccc1[s+]2-c1ccc(C(F)(F)F)cc1 ; CC(=O)c1ccc2c(c1)c1ccccc1[s+]2-c1cccc(F)c1]

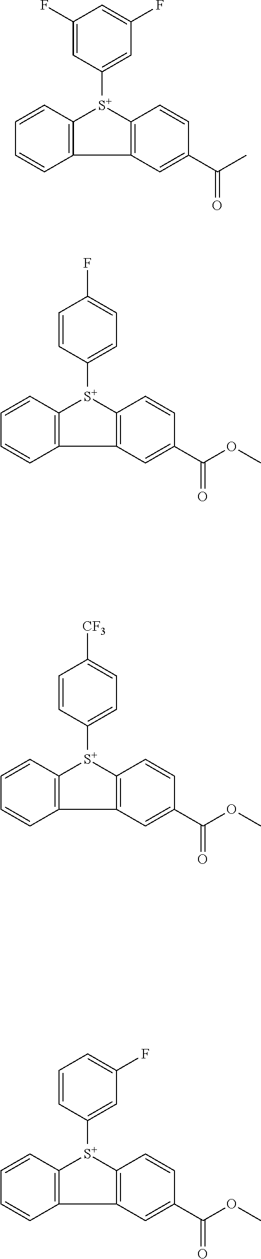 [SMILES: CC(=O)c1ccc2c(c1)c1ccccc1[s+]2-c1cc(F)cc(F)c1 ; COC(=O)c1ccc2c(c1)c1ccccc1[s+]2-c1ccc(F)cc1 ; COC(=O)c1ccc2c(c1)c1ccccc1[s+]2-c1ccc(C(F)(F)F)cc1 ; COC(=O)c1ccc2c(c1)c1ccccc1[s+]2-c1cccc(F)c1]

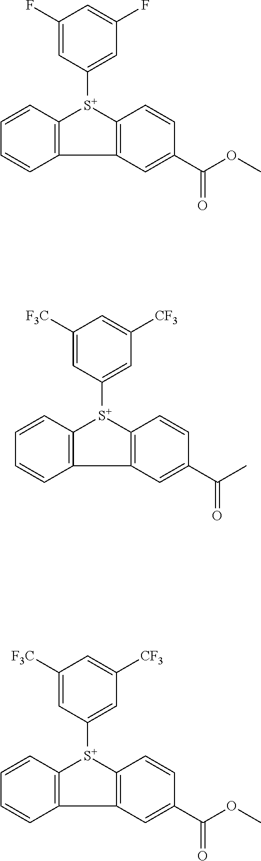 [SMILES: COC(=O)c1ccc2c(c1)c1ccccc1[s+]2-c1cc(F)cc(F)c1 ; CC(=O)c1ccc2c(c1)c1ccccc1[s+]2-c1cc(C(F)(F)F)cc(C(F)(F)F)c1 ; COC(=O)c1ccc2c(c1)c1ccccc1[s+]2-c1cc(C(F)(F)F)cc(C(F)(F)F)c1]

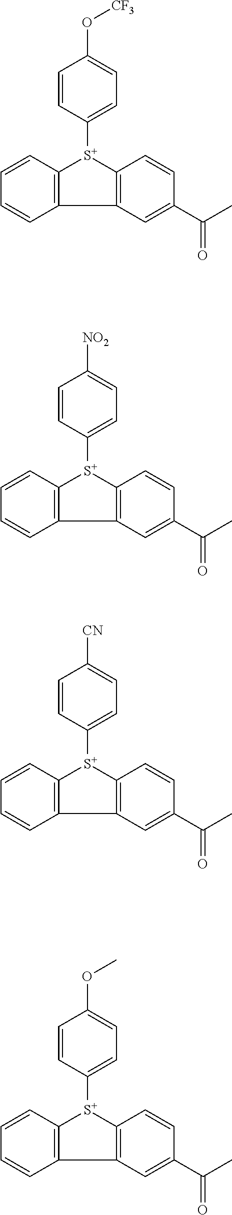 [SMILES: CC(=O)c1ccc2c(c1)c1ccccc1[s+]2-c1ccc(OC(F)(F)F)cc1 ; CC(=O)c1ccc2c(c1)c1ccccc1[s+]2-c1ccc([N+](=O)[O-])cc1 ; CC(=O)c1ccc2c(c1)c1ccccc1[s+]2-c1ccc(C#N)cc1 ; COc1ccc(-[s+]2c3ccccc3c3cc(C(C)=O)ccc32)cc1]

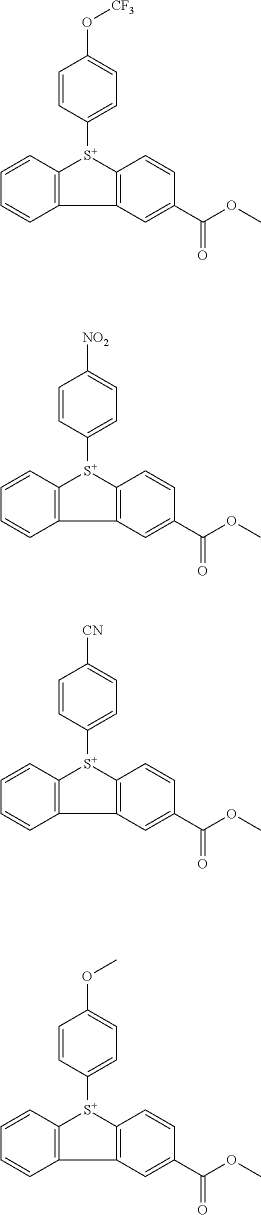 [SMILES: COC(=O)c1ccc2c(c1)c1ccccc1[s+]2-c1ccc(OC(F)(F)F)cc1 ; COC(=O)c1ccc2c(c1)c1ccccc1[s+]2-c1ccc([N+](=O)[O-])cc1 ; COC(=O)c1ccc2c(c1)c1ccccc1[s+]2-c1ccc(C#N)cc1 ; COC(=O)c1ccc2c(c1)c1ccccc1[s+]2-c1ccc(OC)cc1]

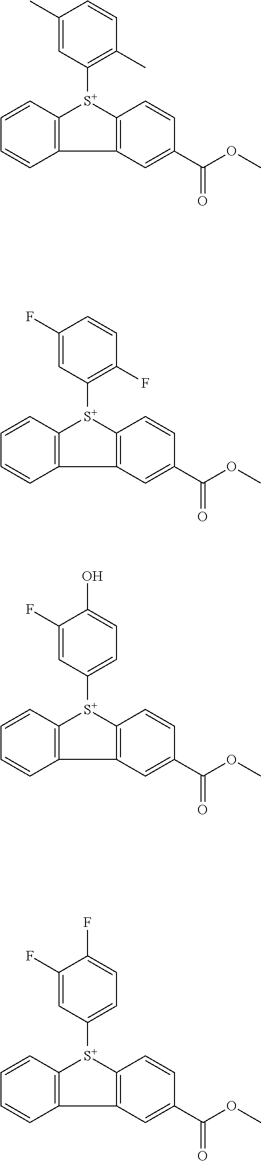 [SMILES: COC(=O)c1ccc2c(c1)c1ccccc1[s+]2-c1cc(C)ccc1C ; COC(=O)c1ccc2c(c1)c1ccccc1[s+]2-c1cc(F)ccc1F ; COC(=O)c1ccc2c(c1)c1ccccc1[s+]2-c1ccc(O)c(F)c1 ; COC(=O)c1ccc2c(c1)c1ccccc1[s+]2-c1ccc(F)c(F)c1]

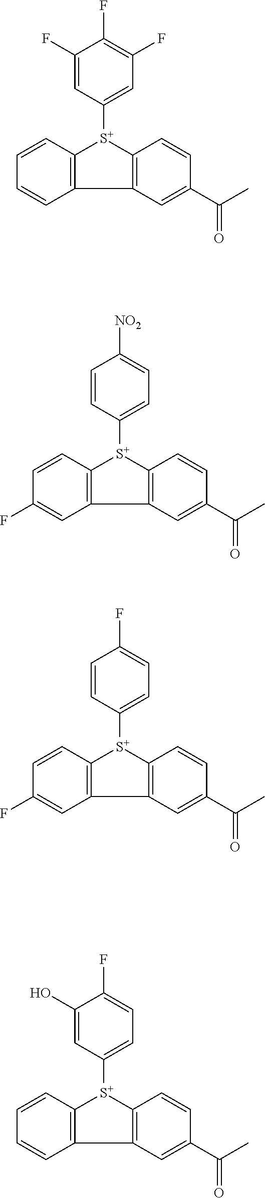 [SMILES: CC(=O)c1ccc2c(c1)c1ccccc1[s+]2-c1cc(F)c(F)c(F)c1 ; CC(=O)c1ccc2c(c1)c1cc(F)ccc1[s+]2-c1ccc([N+](=O)[O-])cc1 ; CC(=O)c1ccc2c(c1)c1cc(F)ccc1[s+]2-c1ccc(F)cc1 ; CC(=O)c1ccc2c(c1)c1ccccc1[s+]2-c1ccc(F)c(O)c1]

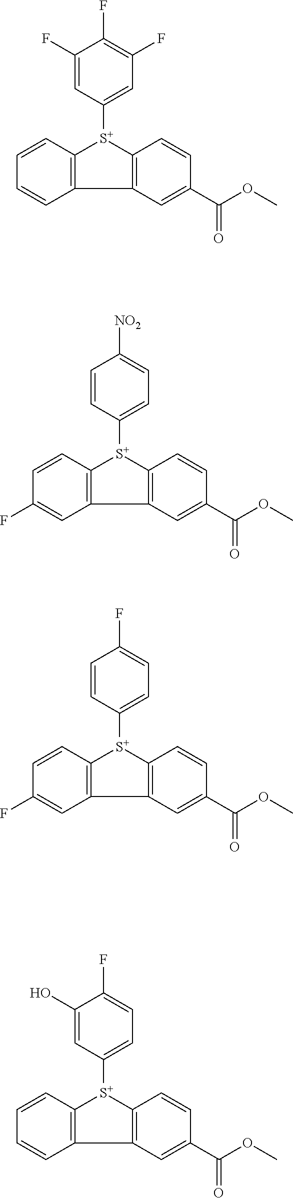 [SMILES: COC(=O)c1ccc2c(c1)c1ccccc1[s+]2-c1cc(F)c(F)c(F)c1 ; COC(=O)c1ccc2c(c1)c1cc(F)ccc1[s+]2-c1ccc([N+](=O)[O-])cc1 ; COC(=O)c1ccc2c(c1)c1cc(F)ccc1[s+]2-c1ccc(F)cc1 ; COC(=O)c1ccc2c(c1)c1ccccc1[s+]2-c1ccc(F)c(O)c1]

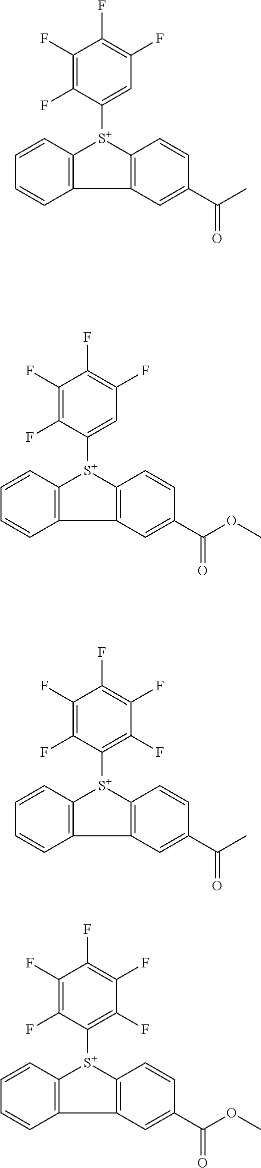 [SMILES: CC(=O)c1ccc2c(c1)c1ccccc1[s+]2-c1cc(F)c(F)c(F)c1F ; COC(=O)c1ccc2c(c1)c1ccccc1[s+]2-c1cc(F)c(F)c(F)c1F ; CC(=O)c1ccc2c(c1)c1ccccc1[s+]2-c1c(F)c(F)c(F)c(F)c1F ; COC(=O)c1ccc2c(c1)c1ccccc1[s+]2-c1c(F)c(F)c(F)c(F)c1F]

Specific examples of the iodonium cation represented by M⁺ include the following, but are not limited thereto.

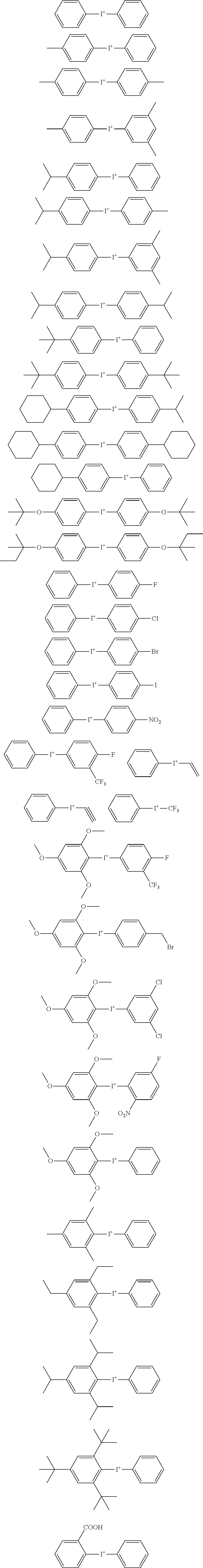

Iodine atoms greatly absorb EUV having a wavelength of 13.5 nm, and an effect that secondary electrons are generated from iodine atoms during exposure has been observed. Therefore, when iodine atoms are used in EUV lithography, improvement in lithography performance can be expected.

In addition, iodine atoms have a high molecular weight, and therefore, has a characteristic that acid diffusion can be reduced when contained in an anion structure. Furthermore, secondary electrons are generated from iodine atoms during EUV exposure, and higher sensitivity can be achieved. Thus, when an iodine atom is incorporated as necessary in an anion moiety and/or a cation moiety of a repeating unit having an acid-generating moiety, it is possible to construct a resist having high sensitivity, low LWR, and low CDU. In addition, iodine atoms also have an electron-withdrawing effect, and therefore, an effect that acid-labile groups are eliminated (deprotection) and acidic groups can be produced easily can also be expected.

The base polymer may further contain a repeating unit-c containing an adhesive group selected from a hydroxy group, a carboxy group, a lactone ring, a carbonate group, a thiocarbonate group, a carbonyl group, a cyclic acetal group, an ether bond, an ester bond, a sulfonic acid ester bond, a cyano group, an amide group, —O—C(═O)—S—, and —O—C(═O)—NH—.

Examples of a monomer to give the repeating unit-c include ones shown below, but are not limited thereto. Note that, in the following formulae, R^{A} is as defined above.

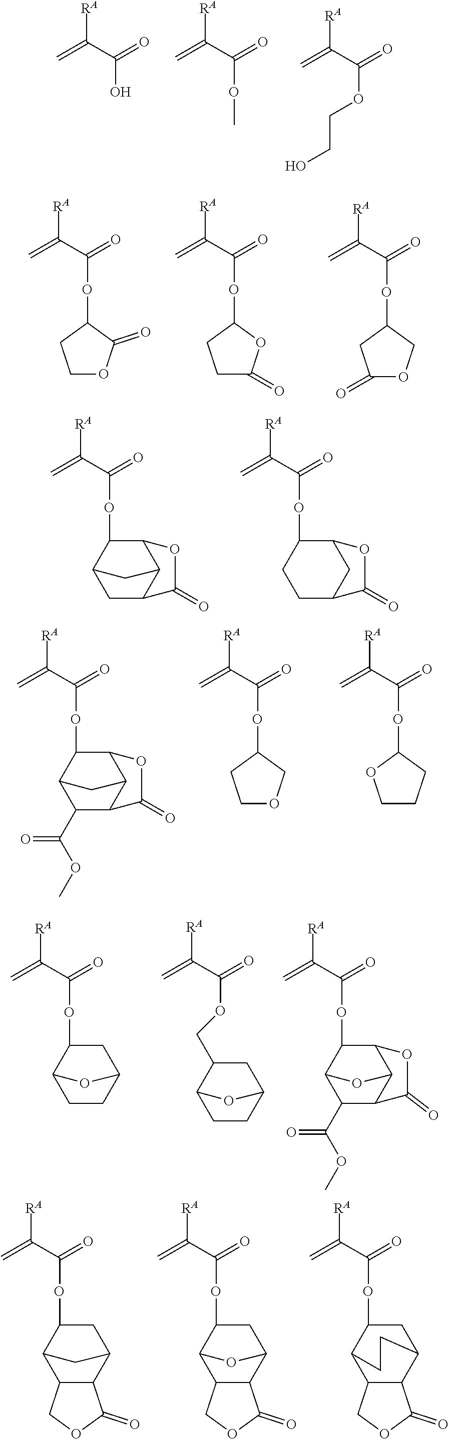

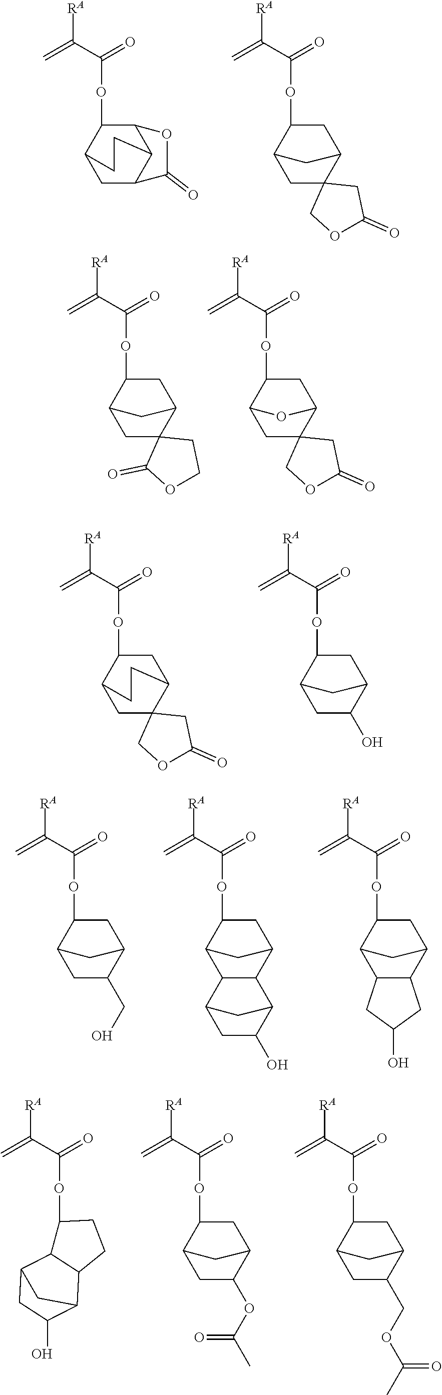

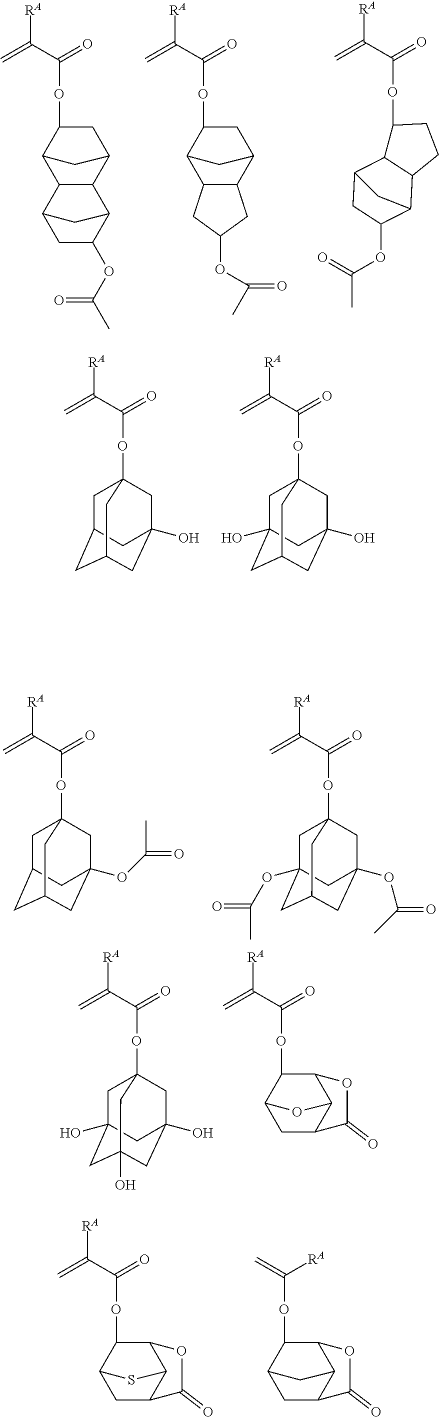

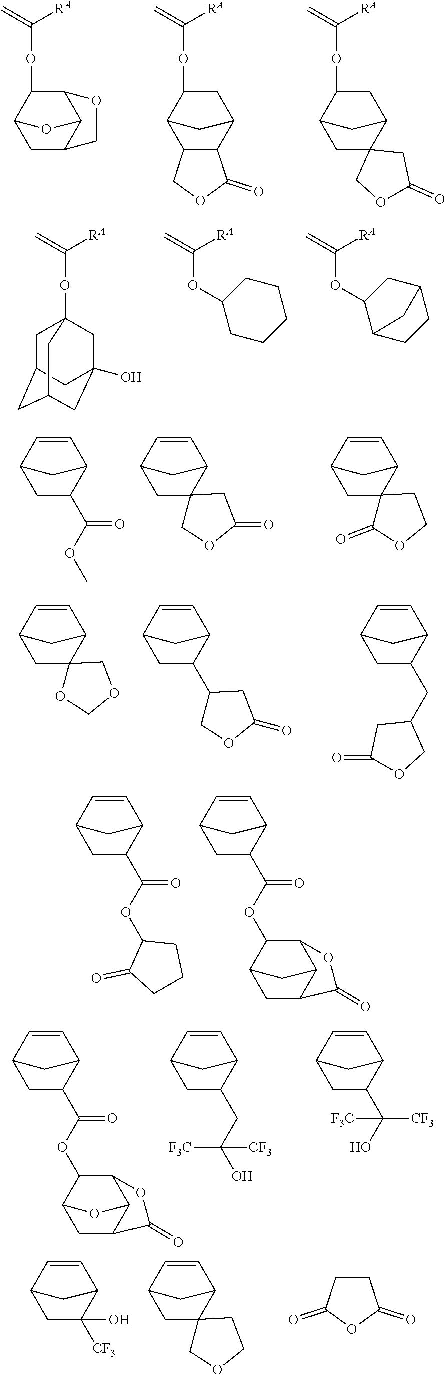

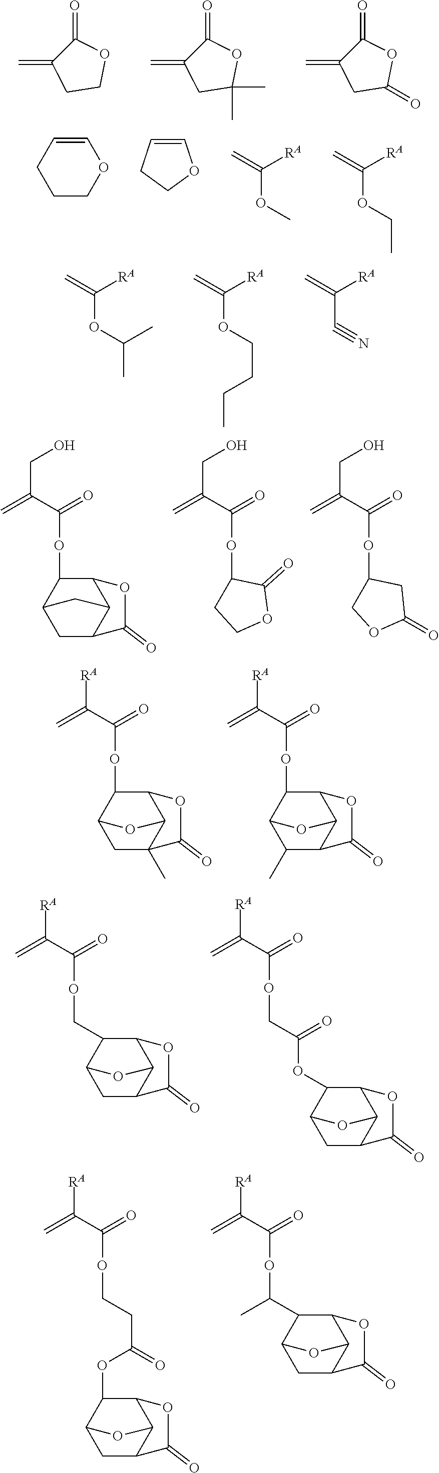

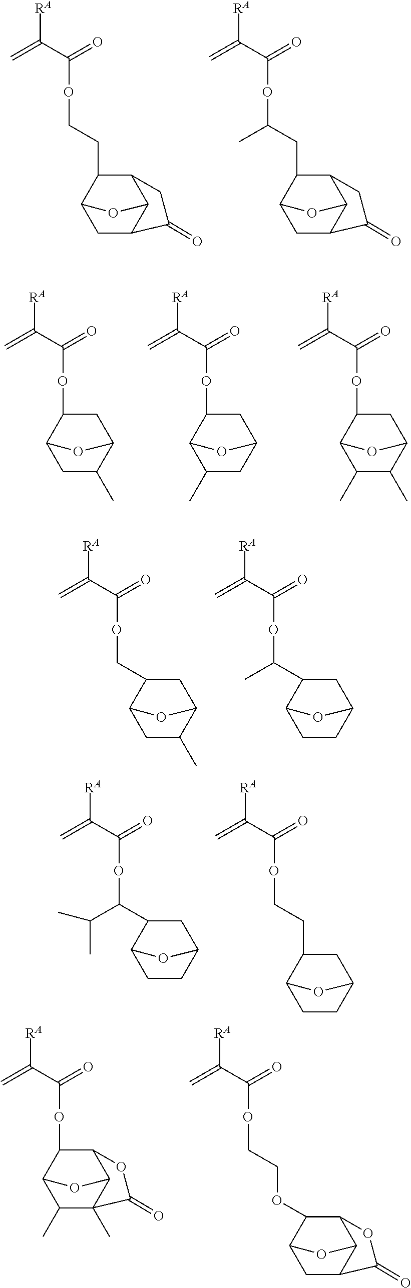

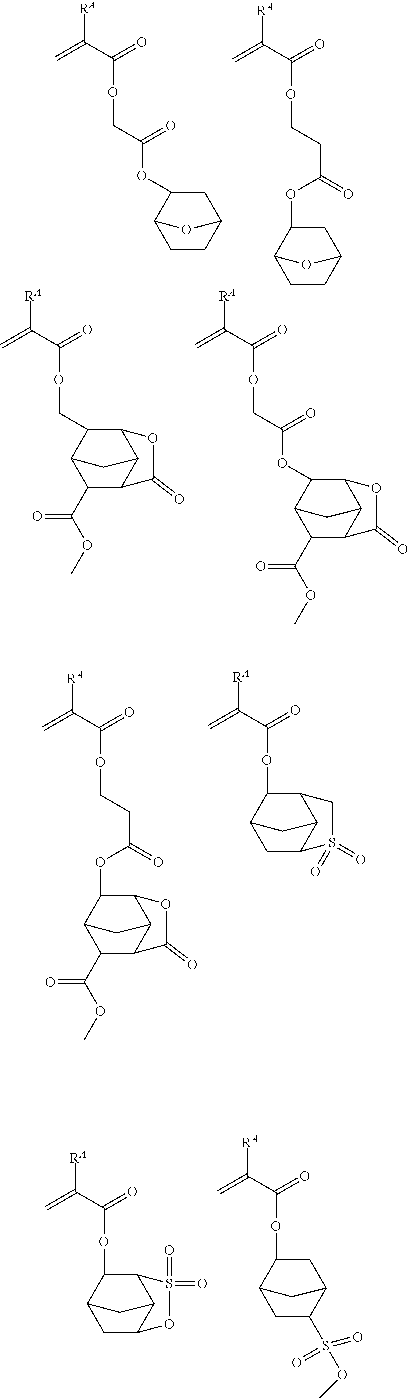

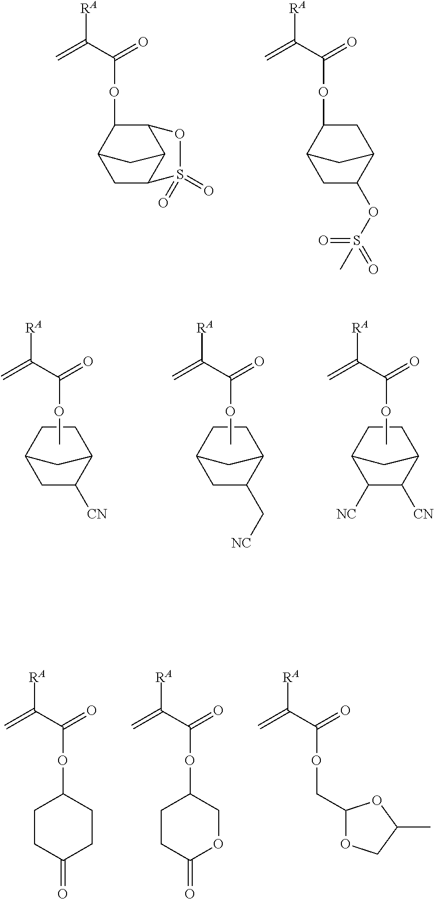

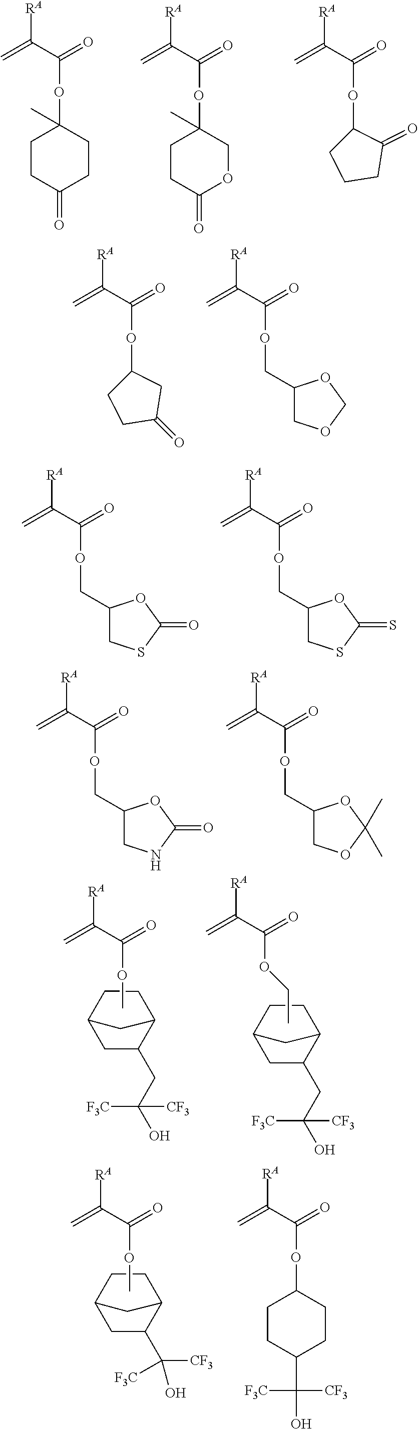

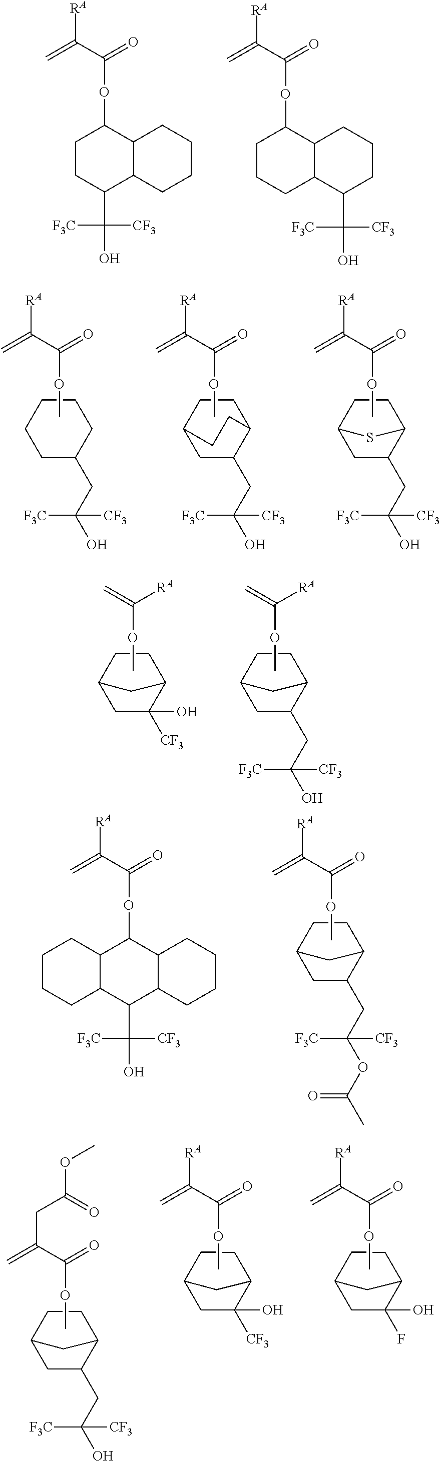

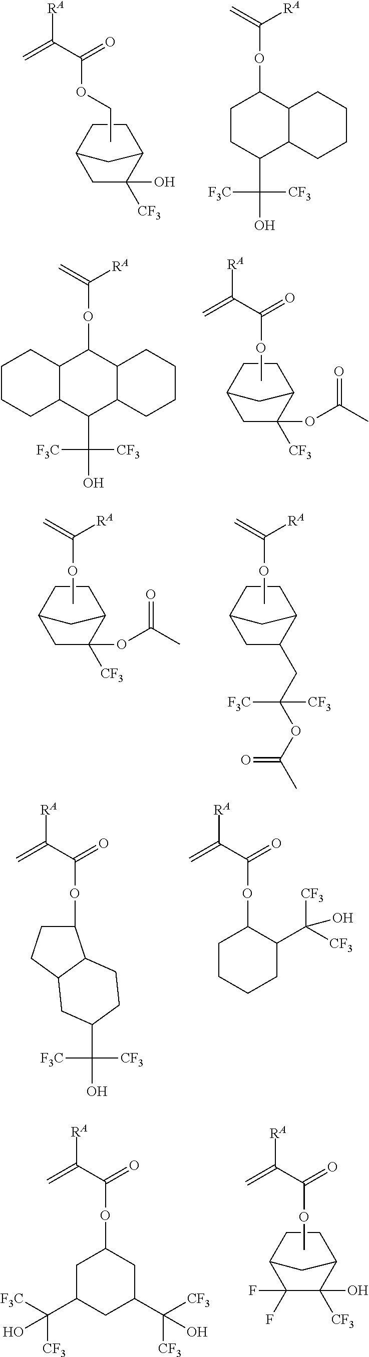

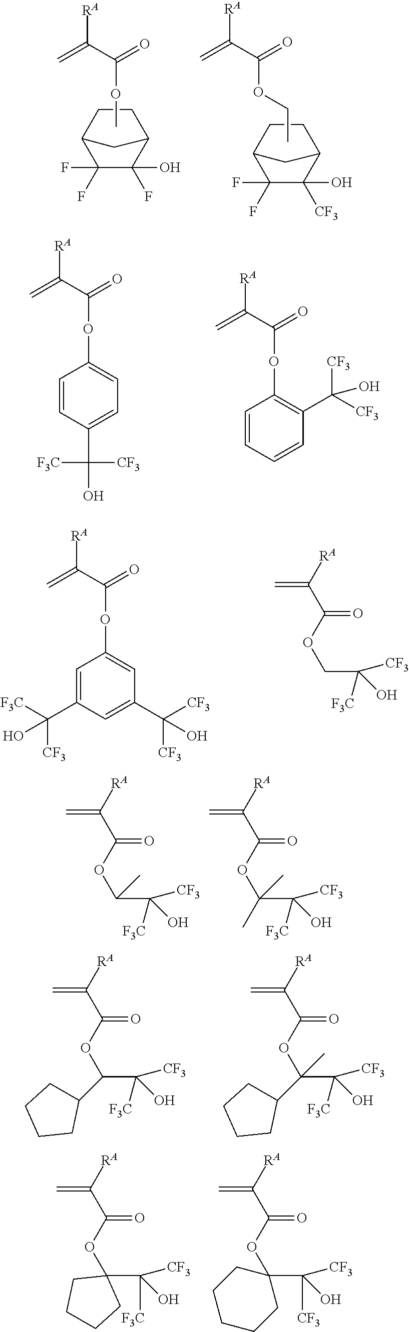

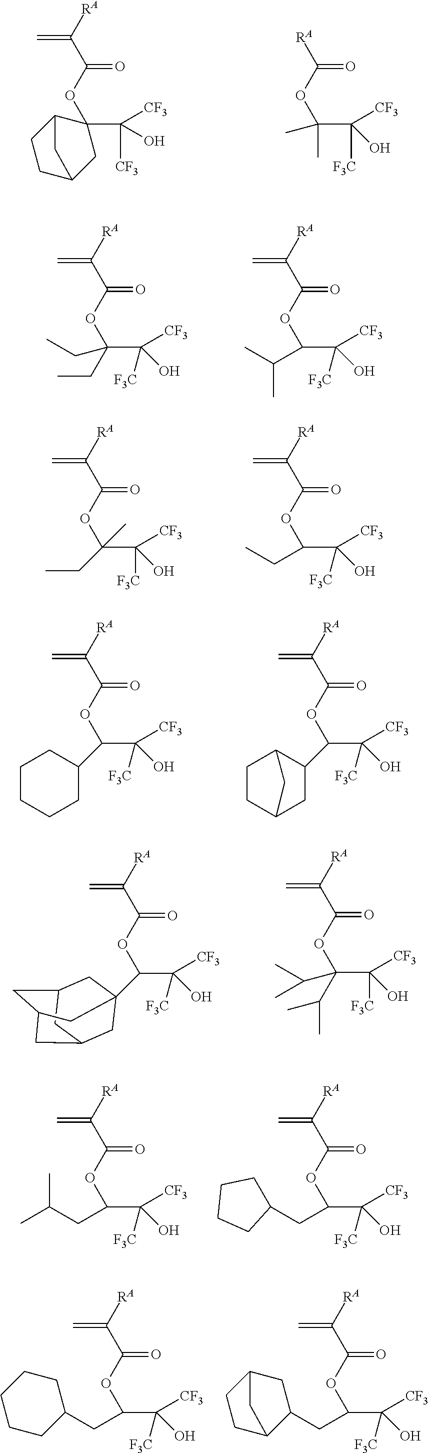

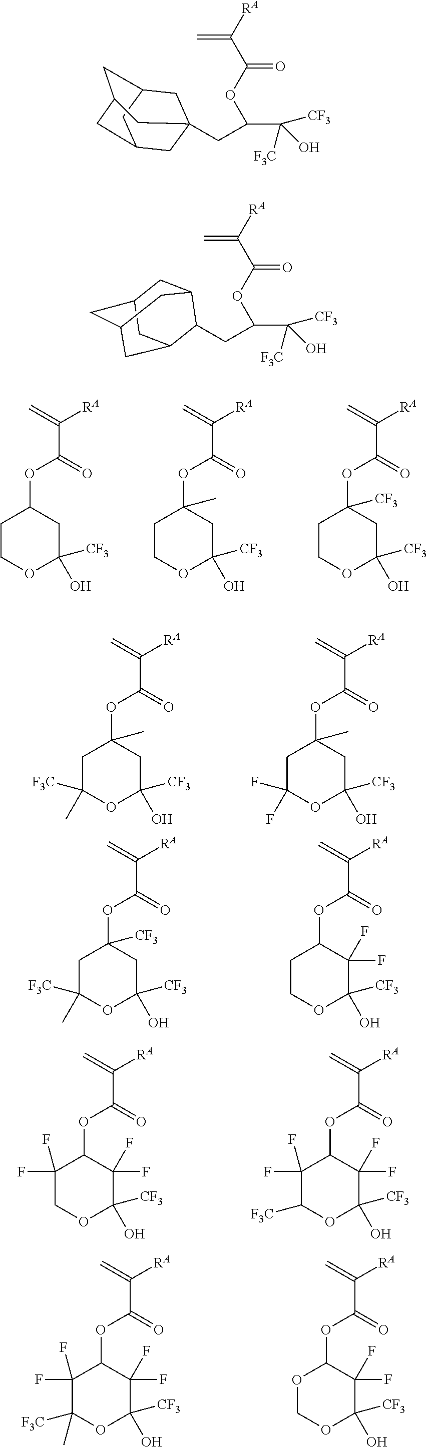

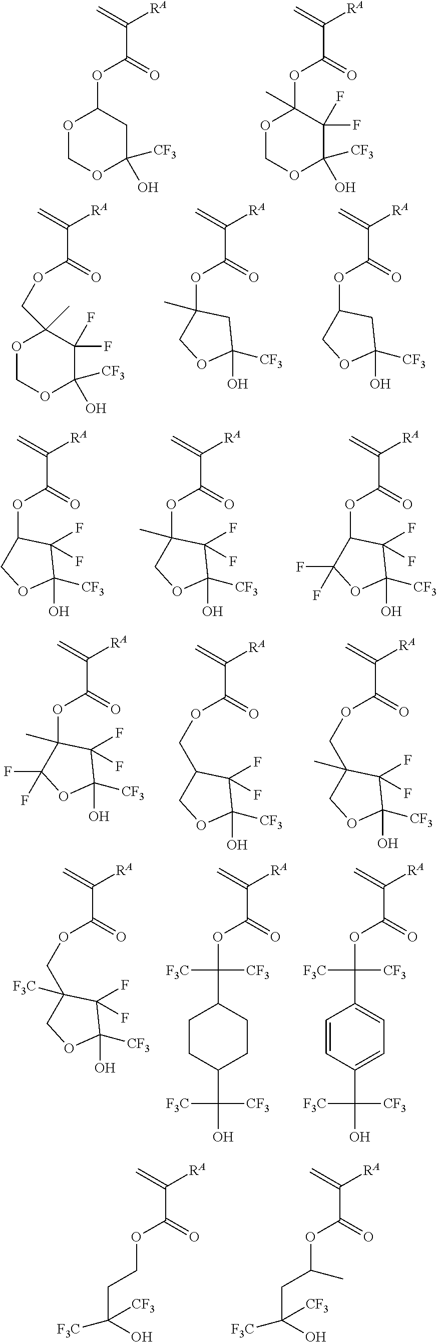

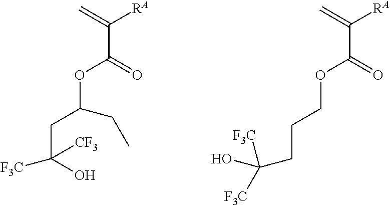

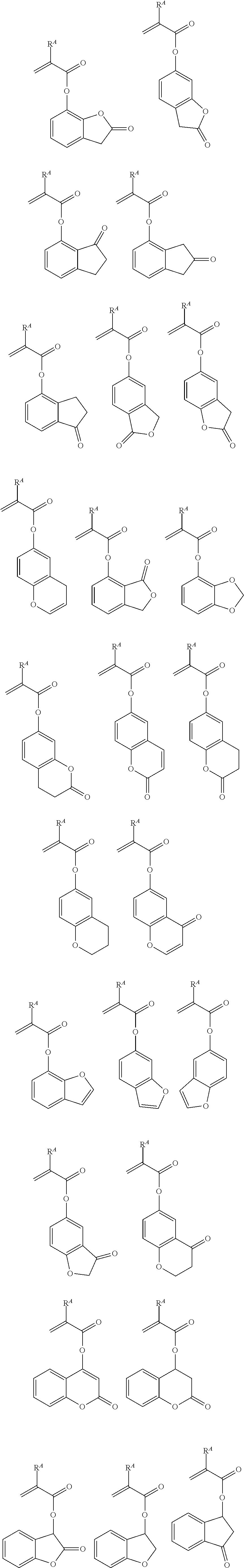

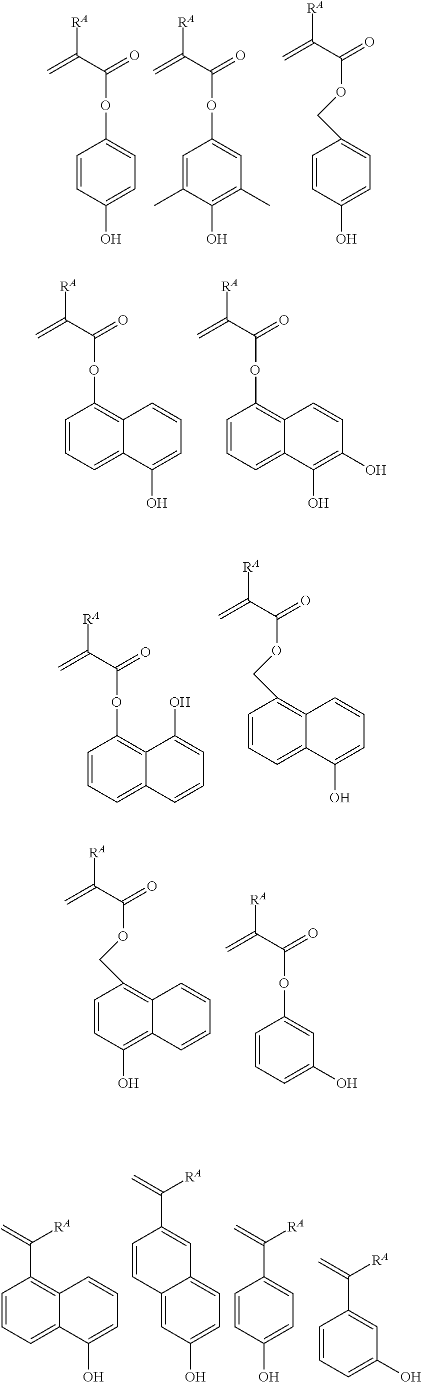

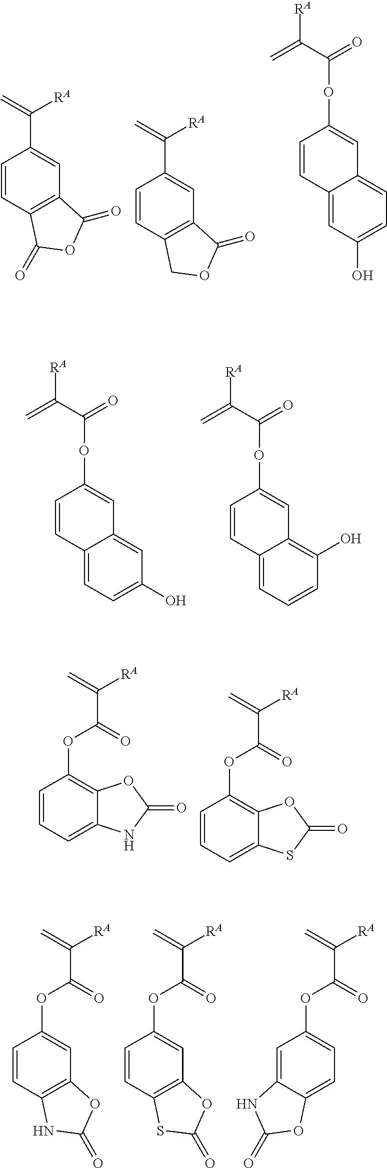

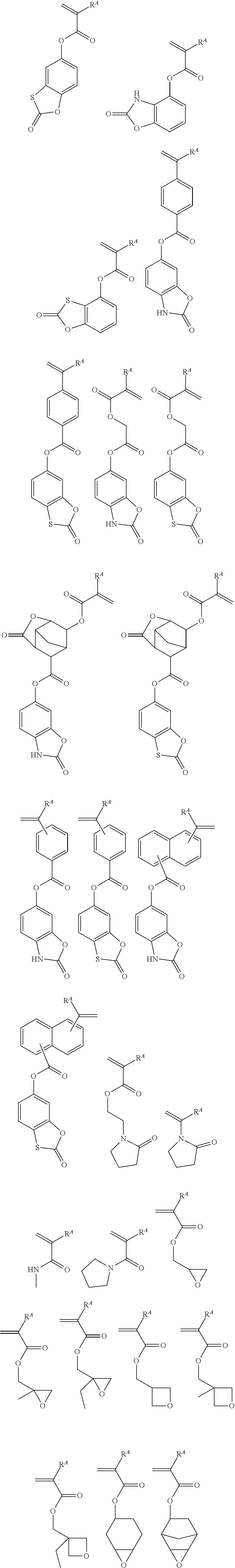

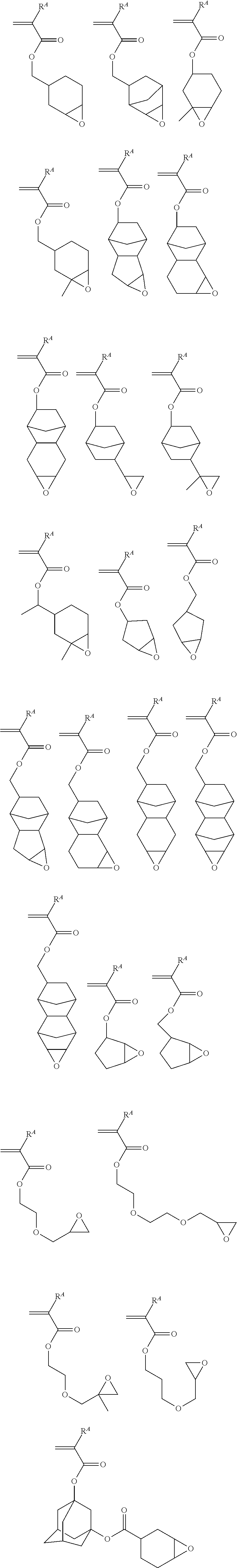

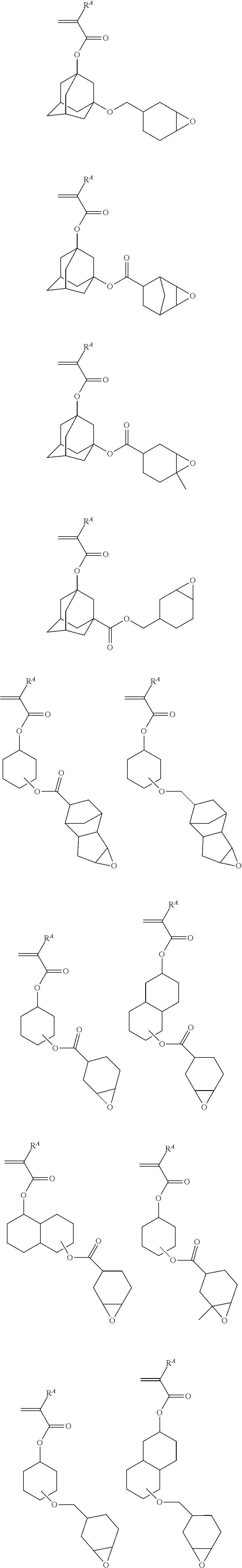

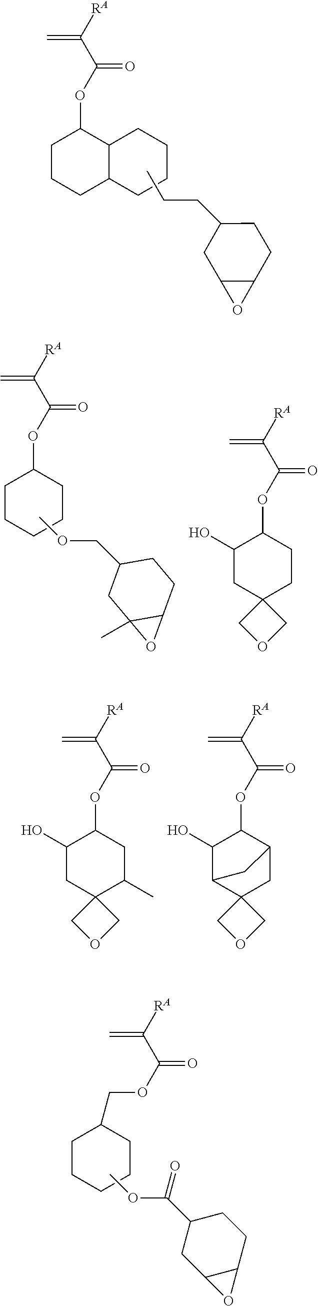

Furthermore, it is also possible to copolymerize a monomer having an adhesive group disclosed in JP 6020477 B2, JP 6028744 B2, JP 6044557 B2, JP 6044566 B2, and JP 6052207 B2.

The base polymer may further contain a repeating unit-d not containing an amino group and containing an iodine atom. Examples of a monomer to give the repeating unit-d include ones shown below, but are not limited thereto. Note that, in the following formulae, R^{A} is as defined above.

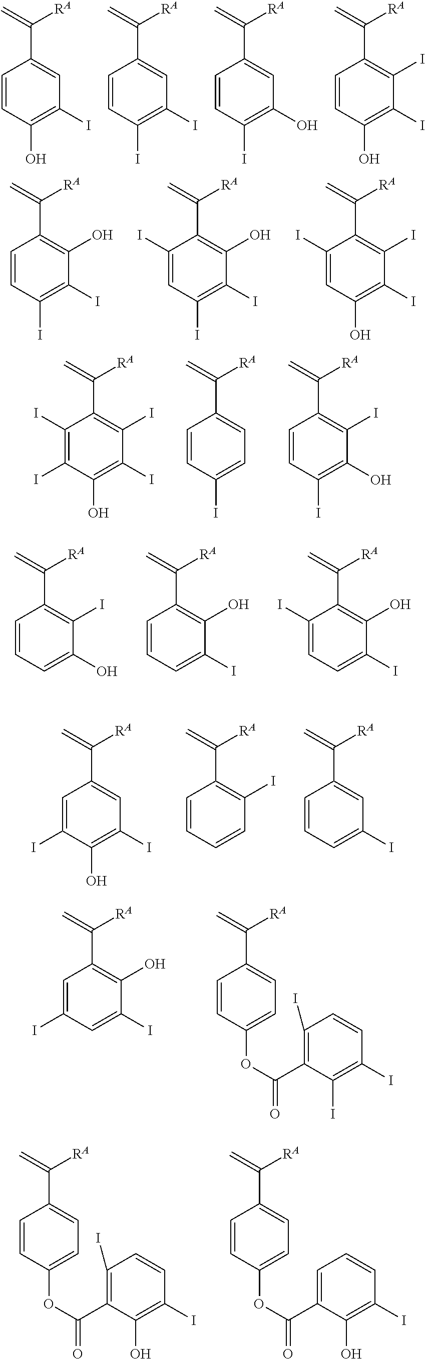

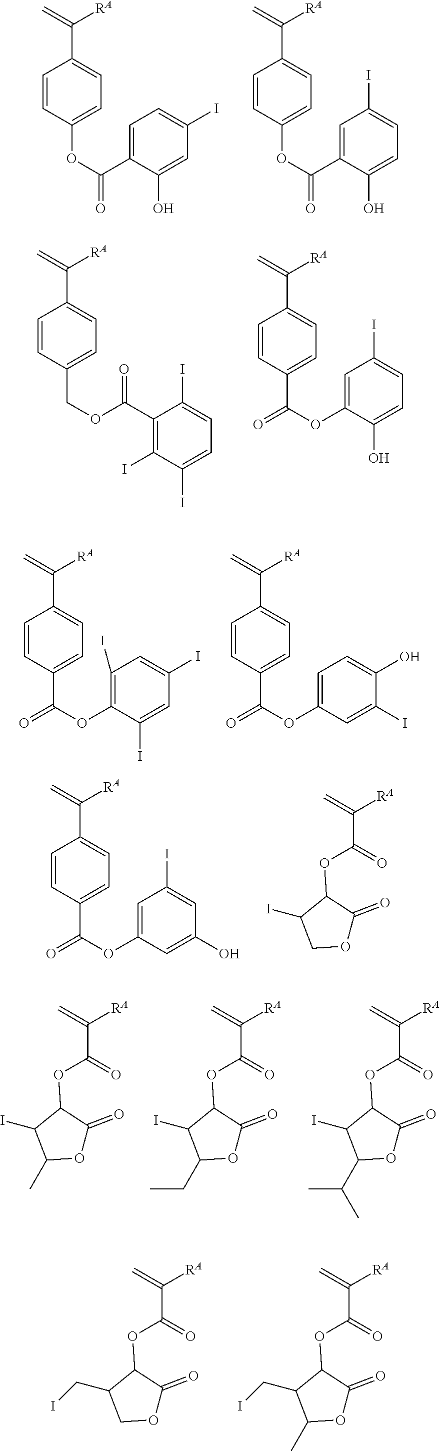

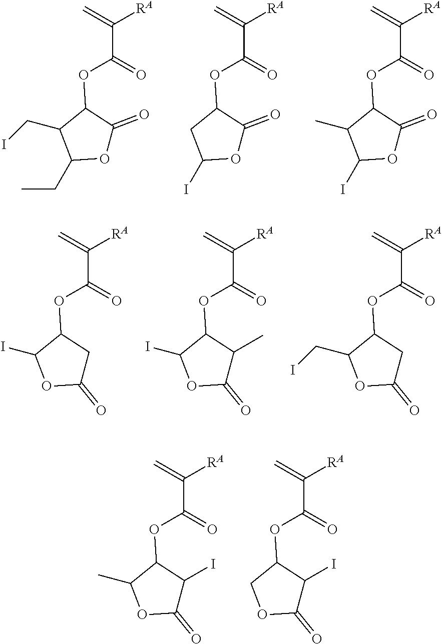

The base polymer may contain a repeating unit-e different from the above-described repeating units. Examples of the repeating unit-e include ones derived from styrene, vinylnaphthalene, indene, acenaphthylene, coumarin, coumarone, etc.

In the base polymer, the content ratios (molar fraction) of the repeating units-a1, -a2, -a3, -b1, -b2, -b3, -b4, -b5, -c, -d, and -e relative to all the repeating units are preferably 0≤a1≤1.0, 0≤a2≤1.0, 0≤a3≤1.0, 0≤a1+a2+a3≤1.0, 0≤b1≤0.8, 0≤b2≤0.8, 0≤b3≤0.8, 0≤b4≤0.8, 0≤b5≤0.8, 0≤b1+b2+b3+b4+b5≤0.8, 0≤c≤0.5, 0≤d≤0.9, and 0≤e≤0.5; more preferably 0≤a1≤0.9, 0≤a2≤0.9, 0≤a3≤0.9, 0.1≤a1+a2+a3≤0.9, 0≤b1≤0.7, 0≤b2 K 0.7, 0≤b3≤0.7, 0≤b4≤0.7, 0≤b5≤0.7, 0≤b1+b2+b3+b4+b5≤0.7, 0≤c≤0.4, 0≤d≤0.8, and 0≤e≤0.4; and further preferably 0≤a1≤0.8, 0≤a2≤0.8, 0≤a3≤0.8, 0.1≤a1+a2+a3≤0.8, 0≤b1≤0.6, 0≤b2≤0.6, 0≤b3≤0.6, 0≤b4≤0.6, 0≤b5≤0.6, 0≤b1+b2+b3+b4+b5≤0.6, 0≤c≤0.35, 0≤d≤0.7, and 0≤e≤0.35, provided that a1+a2+a3+b1+b2+b3+b4+b5+c+d+e=1.0. In the present description, the recitations of numerical ranges by endpoints include all numbers subsumed within that range.

The base polymer may be synthesized, for example, by subjecting the monomers to give the repeating units described above to heat polymerization in an organic solvent to which a radical polymerization initiator has been added.

Examples of the organic solvent used in the polymerization include toluene, benzene, tetrahydrofuran (THF), diethyl ether, dioxane, propylene glycol monomethyl ether, γ-butyrolactone, mixed solvents thereof, etc. Examples of the polymerization initiator include 2,2′-azobisisobutyronitrile (AIBN), 2,2′-azobis(2,4-dimethylvaleronitrile), dimethyl-2,2′-azobis(2-methylpropionate), benzoyl peroxide, lauroyl peroxide, etc. The temperature during the polymerization is preferably 50 to 80° C. The reaction time is preferably 2 to 100 hours, more preferably 5 to 20 hours.

In the case where the monomer containing a hydroxy group is copolymerized, the process may include: substituting the hydroxy group with an acetal group susceptible to deprotection with acid, such as an ethoxyethoxy group, prior to the polymerization; and the deprotection with weak acid and water after the polymerization. Alternatively, the process may include: substituting the hydroxy group with an acetyl group, a formyl group, a pivaloyl group, or the like; and performing alkaline hydrolysis after the polymerization.

In a case where hydroxystyrene or hydroxyvinylnaphthalene is copolymerized, at first, acetoxystyrene or acetoxyvinylnaphthalene may be used in place of hydroxystyrene or hydroxyvinylnaphthalene; after the polymerization, the acetoxy group may be deprotected by the alkaline hydrolysis as described above to convert the acetoxystyrene or acetoxyvinylnaphthalene to hydroxystyrene or hydroxyvinylnaphthalene.

In the alkaline hydrolysis, a base is usable, such as ammonia water or triethylamine. The reaction temperature is preferably −20 to 100° C., more preferably 0 to 60° C. The reaction time is preferably 0.2 to 100 hours, more preferably 0.5 to 20 hours.

The base polymer has a weight-average molecular weight (Mw) in terms of polystyrene of preferably 1,000 to 500,000, more preferably 2,000 to 30,000, determined by gel permeation chromatography (GPC) using THF as an eluent. When the Mw is 1,000 or more, the resist material is provided with excellent heat resistance. When the Mw is 500,000 or less, a footing phenomenon after pattern formation hardly occurs after dry development. Note that number-average molecular weight (Mn) can also be determined by the above-described GPC.

Furthermore, when the base polymer has a wide molecular weight distribution (Mw/Mn), low-molecular-weight and high-molecular-weight polymers are present, and therefore, there are risks of foreign matters appearing on the pattern after the exposure and the degradation of pattern profile. The finer the pattern rule, the stronger the influences of Mw and Mw/Mn. Hence, in order to obtain a resist material suitably used for finer pattern dimensions, the base polymer preferably has a narrow dispersity Mw/Mn of 1.0 to 2.0, particularly preferably 1.0 to 1.5.

To achieve a narrow-dispersity polymer, it is possible to use, not only normal radical polymerization, but also living radical polymerization. Examples of living radical polymerization include living radical polymerization using nitroxide radicals (Nitroxide-Mediated radical Polymerization: NMP), atom transfer radical polymerization (ATRP), and reversible addition-fragmentation chain transfer (RAFT) polymerization.

The base polymer may include two or more polymers having different composition ratios, Mw, and Mw/Mn. Furthermore, a polymer containing a repeating unit-a and a polymer not containing a repeating unit-a may be blended.

### [Organic Solvent]

The inventive resist material may contain an organic solvent. This organic solvent is not particularly limited, as long as it is capable of dissolving the above-described components and components described below. Specific examples of the organic solvent include ones disclosed in paragraphs [0144] and [0145] of JP 2008-111103 A: ketones, such as cyclohexanone, cyclopentanone, methyl-2-n-pentyl ketone, and 2-heptanone; alcohols, such as 3-methoxybutanol, 3-methyl-3-methoxybutanol, 1-methoxy-2-propanol, 1-ethoxy-2-propanol, and diacetone alcohol; ethers, such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters, such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; lactones, such as γ-butyrolactone; etc.

In the inventive resist material, the organic solvent is preferably contained in an amount of 100 to 10000 parts by mass, more preferably 200 to 8000 parts by mass based on 100 parts by mass of the base polymer. One kind of the organic solvent may be used, or two or more kinds thereof may be used in mixture.

### [Quencher]

The inventive resist material may contain a quencher. Note that a quencher means a compound that is capable of preventing, by trapping the acid, an acid that is generated from an acid generator in a resist material from diffusing to unexposed portions.

Examples of the quencher include conventional basic compounds. Specific examples of the conventional basic compounds include primary, secondary, and tertiary aliphatic amines, mixed amines, aromatic amines, heterocyclic amines, nitrogen-containing compounds having a carboxy group, nitrogen-containing compounds having a sulfonyl group, nitrogen-containing compounds having a hydroxy group, nitrogen-containing compounds having a hydroxyphenyl group, alcoholic nitrogen-containing compounds, amides, imides, carbamates, etc. Particularly preferable are primary, secondary, and tertiary amine compounds disclosed in paragraphs [0146] to [0164] of JP 2008-111103 A; especially amine compounds having a hydroxy group, an ether bond, an ester bond, a lactone ring, a cyano group, or a sulfonic acid ester bond; compounds having a carbamate bond disclosed in JP 3790649 B; etc. Adding such a basic compound can, for example, further suppress the acid diffusion rate in the resist film and correct the shape.

Other examples of the quencher include onium salts, such as sulfonium salts, iodonium salts, and ammonium salts of fluorinated alkoxides, carboxylic acids, or sulfonic acids which are not fluorinated at α position as disclosed in JP 2008-158339 A. While α-fluorinated sulfonic acid, imide acid, or methide acid is necessary to deprotect the acid-labile group of carboxylic acid ester, a fluorinated alcohol, carboxylic acid, or sulfonic acid not fluorinated at a position is released by salt exchange with the onium salt. Such fluorinated alcohol, carboxylic acid, and sulfonic acid not fluorinated at a position hardly induce a deprotection reaction, and thus function as quenchers.

Specific examples of such quenchers include a compound shown by the following formula (4) (onium salt of sulfonic acid not fluorinated at a position), a compound shown by the following formula (5) (onium salt of carboxylic acid), and a compound shown by the following formula (6) (onium salt of alkoxide).

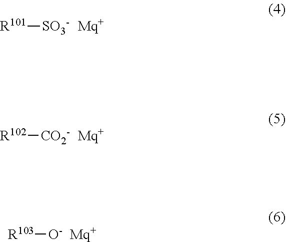

In the formula (4), R¹⁰¹ represents a hydrogen atom or a hydrocarbyl group having 1 to 40 carbon atoms and optionally containing a heteroatom, but excludes groups in which a hydrogen atom bonded to the carbon atom at a position of the sulfo group is substituted with a fluorine atom or a fluoroalkyl group.

The hydrocarbyl group having 1 to 40 carbon atoms represented by R¹⁰¹ may be saturated or unsaturated, and may be linear, branched, or cyclic. Specific examples thereof include: alkyl groups having 1 to 40 carbon atoms, such as a methyl group, an ethyl group, an n-propyl group, an isopropyl group, an n-butyl group, an isobutyl group, a sec-butyl group, a tert-butyl group, an n-pentyl group, a tert-pentyl group, an n-hexyl group, an n-octyl group, a 2-ethylhexyl group, an n-nonyl group, and an n-decyl group; cyclic saturated hydrocarbyl groups having 3 to 40 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decyl group, an adamantyl group, and an adamantylmethyl group; alkenyl groups having 2 to 40 carbon atoms, such as a vinyl group, an allyl group, a propenyl group, a butenyl group, and a hexenyl group; cyclic unsaturated aliphatic hydrocarbyl groups having 3 to 40 carbon atoms, such as a cyclohexenyl group; aryl groups having 6 to 40 carbon atoms, such as a phenyl group, a naphthyl group, alkylphenyl groups (such as a 2-methylphenyl group, a 3-methylphenyl group, a 4-methylphenyl group, a 4-ethylphenyl group, a 4-tert-butylphenyl group, and a 4-n-butylphenyl group), dialkylphenyl groups or trialkylphenyl groups (such as a 2,4-dimethylphenyl group and a 2,4,6-triisopropylphenyl group), alkylnaphthyl groups (such as a methylnaphthyl group and an ethylnaphthyl group), and dialkylnaphthyl groups (such as a dimethylnaphthyl group and a diethylnaphthyl group); aralkyl groups having 7 to 40 carbon atoms, such as a benzyl group, a 1-phenylethyl group, and a 2-phenylethyl group; etc.

Moreover, part or all of the hydrogen atoms of the hydrocarbyl groups may be substituted with a group containing a heteroatom, such as an oxygen atom, a sulfur atom, a nitrogen atom, or a halogen atom, and part of the —CH₂— of the hydrocarbyl groups may be substituted with a group containing a heteroatom, such as an oxygen atom, a sulfur atom, or a nitrogen atom. Thus, the resulting hydrocarbyl group may contain a hydroxy group, a cyano group, a carbonyl group, an ether bond, an ester bond, a sulfonic acid ester bond, a carbonate bond, a lactone ring, a sultone ring, carboxylic anhydride (—C(═O)—O—C(═O)—), a haloalkyl group, etc. Specific examples of the hydrocarbyl group containing a heteroatom include: heteroaryl groups, such as a thienyl group; alkoxyphenyl groups, such as a 4-hydroxyphenyl group, a 4-methoxyphenyl group, a 3-methoxyphenyl group, a 2-methoxyphenyl group, a 4-ethoxyphenyl group, a 4-tert-butoxyphenyl group, and a 3-tert-butoxyphenyl group; alkoxynaphthyl groups, such as a methoxynaphthyl group, an ethoxynaphthyl group, an n-propoxynaphthyl group, and an n-butoxynaphthyl group; dialkoxynaphthyl groups, such as a dimethoxynaphthyl group and a diethoxynaphthyl group; aryloxoalkyl groups, such as 2-aryl-2-oxoethyl groups including a 2-phenyl-2-oxoethyl group, a 2-(1-naphthyl)-2-oxoethyl group, and a 2-(2-naphthyl)-2-oxoethyl group; etc.

In the formula (5), R¹⁰² represents a hydrocarbyl group having 1 to 40 carbon atoms and optionally containing a heteroatom. Specific examples of the hydrocarbyl group represented by R¹⁰² include those exemplified as the hydrocarbyl group represented by R¹⁰¹. Other specific examples thereof include fluorinated alkyl groups, such as a trifluoromethyl group, a trifluoroethyl group, a 2,2,2-trifluoro-1-methyl-1-hydroxyethyl group, and a 2,2,2-trifluoro-1-(trifluoromethyl)-1-hydroxyethyl group; fluorinated aryl groups, such as a pentafluorophenyl group and a 4-trifluoromethylphenyl group; etc.

In the formula (6), R¹⁰³ represents a saturated hydrocarbyl group having 1 to 8 carbon atoms and having at least three fluorine atoms or represents an aryl group having 6 to 10 carbon atoms and having at least three fluorine atoms, and optionally contains a nitro group.

In the formulae (4), (5), and (6), Mq⁺ represents an onium cation. The onium cation is preferably a sulfonium cation, an iodonium cation, or an ammonium cation, more preferably a sulfonium cation. Specific examples of the sulfonium cation include those given as examples of the sulfonium cation represented by M⁺ in the description of the formulae (b2) to (b5).

A sulfonium salt of a carboxylic acid containing an iodized benzene ring shown by the following formula (7) can also be used suitably as the quencher.

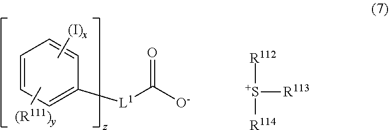

In the formula (7), “x” represents an integer of 1 to 5. “y” represents an integer of 0 to 3. “z” represents an integer of 1 to 3.

In the formula (7), R¹¹¹ represents a hydroxy group, a fluorine atom, a chlorine atom, a bromine atom, an amino group, a nitro group, a cyano group, —N(R^{111A})—C(═O)—R^{111B}, or —N(R^{111A})—C(═O)—O—R^{111B}; or a saturated hydrocarbyl group having 1 to 6 carbon atoms, a saturated hydrocarbyloxy group having 1 to 6 carbon atoms, a saturated hydrocarbylcarbonyloxy group having 2 to 6 carbon atoms, or a saturated hydrocarbylsulfonyloxy group having 1 to 4 carbon atoms, the groups optionally having part or all of hydrogen atoms substituted with a halogen atom. R^{111A} represents a hydrogen atom or a saturated hydrocarbyl group having 1 to 6 carbon atoms. R^{111B} represents a saturated hydrocarbyl group having 1 to 6 carbon atoms or an unsaturated aliphatic hydrocarbyl group having 2 to 8 carbon atoms. When “y” and/or “z” is 2 or more, the R¹¹¹'s may be identical to or different from each other.

In the formula (7), L¹ represents a single bond or a linking group having a valency of z+1 and having 1 to 20 carbon atoms, and optionally contains at least one selected from an ether bond, a carbonyl group, an ester bond, an amide bond, a sultone ring, a lactam ring, a carbonate bond, a halogen atom, a hydroxy group, and a carboxy group. The saturated hydrocarbyl group, saturated hydrocarbyloxy group, saturated hydrocarbylcarbonyloxy group, and saturated hydrocarbylsulfonyloxy group may be linear, branched, or cyclic.

In the formula (7), R¹¹², R¹¹³, and R¹¹⁴ each independently represent a halogen atom or a hydrocarbyl group having 1 to 20 carbon atoms and optionally containing a heteroatom. The hydrocarbyl group may be saturated or unsaturated and may be linear, branched, or cyclic.

Specific examples of the compound represented by the formula (7) include ones disclosed in JP 2017-219836 A and JP 2021-91666 A.

Other examples of the quencher include polymer-type quenchers disclosed in JP 2008-239918 A. The quenchers enhance the rectangularity of a resist pattern by being oriented on the resist film surface. The polymer-type quencher also has effects of preventing rounding of a pattern top and film thickness loss of a pattern when a top coat for immersion exposure is applied.

Furthermore, it is also possible to use, as a quencher: betaine type sulfonium salts disclosed in JP 6848776 B2 and JP 2020-37544 A; methide acids containing no fluorine atoms disclosed in JP 2020-55797 A; sulfonium salts of sulfonamides disclosed in JP 5807552 B2; sulfonium salts of sulfonamides containing an iodine atom disclosed in JP 2019-211751 A; phenol; halogen; and acid generators that generate carbonic acid.

When the inventive resist material contains the quencher, the contained amount is preferably 0 to 5 parts by mass, more preferably 0 to 4 parts by mass based on 100 parts by mass of the base polymer. One kind of the quencher may be used, or two or more kinds thereof may be used in combination.

### [Other Components]

In addition to the above-described components, an acid generator (hereinafter, also referred to as an externally added acid generator), a surfactant, a water-repellency enhancer, an acetylene alcohol, etc. may be contained.

Examples of the acid generator include compounds that generate acids in response to actinic light or radiation (photo-acid generator). The photo-acid generator component is not particularly limited, as long as the compound generates an acid upon high-energy beam irradiation. Preferably, the photo-acid generator generates a sulfonic acid, imide acid, or methide acid. Specific examples of suitable photo-acid generators include sulfonium salt, iodonium salt, sulfonyldiazomethane, N-sulfonyloxyimide, oxime-O-sulfonate type acid generators, etc. Specific examples of the acid generator include ones disclosed in paragraphs [0122] to [0142] of JP 2008-111103 A, JP 2018-5224 A, and JP 2018-25789 A. When the inventive resist material contains an externally added acid generator, the contained amount is preferably 0 to 200 parts by mass, preferably 0.1 to 100 parts by mass based on 100 parts by mass of the base polymer.

Specific examples of the surfactant include ones disclosed in paragraphs [0165] and [0166] of JP 2008-111103 A. Adding a surfactant can further enhance or control the coatability of the resist material. When the inventive resist material contains a surfactant, the contained amount is preferably 0.0001 to 10 parts by mass based on 100 parts by mass of the base polymer. One kind of the surfactant may be used, or two or more kinds thereof may be used in combination.

The water-repellency enhancer improves the water-repellency of the resist film surface, and can be employed in immersion lithography with no top coat. The water-repellency enhancer is preferably a polymer containing a fluorinated alkyl group, a polymer containing a 1,1,1,3,3,3-hexafluoro-2-propanol residue with a particular structure, etc., preferably ones exemplified in JP 2007-297590 A, JP 2008-111103 A, etc. The water-repellency enhancer needs to be dissolved in an alkali developer or an organic solvent developer. The water-repellency enhancer having a particular 1,1,1,3,3,3-hexafluoro-2-propanol residue mentioned above has favorable solubility to developers. A polymer containing a repeating unit with an amino group or amine salt as a water-repellency enhancer exhibits high effects of preventing acid evaporation during PEB and opening failure of a hole pattern after development. When the inventive resist material contains the water-repellency enhancer, the contained amount is preferably 0 to 20 parts by mass, more preferably 0.5 to 10 parts by mass based on 100 parts by mass of the base polymer. One kind of the water-repellency enhancer may be used, or two or more kinds thereof may be used in combination.

Specific examples of the acetylene alcohol include ones disclosed in paragraphs [0179] to [0182] of JP 2008-122932 A. When the inventive resist material contains the acetylene alcohol, the contained amount is preferably 0 to 5 parts by mass based on 100 parts by mass of the base polymer. One kind of the acetylene alcohol may be used, or two or more kinds thereof may be used in combination.

### [Patterning Process]

When the inventive resist material is used for manufacturing various integrated circuits, known lithography techniques can be applied as necessary. Examples of patterning processes include the steps of: forming a resist film on a substrate by using the above-described resist material; exposing the resist film to a high-energy beam; and baking the exposed resist film and forming a pattern through dry etching.

For example, the inventive resist material is applied onto a substrate (such as Si, SiO₂, SiN, SiON, SiC, TiN, WSi, BPSG, SOG, organic antireflective film, or carbon film) for manufacturing an integrated circuit or a substrate (such as Cr, CrO, CrON, MoSi₂, or SiO₂) for manufacturing a mask circuit by an appropriate coating process, such as spin coating, roll coating, flow coating, dip coating, spray coating, or doctor coating, so that the coating film has a thickness of 0.01 to 2 μm. The resultant is prebaked on a hot plate preferably at 60 to 150° C. for 10 seconds to 30 minutes, more preferably at 80 to 120° C. for 30 seconds to 20 minutes. In this manner, a resist film can be formed.

The substrate may be a multilayer film in which an inorganic film or the like containing Si, Ti, Hf, Sn, W, etc. is laminated under a carbon-based film. The substrate may also have a structure in which a carbon-based film is further laminated under the inorganic film.

Subsequently, the resist film is exposed by using a high-energy beam. Specific examples of the high-energy beam include ultraviolet ray, deep ultraviolet ray, EB, EUV having a wavelength of 3 to 15 nm, X-ray, soft X-ray, excimer laser beam, γ-ray, and synchrotron radiation. When ultraviolet ray, deep ultraviolet ray, EUV, X-ray, soft X-ray, excimer laser beam, γ-ray, synchrotron radiation, or the like is employed as the high-energy beam, the irradiation is performed directly or while using a mask for forming a target pattern at an exposure dose of preferably about 1 to 200 mJ/cm², more preferably about 10 to 100 mJ/cm². When an EB is employed as the high-energy beam, the exposure dose is preferably about 0.1 to 300 μC/cm², more preferably about 0.5 to 200 μC/cm², and the writing is performed directly or while using a mask for forming a target pattern. As stated above, the inventive resist material is particularly suitable for fine patterning with a KrF excimer laser beam, an ArF excimer laser beam, an EB, EUV, X-ray, soft X-ray, γ-ray, or synchrotron radiation, among the high-energy beams, and is especially suitable for fine patterning with EB or EUV.

Specific examples include: patterning processes in which exposure is performed with an extreme ultraviolet ray having a wavelength of 3 to 15 nm; and patterning processes in which exposure is performed with an electron beam with an acceleration voltage of 1 to 150 kV.

The exposure may be followed by PEB on a hot plate or in an oven preferably at 30 to 150° C. for 10 seconds to 30 minutes, more preferably at 50 to 120° C. for 30 seconds to 20 minutes. The acid-labile groups containing silicon undergo deprotection due to a deprotection reaction during PEB, and the deprotection component containing silicon evaporates from within the film.

As described above, dry etching is performed after the PEB and the exposed portions are etched to open space portions. For the dry etching, preferably used are gases containing oxygen, hydrogen, ammonia, etc. and containing nitrogen, helium, argon, carbon dioxide, or carbon monoxide for dilution.

After the development, a hole pattern or trench pattern can be shrunk by thermal flow, RELACS process, or DSA process. A shrink agent is applied onto the hole pattern, and the shrink agent undergoes crosslinking on the resist film surface by diffusion of the acid catalyst from the resist film during baking, so that the shrink agent is attached to sidewalls of the hole pattern. The baking temperature is preferably 70 to 180° C., more preferably 80 to 170° C. The baking time is preferably 10 to 300 seconds. The extra shrink agent is removed, and thus the hole pattern is shrunk.

As described above, the present invention includes: forming a resist film by using a resist material containing a base polymer having a silicon-containing acid-labile group; and subjecting the resist film to exposure and baking, and then to development by dry etching to form a pattern.

By using a resist material containing, as a base, a polymer having a repeating unit substituted with an acid-labile group having a silicon atom, unexposed portions can provide a portion having silicon-containing groups, and exposed portions can provide a portion where the contained amount of silicon is reduced by deprotection. When this is dry-etched by using a gas that reacts selectively with silicon-containing groups, the etching rate in the unexposed portions is decreased and the etching rate in the exposed portions is increased, thus increasing the selectivity of the etching rate between the exposed portions and the unexposed portions. By making use of the difference in etching rate achieved by this selective etching, a fine pattern can be formed with a high aspect ratio.

As described, in the inventive patterning process, an acid is generated in a resist film by exposure, the acid-labile group containing silicon in the polymer undergoes deprotection and the silicon content is reduced, and exposed portions are opened by dry etching to form a pattern. In particular, when performing dry etching with using an oxidation reaction-based gas, such as oxygen, for example, etching with a gas containing oxygen, silicon-containing groups form silicon dioxide and the etching rate decreases in unexposed portions, but on the other hand, in exposed portions, the silicon content decreases, and therefore, the etching rate increases. Thus, positive patterns are formed by the difference in etching rate between exposed portions and unexposed portions being large. Development by dry etching makes it possible to form a fine pattern with a high aspect ratio, since pattern collapse due to capillary force does not occur.

In the case of a resist material containing a large amount of fluorine or iodine, which have high water repellency and hardly dissolve in an alkaline developer, a residue is generated after alkaline development in some cases. If a residue is generated in a space portion of an opening in a resist, the residue may cause a defect. In particular, a residue is likely to be generated in a pattern having a narrow pitch. According to the dry development of the present invention, the generation of residues can be suppressed, and defects in narrow-pitch patterns can be reduced.

The inventive patterning process has a high technical value in that it can provide a patterning process that does not cause pattern collapse or pattern deformation in accordance with the progress in the miniaturization of pattern rule that accompanies higher integration and higher processing speed of LSIs. Such a patterning process has been desired in the present technical field.

### EXAMPLES

Hereinafter, the present invention will be specifically described with reference to Synthesis Examples, Preparation Examples, Examples, and Comparative Examples, but the present invention is not limited to the following Examples.

### [Synthesis Example] Synthesis of Base Resins

A copolymerization reaction was performed in THF with a combination of the monomers, a crystal was precipitated in methanol, furthermore, washing with hexane was repeated, and then isolation and drying were performed to synthesize base resins (Polymers 1 to 12 and Comparative Polymer 1) having the composition shown below. The composition of the obtained base resins was confirmed by 1H-NMR and Mw and Mw/Mn were confirmed by GPC (eluent: THF, standard: polystyrene).

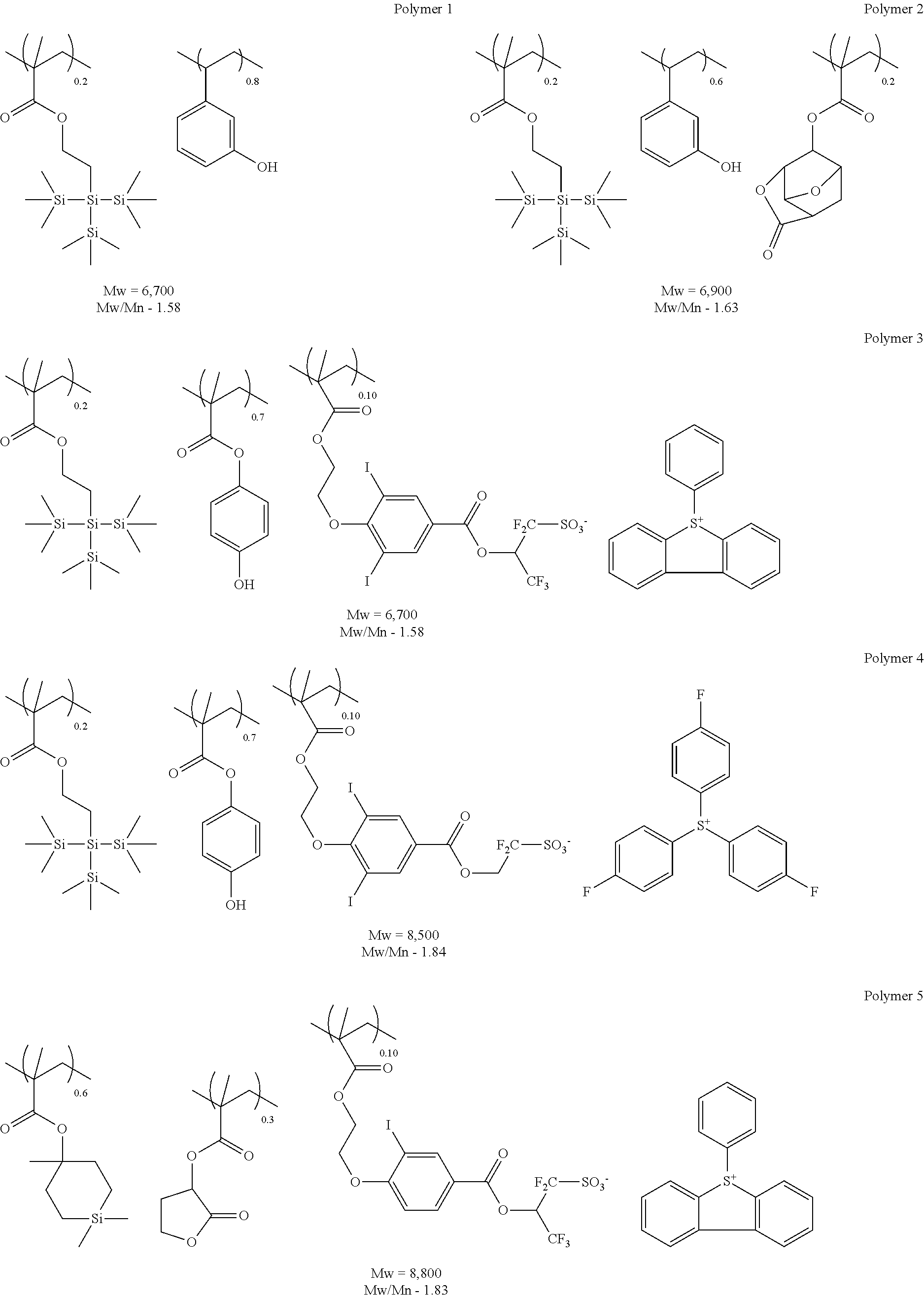

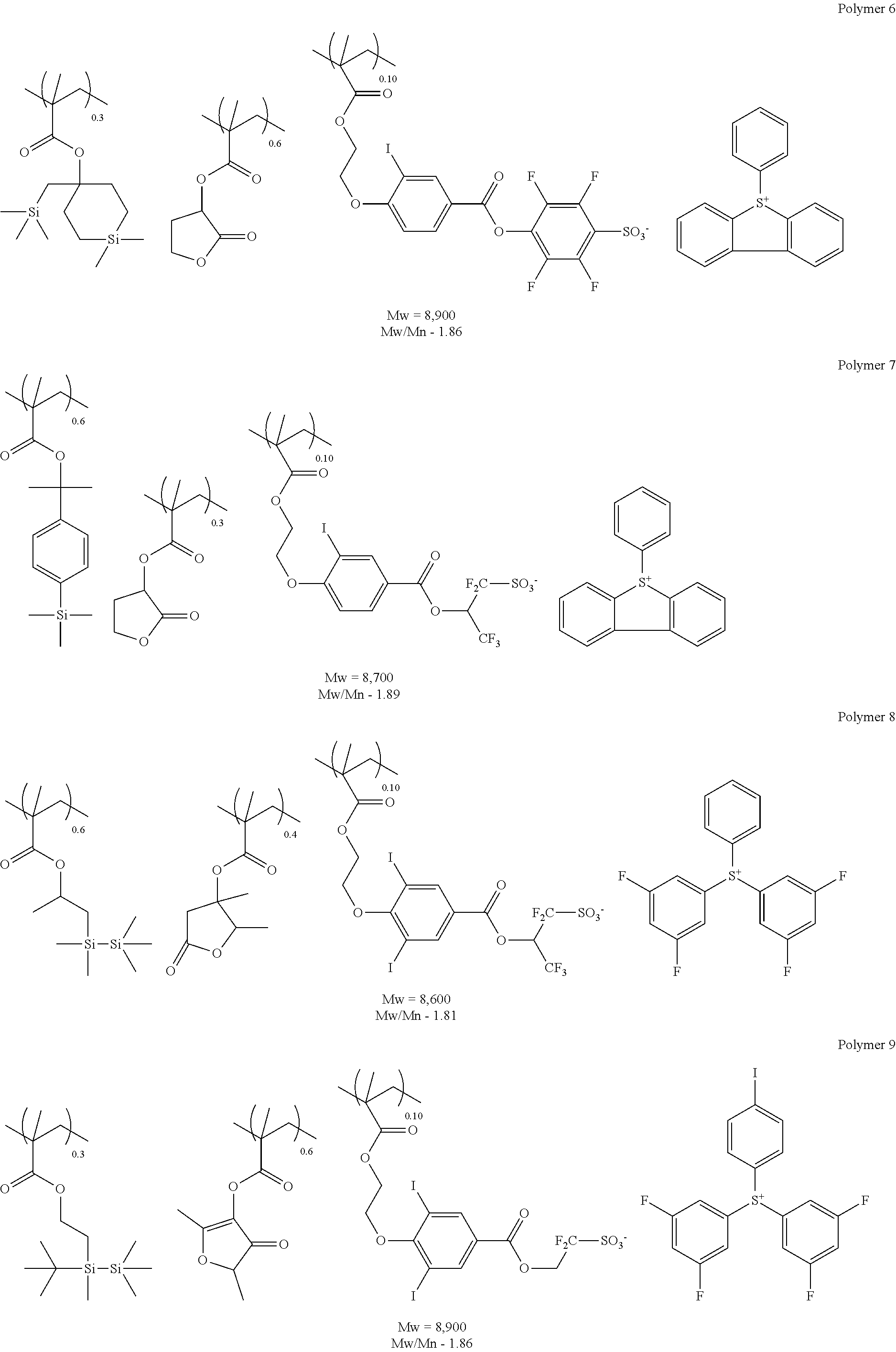

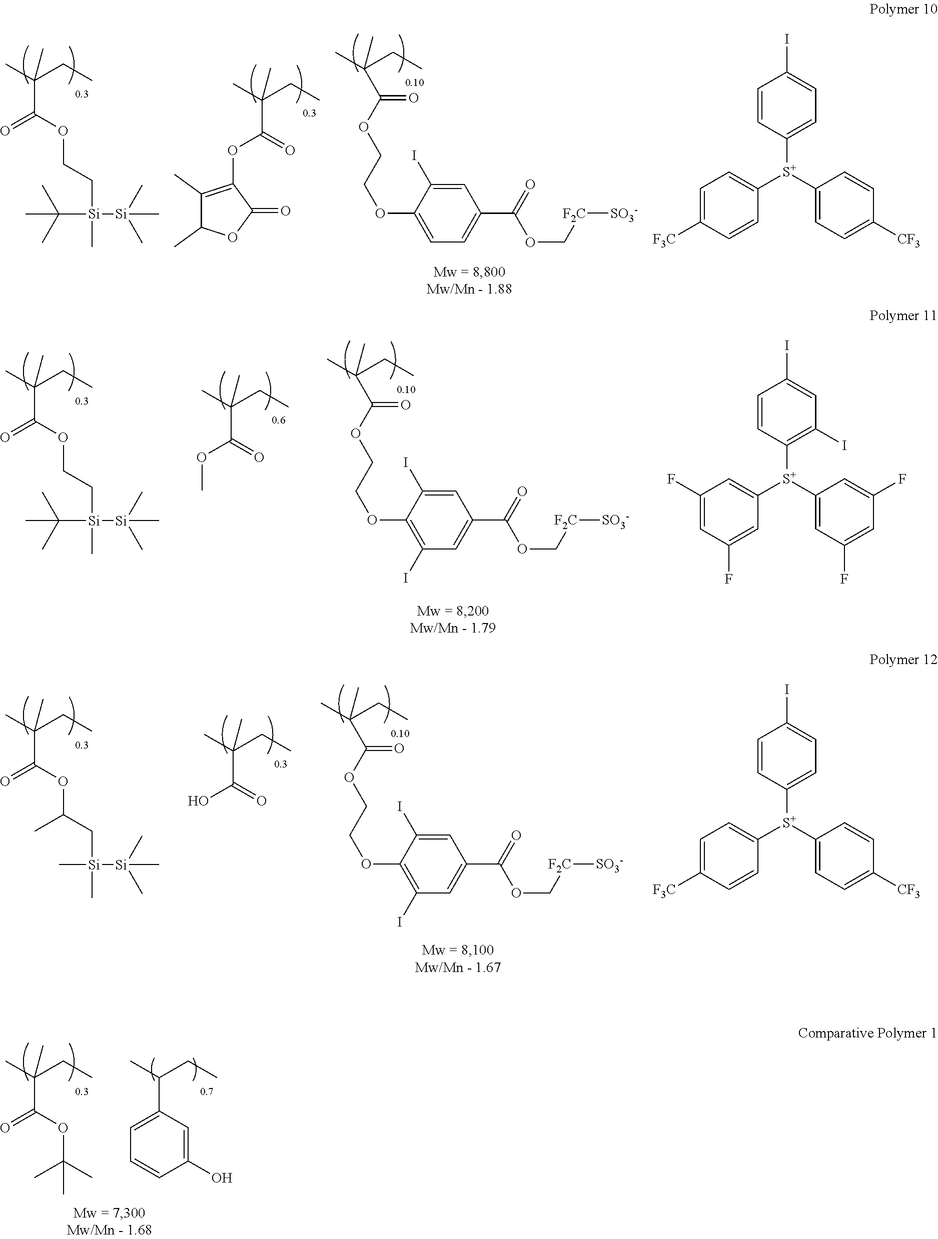

### [Preparation Examples 1 to 12 and Comparative Preparation Example 1] Preparation of Resist Materials

According to the composition shown in Table 1, components were dissolved in a solvent in which 50 ppm of a surfactant Polyfox636, manufactured by OMNOVA Solutions Inc., had been dissolved. The resulting solution was filtered through a filter having a pore size of 0.2 μm. In this manner, positive resist materials were prepared.

The components in Table 1 are as follows.
Acid generators: PAG-1 and PAG-2

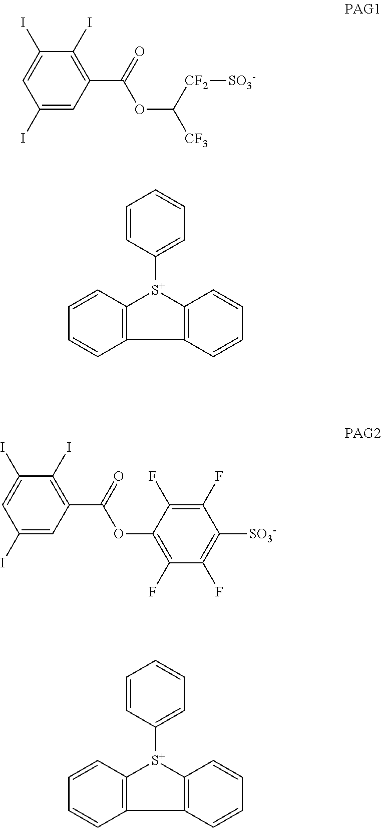

Quenchers: quenchers 1 to 3

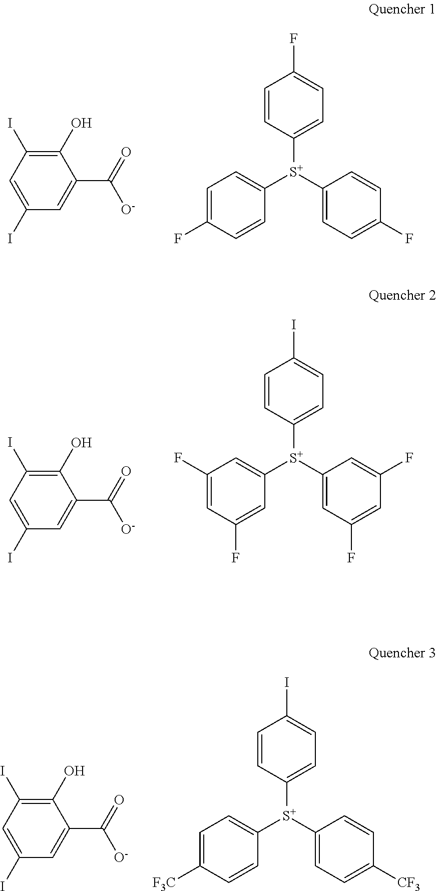 [SMILES: O=C([O-])c1cc(I)cc(I)c1O ; Fc1ccc([S+](c2ccc(F)cc2)c2ccc(F)cc2)cc1 ; O=C([O-])c1cc(I)cc(I)c1O ; Fc1cc(F)cc([S+](c2ccc(I)cc2)c2cc(F)cc(F)c2)c1 ; O=C([O-])c1cc(I)cc(I)c1O ; FC(F)(F)c1ccc([S+](c2ccc(I)cc2)c2ccc(C(F)(F)F)cc2)cc1]

Organic solvents:
   PGMEA (propylene glycol monomethyl ether acetate)
   DAA (diacetone alcohol)

TABLE 1

| | Resist | Polymer | Acid generator | Quencher | Organic solvent |
|---|---|---|---|---|---|
| | material | (parts by mass) | (parts by mass) | (parts by mass) | (parts by mass) |
| Preparation | R-1 | Polymer 1 | PAG-1 | Quencher 1 | PGMEA (1,400) |
| Example 1 | | (100) | (20.0) | (6.0) | DAA (400) |
| Preparation | R-2 | Polymer 2 | PAG-2 | Quencher 1 | PGMEA (1,400) |
| Example 2 | | (100) | (20.0) | (6.0) | DAA (400) |
| Preparation | R-3 | Polymer 3 | — | Quencher 1 | PGMEA (1,400) |
| Example 3 | | (100) | | (6.0) | DAA (400) |
| Preparation | R-4 | Polymer 4 | — | Quencher 1 | PGMEA (1,400) |
| Example 4 | | (100) | | (6.0) | DAA (400) |
| Preparation | R-5 | Polymer 5 | — | Quencher 1 | PGMEA (1,400) |
| Example 5 | | (100) | | (6.0) | DAA (400) |
| Preparation | R-6 | Polymer 6 | — | Quencher 1 | PGMEA (1,400) |
| Example 6 | | (100) | | (6.0) | DAA (400) |
| Preparation | R-7 | Polymer 7 | — | Quencher 1 | PGMEA (1,400) |
| Example 7 | | (100) | | (6.0) | DAA (400) |
| Preparation | R-8 | Polymer 8 | — | Quencher 1 | PGMEA (1,400) |
| Example 8 | | (100) | | (6.0) | DAA (400) |
| Preparation | R-9 | Polymer 9 | — | Quencher 2 | PGMEA (1,400) |
| Example 9 | | (100) | | (8.5) | DAA (400) |
| Preparation | R-10 | Polymer 10 | — | Quencher 3 | PGMEA (1,400) |
| Example 10 | | (100) | | (9.1) | DAA (400) |
| Preparation | R-11 | Polymer 11 | — | Quencher 3 | PGMEA (1,400) |
| Example 11 | | (100) | | (9.1) | DAA (400) |
| Preparation | R-12 | Polymer 12 | — | Quencher 3 | PGMEA (1,400) |
| Example 12 | | (100) | | (9.1) | DAA (400) |
| Comparative | CR-1 | Comparative | PAG-1 | Quencher 1 | PGMEA (1,400) |
| Preparation | | polymer 1 | (20.0) | (6.0) | DAA (400) |
| Example 1 | | (100) | | | |

### [Examples 1-1 to 1-12 and Comparative Example 1-1] KrF Exposure, Dry Etching Evaluation

Each of the resist materials (R-1 to R-12 and CR-1) was respectively applied by spin-coating onto a Si substrate on which an antireflective film DUV-42 manufactured by Nissan Chemical Corporation had been formed with a film thickness of 60 nm, and was prebaked by using a hot plate at 105° C. for 60 seconds to prepare a resist film with a film thickness of 140 nm. The resist film was exposed in a 90-nm line-and-space pattern by using a KrF excimer scanner (XT860N, NA: 0.8, dipole illumination, 6% halftone phase shift mask) manufactured by ASML, followed by PEB on the hot plate at the temperature shown in Table 2 for 60 seconds.

The wafers after the PEB were etched under the following conditions by using a dry etching apparatus Telius manufactured by Tokyo Electron Ltd.

| | | |
|---|---|---|
| Chamber pressure | 12.0 | Pa |
| RF-power | 600 | W |
| Bias power | 50 | W |
| Stage temperature | 25° | C. |
| O₂ gas flow rate | 60 | sccm |
| N₂ gas flow rate | 200 | sccm |
| Time | 30 | sec |

The resist film and the antireflective film in the exposed portions were allowed to undergo film loss by dry etching, and the dry etching was performed until the surface of the Si substrate appeared.

Using a CD-SEM CG-6300 manufactured by Hitachi High-Technologies Corporation, the exposure dose at which 90-nm lines and spaces are formed at 1:1 was obtained as the sensitivity of the resist, the wafer was cut, and the cross section of the 90-nm line-and-space pattern was observed with an electron microscope S-4100 manufactured by Hitachi High-Technologies Corporation.

The results are shown together in Table 2.

TABLE 2

| | | PEB | | Cross- |
|---|---|---|---|---|
| | | temperature | Sensitivity | sectional |
| | Resist | (° C.) | (mJ/cm²) | profile |
| Example 1-1 | R-1 | 90 | 77 | Rectangular |
| Example 1-2 | R-2 | 90 | 86 | Rectangular |
| Example 1-3 | R-3 | 100 | 76 | Rectangular |
| Example 1-4 | R-4 | 90 | 68 | Rectangular |
| Example 1-5 | R-5 | 90 | 78 | Rectangular |
| Example 1-6 | R-6 | 95 | 80 | Rectangular |
| Example 1-7 | R-7 | 90 | 72 | Rectangular |
| Example 1-8 | R-8 | 90 | 115 | Rectangular |
| Example 1-9 | R-9 | 90 | 133 | Rectangular |
| Example 1-10 | R-10 | 90 | 140 | Rectangular |
| Example 1-11 | R-11 | 90 | 130 | Rectangular |
| Example 1-12 | R-12 | 90 | 138 | Rectangular |
| Comparative | CR-1 | 100 | — | Line pattern |
| Example 1-1 | | | | was lost |

From the results shown in Table 2, it was shown that, by using a resist material containing, as a base polymer, a polymer in which an acid-labile group containing silicon is copolymerized, a pattern can be formed by the development of the present invention using dry etching (Examples 1-1 to 1-12). In the case of the resist material of Comparative Example 1-1, where a polymer in which an acid-labile group not containing silicon is copolymerized is contained as a base polymer, the film was lost not only in the exposed portions but also in the unexposed portions.

The present description includes the following embodiments.
[1]: A patterning process comprising:
providing a resist material containing a polymer having a silicon-containing acid-labile group;
forming a resist film by using the resist material; and
subjecting the resist film to exposure and baking, and then to development by dry etching to form a pattern.
[2]: The patterning process of [1], wherein the polymer having the silicon-containing acid-labile group has any one or more of repeating units represented by the following general formulae (a1) to (a3),

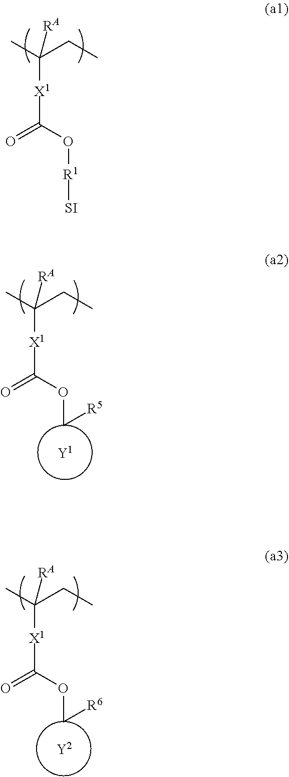

wherein each R^{A} independently represents a hydrogen atom or a methyl group; R¹ represents a linear, branched, or cyclic divalent hydrocarbon group having 1 to 12 carbon atoms and optionally having a trimethylsilyl group or a trimethylsilyloxy group; SI is represented by R²R³R⁴Si and is an organosilicon group containing 1 to 4 silicon atoms; R², R³, and R⁴ each independently represent a trimethylsilyl group, a trimethylsilyloxy group, or a linear, branched, or cyclic monovalent aliphatic hydrocarbon group having 1 to 14 carbon atoms, optionally having a double bond or a triple bond, and optionally having a trimethylsilyl group or a trimethylsilyloxy group; R⁵ represents a linear, branched, or cyclic alkyl group having 1 to 6 carbon atoms and optionally having a silicon atom; R⁶ represents a linear, branched, or cyclic hydrocarbon group having 1 to 6 carbon atoms and having a silicon atom; X¹ represents a single bond, a phenylene group, a naphthylene group, or —C(═O)—R⁷—; R⁷ represents a phenylene group, a naphthylene group, or a linear, branched, or cyclic alkylene group having 1 to 10 carbon atoms and optionally having an oxygen atom, a sulfur atom, or a nitrogen atom; ring Y¹ represents a cyclic organosilicon group having one or more silicon atoms; and ring Y² represents a cyclic organic group not having a silicon atom.
[3]: The patterning process of [2], wherein a resist material containing a polymer having a repeating unit-b having an acid-generating moiety in addition to the one or more of the repeating units is used.
[4]: The patterning process of [3], wherein the repeating unit-b having the acid-generating moiety is any one or more of repeating units selected from repeating units represented by the following formulae (b1) to (b5),

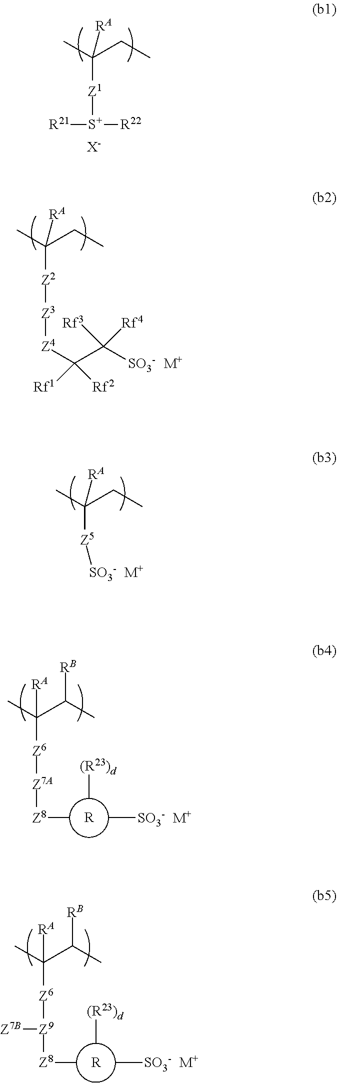

wherein each R^{A} independently represents a hydrogen atom or a methyl group; each R^{B} independently represents a hydrogen atom or is optionally bonded to Z⁶ to form a ring; Z¹ represents a single bond, an aliphatic hydrocarbylene group having 1 to 6 carbon atoms, a phenylene group, a naphthylene group, a group having 7 to 18 carbon atoms derived from a combination of these groups, —O—Z¹¹—, —C(═O)—O—Z¹¹—, or —C(═O)—NH—Z¹¹—; Z¹¹ represents an aliphatic hydrocarbylene group having 1 to 6 carbon atoms, a phenylene group, a naphthylene group, or a group having 7 to 18 carbon atoms derived from a combination of these groups, Z¹¹ optionally containing a carbonyl group, an ester bond, an ether bond, or a hydroxy group; Z² represents a single bond or an ester bond; Z³ represents a single bond, —Z³¹—C(═O)—O—, or —Z³¹—O—; Z³¹ represents a hydrocarbylene group having 1 to 12 carbon atoms, a phenylene group, or a group having 7 to 18 carbon atoms derived from a combination of these groups, Z³¹ optionally containing a carbonyl group, a nitro group, a cyano group, an ester bond, an ether bond, a urethane bond, a fluorine atom, an iodine atom, or a bromine atom; Z⁴ represents a single bond, a methylene group, or an ethylene group; Z⁵ represents a single bond, a methylene group, an ethylene group, a phenylene group, a methylphenylene group, a dimethylphenylene group, a fluorinated phenylene group, a phenylene group substituted with a trifluoromethyl group, —O—Z⁵¹—, —C(═O)—O—Z⁵¹—, or —C(═O)—NH—Z⁵¹—; Z⁵¹ represents an aliphatic hydrocarbylene group having 1 to 6 carbon atoms, a phenylene group, a methylphenylene group, a dimethylphenylene group, a fluorinated phenylene group, or a phenylene group substituted with a trifluoromethyl group, Z⁵¹ optionally containing a carbonyl group, an ester bond, an ether bond, a hydroxy group, or a halogen atom; Z⁶ represents a single bond, a phenylene group, a naphthylene ring, an ester bond, or an amide bond; Z^{7A} represents a single bond or a divalent organic group having 1 to 24 carbon atoms, Z^{7A} optionally having at least one selected from a halogen atom, an oxygen atom, a nitrogen atom, and a sulfur atom; Z^{7B} represents a monovalent organic group having 1 to 10 carbon atoms, Z^{7B} optionally having at least one selected from a halogen atom, an oxygen atom, a nitrogen atom, and a sulfur atom; Z⁸ represents a single bond, an ether bond, an ester bond, a thioether bond, or an alkanediyl group having 1 to 6 carbon atoms; Z⁹ represents a trivalent organic group having 1 to 12 carbon atoms, Z⁹ optionally having at least one selected from an oxygen atom, a nitrogen atom, and a sulfur atom; Rf¹ to Rf⁴ each independently represent a hydrogen atom, a fluorine atom, or a trifluoromethyl group, provided that at least one of Rf¹ to Rf⁴ is a fluorine atom or a trifluoromethyl group, Rf¹ and Rf² optionally being combined to form a carbonyl group together with the carbon atom bonded to Rf¹ and Rf²; R²¹ and R²² each independently represent a halogen atom or a hydrocarbyl group having 1 to 20 carbon atoms and optionally containing a heteroatom; R²³ represents a saturated hydrocarbyl group having 1 to 10 carbon atoms, an aryl group having 6 to 10 carbon atoms, a fluorine atom, an iodine atom, a trifluoromethoxy group, a difluoromethoxy group, a cyano group, or a nitro group; ring R represents a (d+2)-valent aromatic hydrocarbon group having 6 to 10 carbon atoms; “d” represents an integer of 0 to 5; X⁻ represents a non-nucleophilic counter ion; and M⁺ represents a sulfonium cation or an iodonium cation.
[5]: The patterning process of [4], wherein the repeating unit-b having the acid-generating moiety is any one or more repeating units selected from the repeating units represented by the formulae (b2) to (b5) in which the Z³, the Z^{7A}, the Z^{7B}, or the M⁺ contains one or more iodine atoms.
[6]: The patterning process of any one of [1] to [5], wherein the exposure is performed with an extreme ultraviolet ray having a wavelength of 3 to 15 nm.
[7]: The patterning process of any one of [1] to [5], wherein the exposure is performed with an electron beam with an acceleration voltage of 1 to 150 kV.
[8]: A resist material for patterning by dry etching, the resist material comprising a polymer having any one or more of repeating units represented by the following general formulae (a1) to (a3),

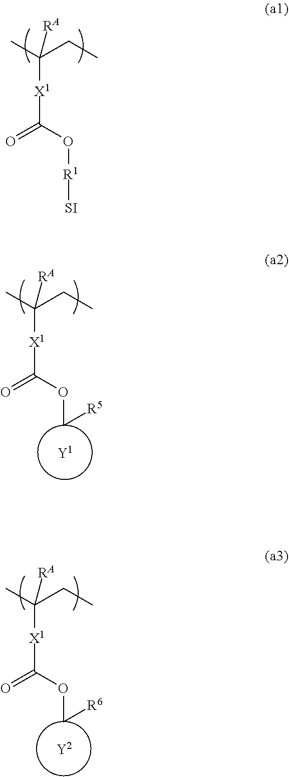

wherein each R^{A} independently represents a hydrogen atom or a methyl group; R¹ represents a linear, branched, or cyclic divalent hydrocarbon group having 1 to 12 carbon atoms and optionally having a trimethylsilyl group or a trimethylsilyloxy group; SI is represented by R²R³R⁴Si and is an organosilicon group containing 1 to 4 silicon atoms; R², R³, and R⁴ each independently represent a trimethylsilyl group, a trimethylsilyloxy group, or a linear, branched, or cyclic monovalent aliphatic hydrocarbon group having 1 to 14 carbon atoms, optionally having a double bond or a triple bond, and optionally having a trimethylsilyl group or a trimethylsilyloxy group; R⁵ represents a linear, branched, or cyclic alkyl group having 1 to 6 carbon atoms and optionally having a silicon atom; R⁶ represents a linear, branched, or cyclic hydrocarbon group having 1 to 6 carbon atoms and having a silicon atom; X¹ represents a single bond, a phenylene group, a naphthylene group, or —C(═O)—R⁷—; R⁷ represents a phenylene group, a naphthylene group, or a linear, branched, or cyclic alkylene group having 1 to 10 carbon atoms and optionally having an oxygen atom, a sulfur atom, or a nitrogen atom; ring Y¹ represents a cyclic organosilicon group having one or more silicon atoms; and ring Y² represents a cyclic organic group not having a silicon atom.
[9]: The resist material of [8], wherein the polymer further has a repeating unit-b having an acid-generating moiety containing one or more iodine atoms.
[10]: The resist material of [8] or [9], wherein the polymer is a copolymer further having any one or more of repeating units selected from repeating units represented by the following formulae (b1) to (b5),

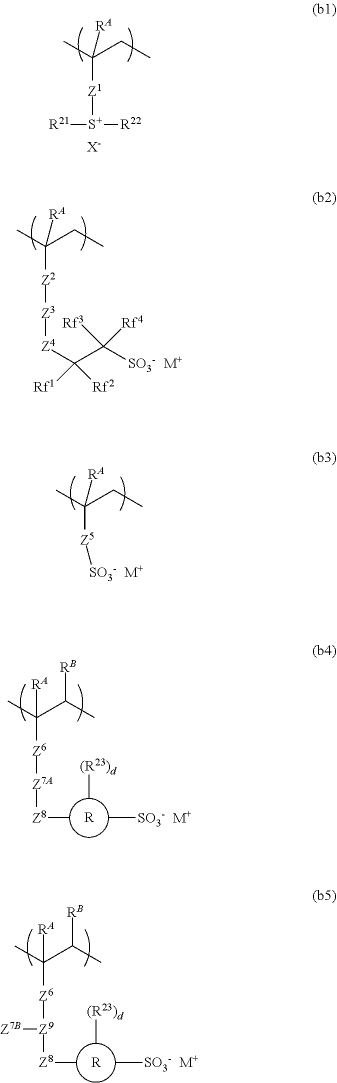

wherein each R^{A} independently represents a hydrogen atom or a methyl group; each R^{B} independently represents a hydrogen atom or is optionally bonded to Z⁶ to form a ring; Z¹ represents a single bond, an aliphatic hydrocarbylene group having 1 to 6 carbon atoms, a phenylene group, a naphthylene group, a group having 7 to 18 carbon atoms derived from a combination of these groups, —O—Z¹¹—, —C(═O)—O—Z¹¹—, or —C(═O)—NH—Z¹¹—, Z¹¹ represents an aliphatic hydrocarbylene group having 1 to 6 carbon atoms, a phenylene group, a naphthylene group, or a group having 7 to 18 carbon atoms derived from a combination of these groups, Z¹¹ optionally containing a carbonyl group, an ester bond, an ether bond, or a hydroxy group; Z² represents a single bond or an ester bond; Z³ represents a single bond, —Z³¹—C(═O)—O—, or —Z³¹—O—; Z³¹ represents a hydrocarbylene group having 1 to 12 carbon atoms, a phenylene group, or a group having 7 to 18 carbon atoms derived from a combination of these groups, Z³¹ optionally containing a carbonyl group, a nitro group, a cyano group, an ester bond, an ether bond, a urethane bond, a fluorine atom, an iodine atom, or a bromine atom; Z⁴ represents a single bond, a methylene group, or an ethylene group; Z⁵ represents a single bond, a methylene group, an ethylene group, a phenylene group, a methylphenylene group, a dimethylphenylene group, a fluorinated phenylene group, a phenylene group substituted with a trifluoromethyl group, —O—Z⁵¹—, —C(═O)—O—Z⁵¹—, or —C(═O)—NH—Z⁵¹—; Z⁵¹ represents an aliphatic hydrocarbylene group having 1 to 6 carbon atoms, a phenylene group, a methylphenylene group, a dimethylphenylene group, a fluorinated phenylene group, or a phenylene group substituted with a trifluoromethyl group, Z⁵¹ optionally containing a carbonyl group, an ester bond, an ether bond, a hydroxy group, or a halogen atom; Z⁶ represents a single bond, a phenylene group, a naphthylene ring, an ester bond, or an amide bond; Z^{7A} represents a single bond or a divalent organic group having 1 to 24 carbon atoms, Z^{7A} optionally having at least one selected from a halogen atom, an oxygen atom, a nitrogen atom, and a sulfur atom; Z^{7B} represents a monovalent organic group having 1 to 10 carbon atoms, Z^{7B} optionally having at least one selected from a halogen atom, an oxygen atom, a nitrogen atom, and a sulfur atom; Z⁸ represents a single bond, an ether bond, an ester bond, a thioether bond, or an alkanediyl group having 1 to 6 carbon atoms; Z⁹ represents a trivalent organic group having 1 to 12 carbon atoms, Z⁹ optionally having at least one selected from an oxygen atom, a nitrogen atom, and a sulfur atom; Rf¹ to Rf⁴ each independently represent a hydrogen atom, a fluorine atom, or a trifluoromethyl group, provided that at least one of Rf¹ to Rf⁴ is a fluorine atom or a trifluoromethyl group, Rf¹ and Rf² optionally being combined to form a carbonyl group together with the carbon atom bonded to Rf¹ and Rf²; R²¹ and R²² each independently represent a halogen atom or a hydrocarbyl group having 1 to 20 carbon atoms and optionally containing a heteroatom; R²³ represents a saturated hydrocarbyl group having 1 to 10 carbon atoms, an aryl group having 6 to 10 carbon atoms, a fluorine atom, an iodine atom, a trifluoromethoxy group, a difluoromethoxy group, a cyano group, or a nitro group; ring R represents a (d+2)-valent aromatic hydrocarbon group having 6 to 10 carbon atoms; “d” represents an integer of 0 to 5; X⁻ represents a non-nucleophilic counter ion; and M⁺ represents a sulfonium cation or an iodonium cation.

It should be noted that the present invention is not limited to the above-described embodiments. The embodiments are just examples, and any examples that have substantially the same feature and demonstrate the same functions and effects as those in the technical concept disclosed in claims of the present invention are included in the technical scope of the present invention.

1. A patterning process comprising:
providing a resist material containing a polymer having a silicon-containing acid-labile group;
forming a resist film by using the resist material; and
subjecting the resist film to exposure and baking, and then to development by dry etching to form a pattern.

2. The patterning process according to claim 1, wherein the polymer having the silicon-containing acid-labile group has any one or more of repeating units represented by the following general formulae (a1) to (a3), 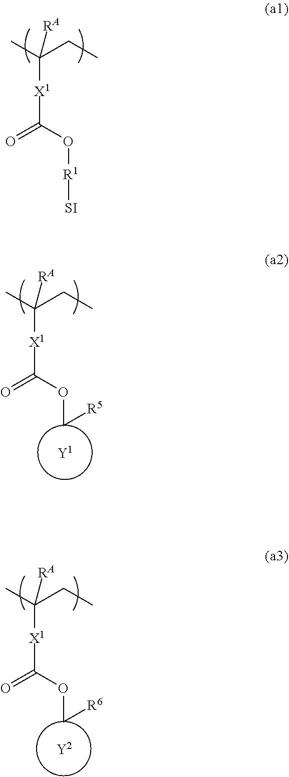
wherein each R^{A} independently represents a hydrogen atom or a methyl group; R¹ represents a linear, branched, or cyclic divalent hydrocarbon group having 1 to 12 carbon atoms and optionally having a trimethylsilyl group or a trimethylsilyloxy group; SI is represented by R²R³R⁴Si and is an organosilicon group containing 1 to 4 silicon atoms; R², R³, and R⁴ each independently represent a trimethylsilyl group, a trimethylsilyloxy group, or a linear, branched, or cyclic monovalent aliphatic hydrocarbon group having 1 to 14 carbon atoms, optionally having a double bond or a triple bond, and optionally having a trimethylsilyl group or a trimethylsilyloxy group; R⁵ represents a linear, branched, or cyclic alkyl group having 1 to 6 carbon atoms and optionally having a silicon atom; R⁶ represents a linear, branched, or cyclic hydrocarbon group having 1 to 6 carbon atoms and having a silicon atom; X¹ represents a single bond, a phenylene group, a naphthylene group, or —C(═O)—R⁷—; R⁷ represents a phenylene group, a naphthylene group, or a linear, branched, or cyclic alkylene group having 1 to 10 carbon atoms and optionally having an oxygen atom, a sulfur atom, or a nitrogen atom; ring Y¹ represents a cyclic organosilicon group having one or more silicon atoms; and ring Y² represents a cyclic organic group not having a silicon atom.

3. The patterning process according to claim 2, wherein a resist material containing a polymer having a repeating unit-b having an acid-generating moiety in addition to the one or more of the repeating units is used.

4. The patterning process according to claim 3, wherein the repeating unit-b having the acid-generating moiety is any one or more of repeating units selected from repeating units represented by the following formulae (b1) to (b5), 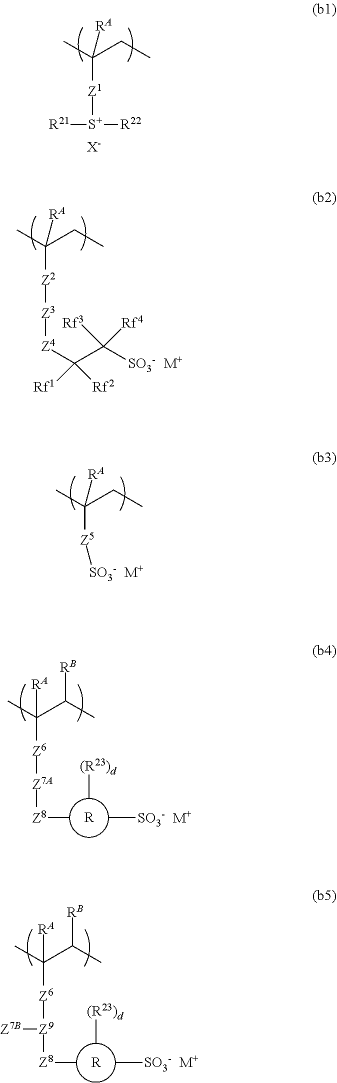
wherein each R^{A} independently represents a hydrogen atom or a methyl group; each R^{B} independently represents a hydrogen atom or is optionally bonded to Z⁶ to form a ring; Z¹ represents a single bond, an aliphatic hydrocarbylene group having 1 to 6 carbon atoms, a phenylene group, a naphthylene group, a group having 7 to 18 carbon atoms derived from a combination of these groups, —O—Z¹¹—, —C(═O)—O—Z¹¹—, or —C(═O)—NH—Z¹¹—; Z¹¹ represents an aliphatic hydrocarbylene group having 1 to 6 carbon atoms, a phenylene group, a naphthylene group, or a group having 7 to 18 carbon atoms derived from a combination of these groups, Z¹¹ optionally containing a carbonyl group, an ester bond, an ether bond, or a hydroxy group; Z² represents a single bond or an ester bond; Z³ represents a single bond, —Z³¹—C(═O)—O—, or —Z³¹—O—; Z³¹ represents a hydrocarbylene group having 1 to 12 carbon atoms, a phenylene group, or a group having 7 to 18 carbon atoms derived from a combination of these groups, Z³¹ optionally containing a carbonyl group, a nitro group, a cyano group, an ester bond, an ether bond, a urethane bond, a fluorine atom, an iodine atom, or a bromine atom; Z⁴ represents a single bond, a methylene group, or an ethylene group; Z⁵ represents a single bond, a methylene group, an ethylene group, a phenylene group, a methylphenylene group, a dimethylphenylene group, a fluorinated phenylene group, a phenylene group substituted with a trifluoromethyl group, —O—Z⁵¹—, —C(═O)—O—Z⁵¹—, or —C(═O)—NH—Z⁵¹—; Z⁵¹ represents an aliphatic hydrocarbylene group having 1 to 6 carbon atoms, a phenylene group, a methylphenylene group, a dimethylphenylene group, a fluorinated phenylene group, or a phenylene group substituted with a trifluoromethyl group, Z⁵¹ optionally containing a carbonyl group, an ester bond, an ether bond, a hydroxy group, or a halogen atom; Z⁶ represents a single bond, a phenylene group, a naphthylene ring, an ester bond, or an amide bond; Z^{7A} represents a single bond or a divalent organic group having 1 to 24 carbon atoms, Z^{7A} optionally having at least one selected from a halogen atom, an oxygen atom, a nitrogen atom, and a sulfur atom; Z^{7B} represents a monovalent organic group having 1 to 10 carbon atoms, Z^{7B} optionally having at least one selected from a halogen atom, an oxygen atom, a nitrogen atom, and a sulfur atom; Z⁸ represents a single bond, an ether bond, an ester bond, a thioether bond, or an alkanediyl group having 1 to 6 carbon atoms; Z⁹ represents a trivalent organic group having 1 to 12 carbon atoms, Z⁹ optionally having at least one selected from an oxygen atom, a nitrogen atom, and a sulfur atom; Rf¹ to Rf⁴ each independently represent a hydrogen atom, a fluorine atom, or a trifluoromethyl group, provided that at least one of Rf¹ to Rf⁴ is a fluorine atom or a trifluoromethyl group, Rf¹ and Rf² optionally being combined to form a carbonyl group together with the carbon atom bonded to Rf¹ and Rf²; R²¹ and R²² each independently represent a halogen atom or a hydrocarbyl group having 1 to 20 carbon atoms and optionally containing a heteroatom; R²³ represents a saturated hydrocarbyl group having 1 to 10 carbon atoms, an aryl group having 6 to 10 carbon atoms, a fluorine atom, an iodine atom, a trifluoromethoxy group, a difluoromethoxy group, a cyano group, or a nitro group; ring R represents a (d+2)-valent aromatic hydrocarbon group having 6 to 10 carbon atoms; “d” represents an integer of 0 to 5; X⁻ represents a non-nucleophilic counter ion; and M⁺ represents a sulfonium cation or an iodonium cation.

5. The patterning process according to claim 4, wherein the repeating unit-b having the acid-generating moiety is any one or more repeating units selected from the repeating units represented by the formulae (b2) to (b5) in which the Z³, the Z^{7A}, the Z^{7B}, or the M⁺ contains one or more iodine atoms.

6. The patterning process according to claim 1, wherein the exposure is performed with an extreme ultraviolet ray having a wavelength of 3 to 15 nm.

7. The patterning process according to claim 1, wherein the exposure is performed with an electron beam with an acceleration voltage of 1 to 150 kV.

8. A resist material for patterning by dry etching, the resist material comprising a polymer having any one or more of repeating units represented by the following general formulae (a1) to (a3), 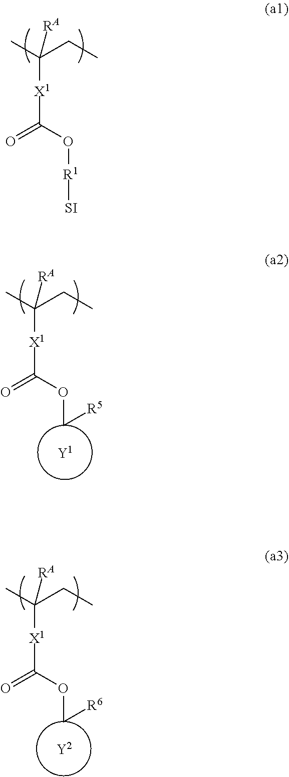
wherein each R^{A} independently represents a hydrogen atom or a methyl group; R¹ represents a linear, branched, or cyclic divalent hydrocarbon group having 1 to 12 carbon atoms and optionally having a trimethylsilyl group or a trimethylsilyloxy group; SI is represented by R²R³R⁴Si and is an organosilicon group containing 1 to 4 silicon atoms; R², R³, and R⁴ each independently represent a trimethylsilyl group, a trimethylsilyloxy group, or a linear, branched, or cyclic monovalent aliphatic hydrocarbon group having 1 to 14 carbon atoms, optionally having a double bond or a triple bond, and optionally having a trimethylsilyl group or a trimethylsilyloxy group; R⁵ represents a linear, branched, or cyclic alkyl group having 1 to 6 carbon atoms and optionally having a silicon atom; R⁶ represents a linear, branched, or cyclic hydrocarbon group having 1 to 6 carbon atoms and having a silicon atom; X¹ represents a single bond, a phenylene group, a naphthylene group, or —C(═O)—R⁷—; R⁷ represents a phenylene group, a naphthylene group, or a linear, branched, or cyclic alkylene group having 1 to 10 carbon atoms and optionally having an oxygen atom, a sulfur atom, or a nitrogen atom; ring Y¹ represents a cyclic organosilicon group having one or more silicon atoms; and ring Y² represents a cyclic organic group not having a silicon atom.

9. The resist material according to claim 8, wherein the polymer further has a repeating unit-b having an acid-generating moiety containing one or more iodine atoms.

10. The resist material according to claim 8, wherein the polymer is a copolymer further having any one or more of repeating units selected from repeating units represented by the following formulae (b1) to (b5), 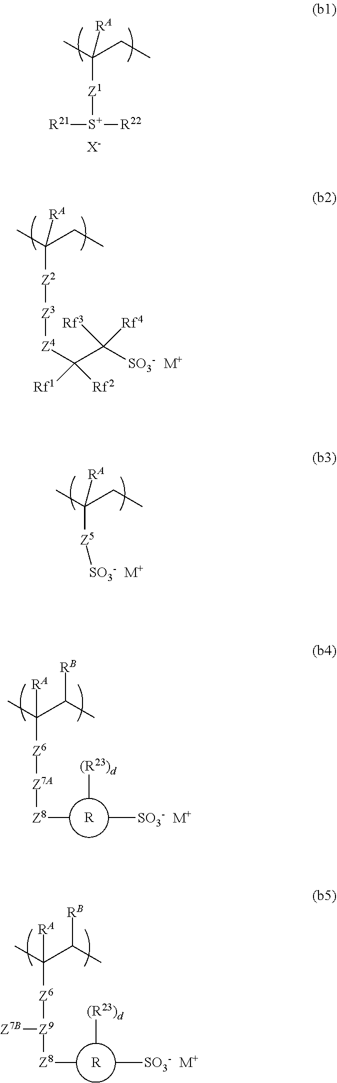
wherein each R^{A} independently represents a hydrogen atom or a methyl group; each R^{B} independently represents a hydrogen atom or is optionally bonded to Z⁶ to form a ring; Z¹ represents a single bond, an aliphatic hydrocarbylene group having 1 to 6 carbon atoms, a phenylene group, a naphthylene group, a group having 7 to 18 carbon atoms derived from a combination of these groups, —O—Z¹¹—, —C(═O)—O—Z¹¹—, or —C(═O)—NH—Z¹¹—; Z¹¹ represents an aliphatic hydrocarbylene group having 1 to 6 carbon atoms, a phenylene group, a naphthylene group, or a group having 7 to 18 carbon atoms derived from a combination of these groups, Z¹¹ optionally containing a carbonyl group, an ester bond, an ether bond, or a hydroxy group; Z² represents a single bond or an ester bond; Z³ represents a single bond, —Z³¹—C(═O)—O—, or —Z³¹—O—; Z³¹ represents a hydrocarbylene group having 1 to 12 carbon atoms, a phenylene group, or a group having 7 to 18 carbon atoms derived from a combination of these groups, Z³¹ optionally containing a carbonyl group, a nitro group, a cyano group, an ester bond, an ether bond, a urethane bond, a fluorine atom, an iodine atom, or a bromine atom; Z⁴ represents a single bond, a methylene group, or an ethylene group; Z⁵ represents a single bond, a methylene group, an ethylene group, a phenylene group, a methylphenylene group, a dimethylphenylene group, a fluorinated phenylene group, a phenylene group substituted with a trifluoromethyl group, —O—Z⁵¹—, —C(═O)—O—Z⁵¹—, or —C(═O)—NH—Z⁵¹—; Z⁵¹ represents an aliphatic hydrocarbylene group having 1 to 6 carbon atoms, a phenylene group, a methylphenylene group, a dimethylphenylene group, a fluorinated phenylene group, or a phenylene group substituted with a trifluoromethyl group, Z⁵¹ optionally containing a carbonyl group, an ester bond, an ether bond, a hydroxy group, or a halogen atom; Z⁶ represents a single bond, a phenylene group, a naphthylene ring, an ester bond, or an amide bond; Z^{7A} represents a single bond or a divalent organic group having 1 to 24 carbon atoms, Z^{7A} optionally having at least one selected from a halogen atom, an oxygen atom, a nitrogen atom, and a sulfur atom; Z^{7B} represents a monovalent organic group having 1 to 10 carbon atoms, Z^{7B} optionally having at least one selected from a halogen atom, an oxygen atom, a nitrogen atom, and a sulfur atom; Z⁸ represents a single bond, an ether bond, an ester bond, a thioether bond, or an alkanediyl group having 1 to 6 carbon atoms; Z⁹ represents a trivalent organic group having 1 to 12 carbon atoms, Z⁹ optionally having at least one selected from an oxygen atom, a nitrogen atom, and a sulfur atom; Rf¹ to Rf⁴ each independently represent a hydrogen atom, a fluorine atom, or a trifluoromethyl group, provided that at least one of Rf¹ to Rf⁴ is a fluorine atom or a trifluoromethyl group, Rf¹ and Rf² optionally being combined to form a carbonyl group together with the carbon atom bonded to Rf¹ and Rf²; R²¹ and R²² each independently represent a halogen atom or a hydrocarbyl group having 1 to 20 carbon atoms and optionally containing a heteroatom; R²³ represents a saturated hydrocarbyl group having 1 to 10 carbon atoms, an aryl group having 6 to 10 carbon atoms, a fluorine atom, an iodine atom, a trifluoromethoxy group, a difluoromethoxy group, a cyano group, or a nitro group; ring R represents a (d+2)-valent aromatic hydrocarbon group having 6 to 10 carbon atoms; “d” represents an integer of 0 to 5; X⁻ represents a non-nucleophilic counter ion; and M⁺ represents a sulfonium cation or an iodonium cation.
